(19) United States
(12) Patent Application Publication
(10) Pub. No.: US 2026/0173642 A1
(43) Pub. Date: Jun. 18, 2026

(54) ORGANIC METAL COMPOUND, ORGANIC ELECTROLUMINESCENT DEVICE CONTAINING SAME AND APPLICATIONS

(71) Applicant: JILIN OLED OPTICAL AND ELECTRONIC MATERIALS CO., LTD., Changchun, Jilin (CN)

(72) Inventors: Hui WANG, Changchun, Jilin (CN); Jianhang LI, Changchun, Jilin (CN)

(21) Appl. No.: 19/128,606

(22) PCT Filed: Apr. 25, 2023
(86) PCT No.: PCT/CN2023/090504

§ 371 Date: May 9, 2025

(30) Foreign Application Priority Data
Nov. 9, 2022 (CN) 202211398553.8

(51) Int. Cl. H10K 50/12; C07F 15/00; C09K 11/06; H10K 85/30; H10K 85/60

(52) U.S. Cl. CPC H10K 50/12; C07F 15/0033; C09K 11/06; H10K 85/342; H10K 85/626; H10K 85/631; H10K 85/654; H10K 85/6572; H10K 85/6574; C09K 2211/185

(57) ABSTRACT

An organic metallic compound, an organic electroluminescent device containing same and applications thereof are provided. The structural formula of the organic metal compound is Ir (L₁)ₘ (L₂)ₙ. m is 2, n is 1, L₁ and L₂ are both ligands.

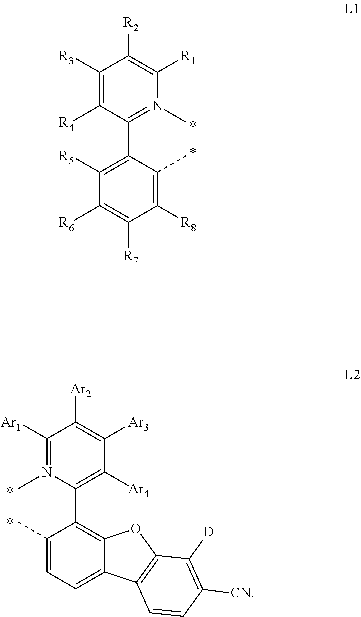

### TECHNICAL FIELD

The present disclosure belongs to the technical field of organic optoelectronic materials, specifically relates to an organic metal compound, organic electroluminescent device containing and applications.

### BACKGROUND

Organic electroluminescence technology is the latest generation of flat panel display technology, in organic luminescence, since the discovery of the phenomenon of phosphorescence, it's been admired by everyone. As the luminous efficiency of phosphorescent materials is significantly higher than the fluorescent luminous efficiency, theoretically speaking, the luminous efficiency can reach 100%, so many scientific research institutions are increasing the research and development of phosphorescent materials, trying to accelerate the industrialization through phosphorescent materials.

However, in current technology, some of the phosphorescent materials have low efficiency and short life when applied in organic light emitting devices. Therefore, how to provide an organic electroluminescent material with long life, high efficiency, and low driving voltage has become a pressing problem for those skilled in the art.

### SUMMARY

In view of the above, the present disclosure provides an organic metal compound, aims to solve the problems of reduced efficiency, poor stability, and short lifespan of existing light-emitting devices.

In order to achieve the above purposes, for the first object, the present disclosure provides an organic metal compound. The present disclosure provides the following technical solutions: An organic metal compound, the structural formula of the organic metal compound is Ir (L₁)ₘ(L₂)ₙ; wherein both L₁ and L₂ are ligands, which are respectively:

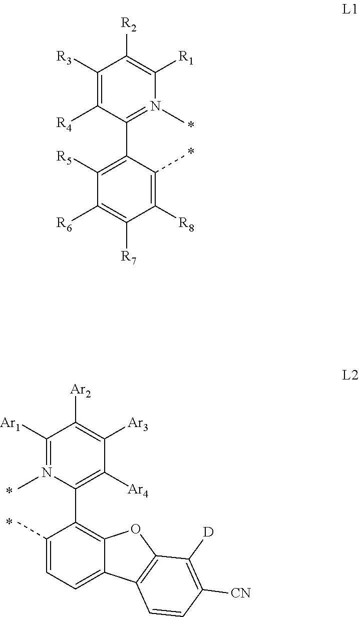

Wherein, the * is the linking key;
R₁-R₈ are each independently selected from —H, -D, -T, —F, —CN, —CH₃, —CD₃, —CT₃, —CF₃, —CH₂F, —CHF₂, substituted or unsubstituted C₂-C₆ alkyl, substituted or unsubstituted C₆-C₁₀ aryl.

Ar₁-Ar₄ are each independently selected from —H, -D, -T, —F, —CN, —CH₃, —CD₃, —CT₃, —CF₃, —CH₂F, —CHF₂, substituted or unsubstituted C₂-C₆ alkyl.

Further, the alkyl groups in R₁-R₈ and Ar₁-Ar₄ are each independently selected from one of substituted or unsubstituted straight-chain alkyl, substituted or unsubstituted branched-chain alkyl, and substituted or unsubstituted cycloalkyl.

It should be noted that the organic metal compounds provided by the present disclosure are capable of modulating the electrochemical properties of the compounds through the combination of deuterated and cyano groups at specific positions of specific heterocyclic ligands. When the obtained organic metallic complexes are applied to organic electroluminescent devices, it results in improved luminescence efficiency, increased lifespan and reduced driving voltage of the devices.

Still further, the organic metal compound is any one of the following structures, but it's not limited to that:

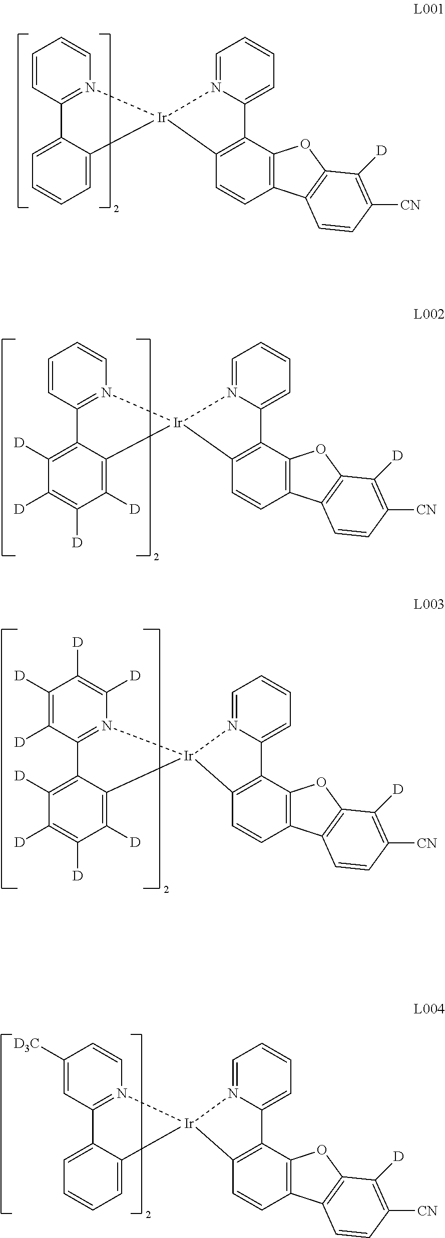

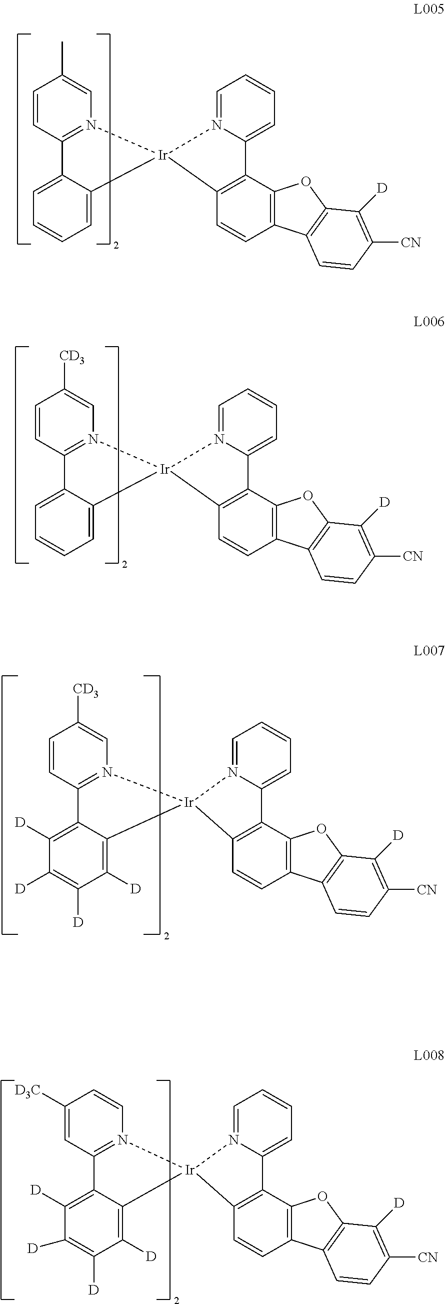

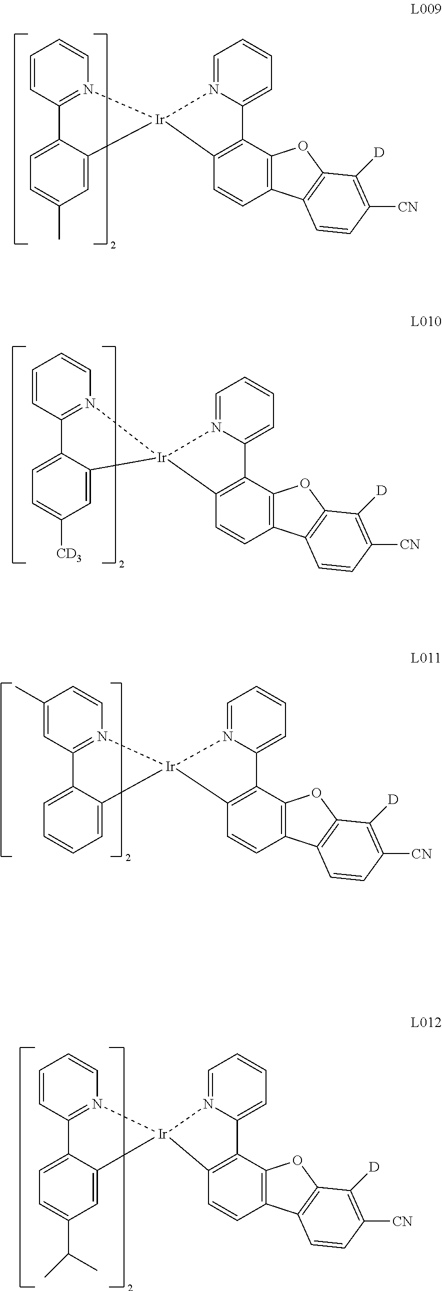

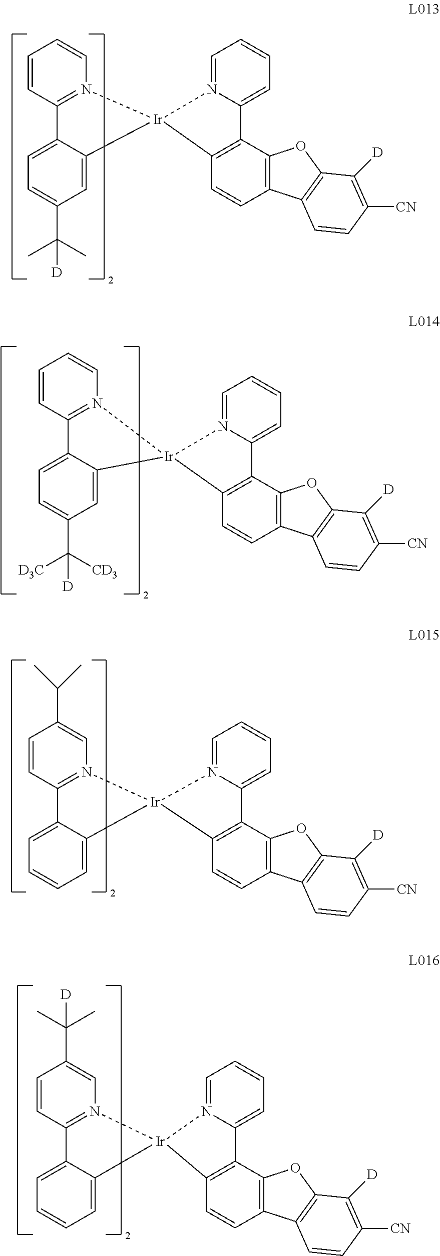

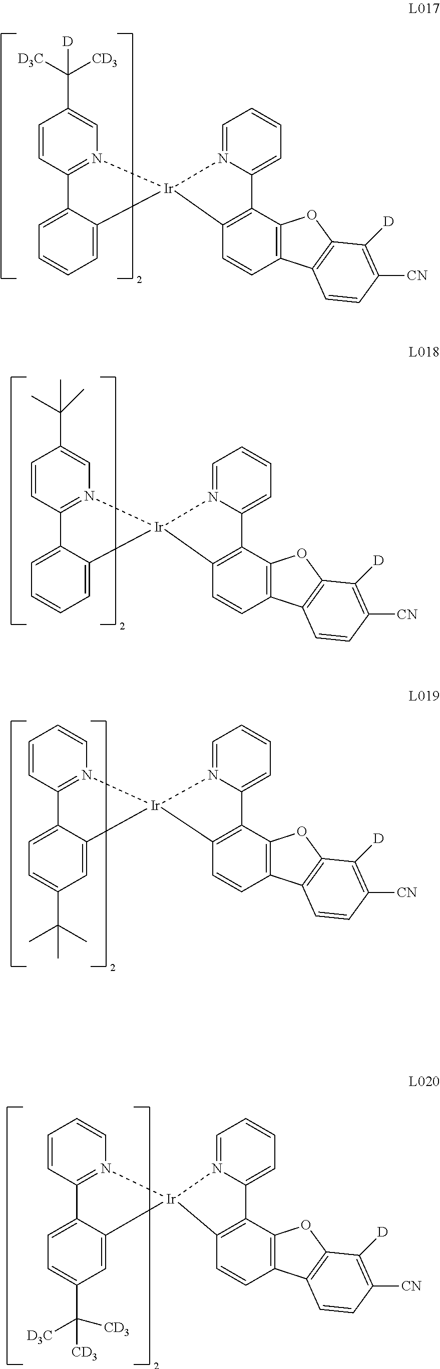

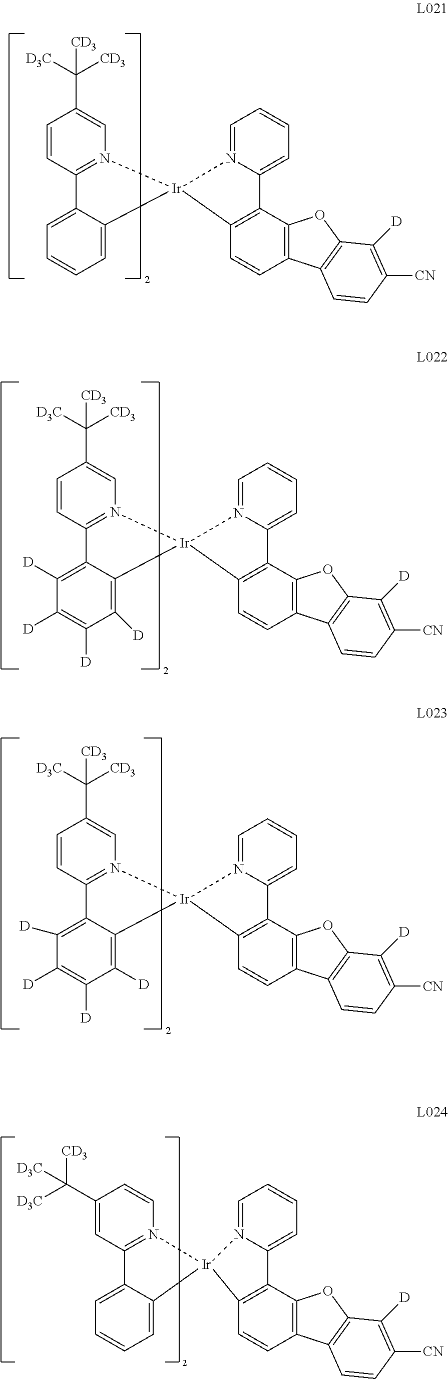

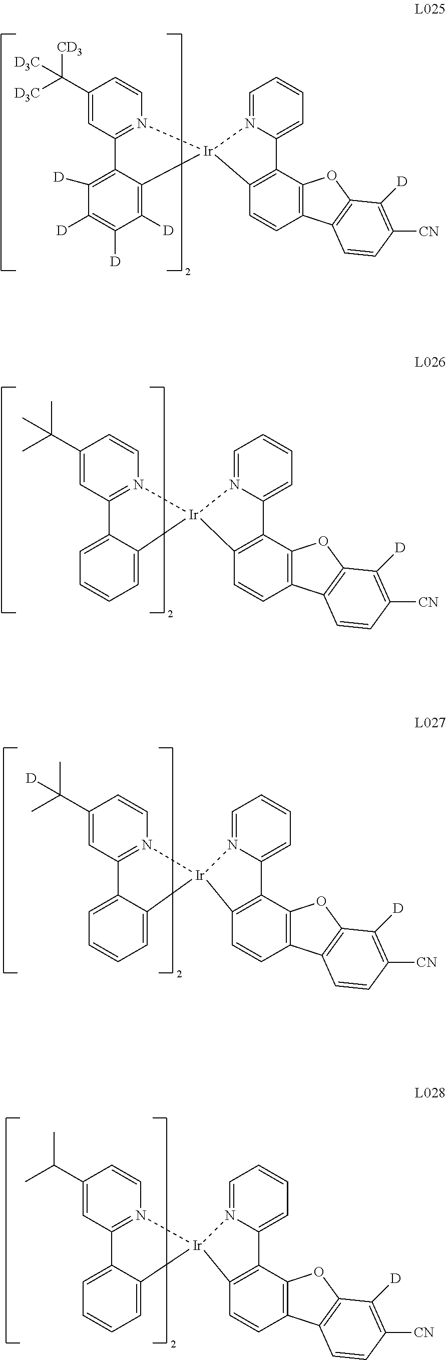

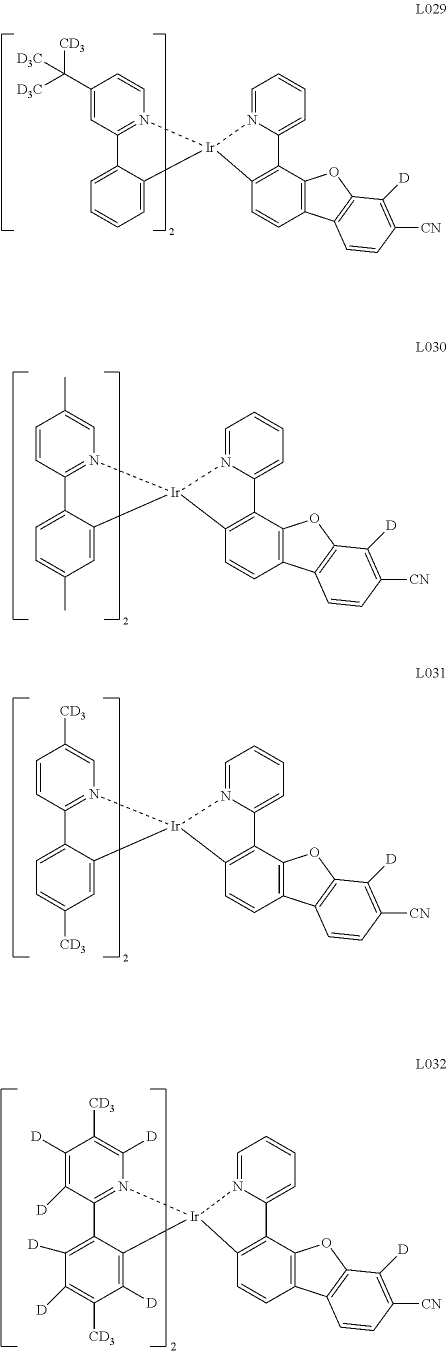

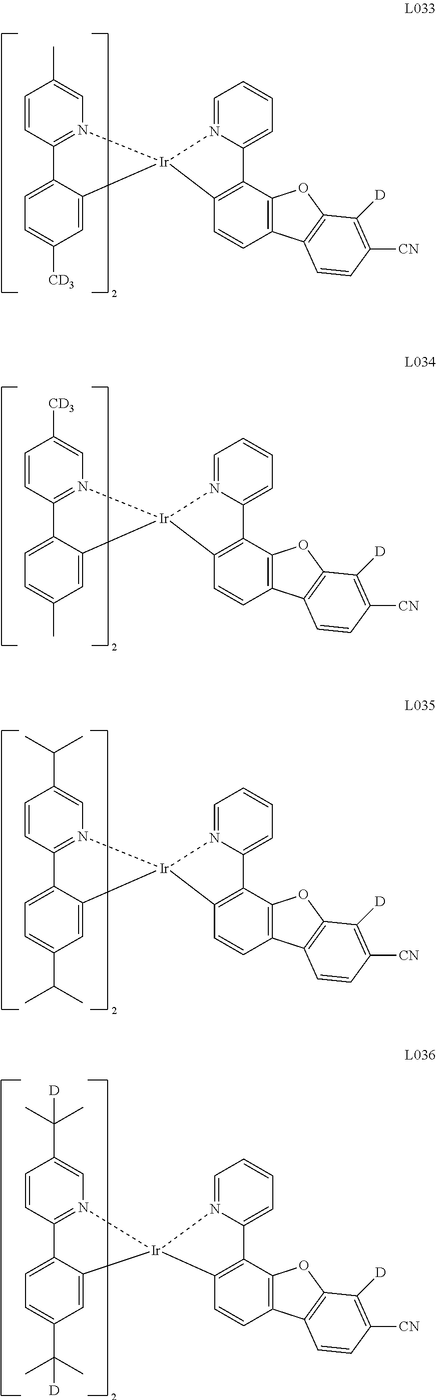

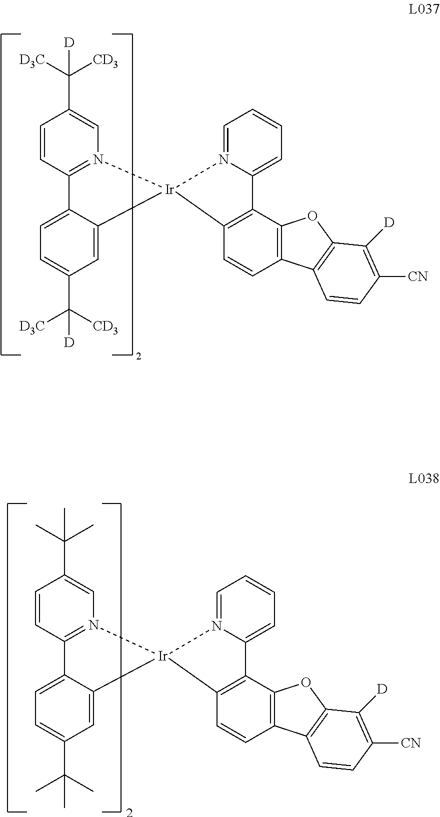

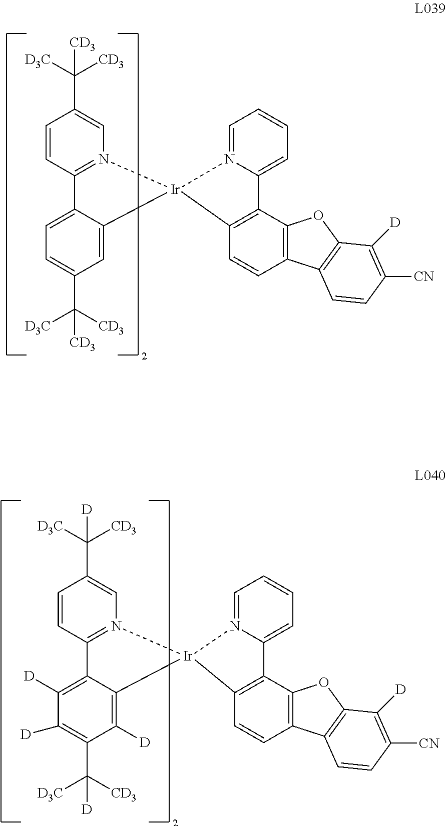

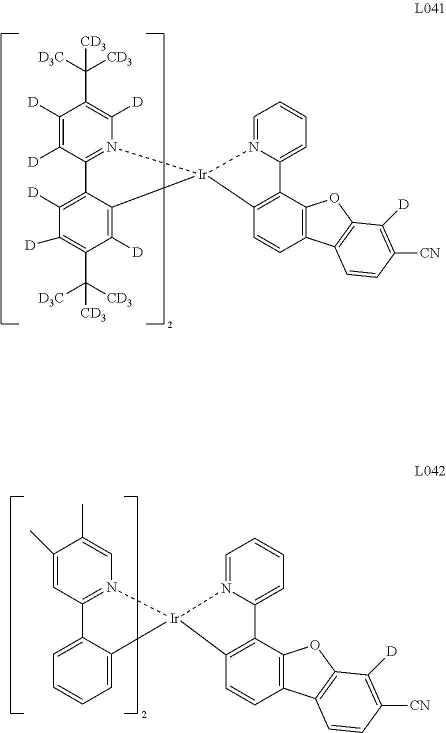

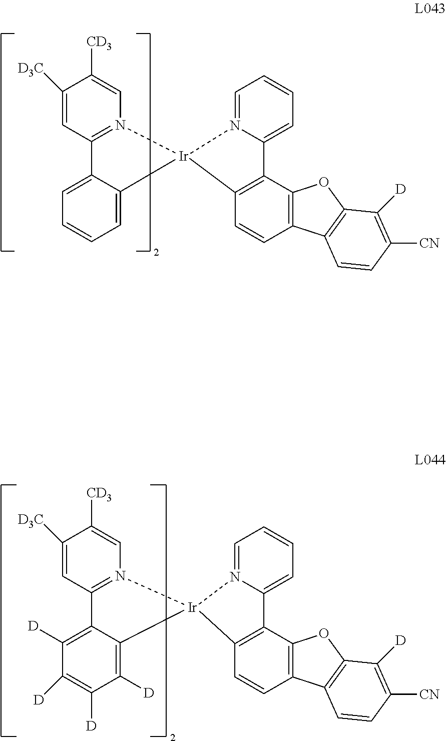

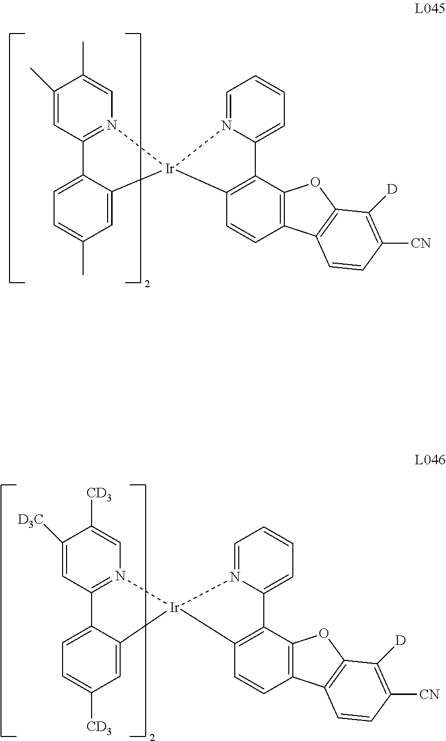

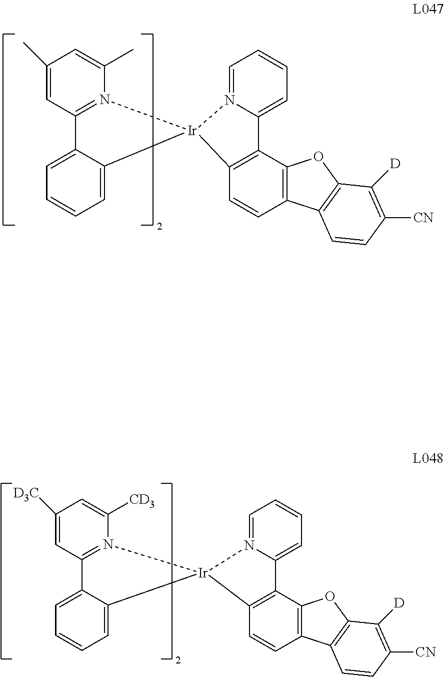

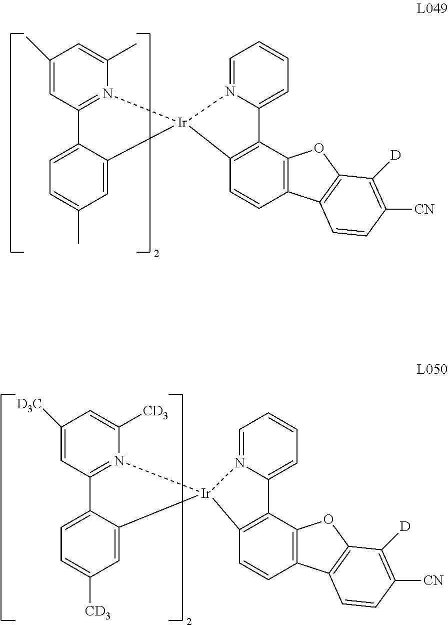

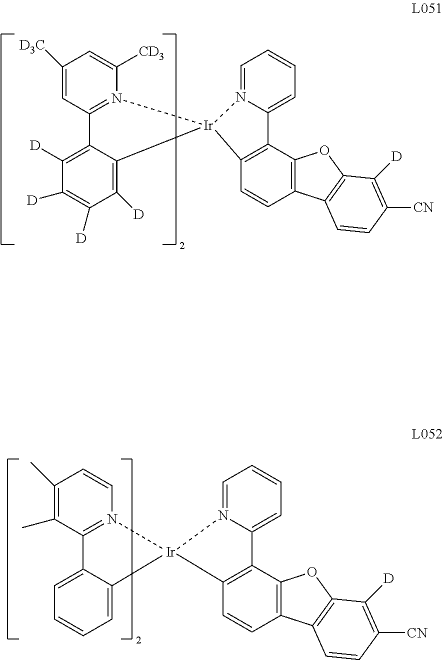

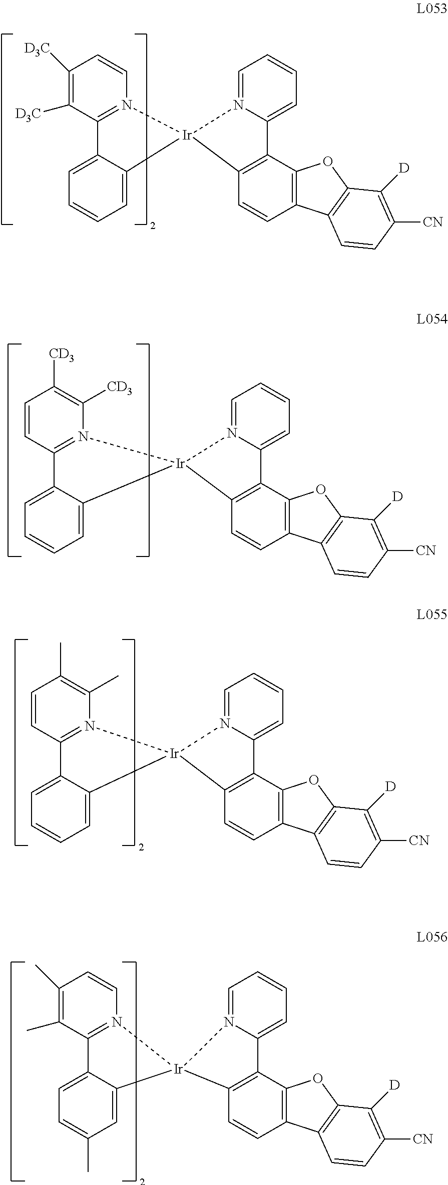

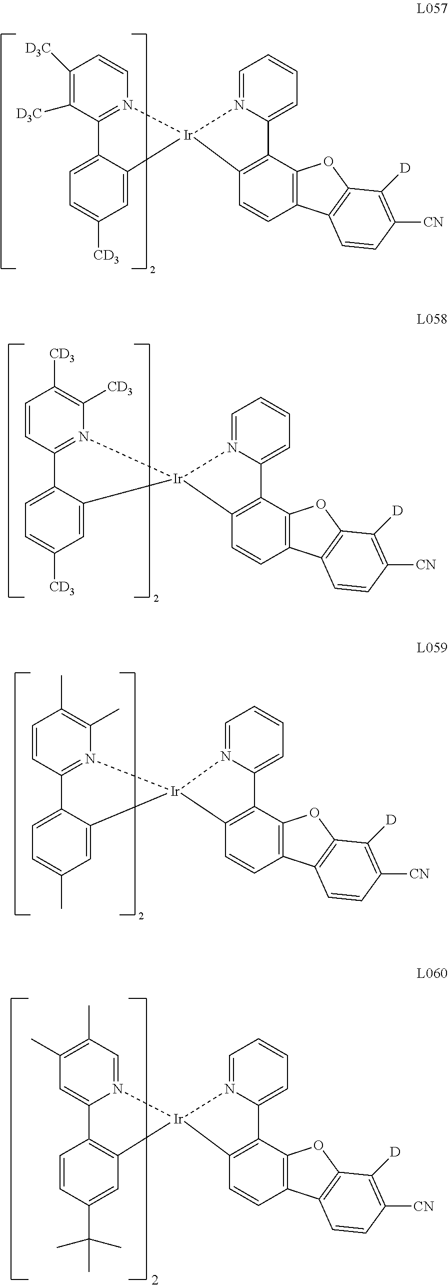

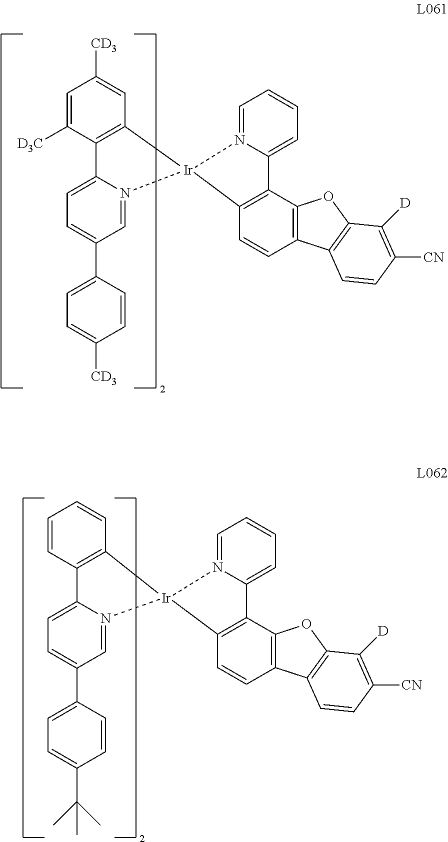

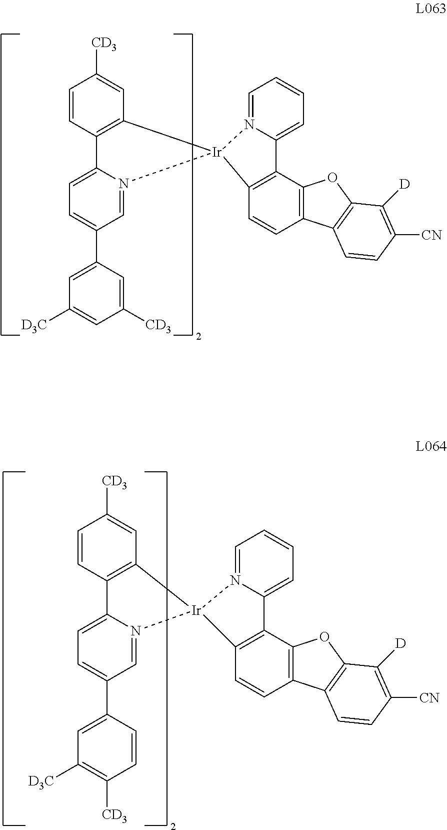

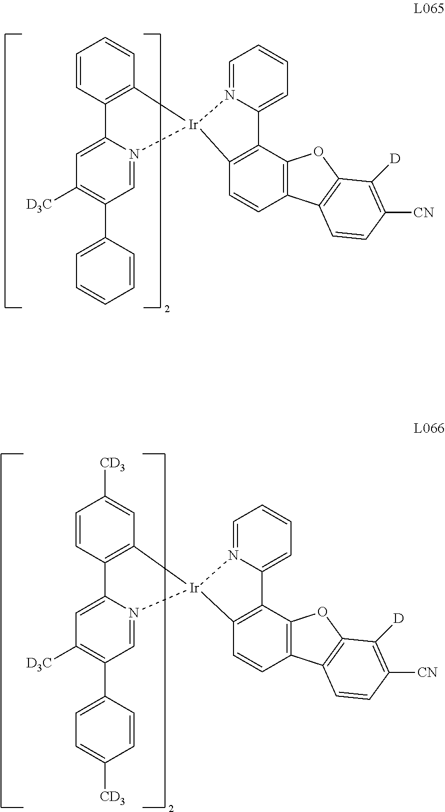

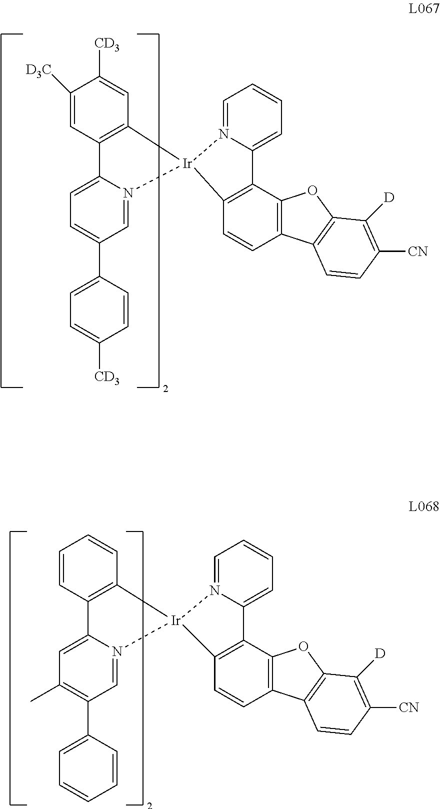

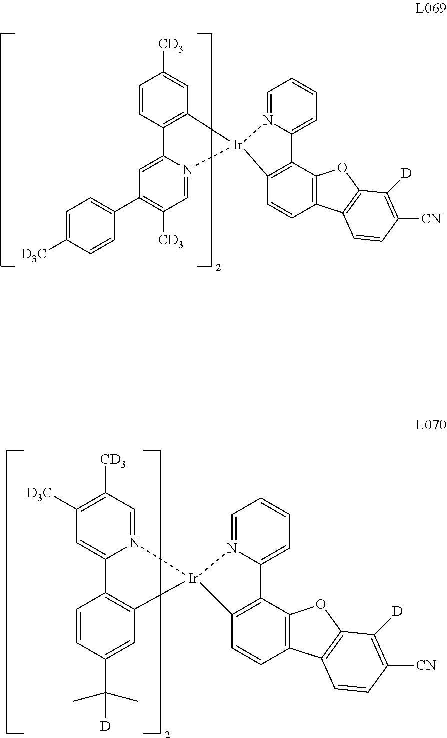

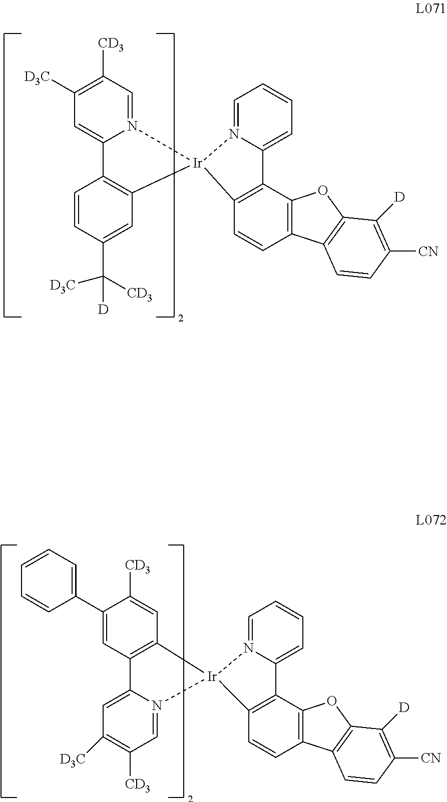

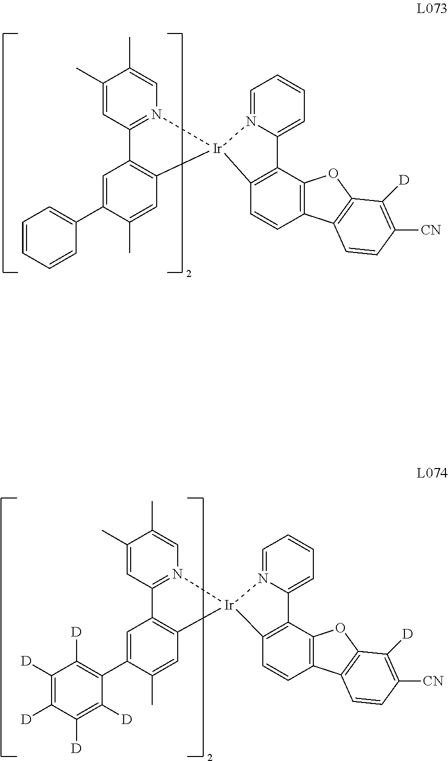

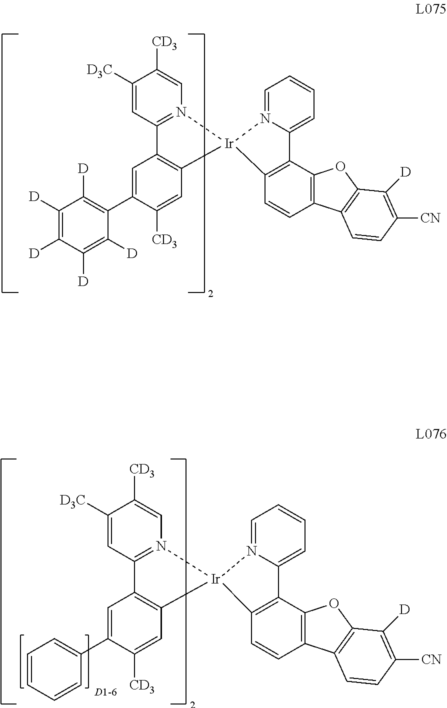

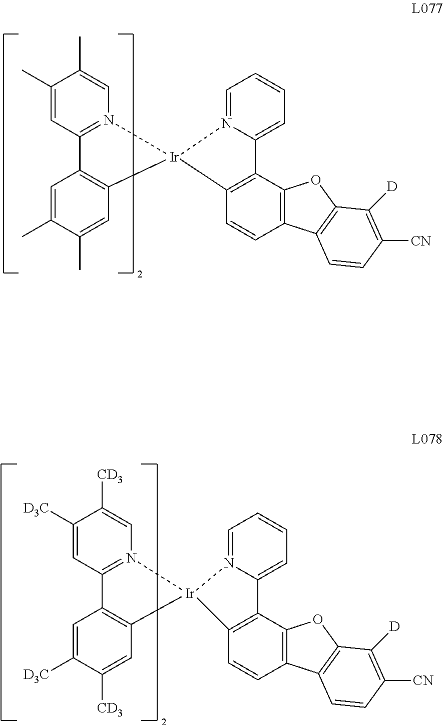

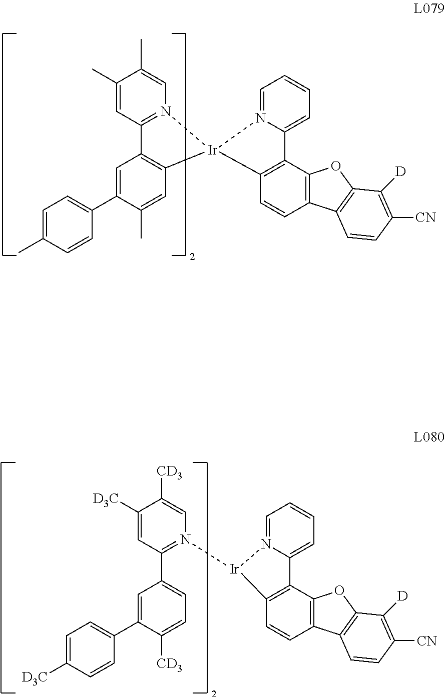

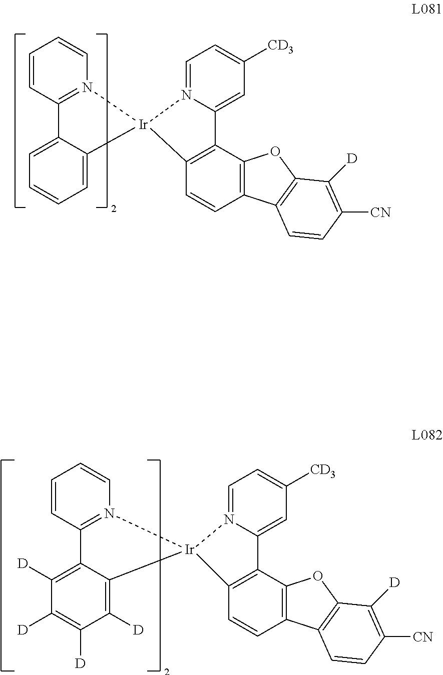

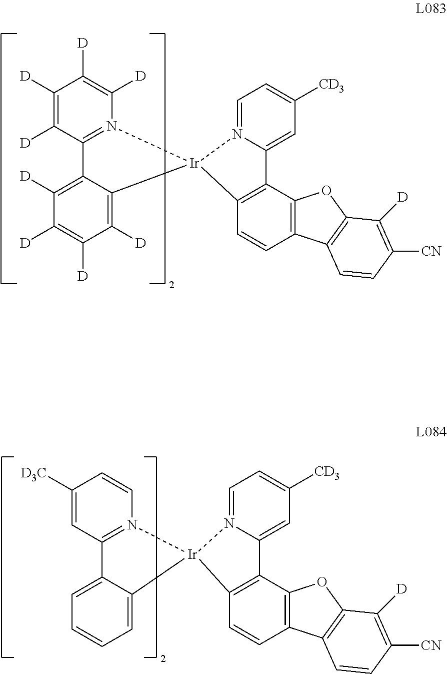

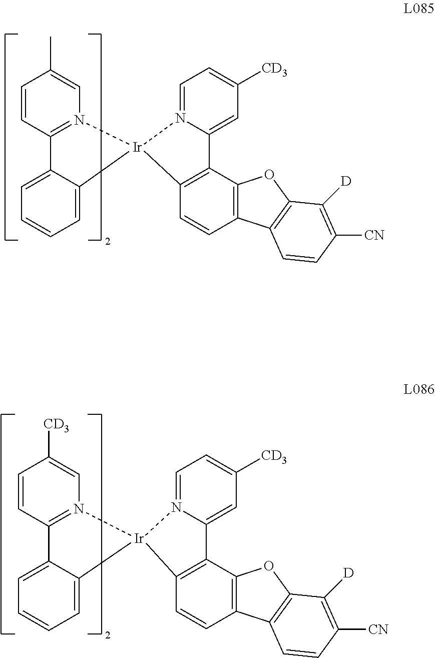

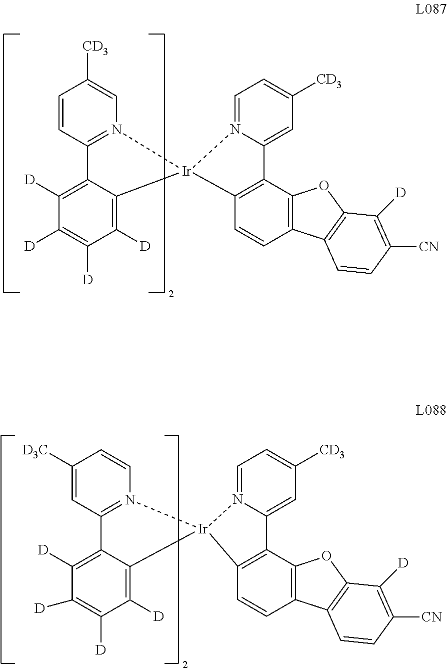

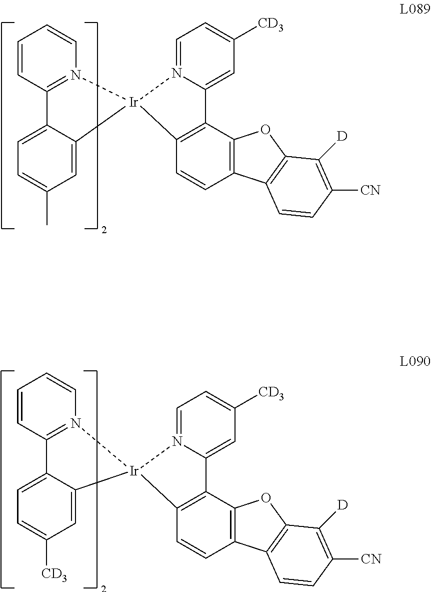

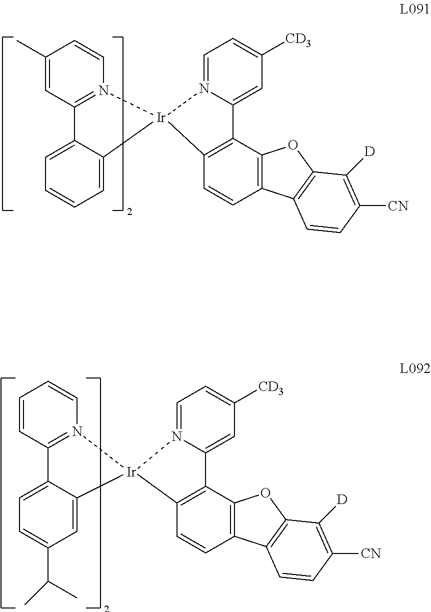

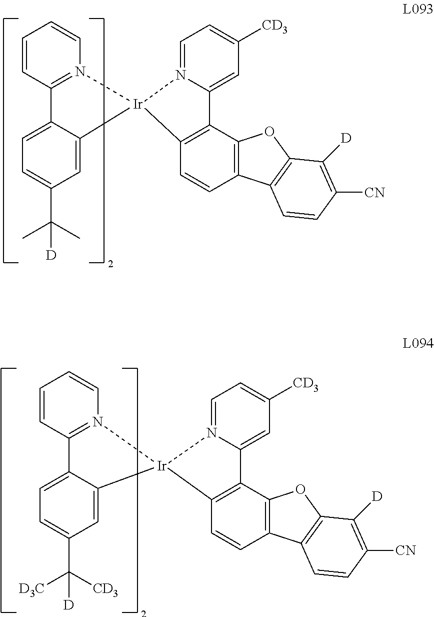

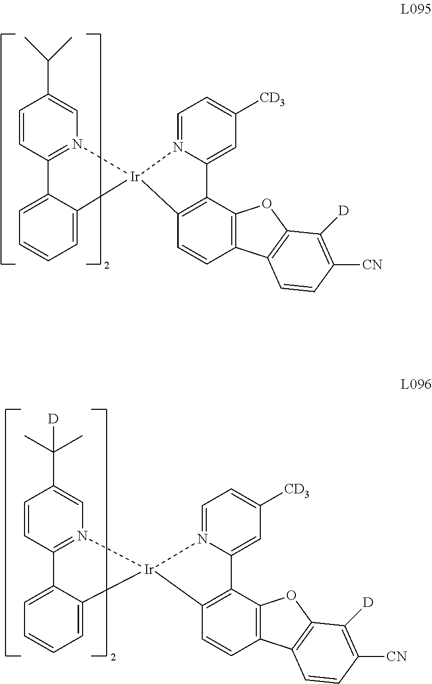

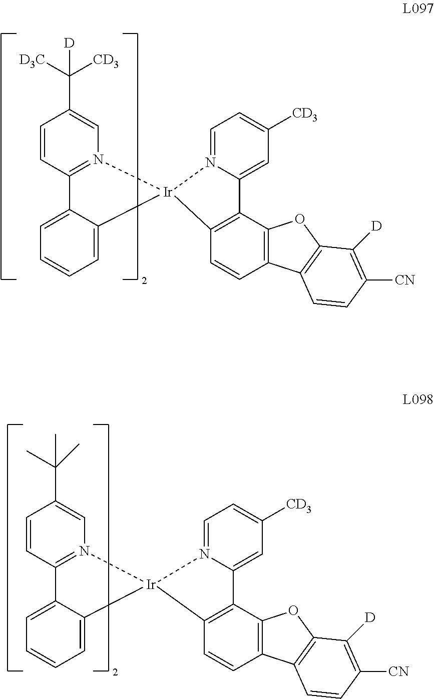

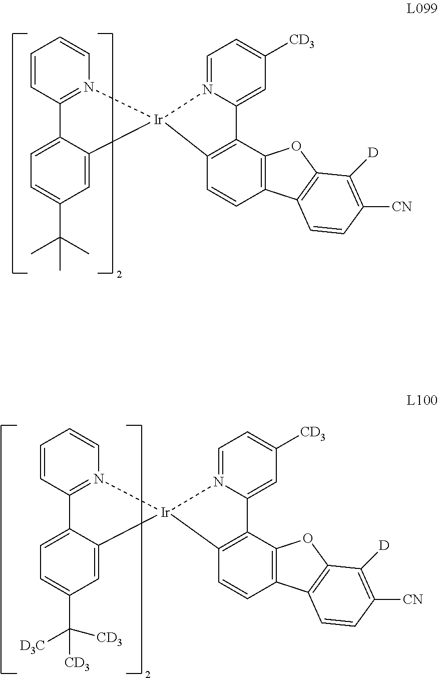

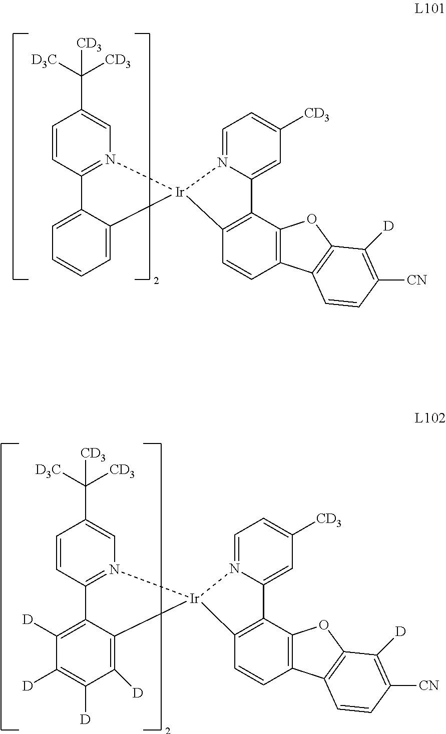

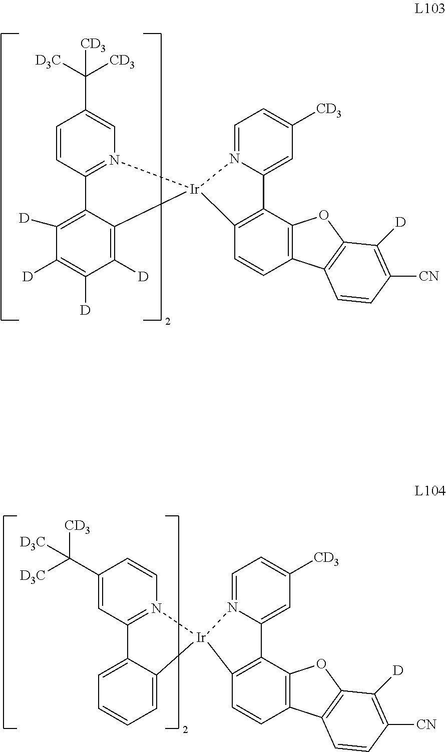

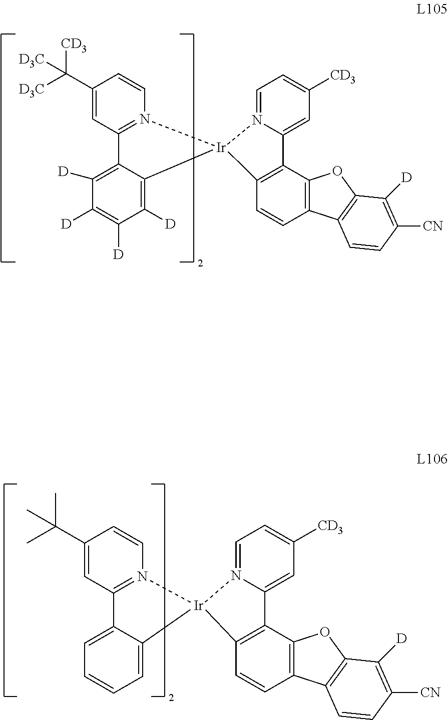

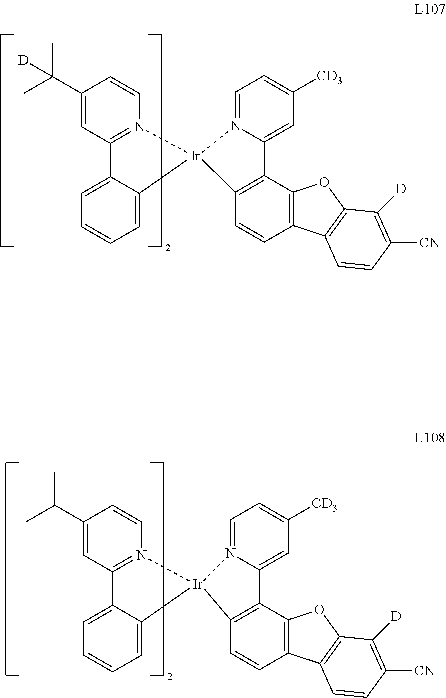

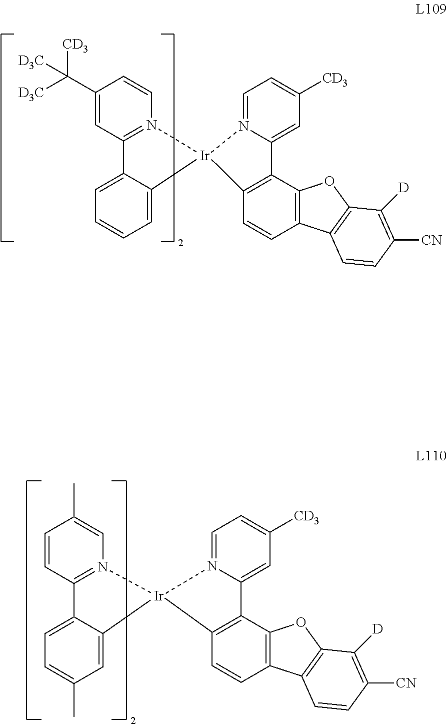

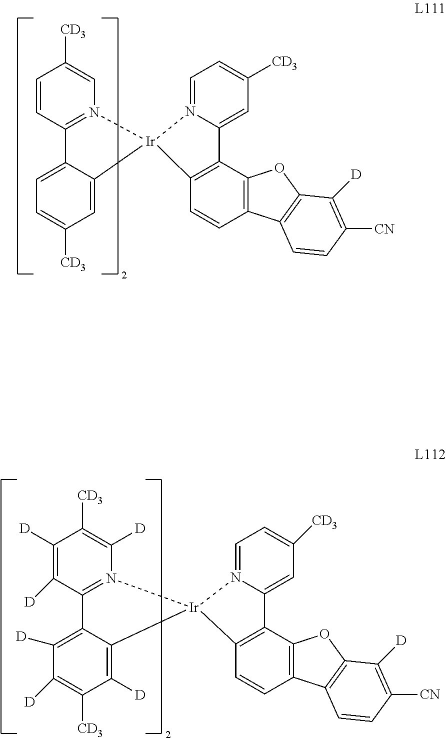

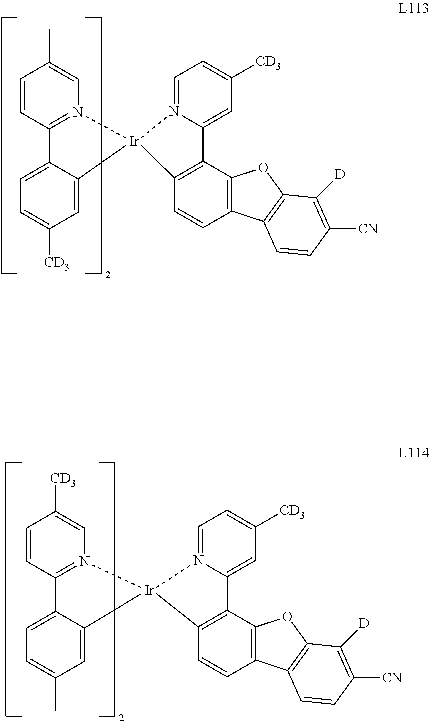

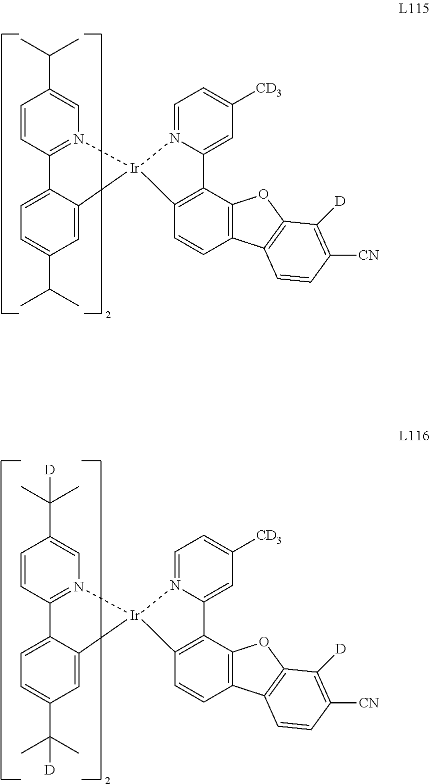

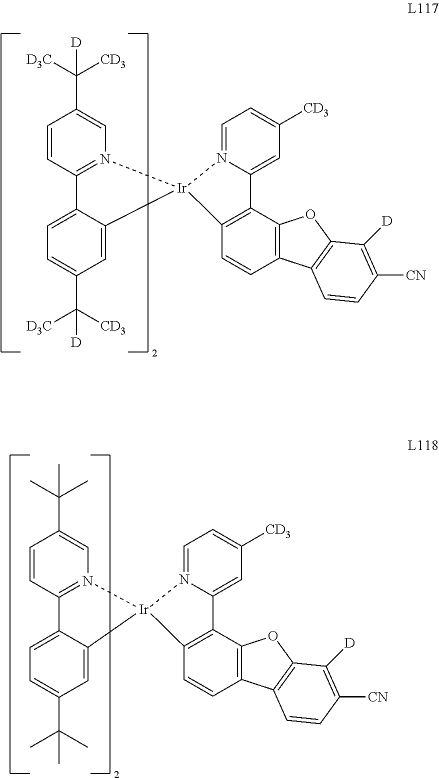

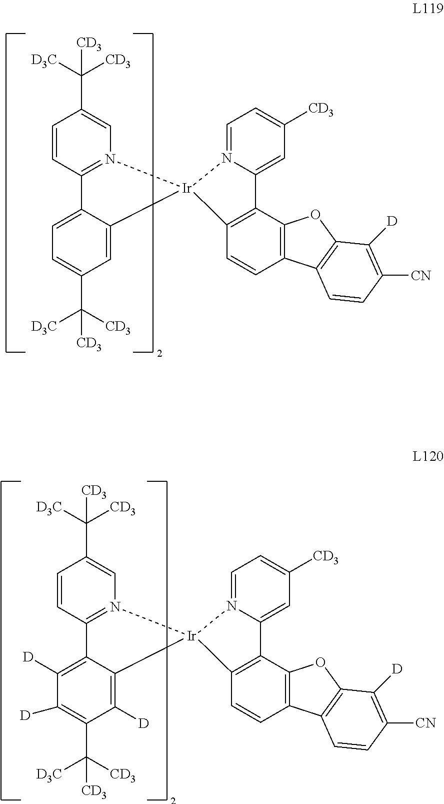

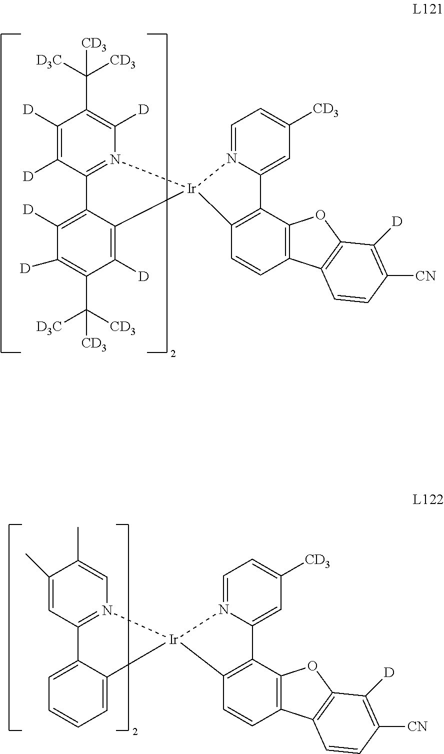

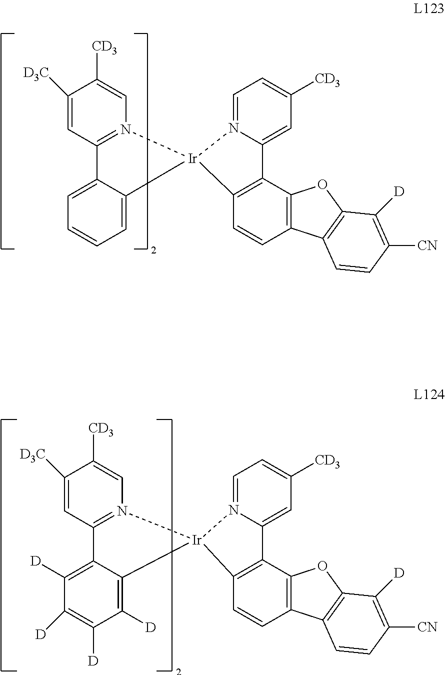

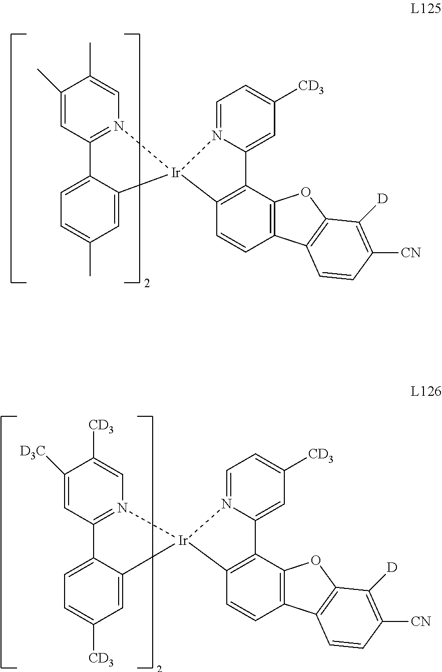

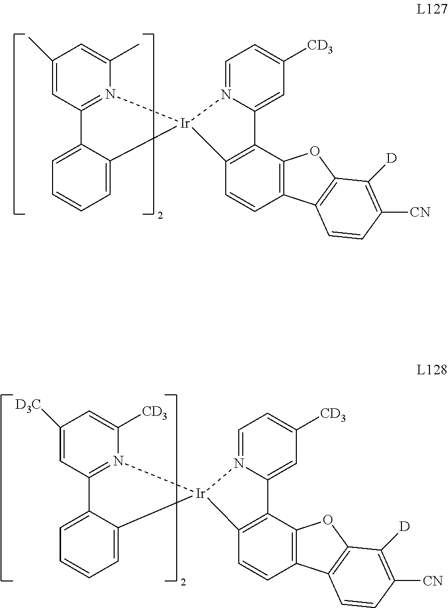

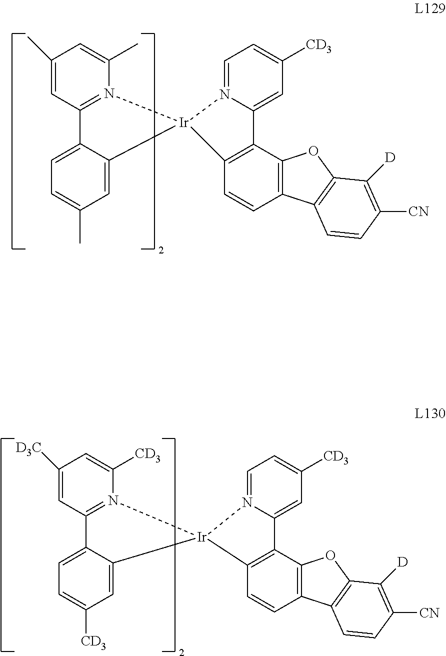

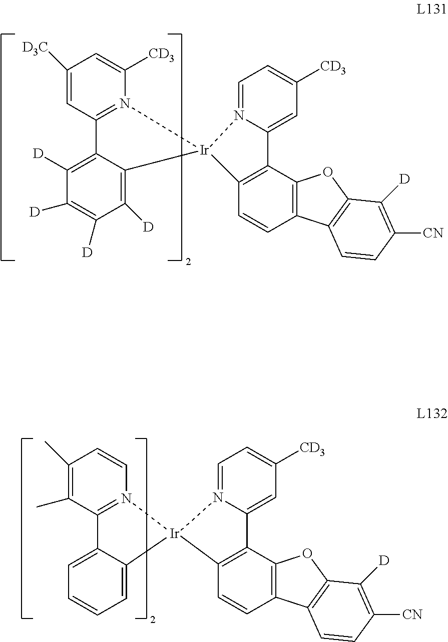

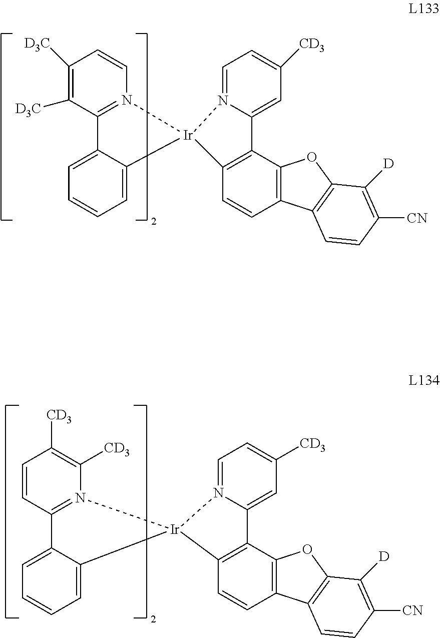

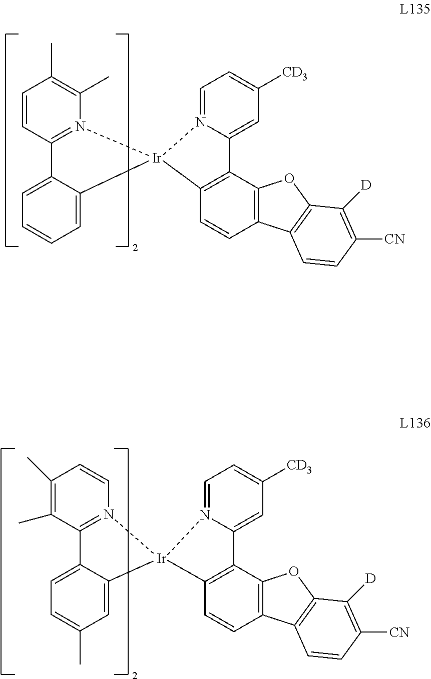

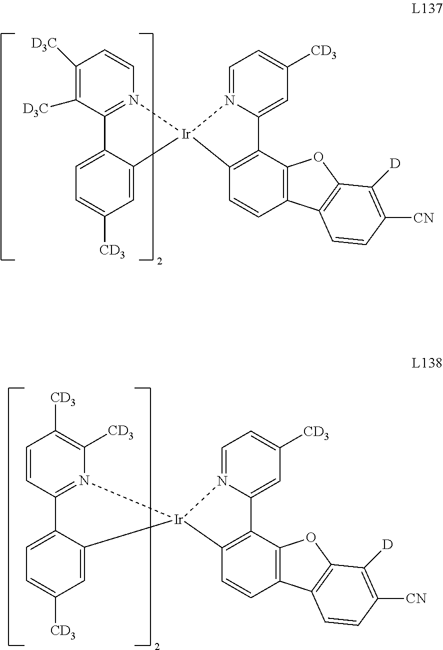

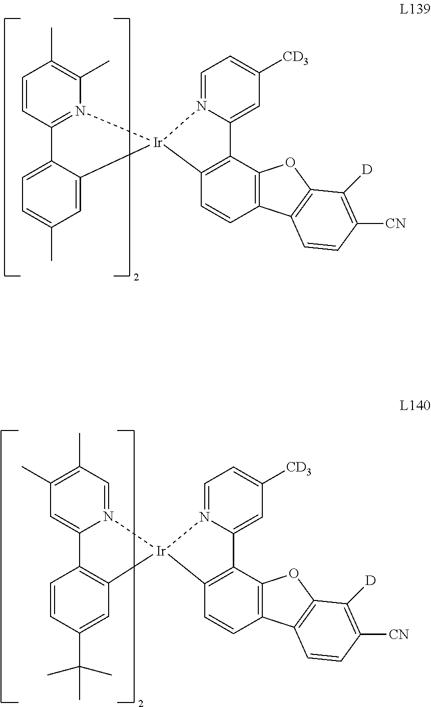

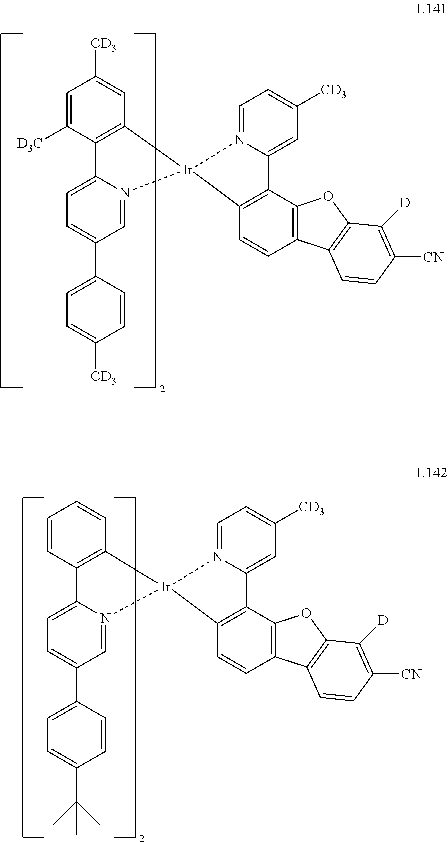

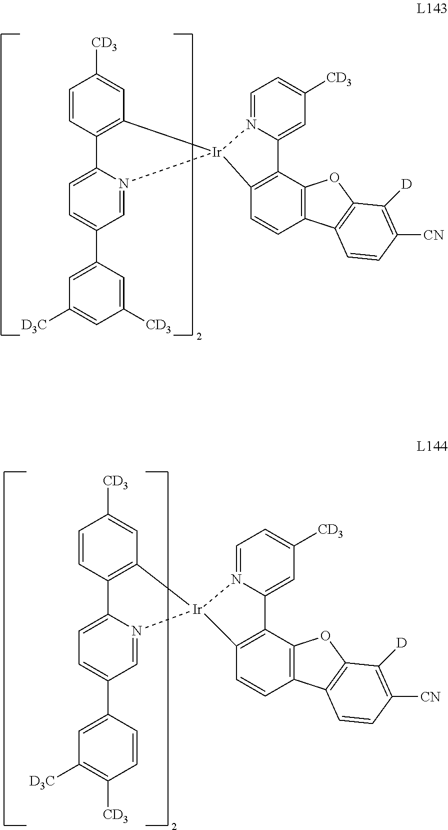

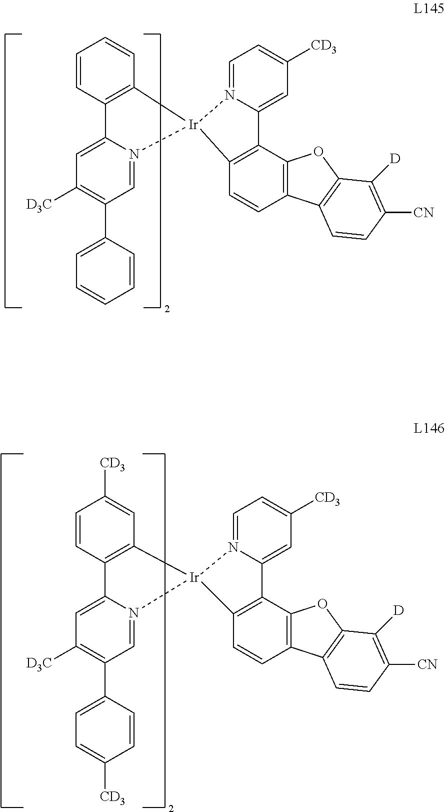

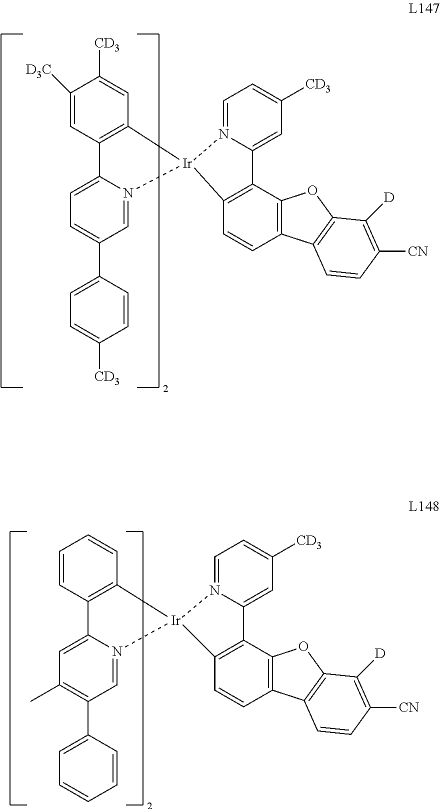

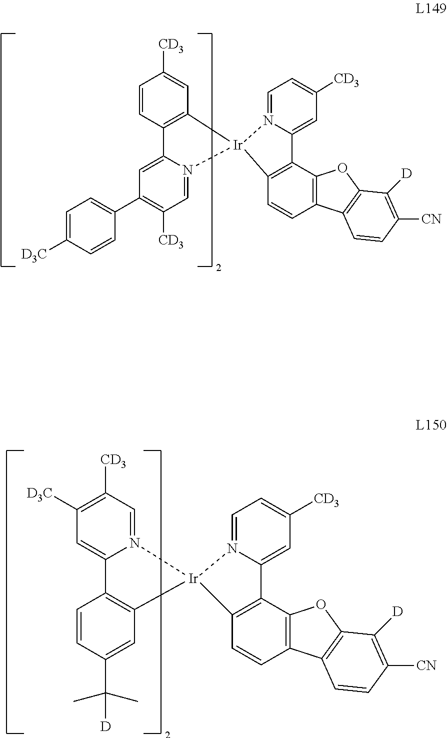

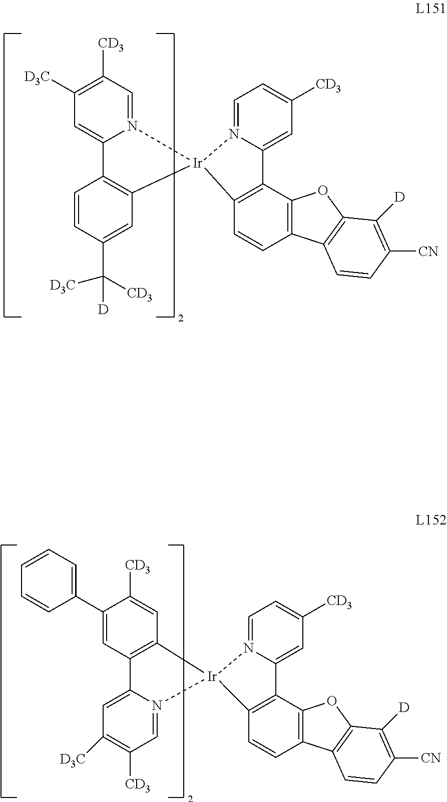

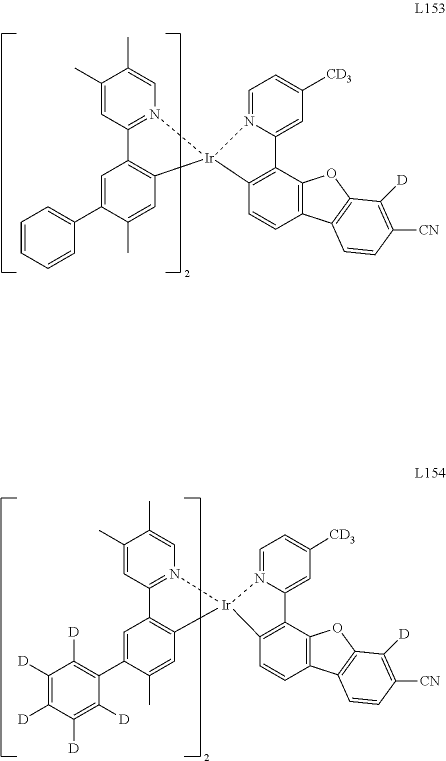

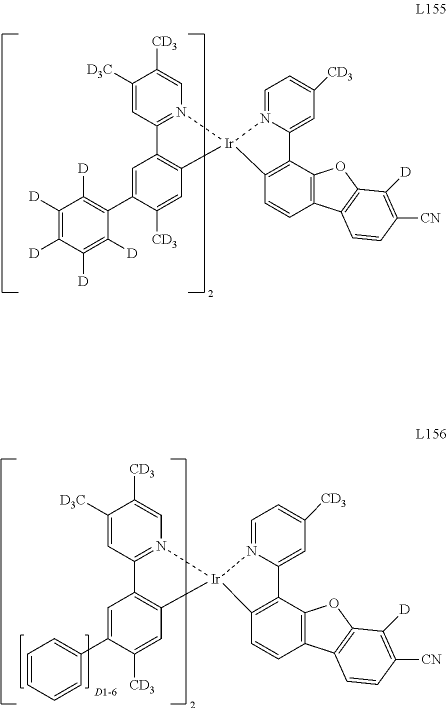

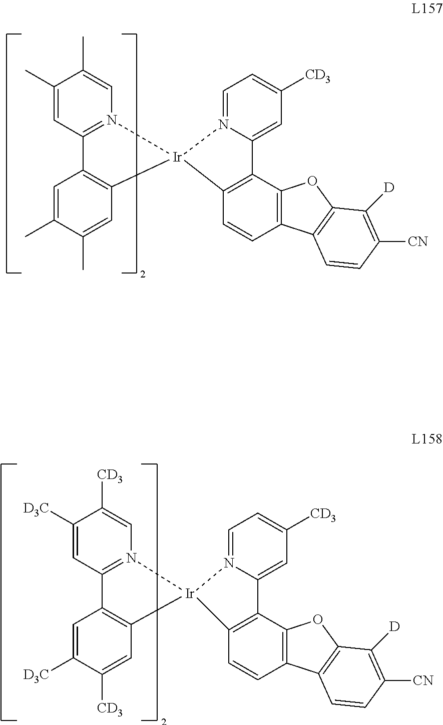

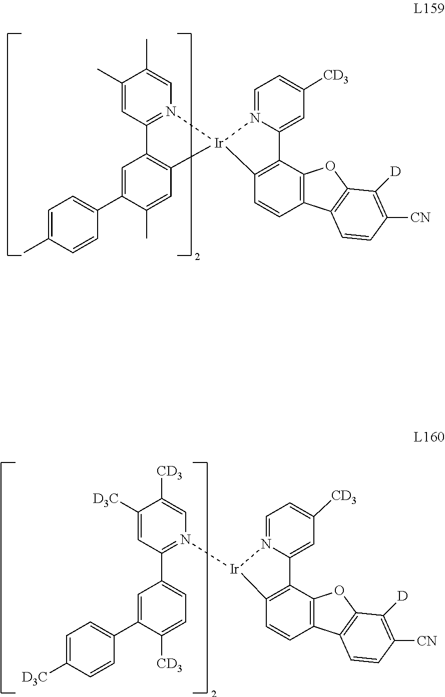

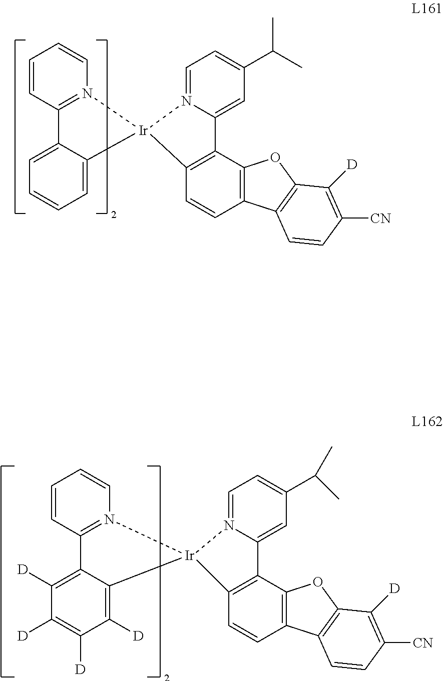

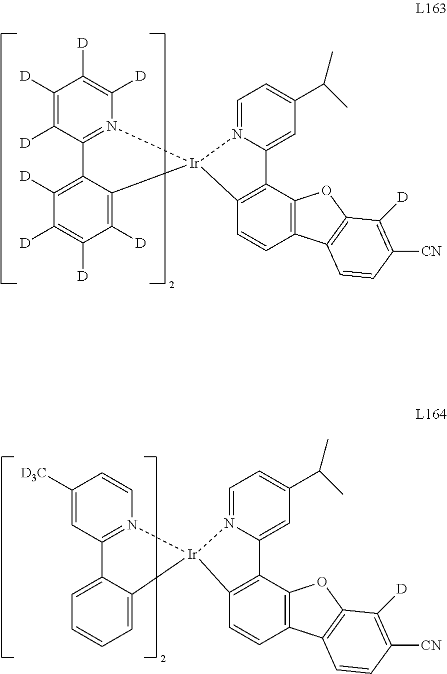

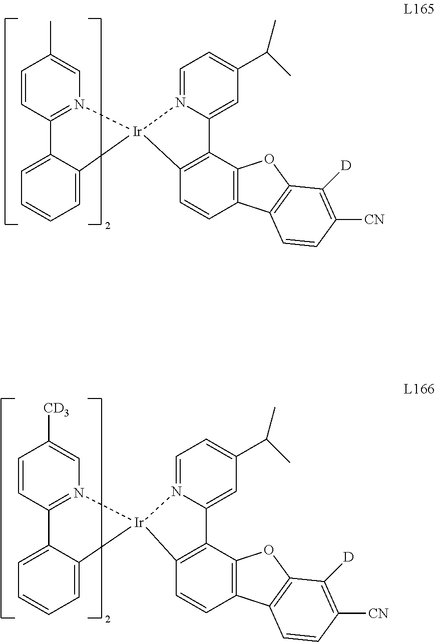

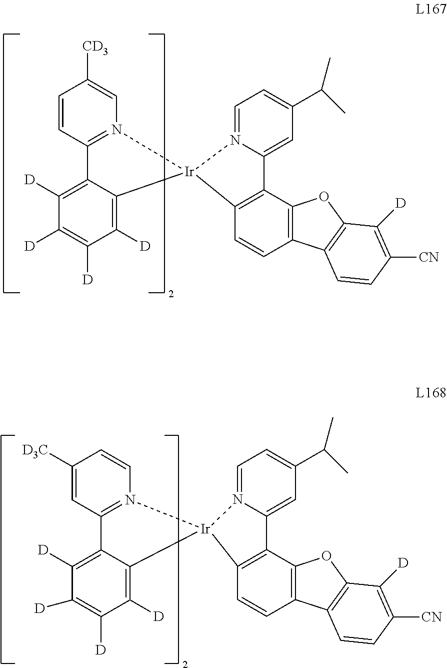

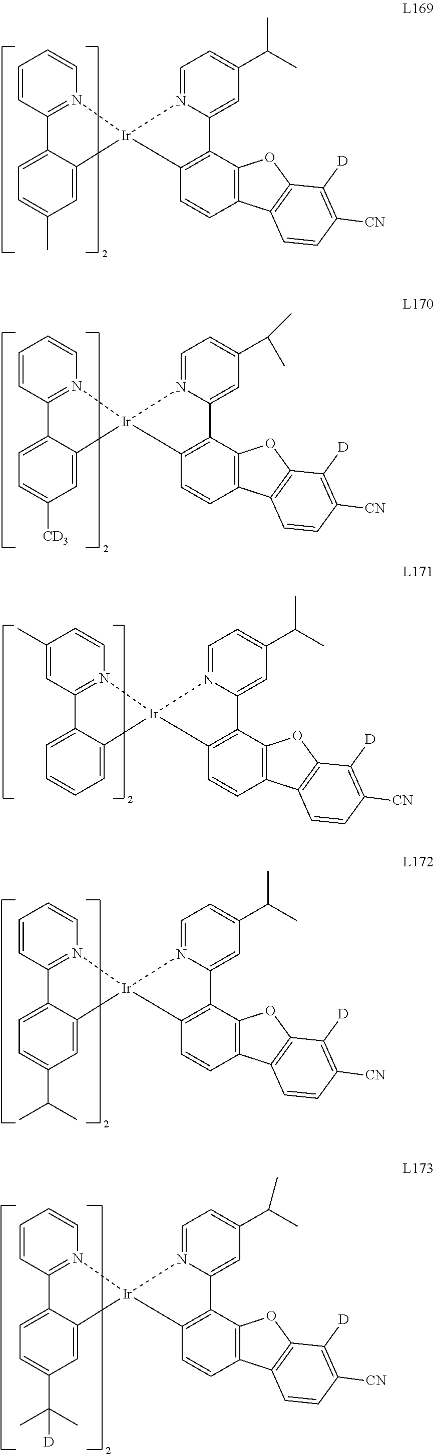

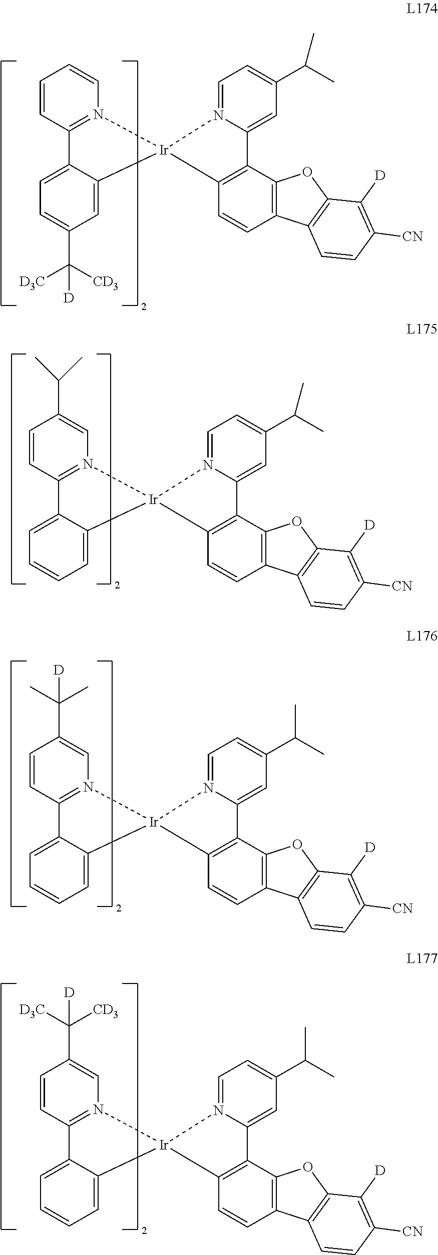

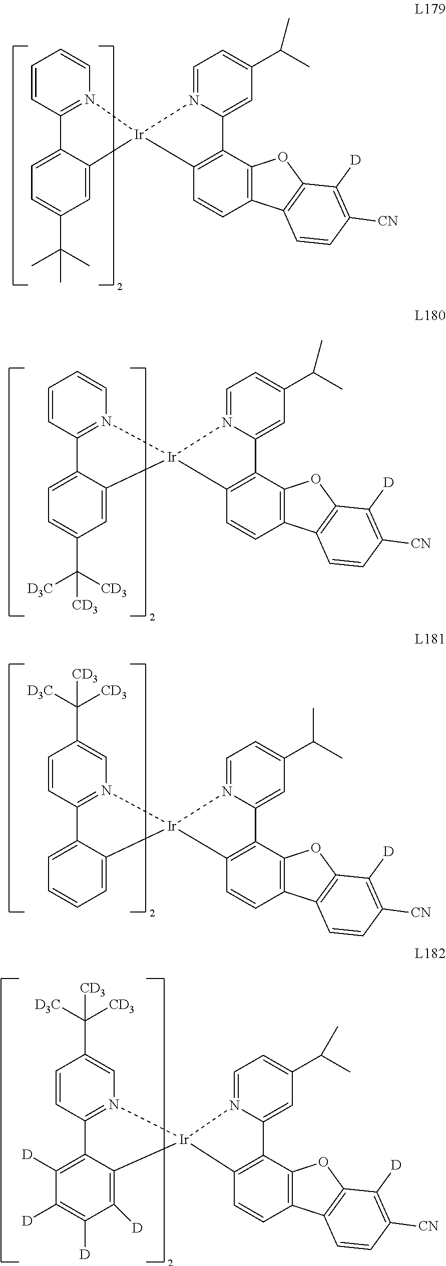

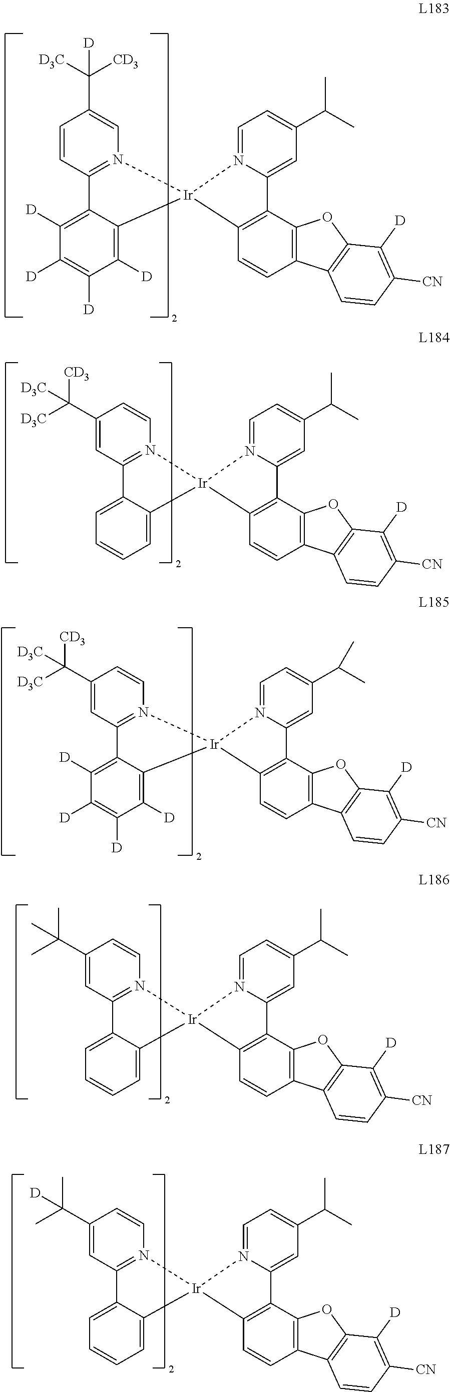

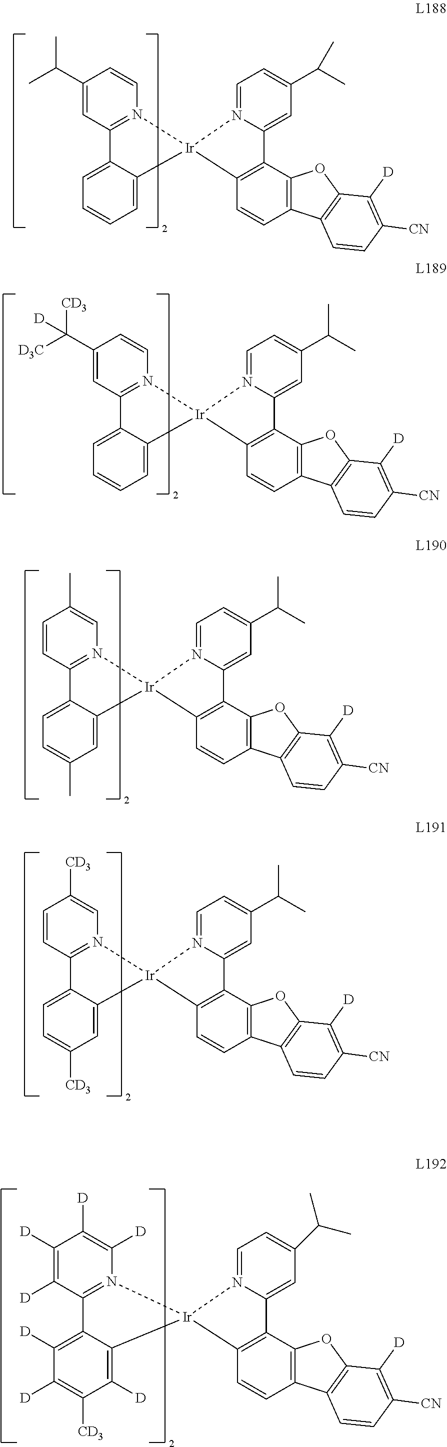

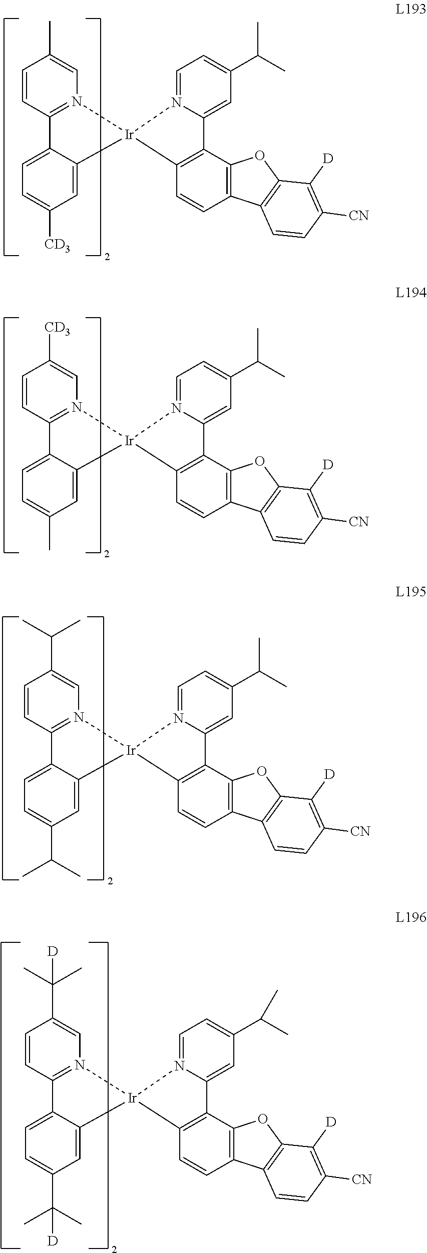

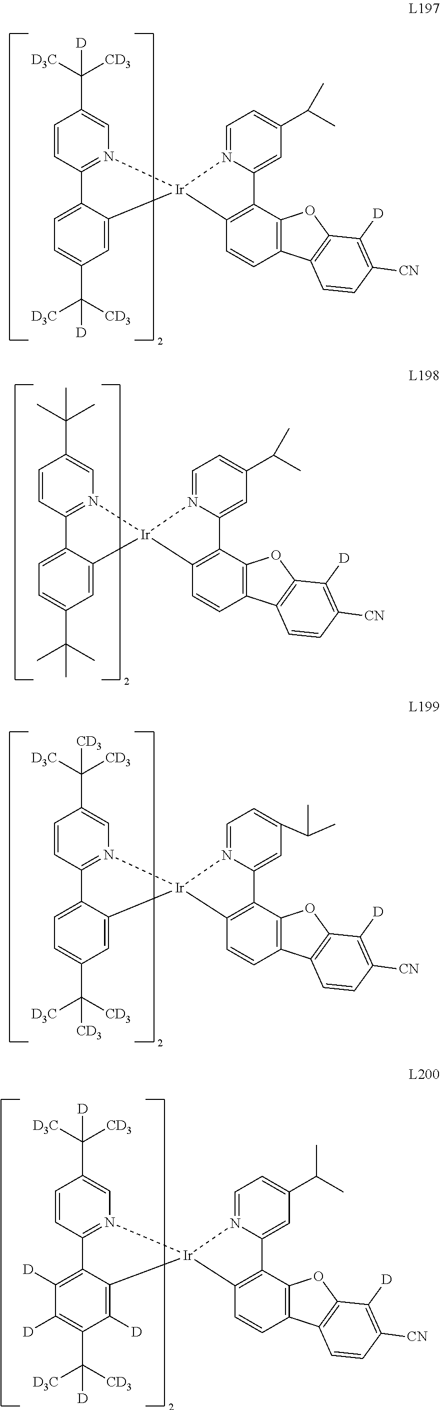

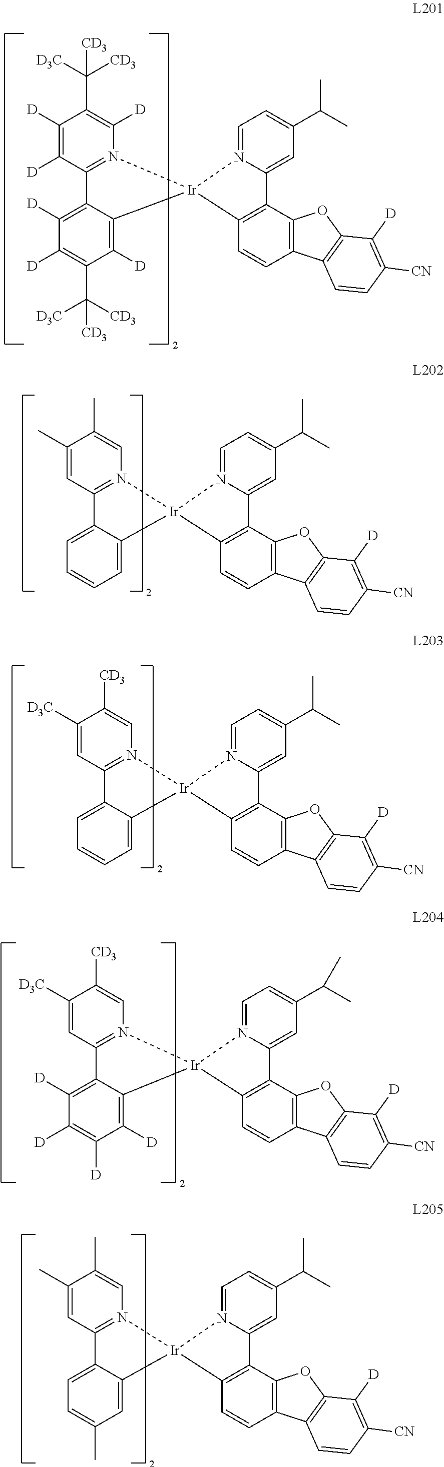

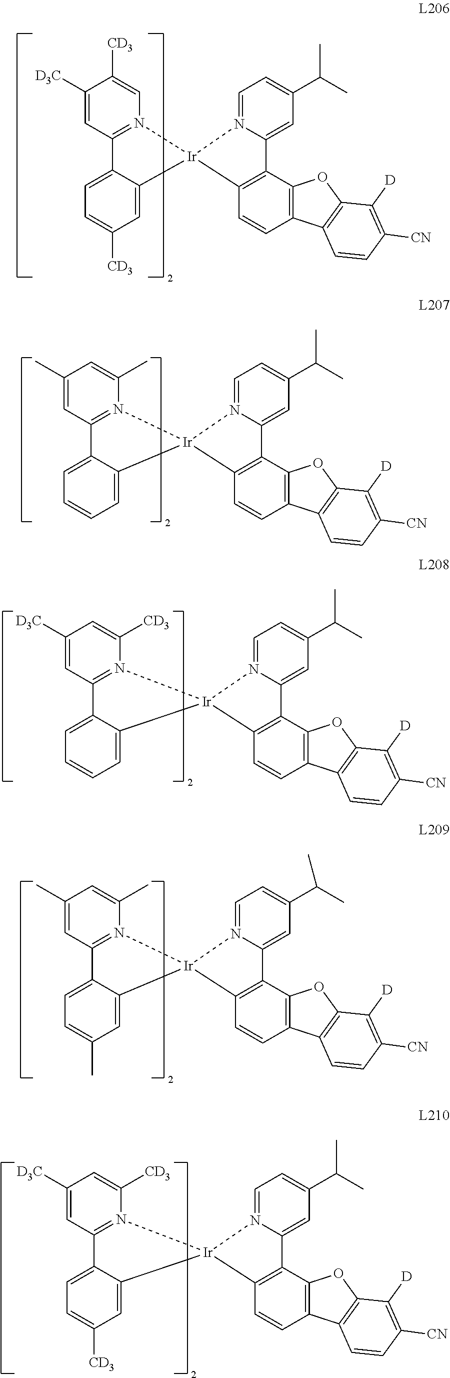

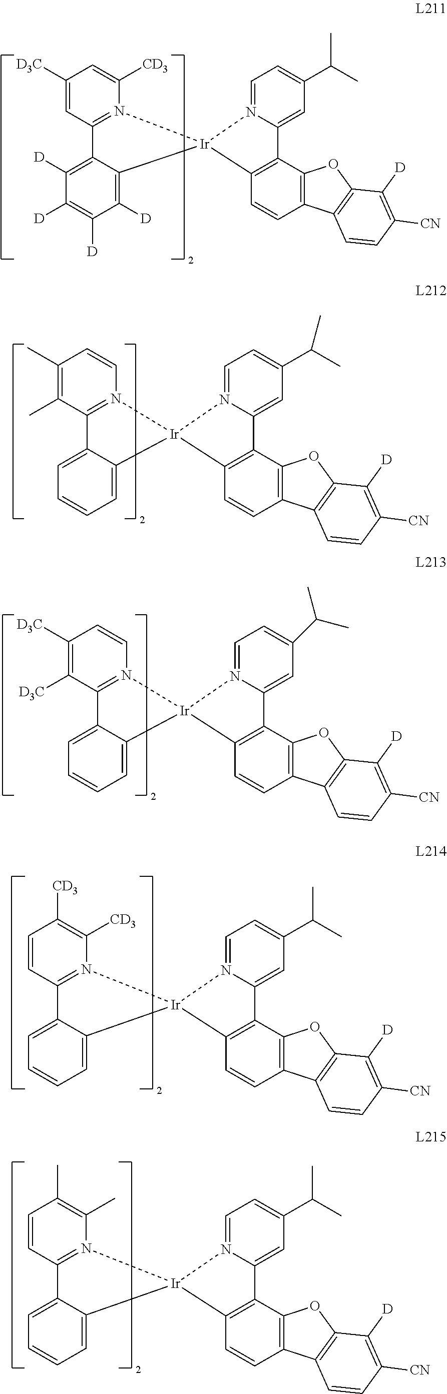

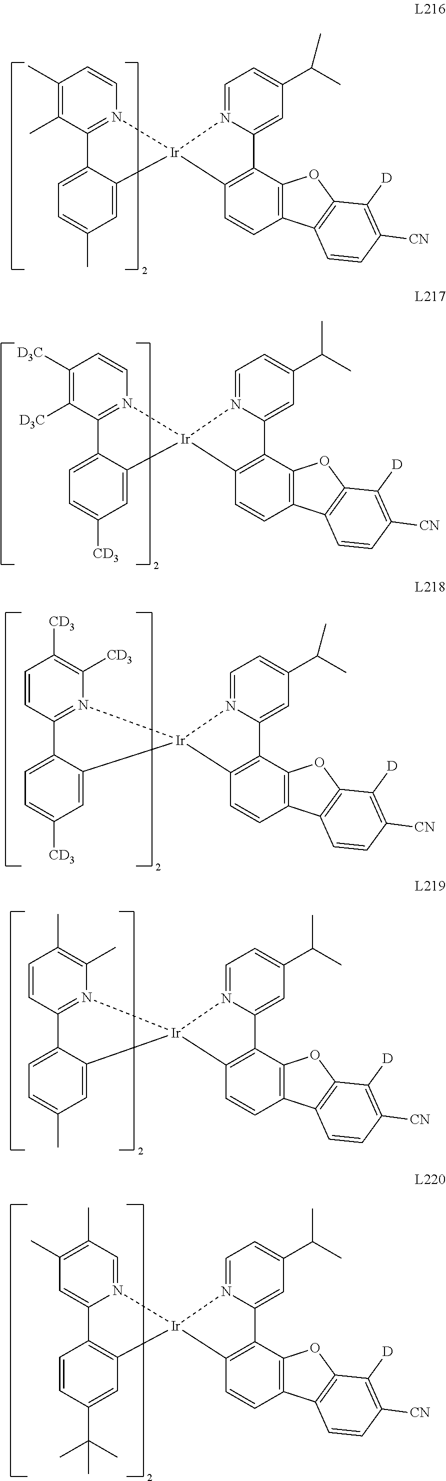

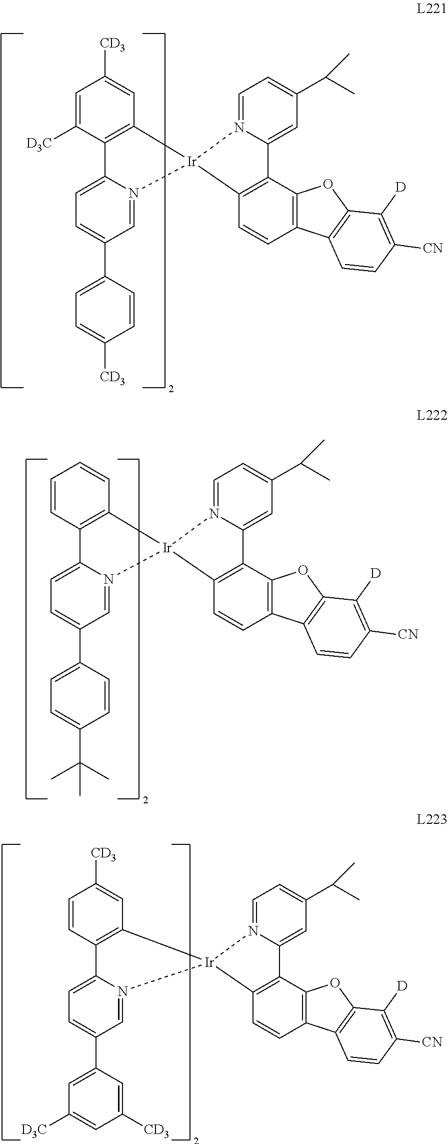

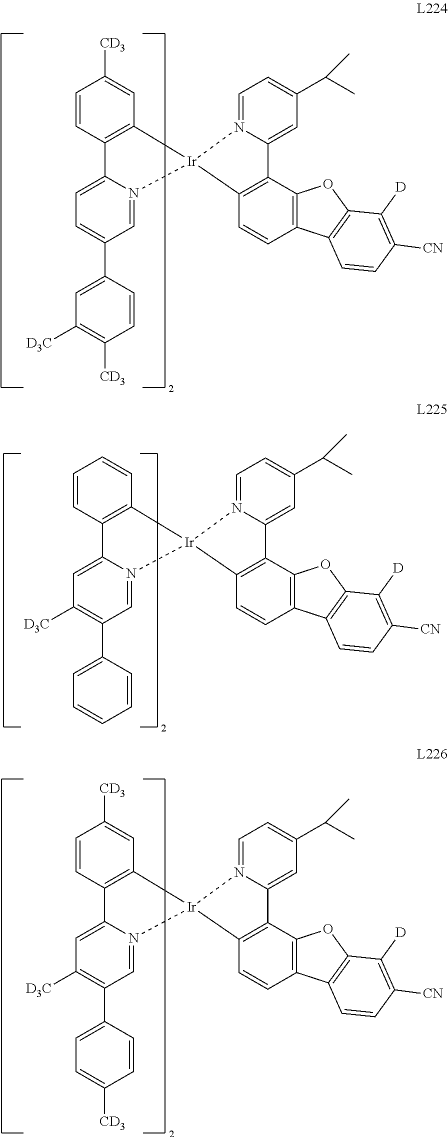

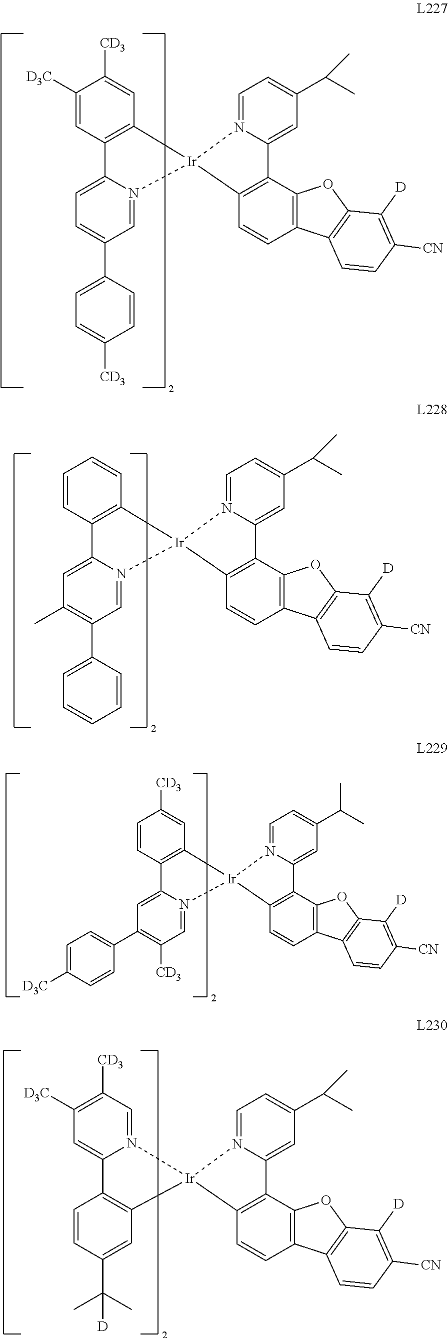

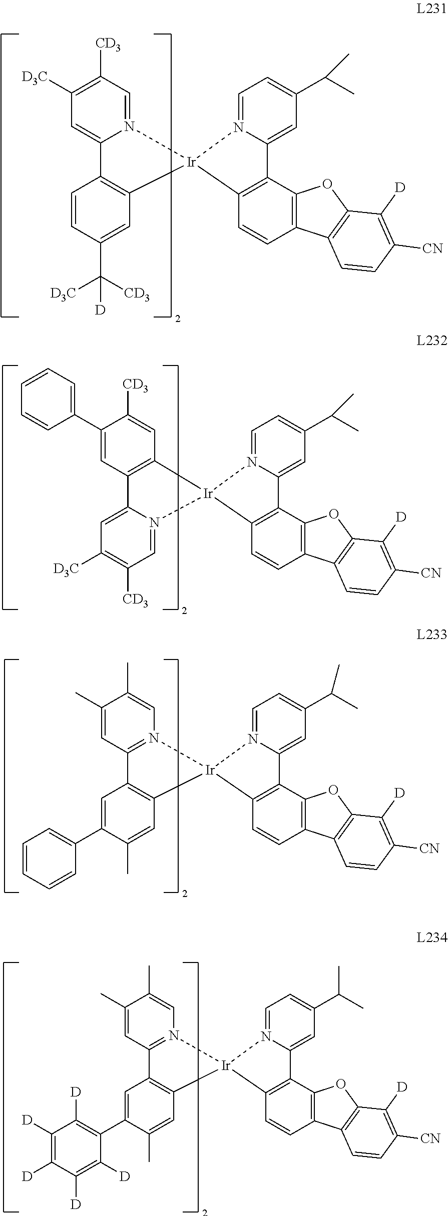

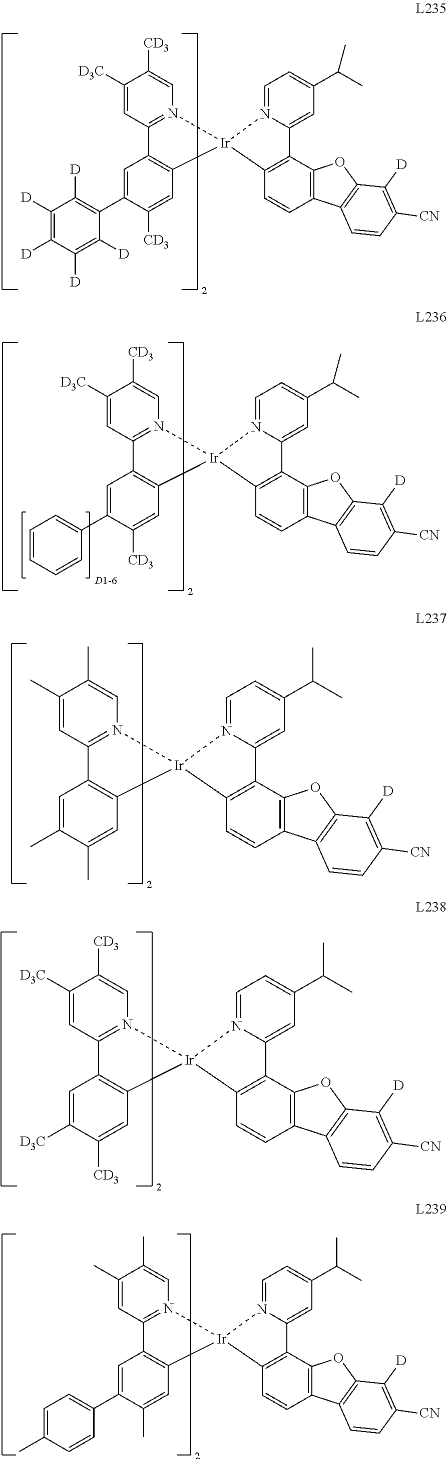

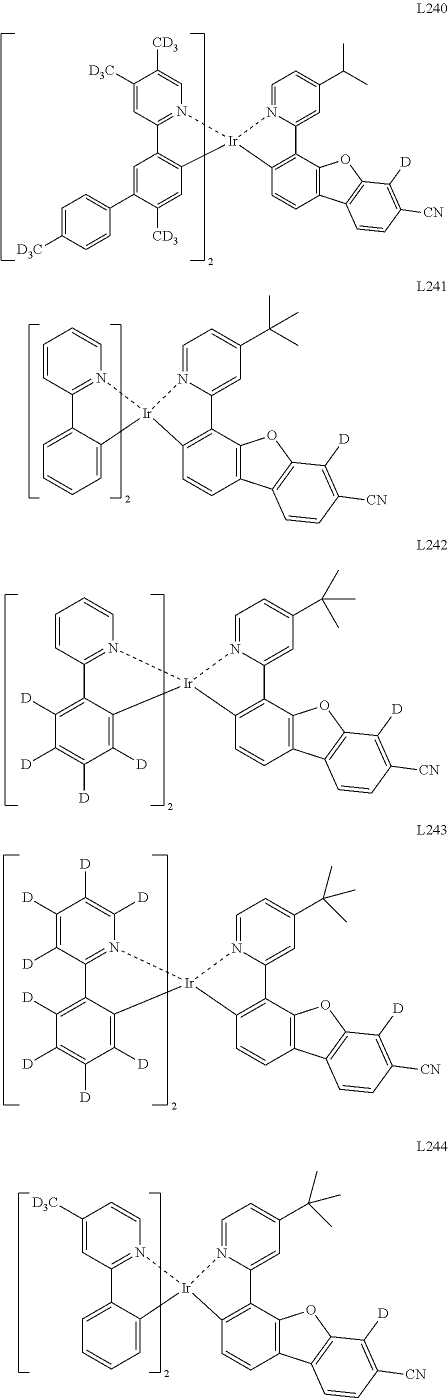

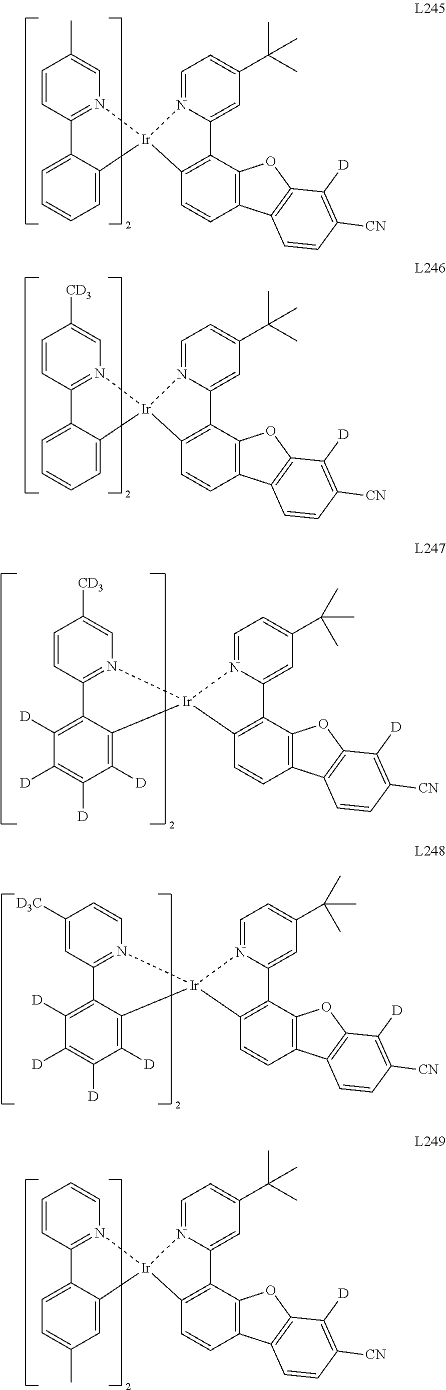

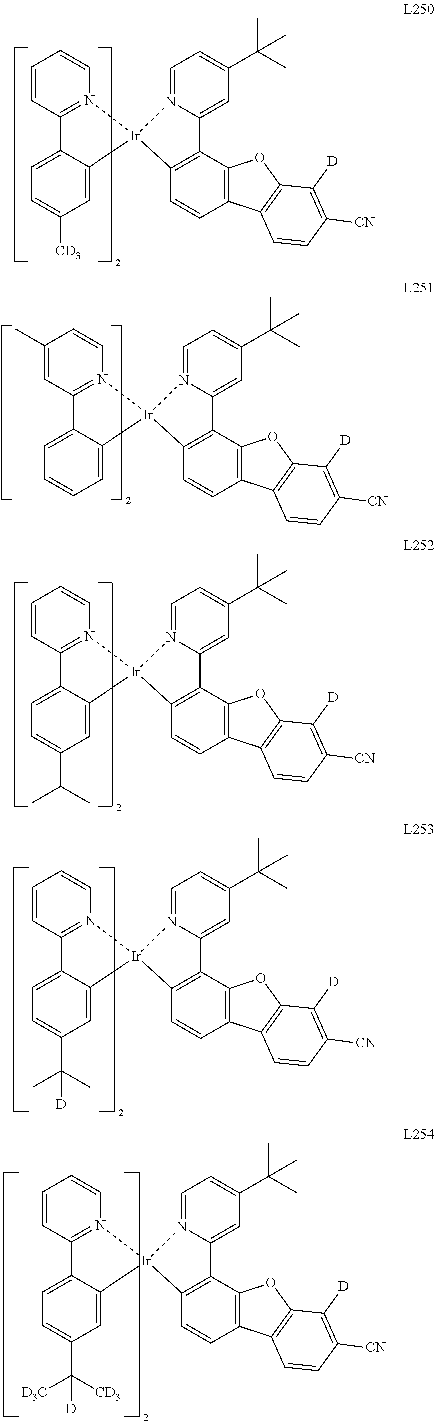

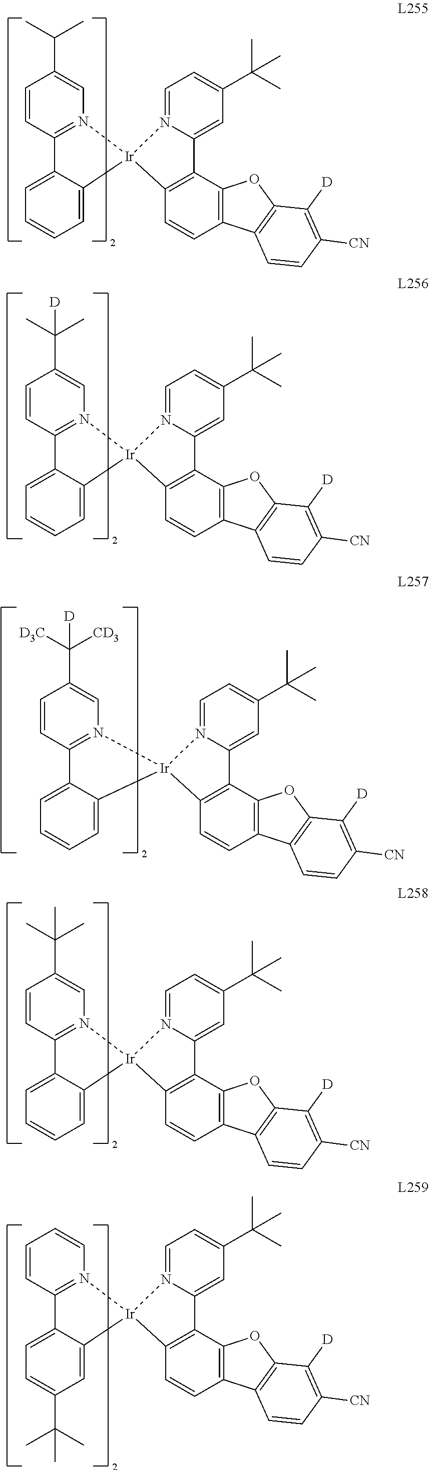

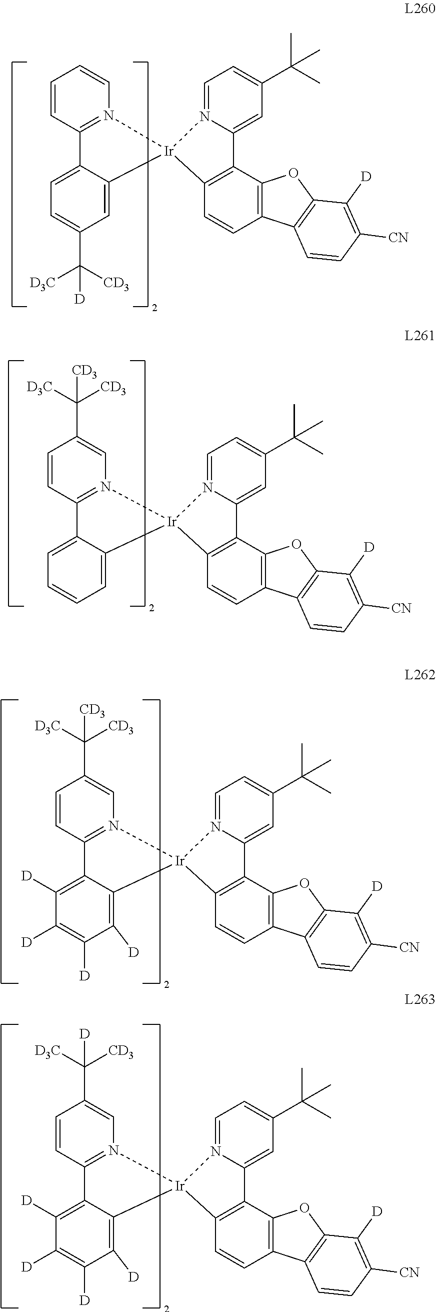

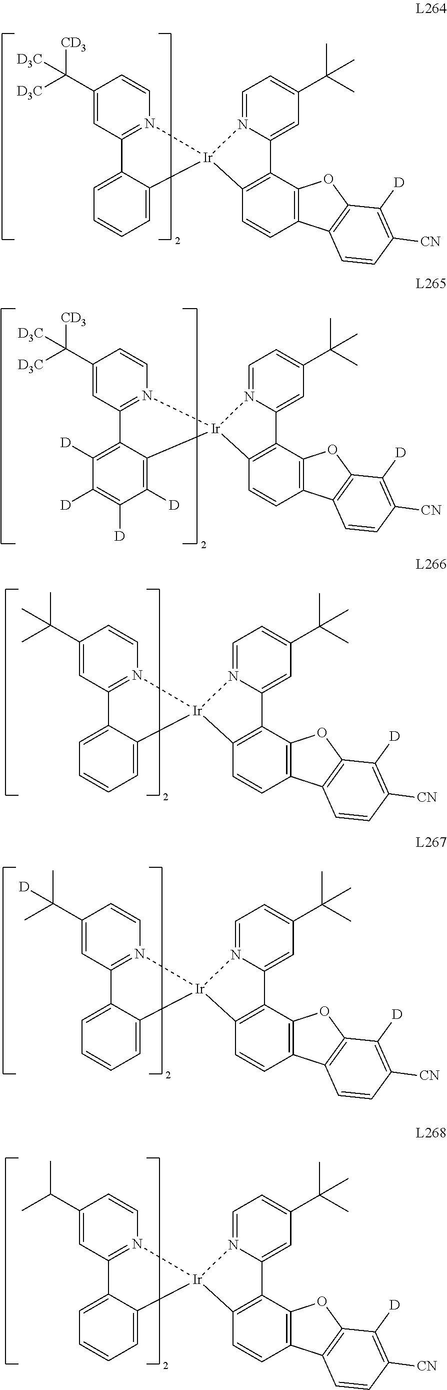

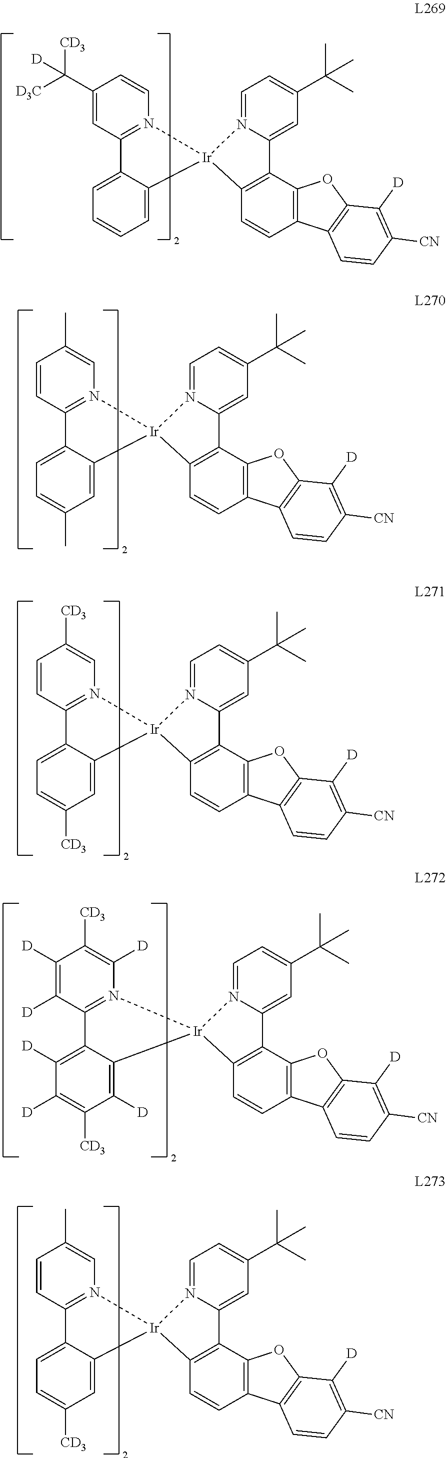

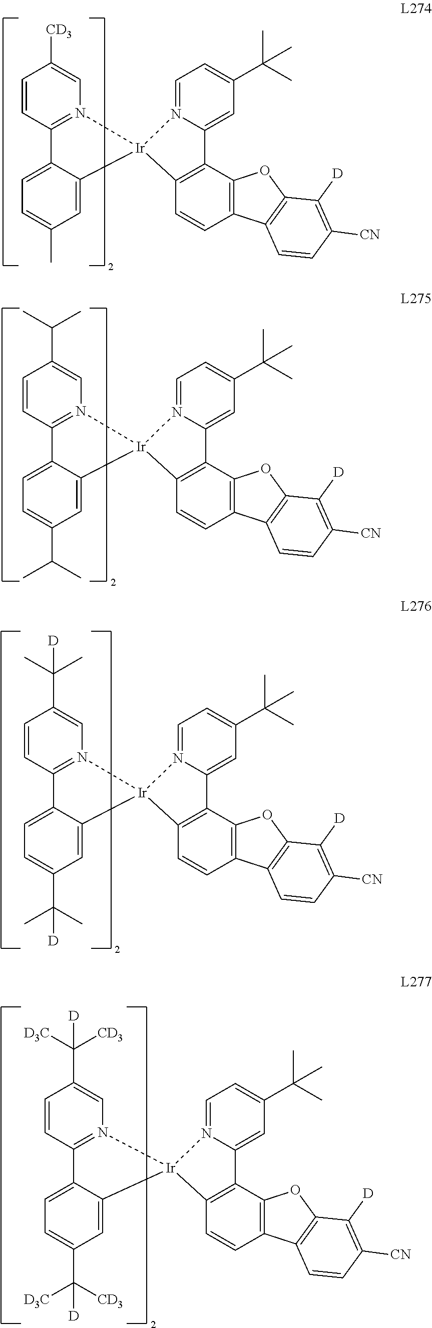

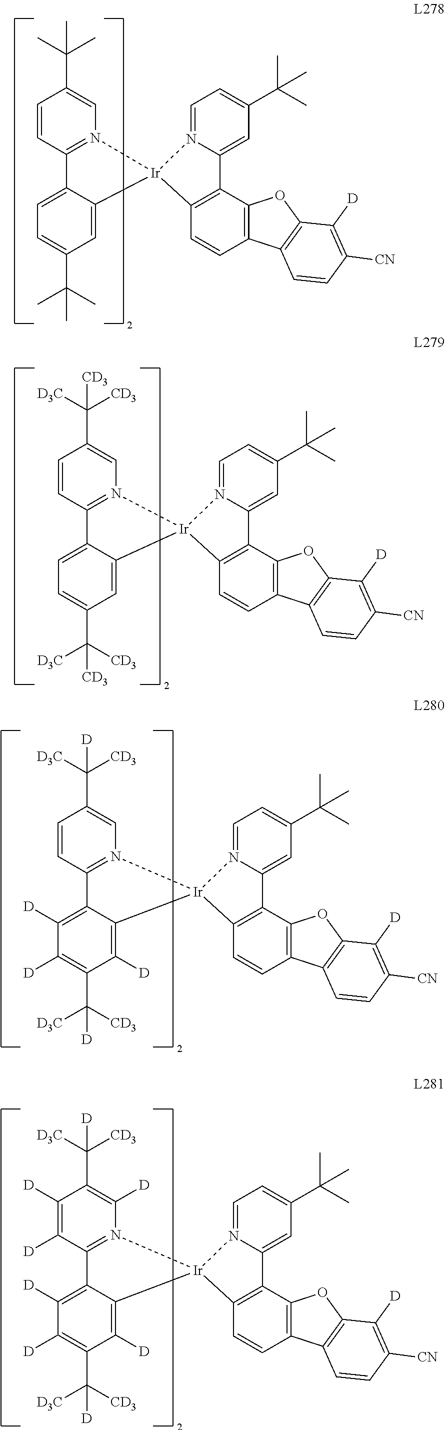

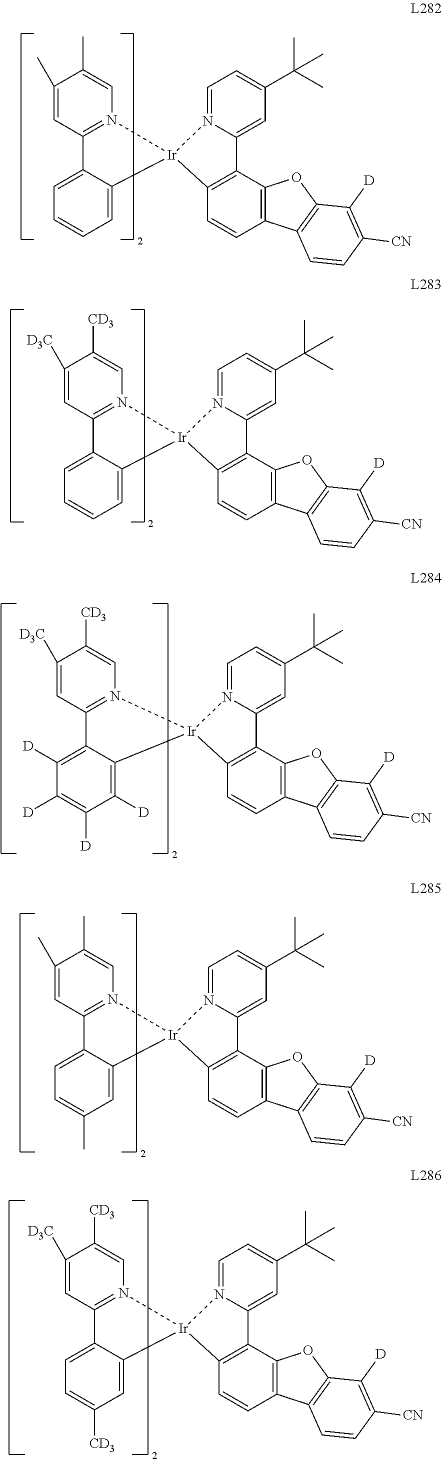

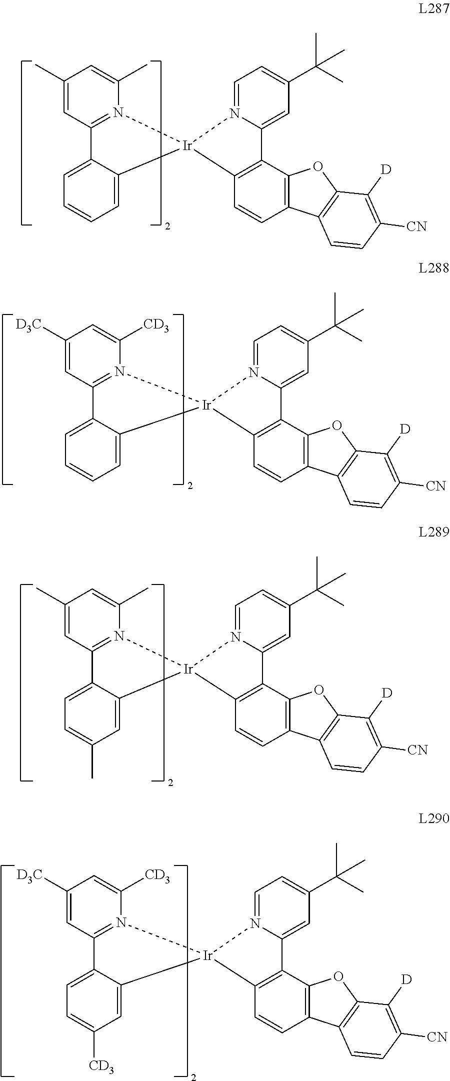

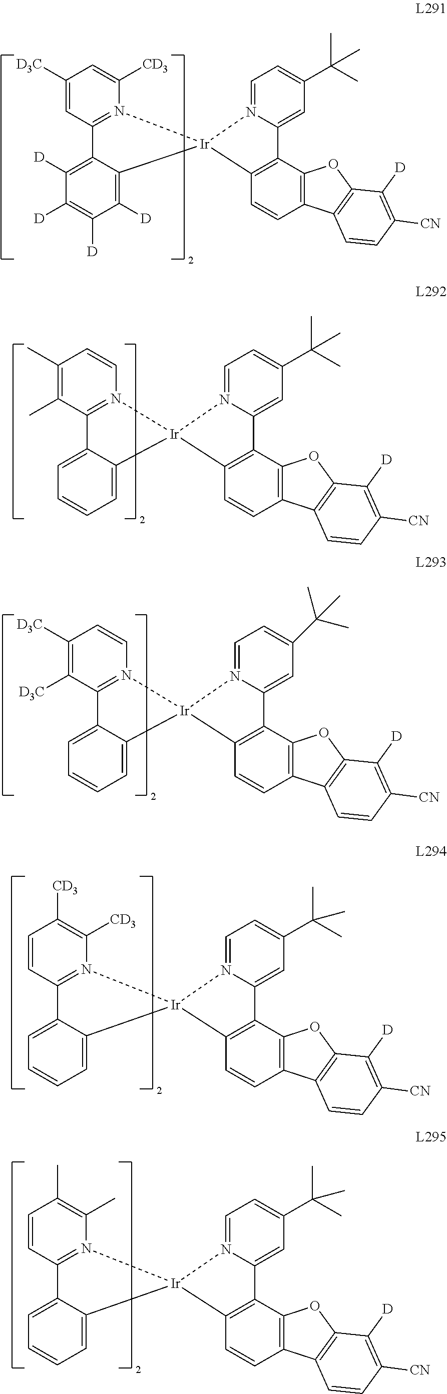

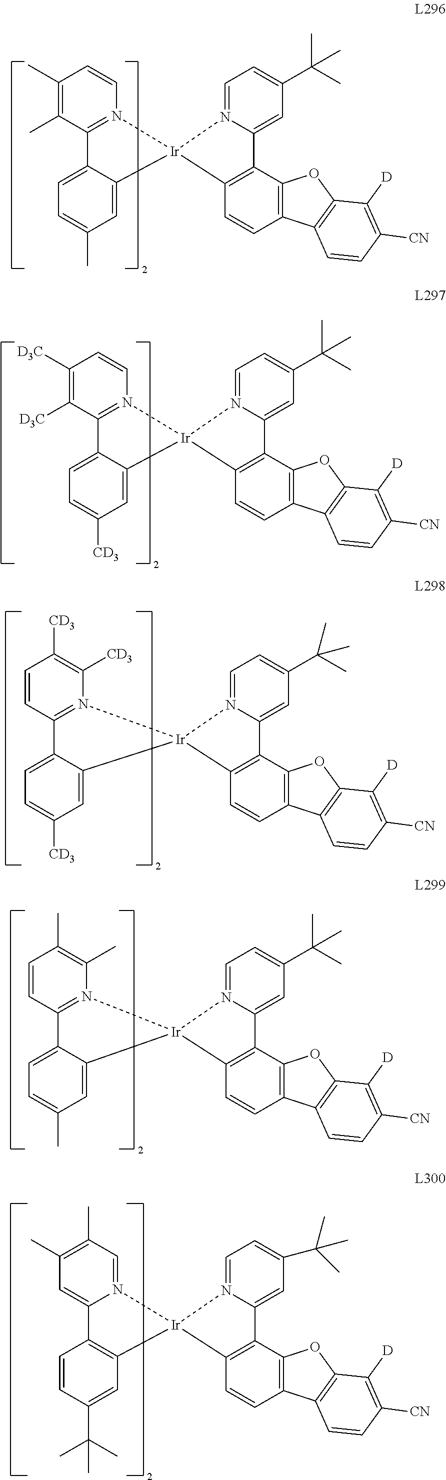

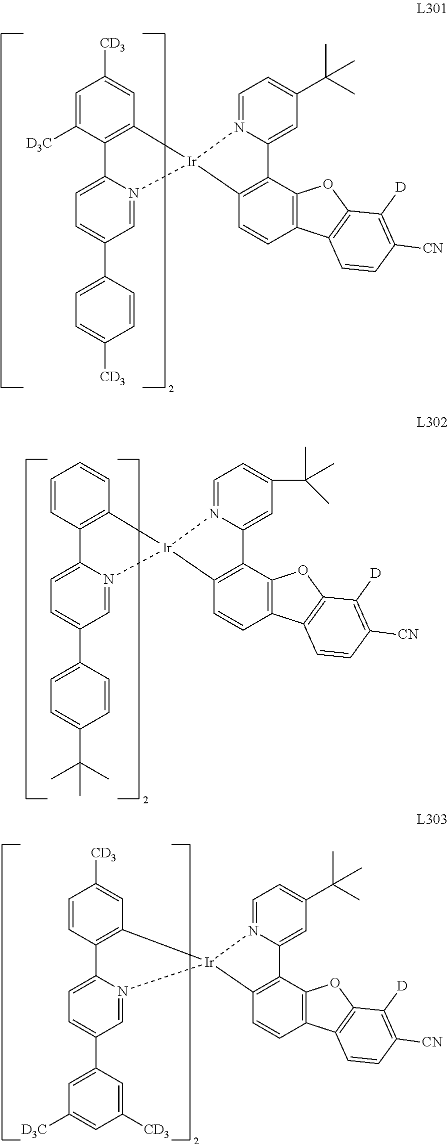

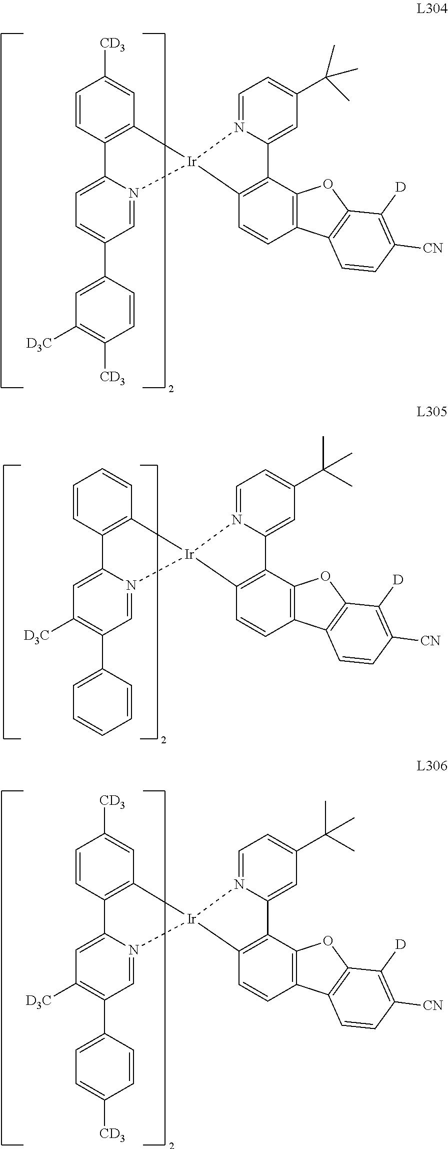

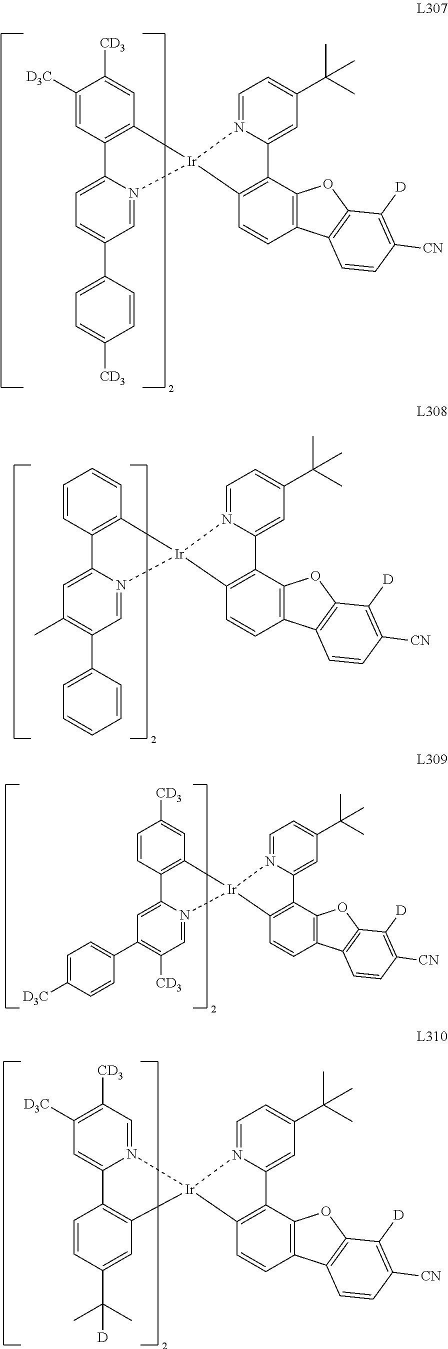

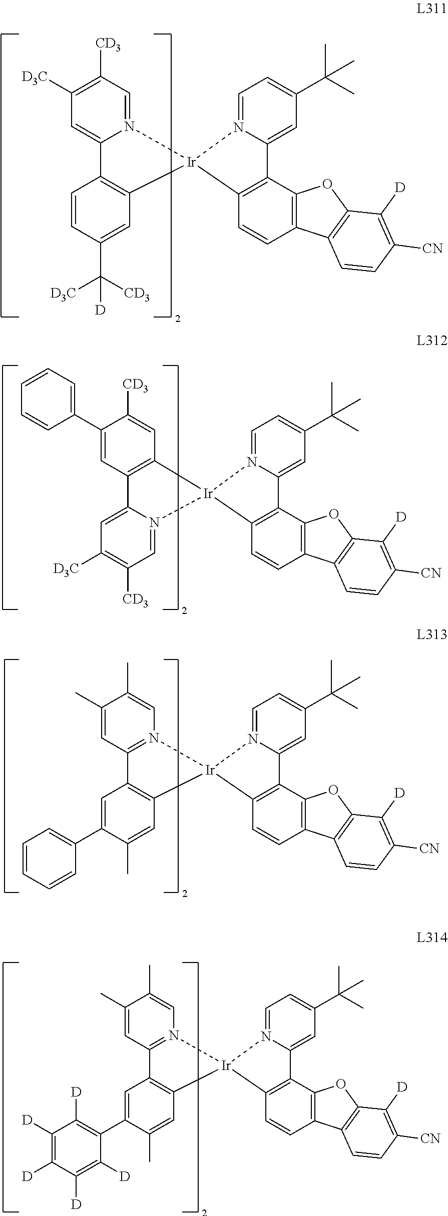

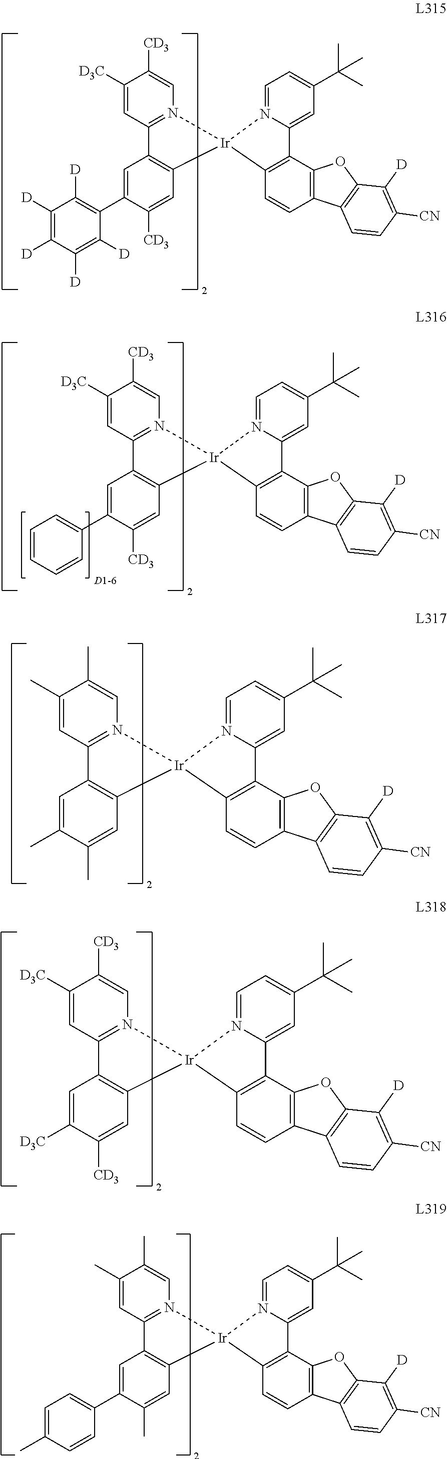

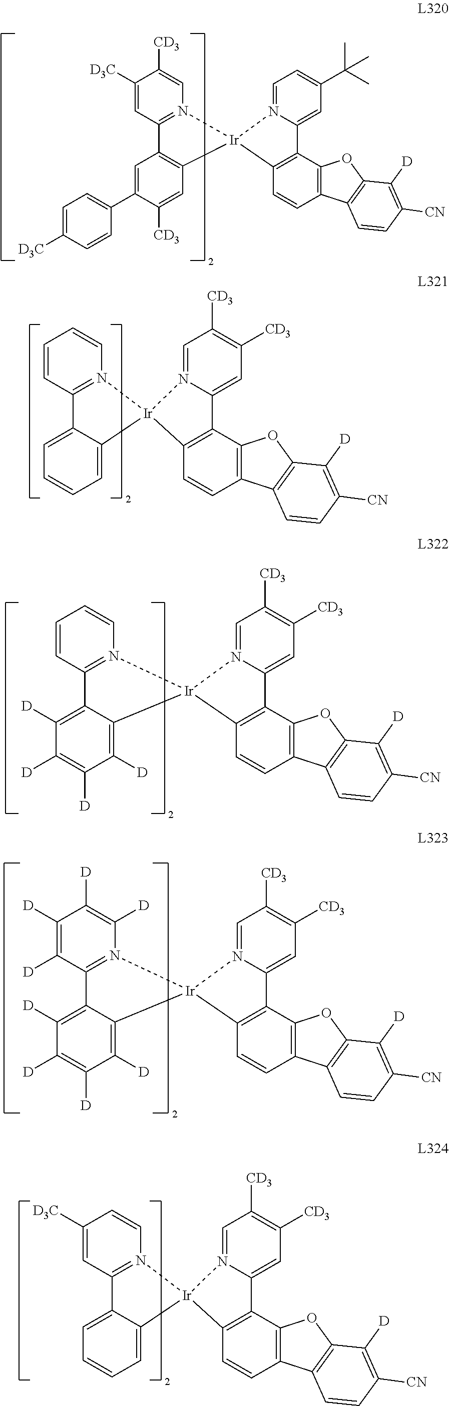

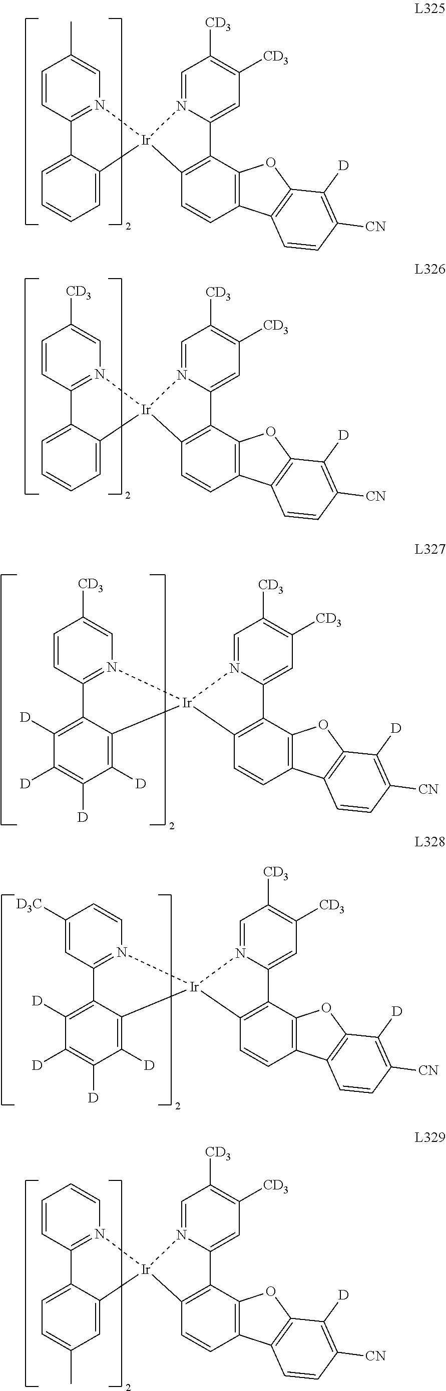

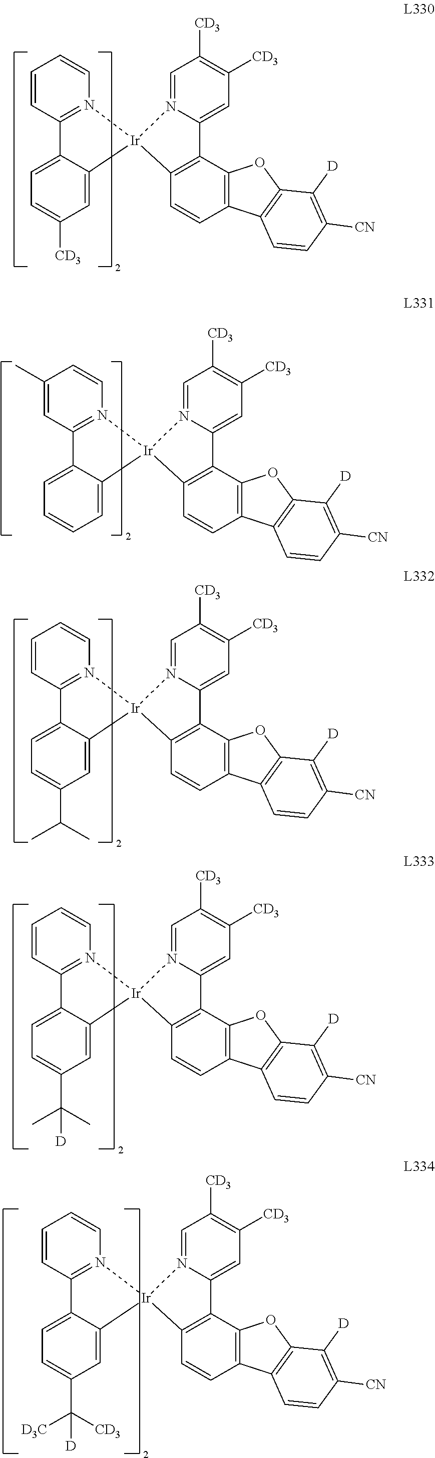

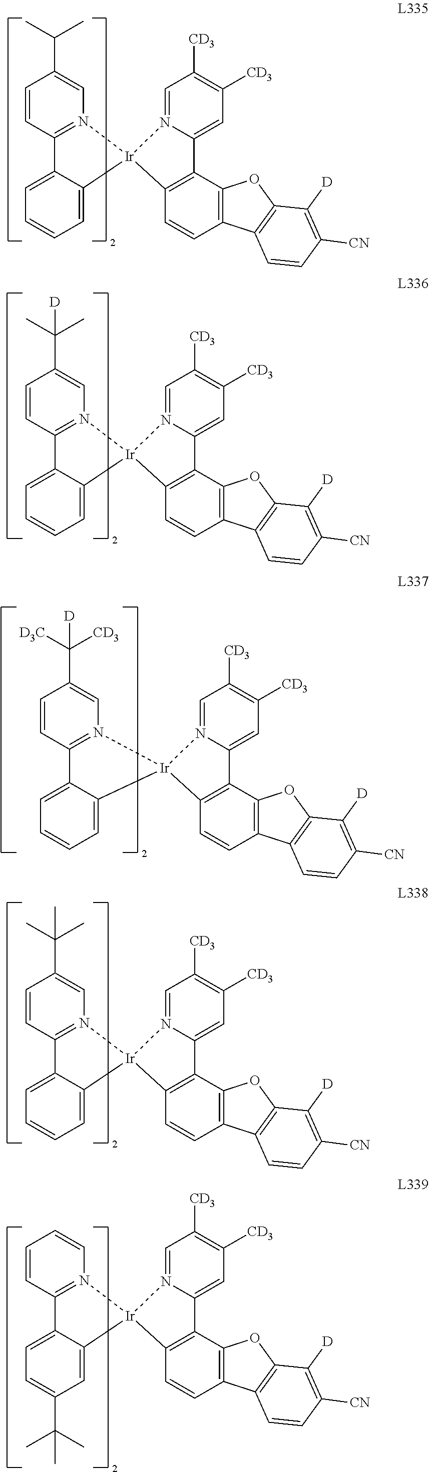

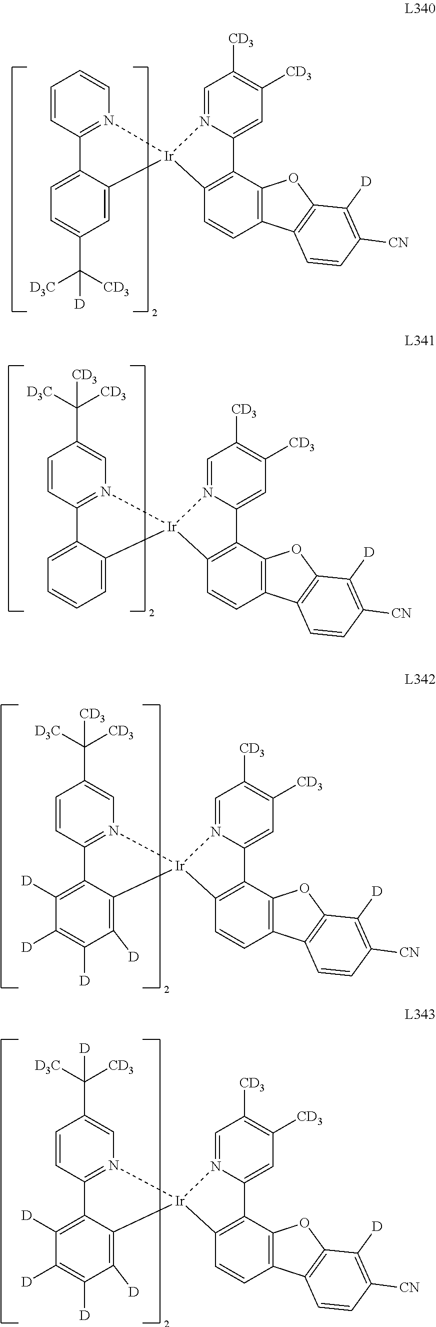

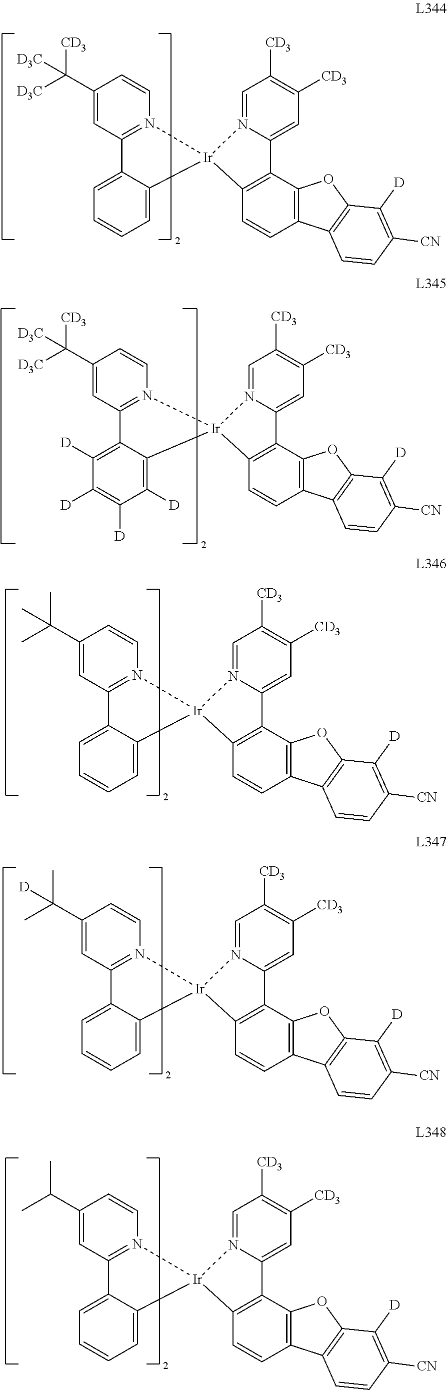

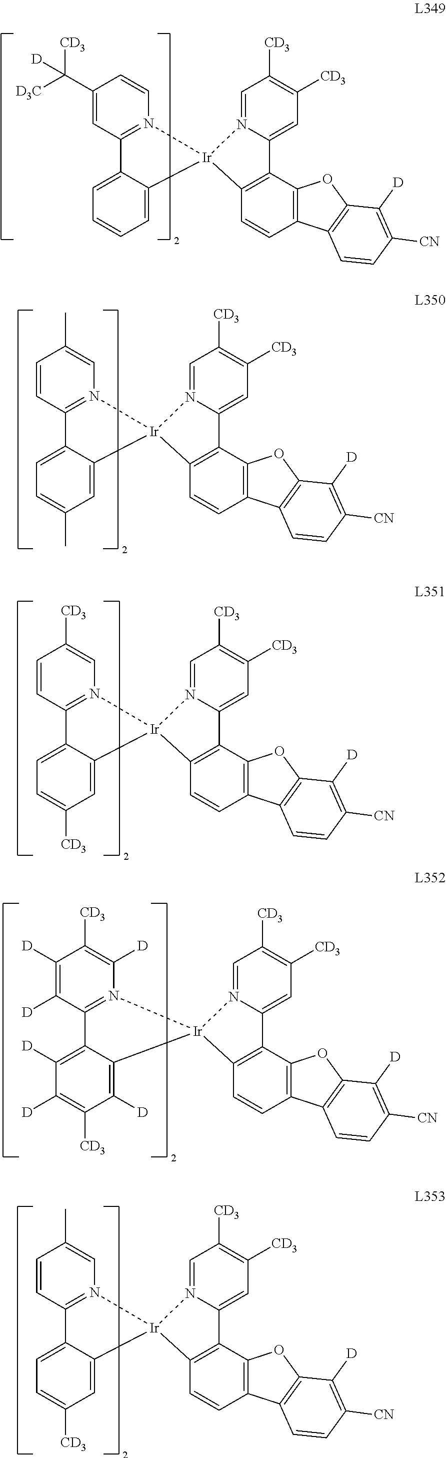

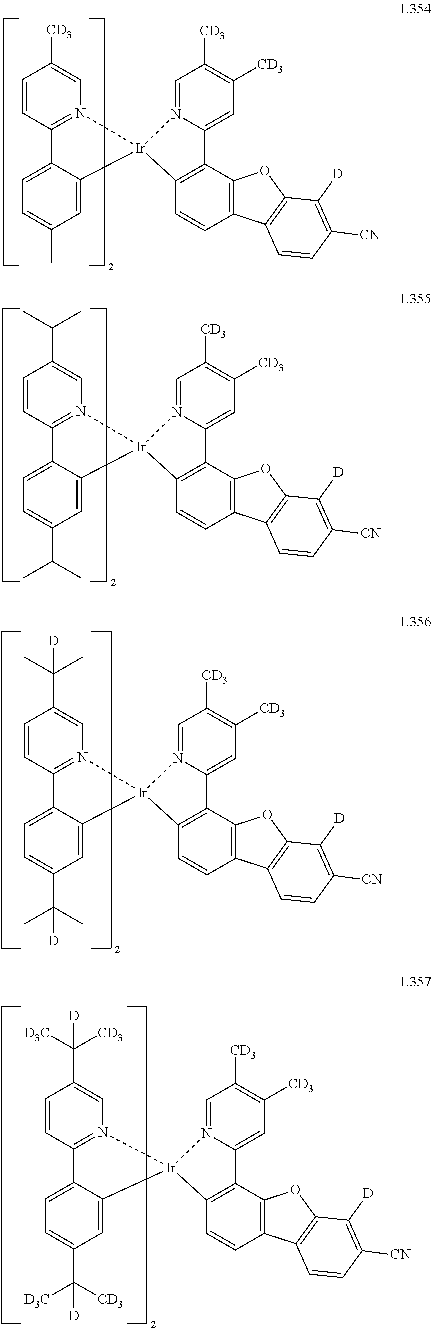

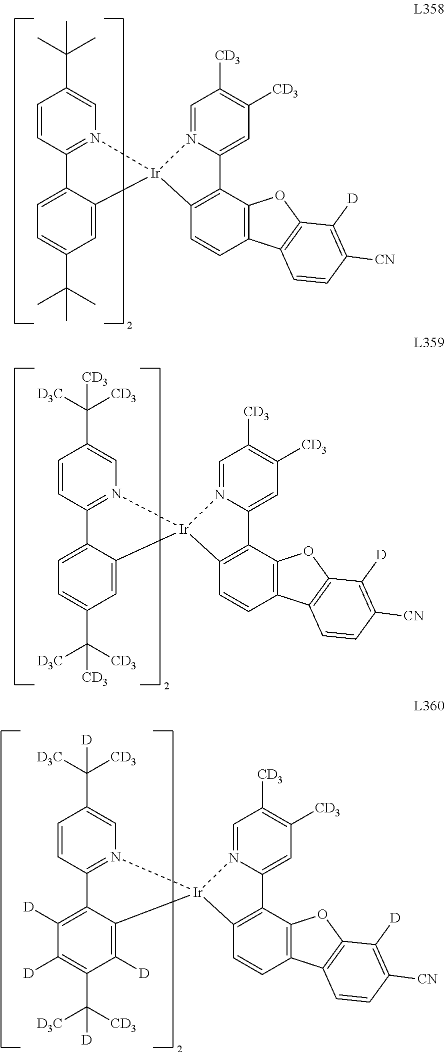

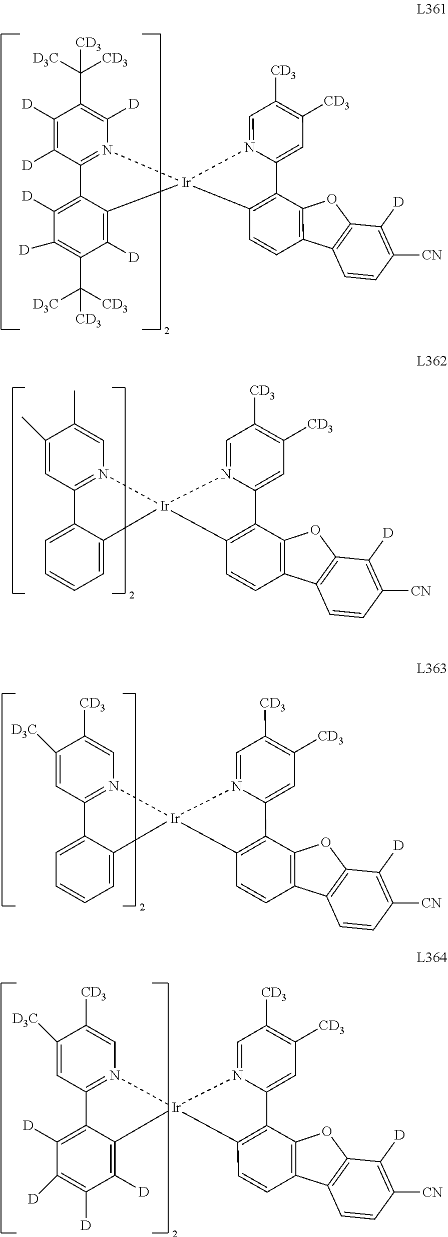

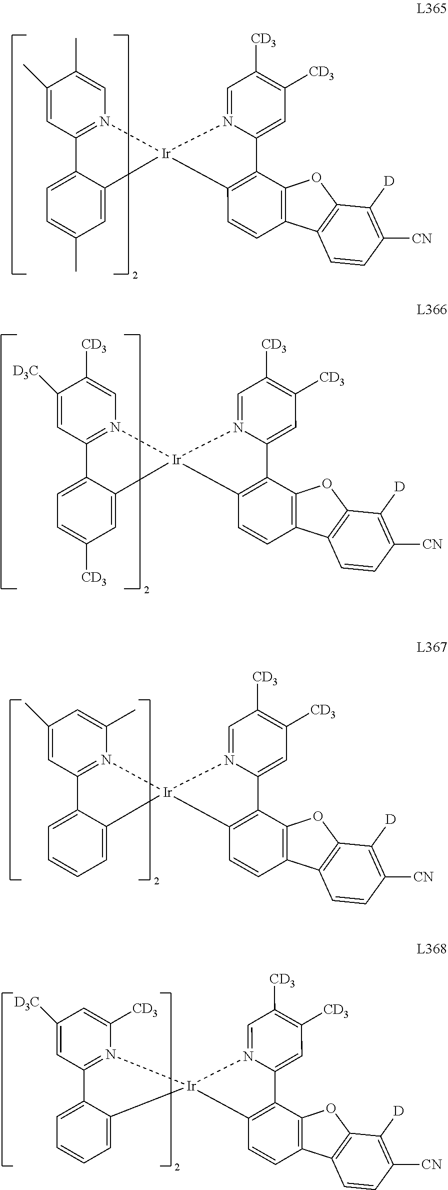

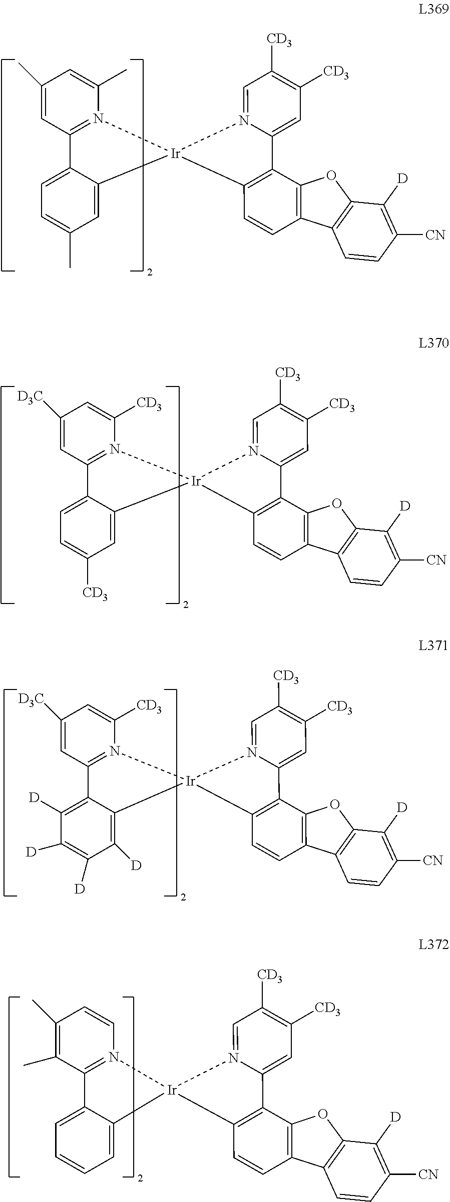

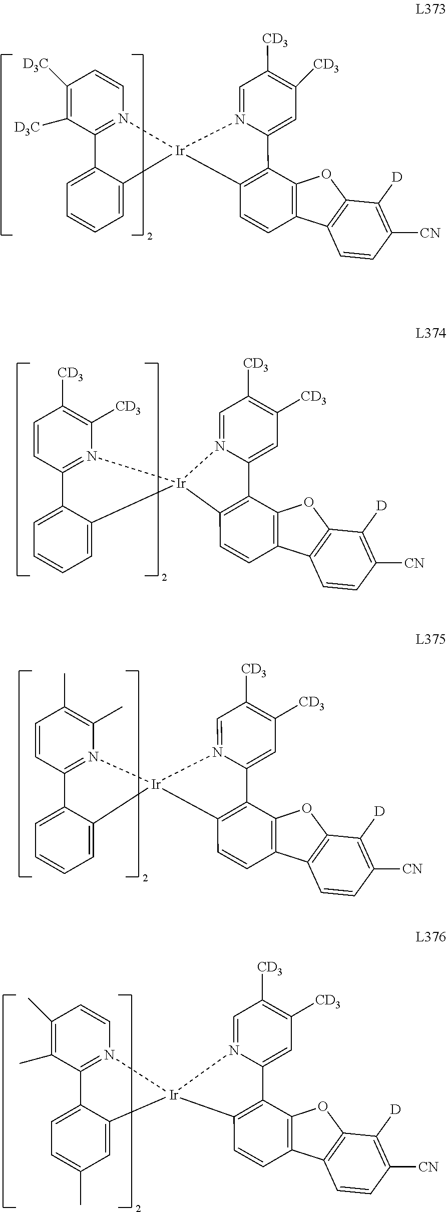

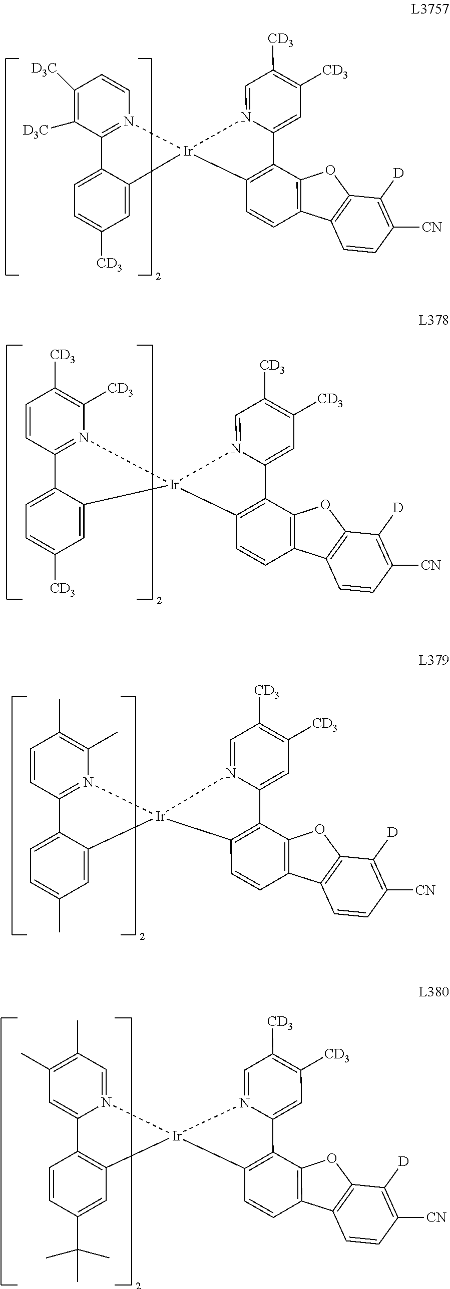

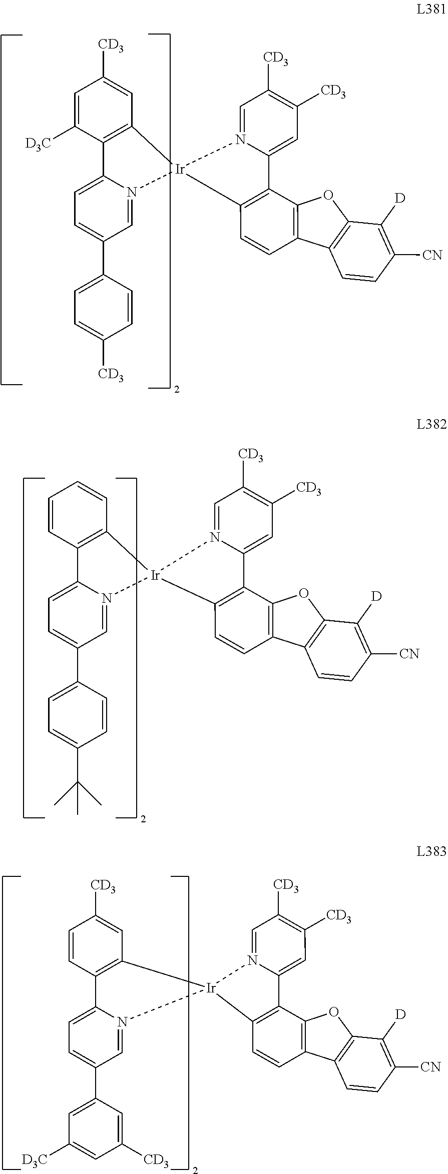

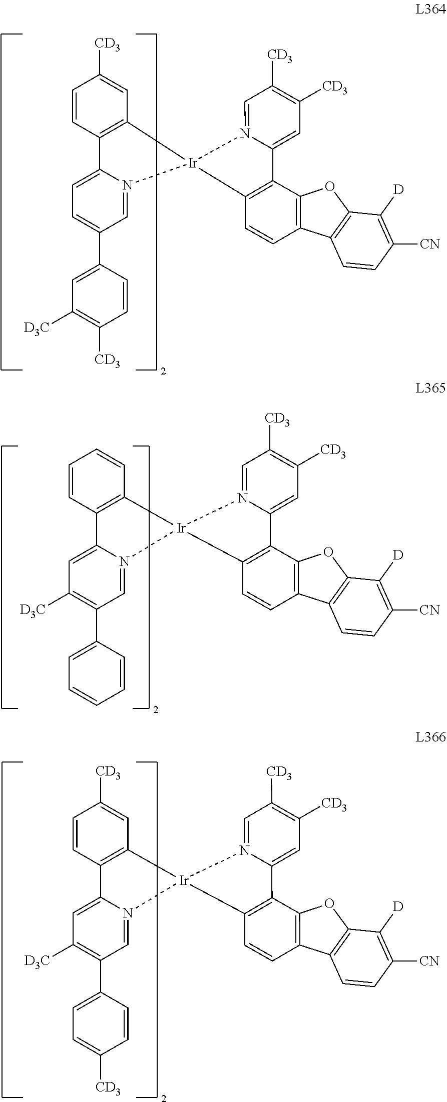

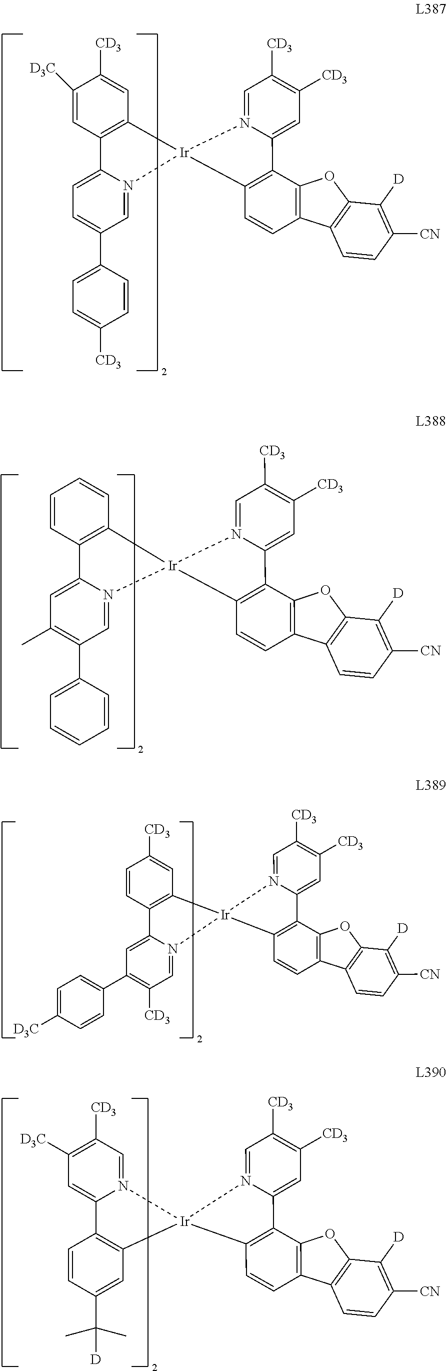

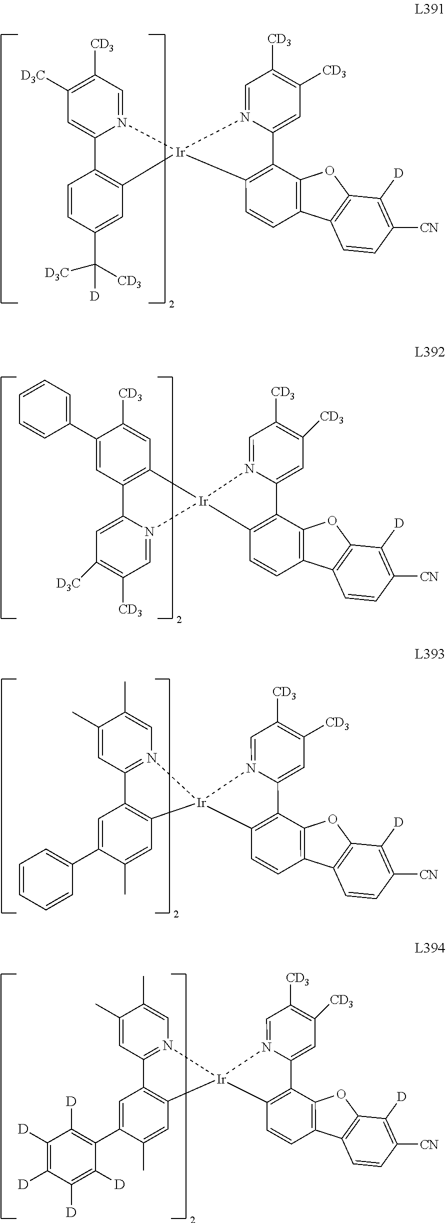

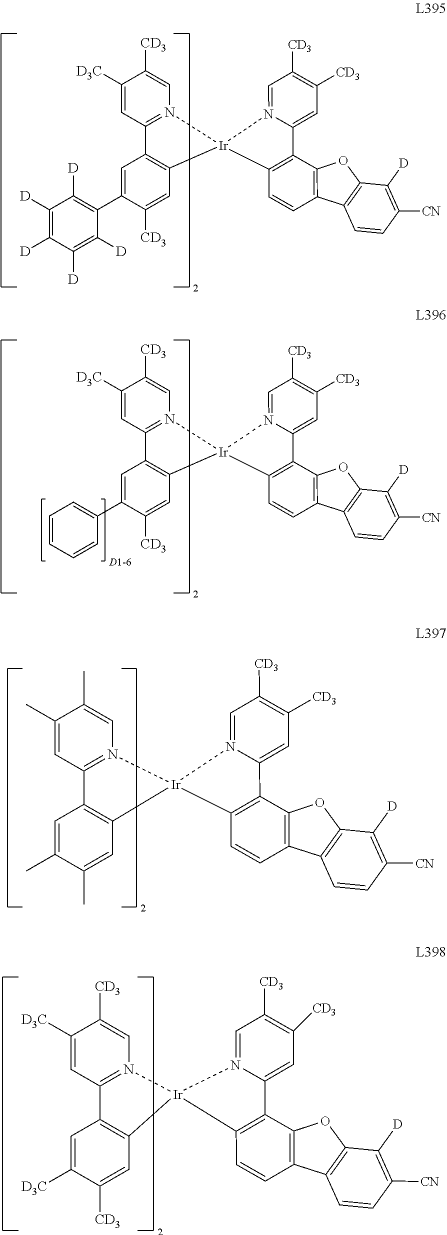

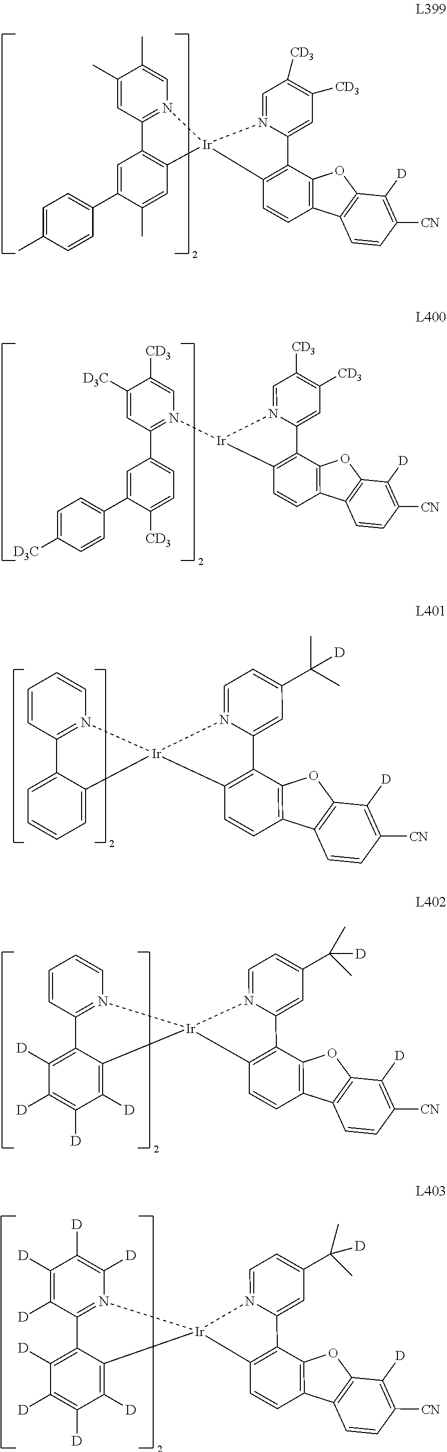

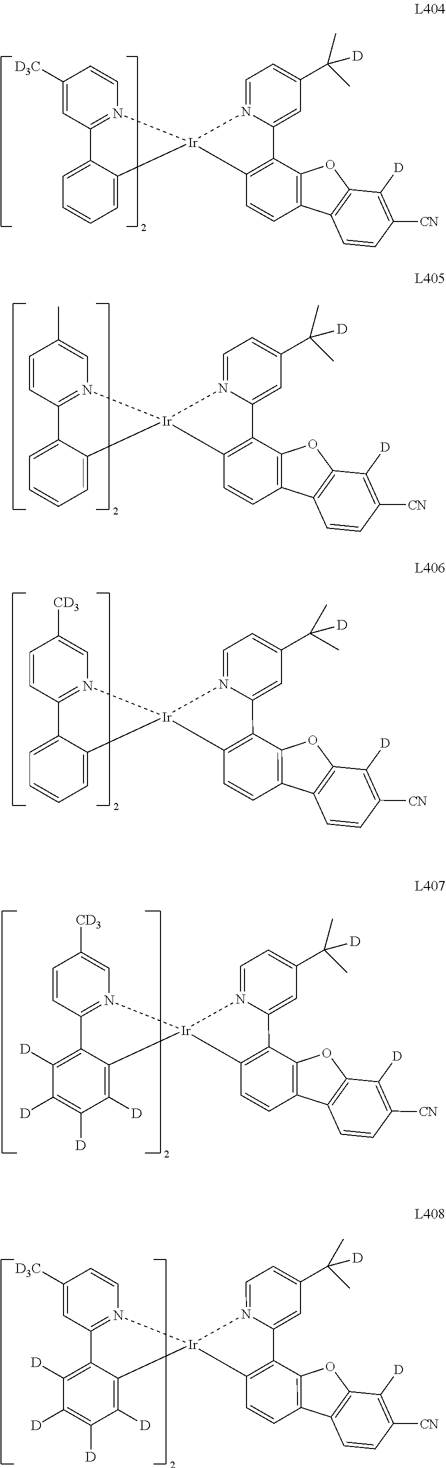

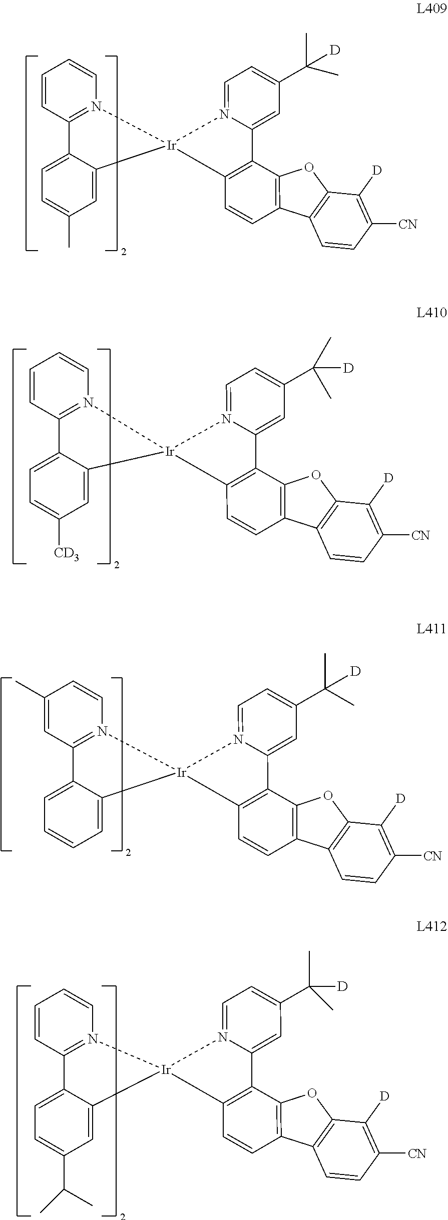

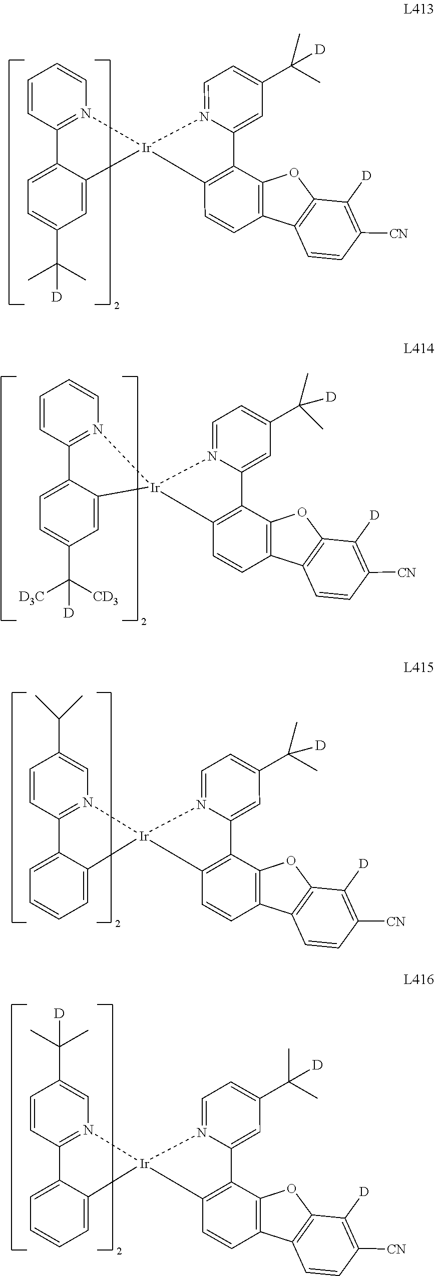

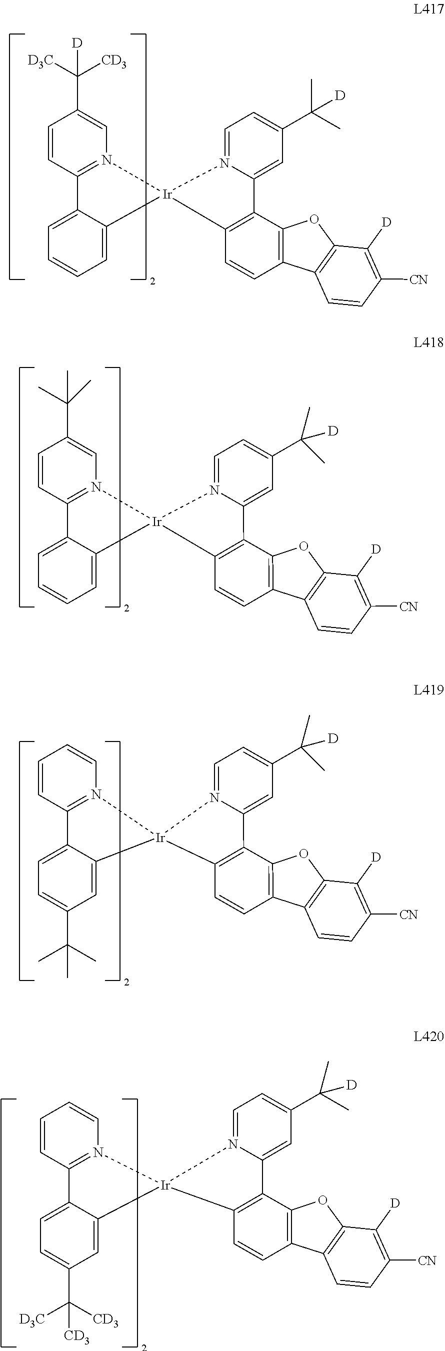

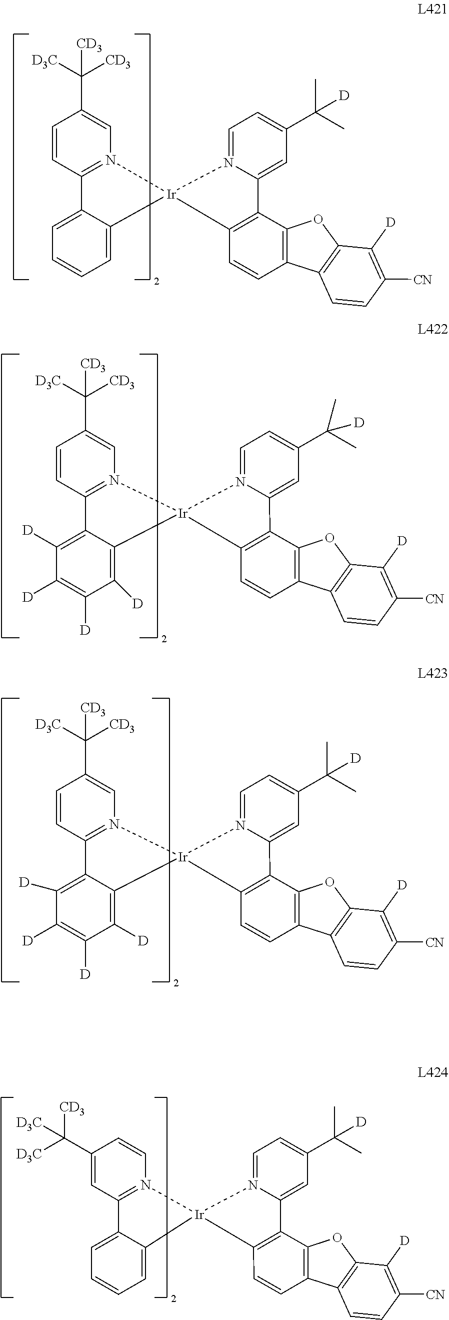

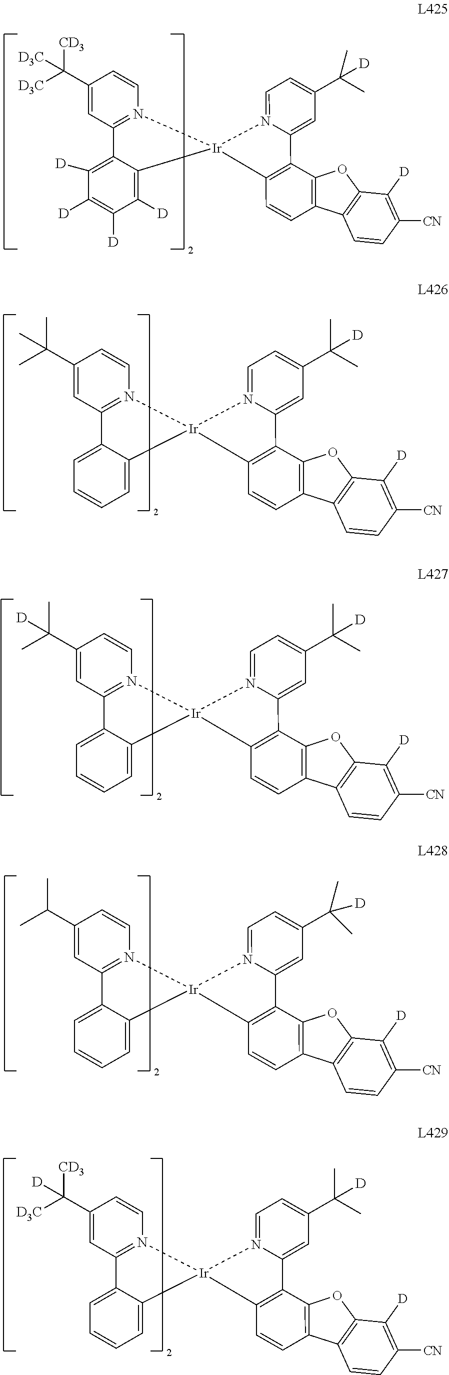

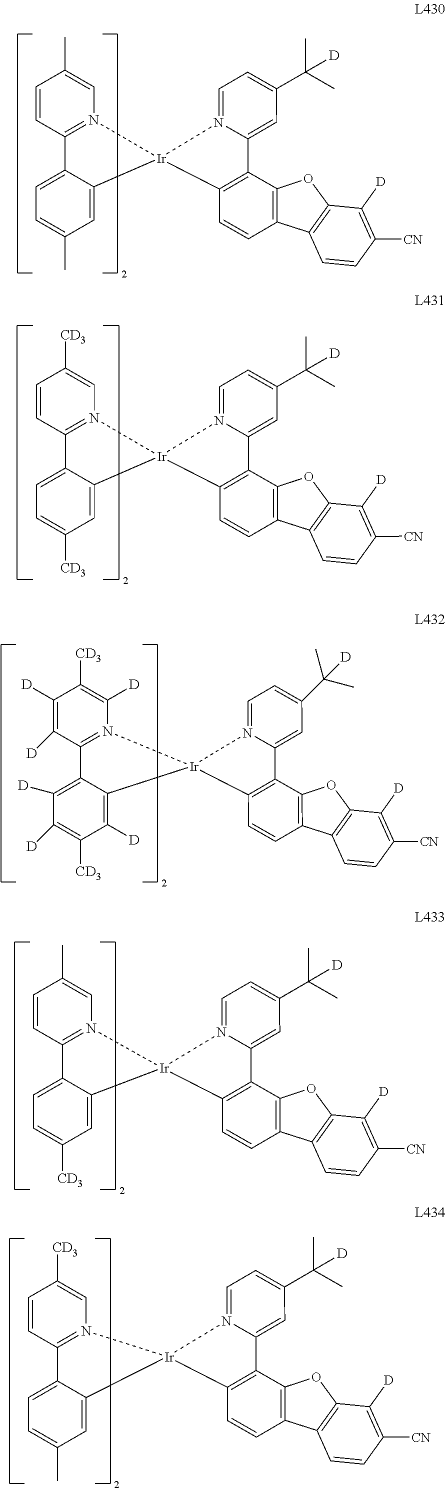

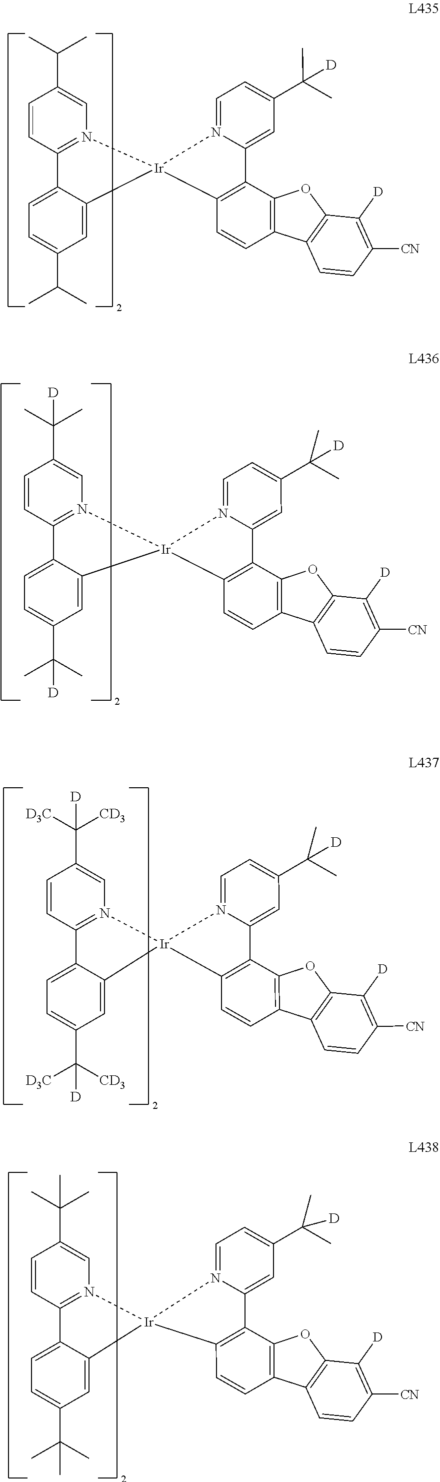

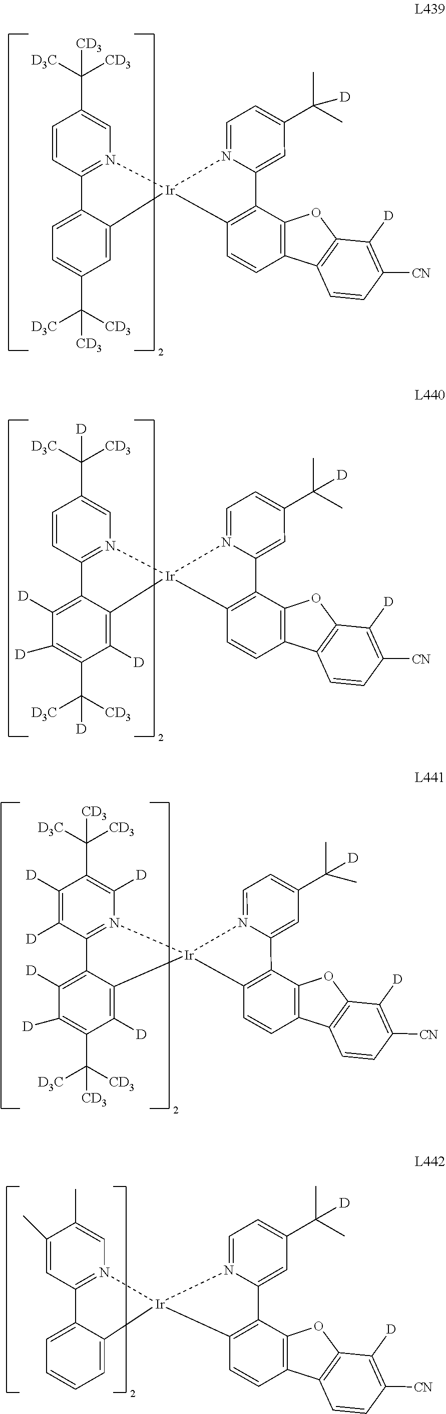

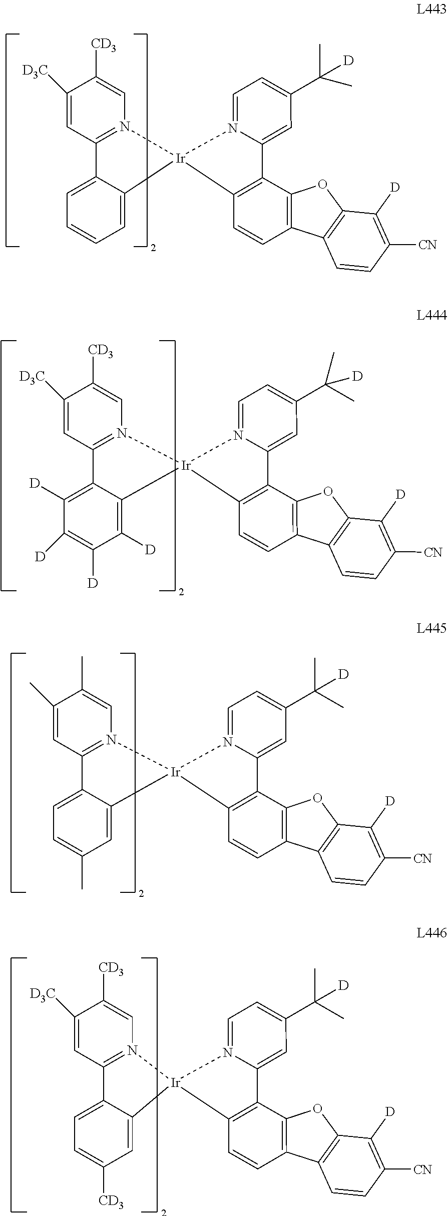

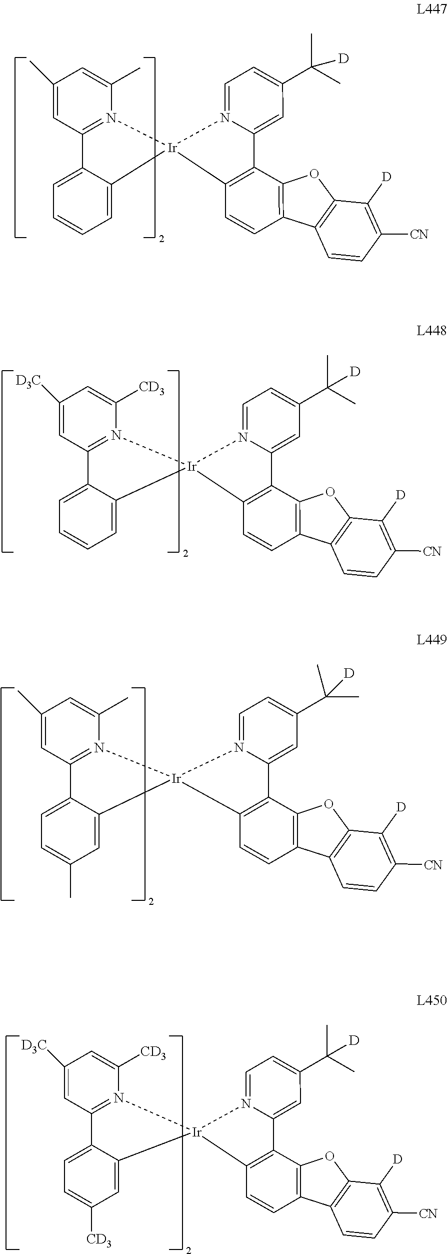

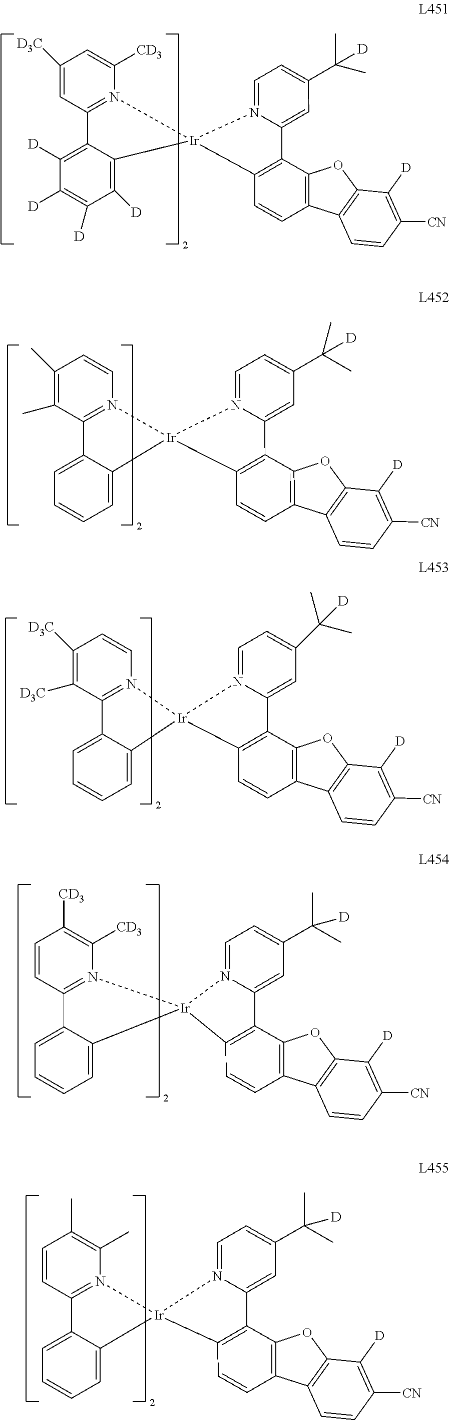

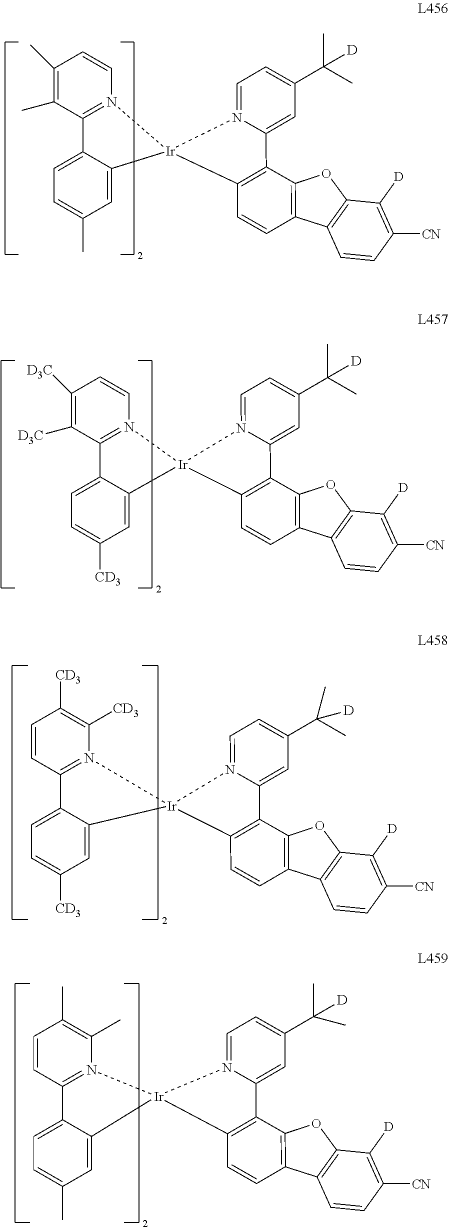

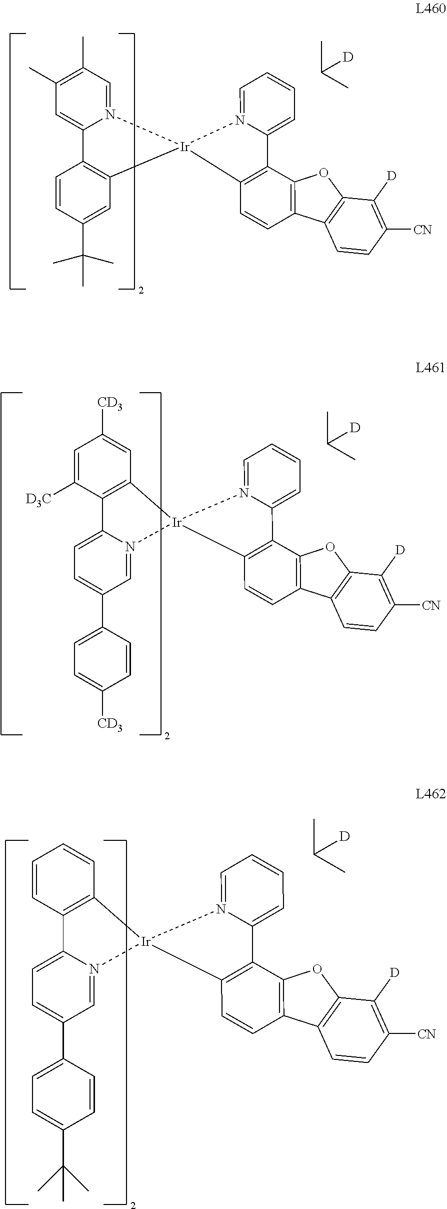

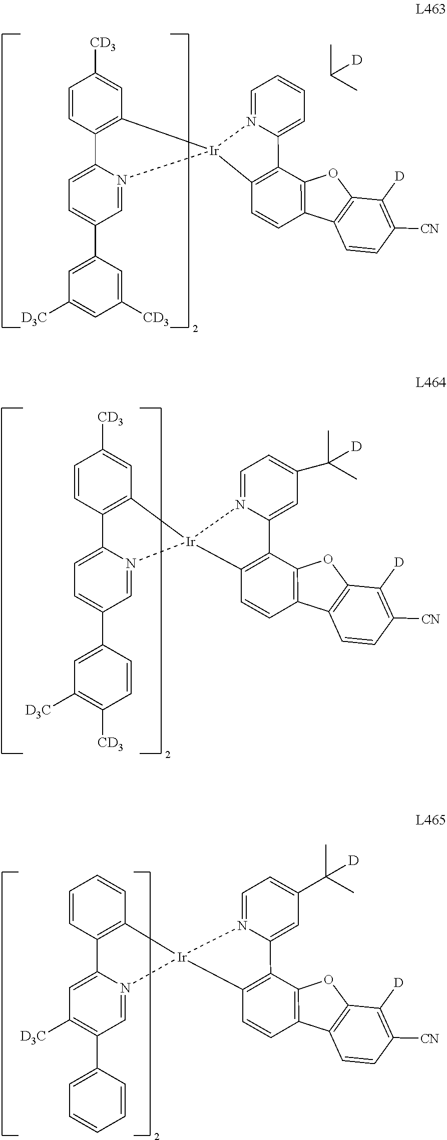

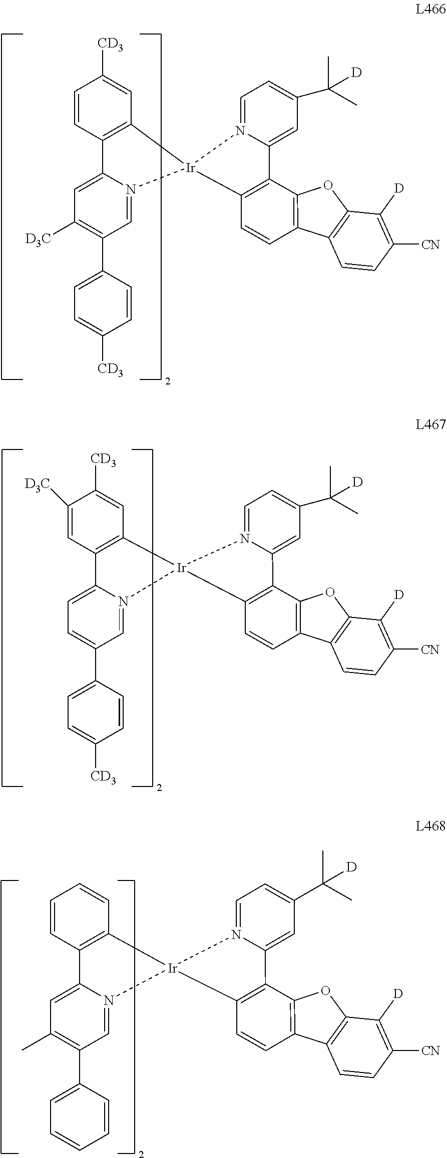

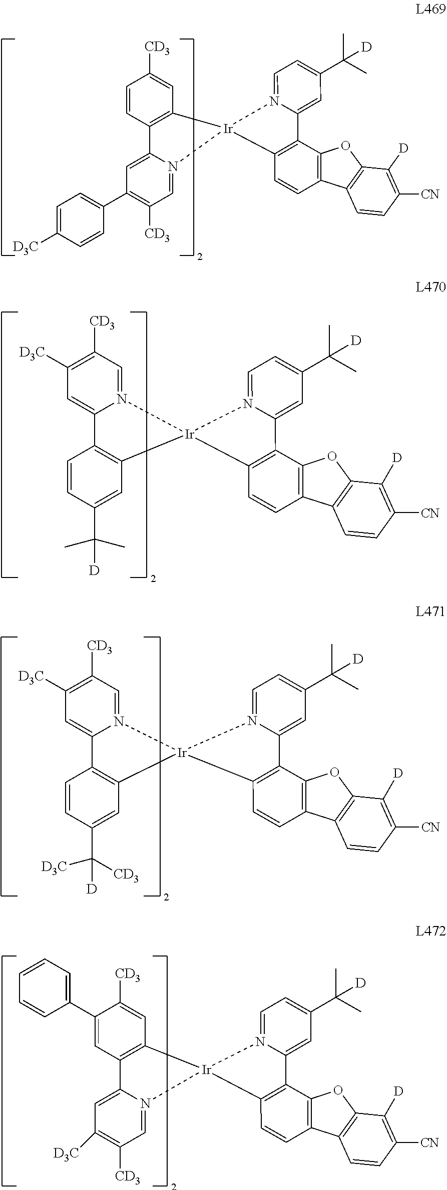

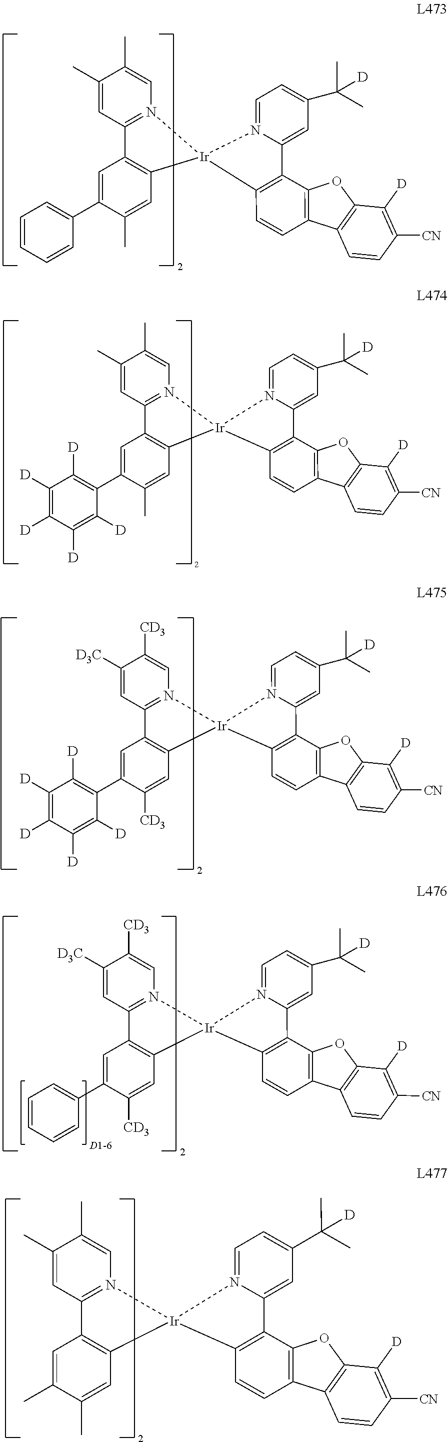

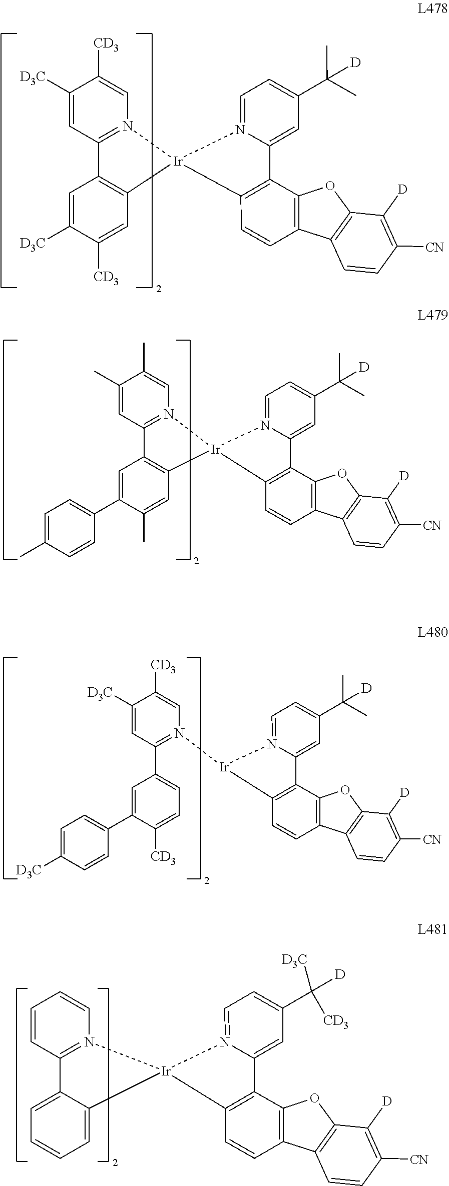

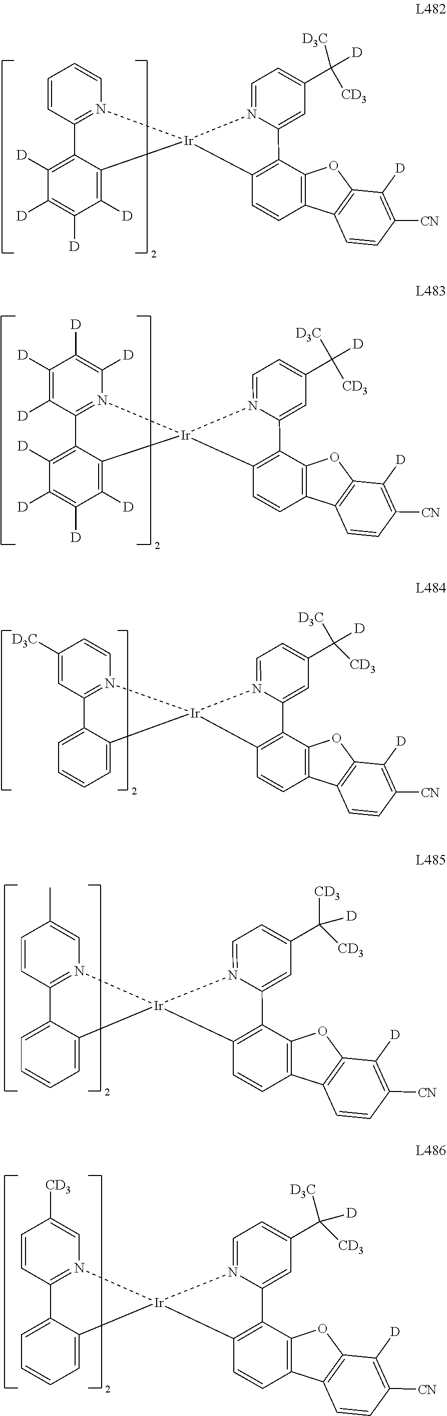

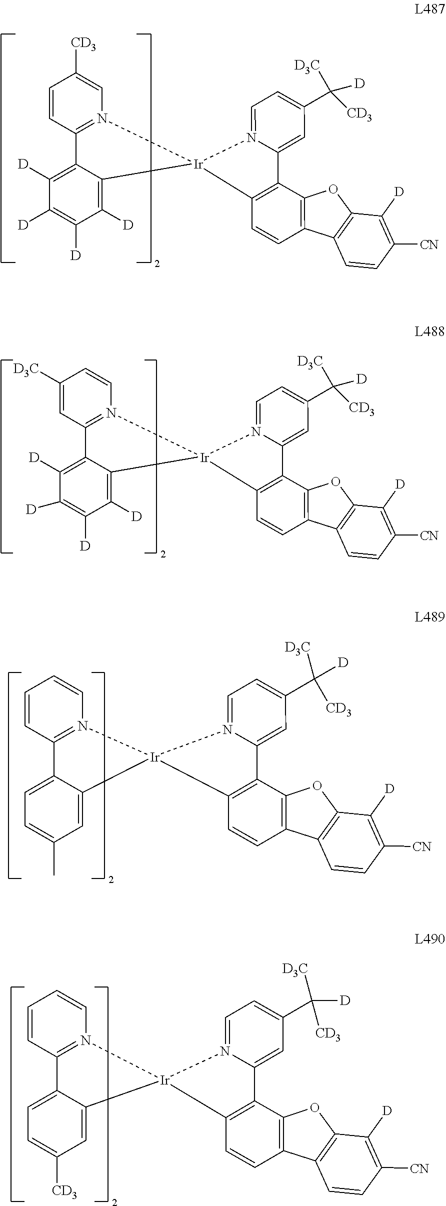

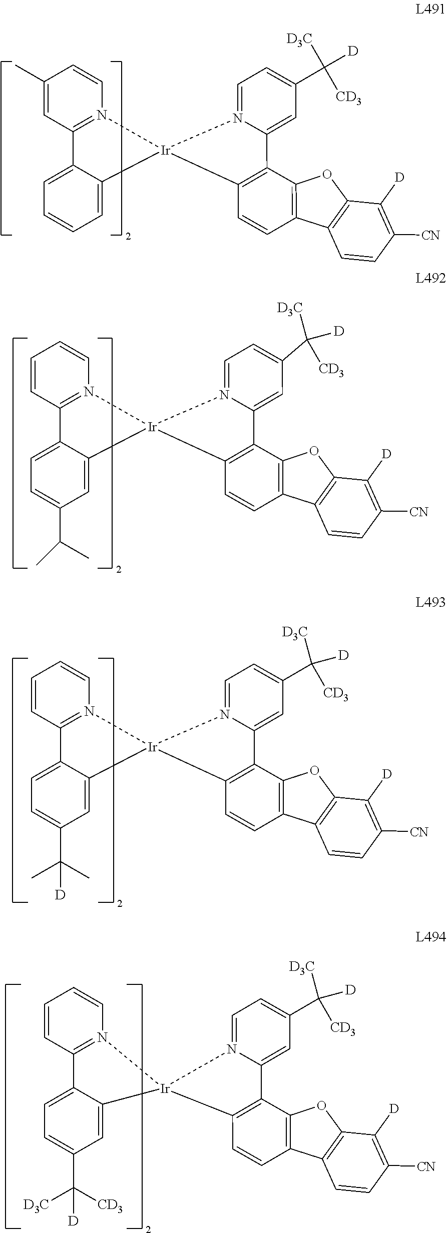

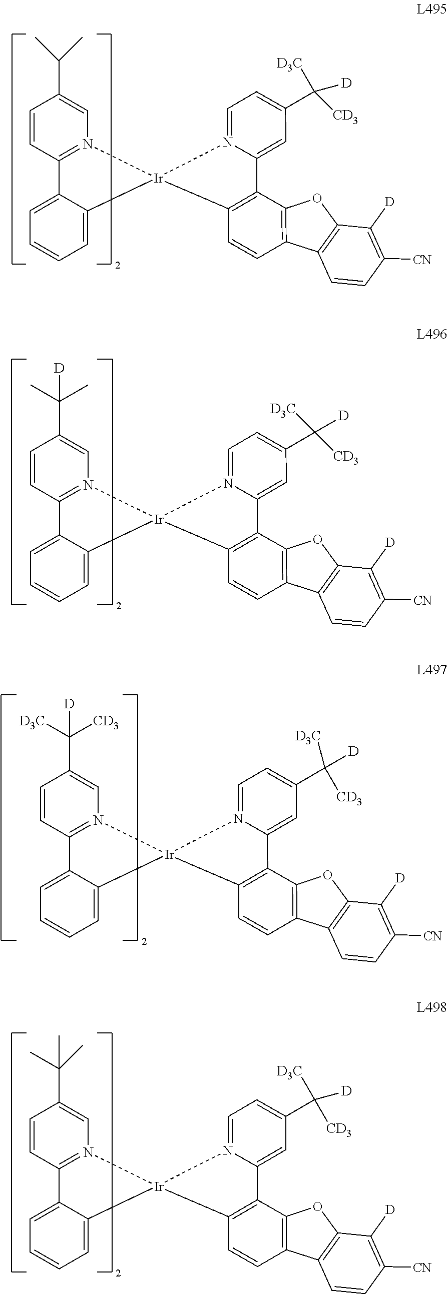

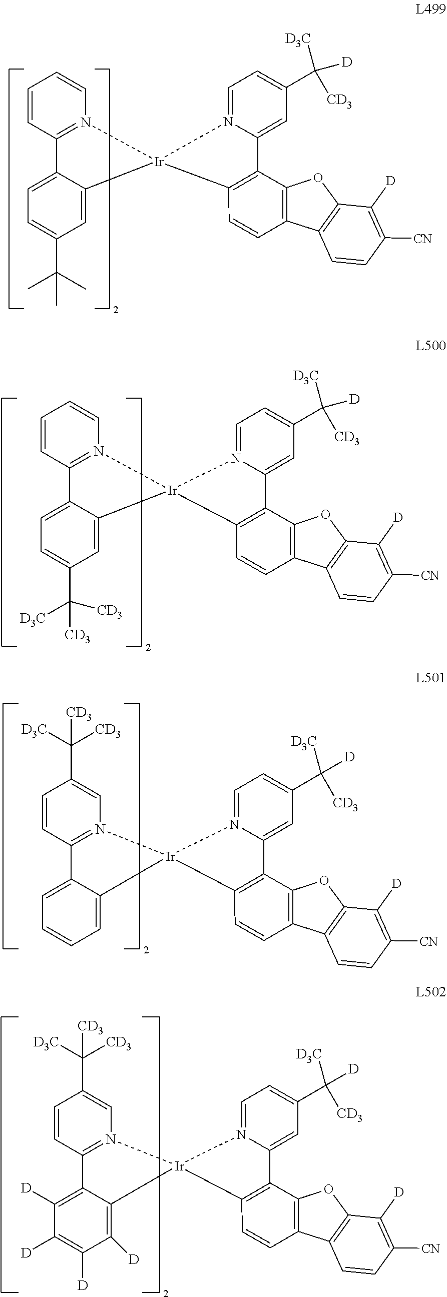

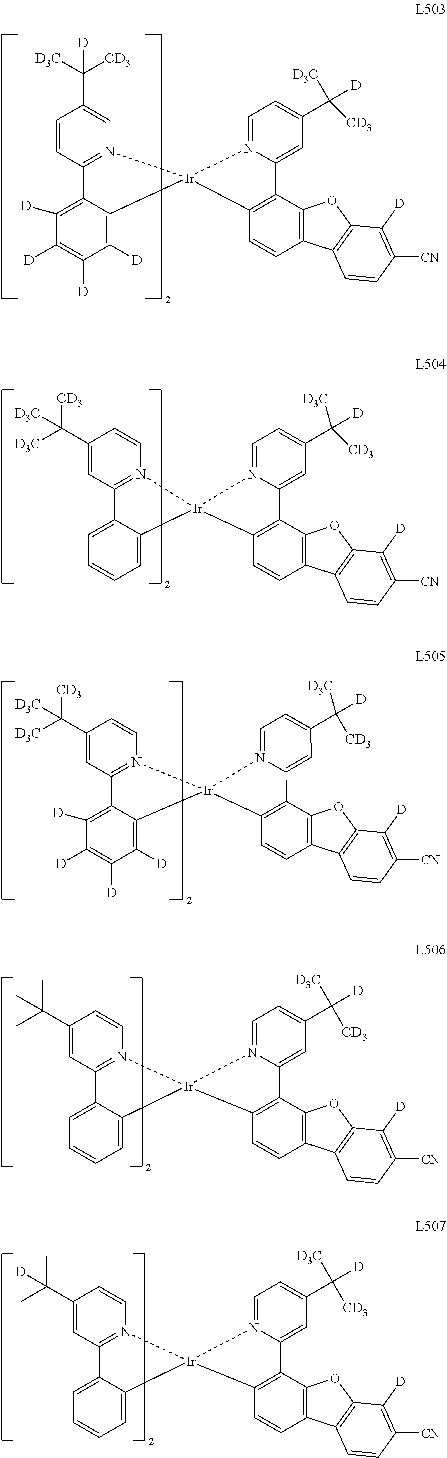

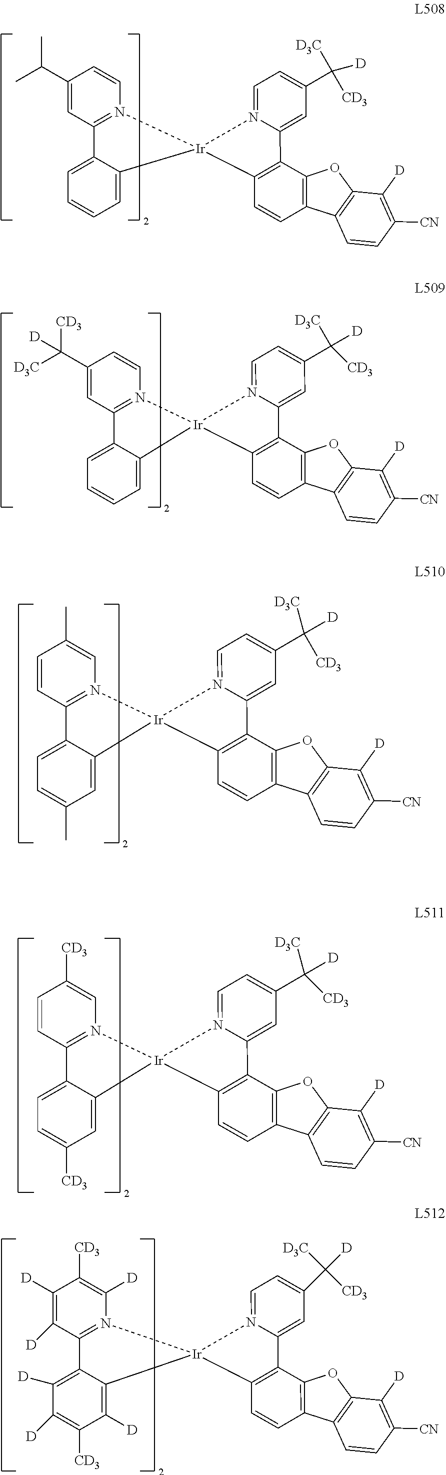

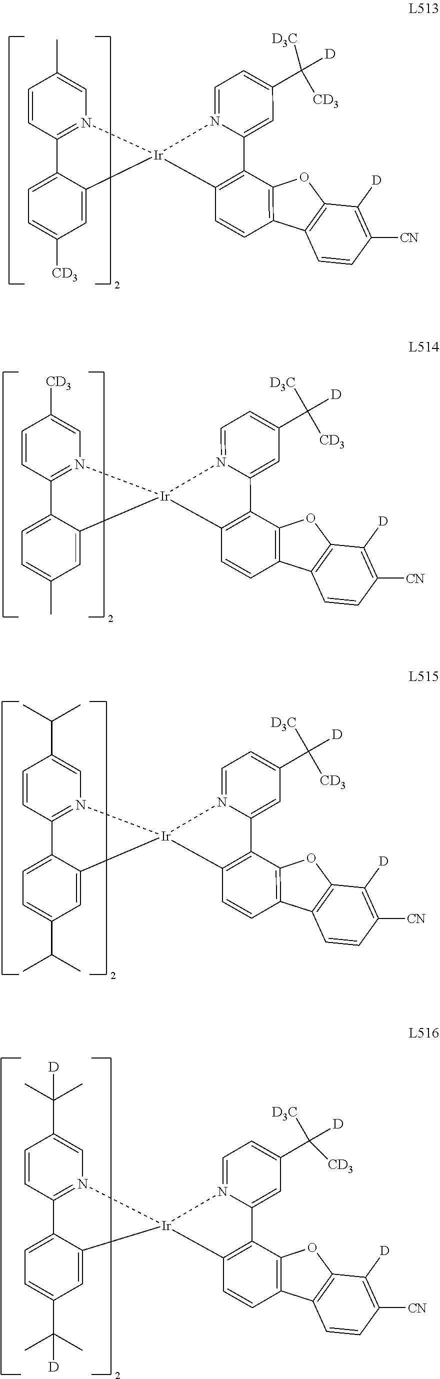

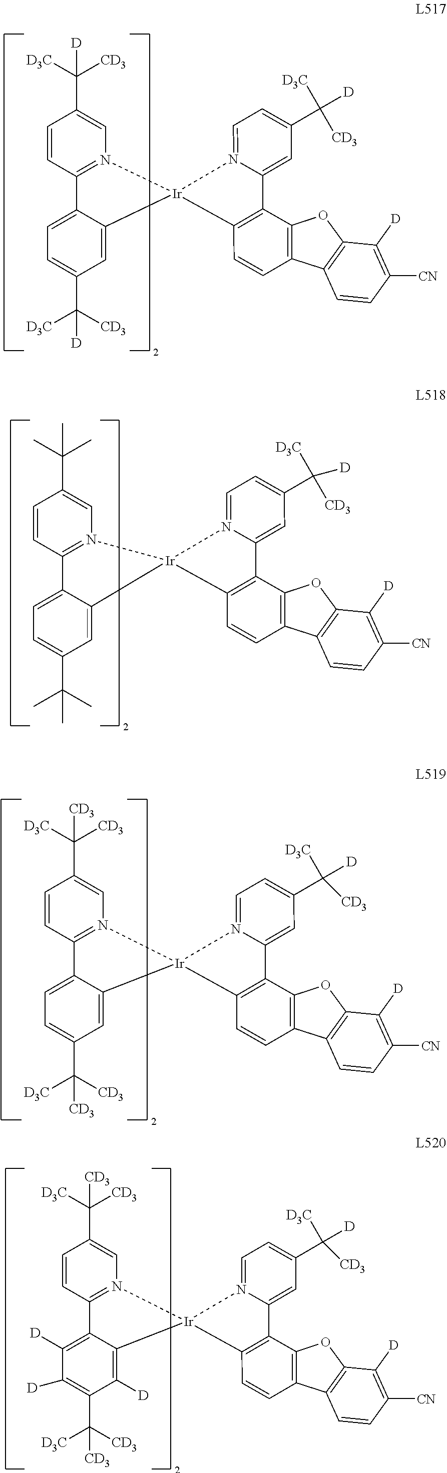

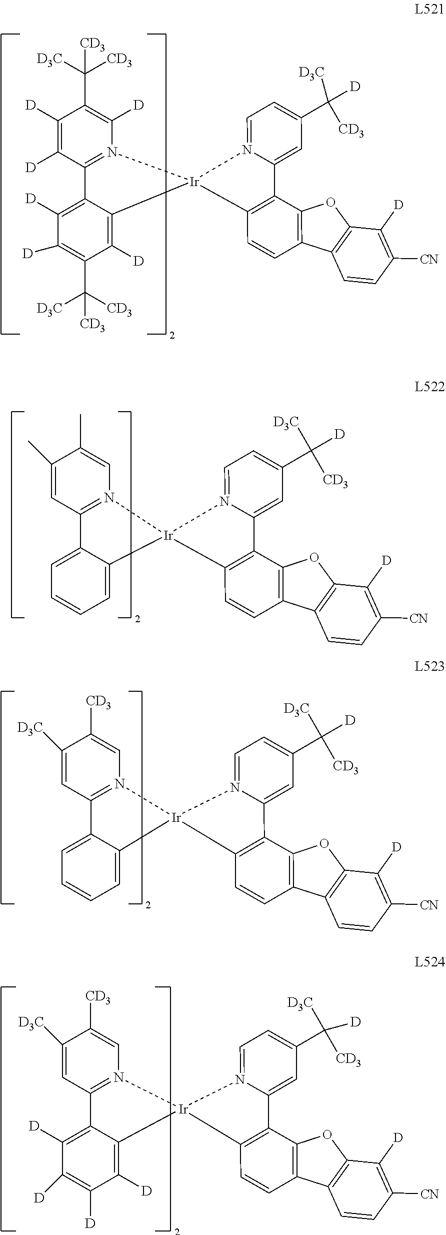

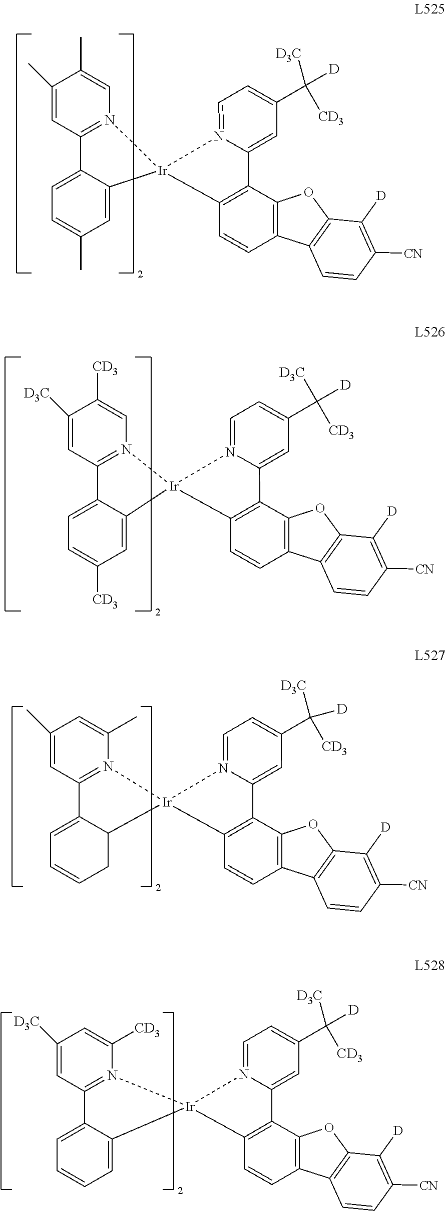

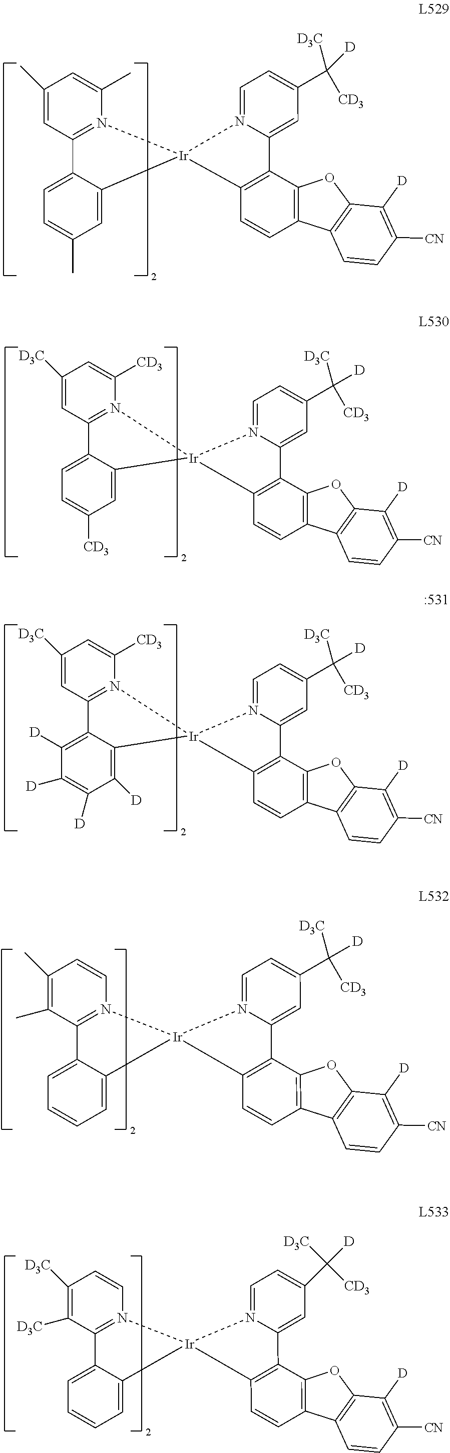

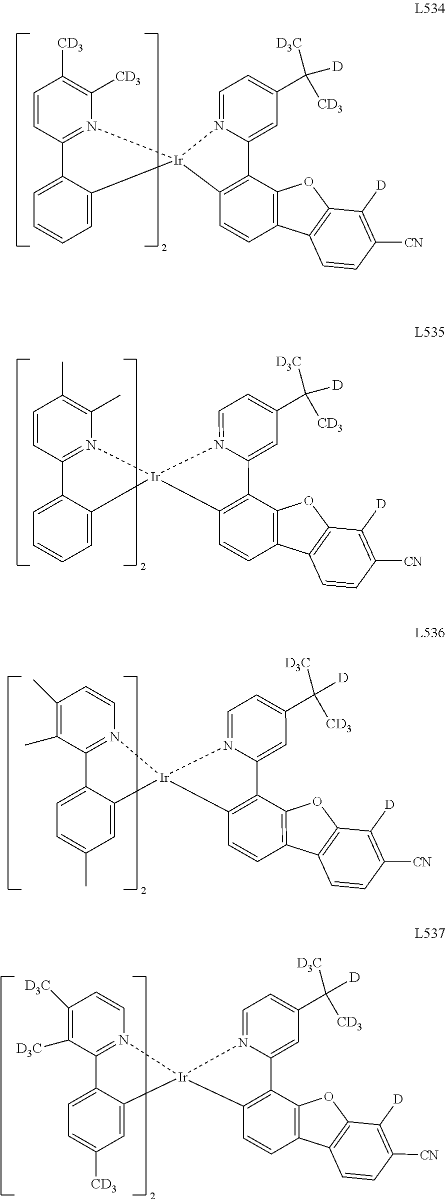

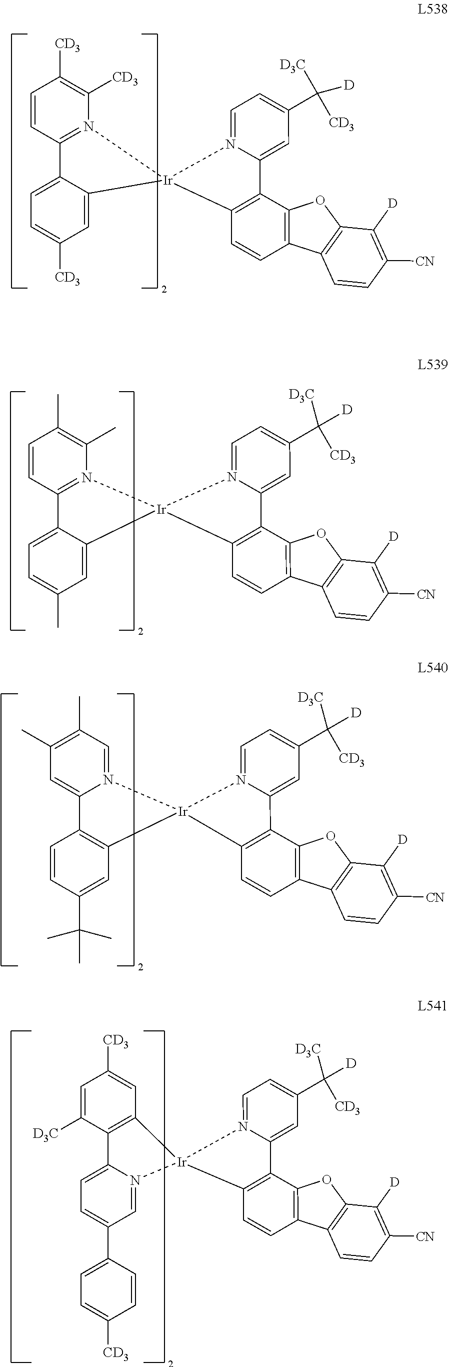

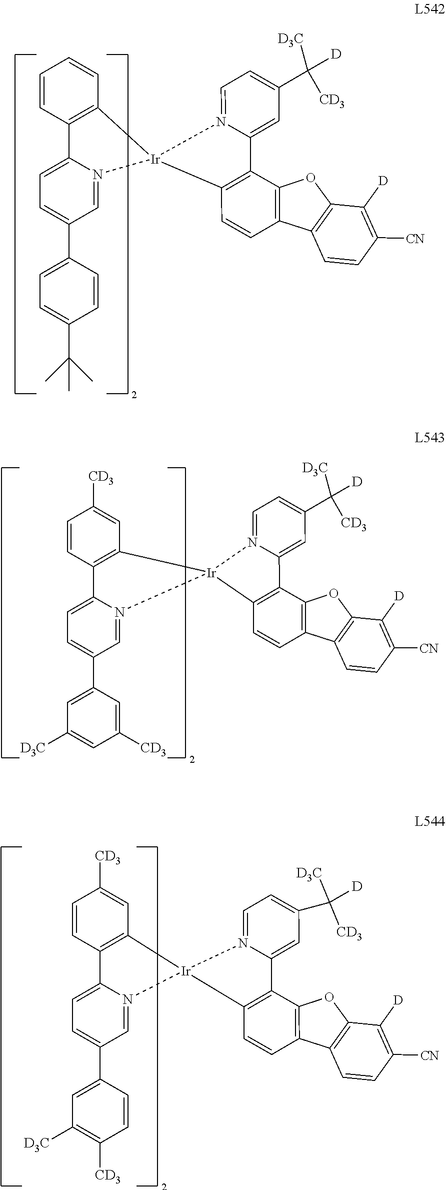

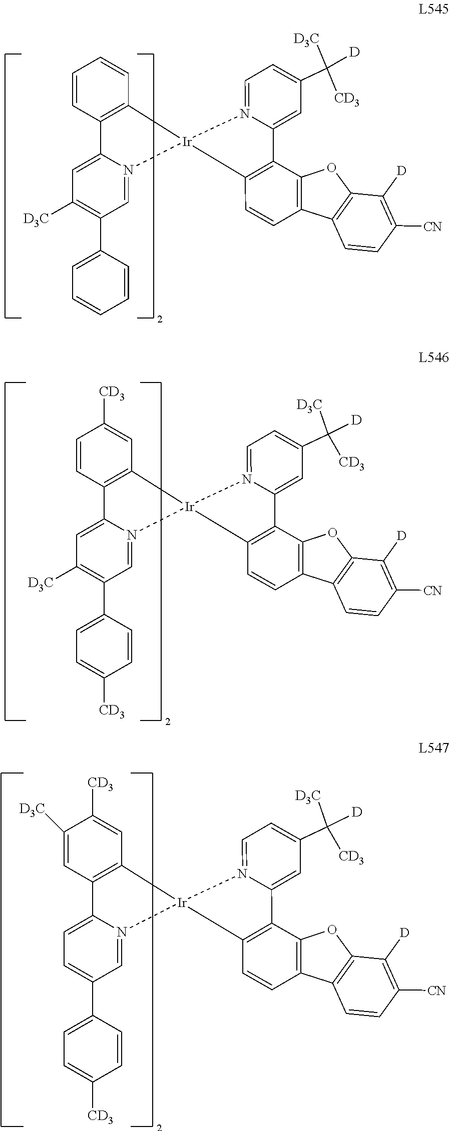

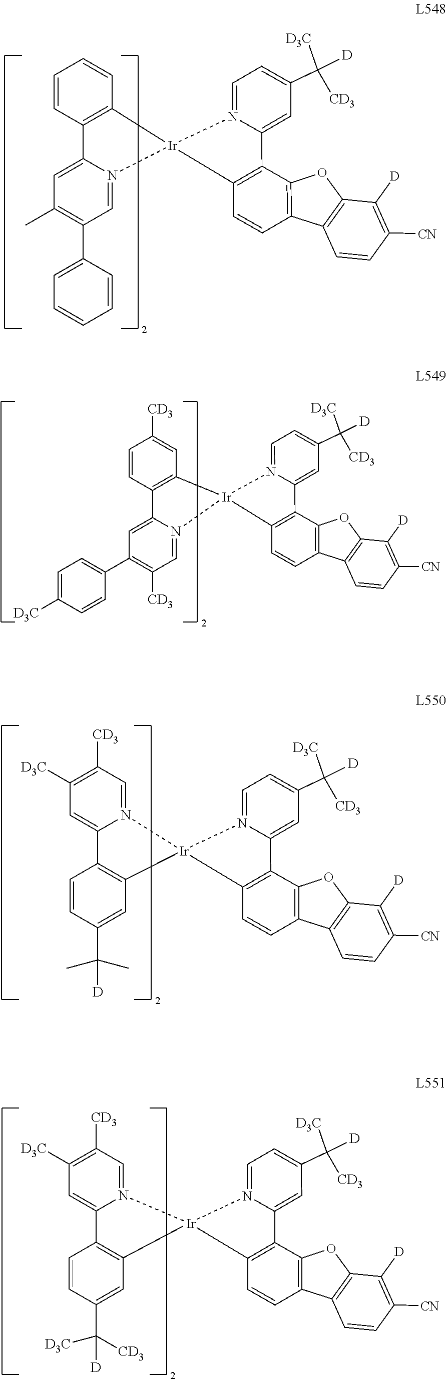

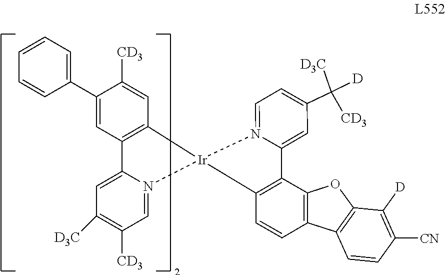

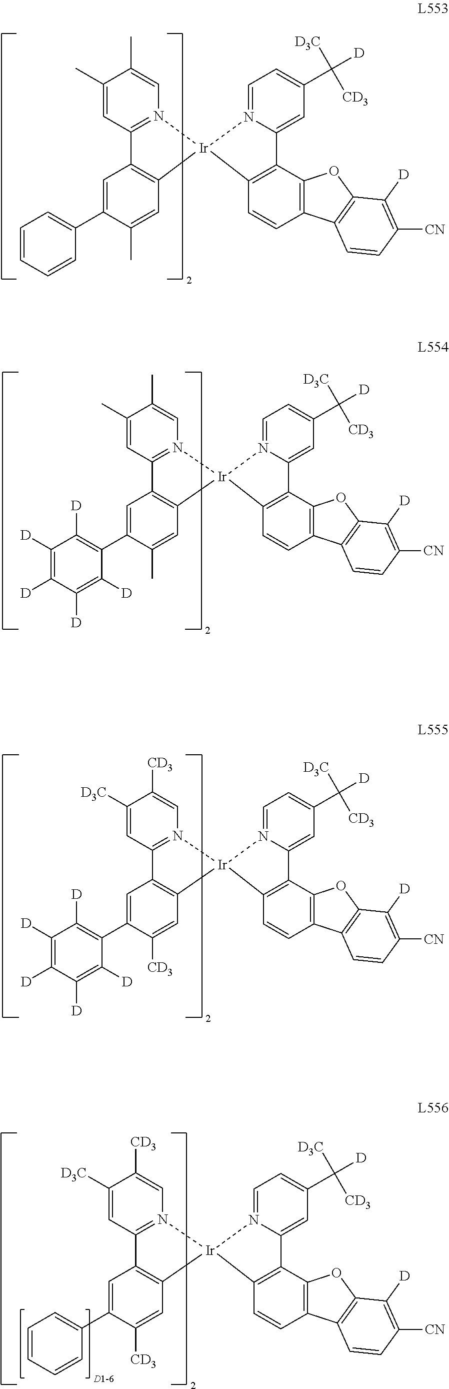

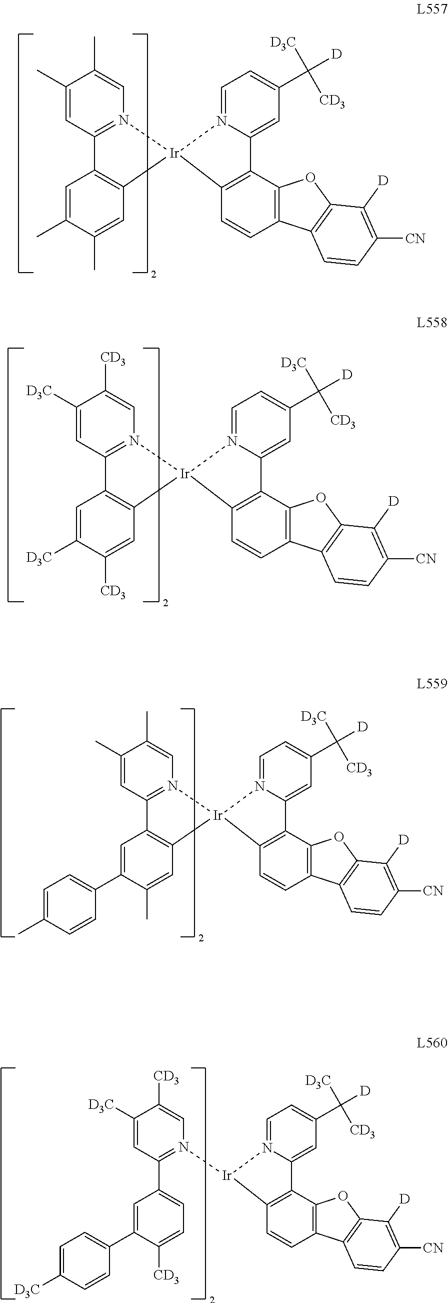

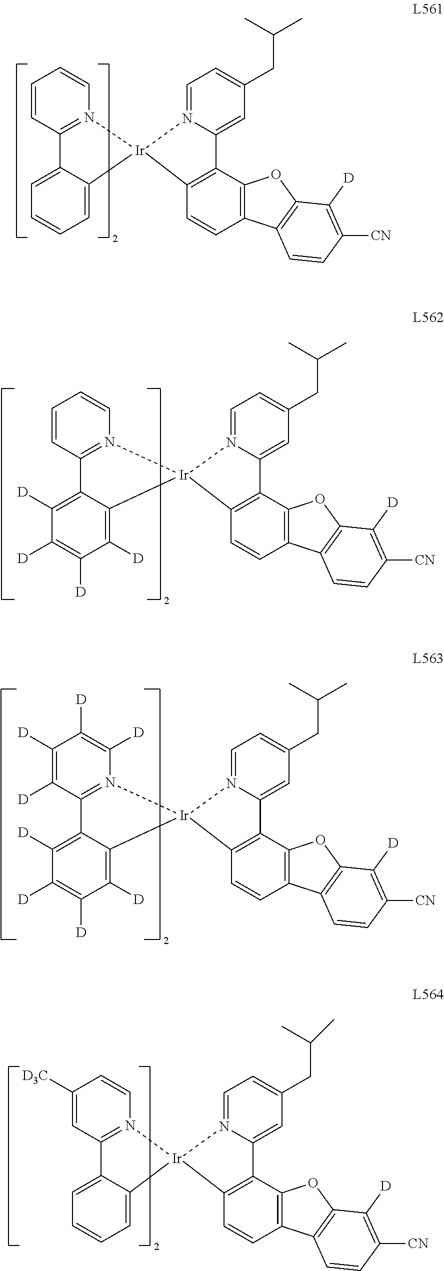

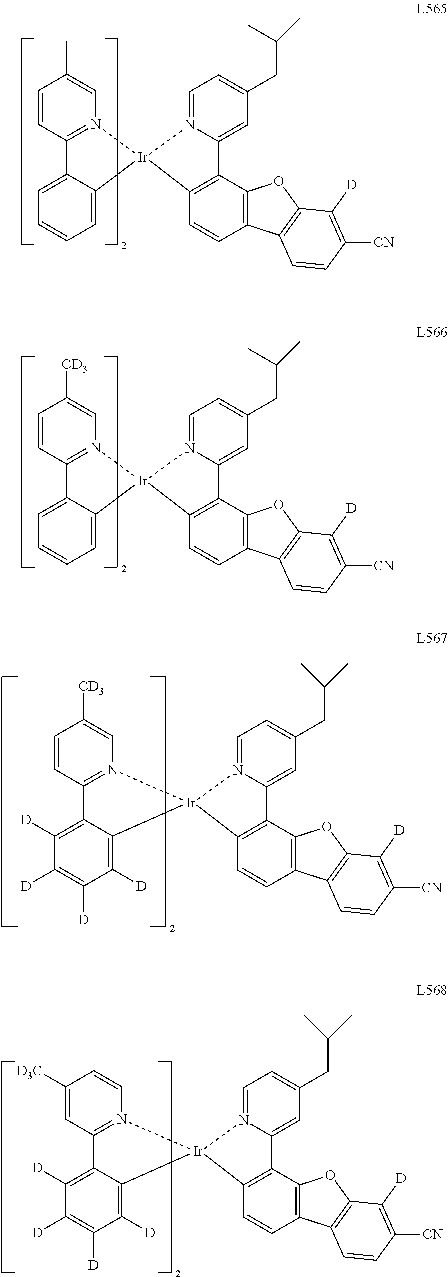

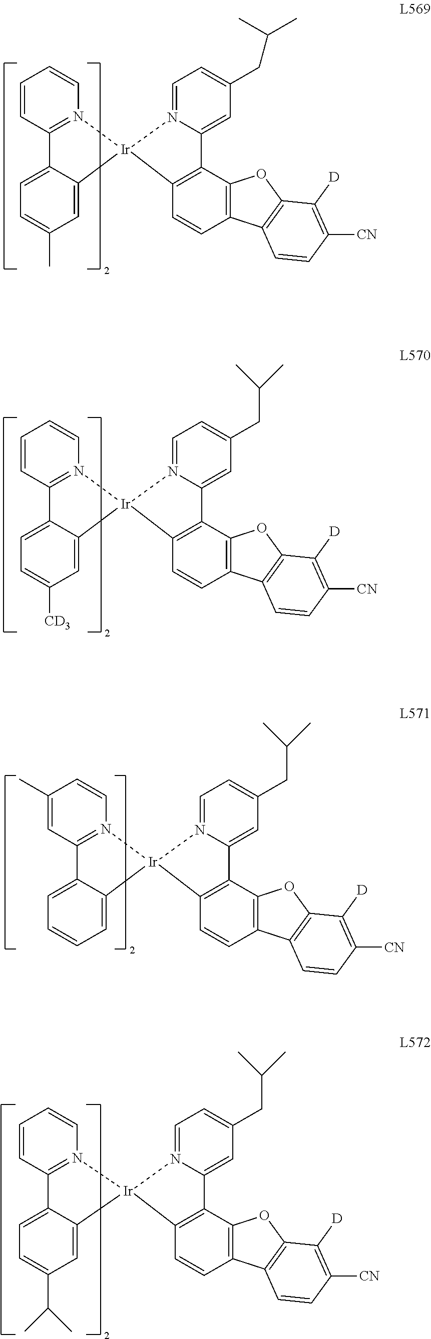

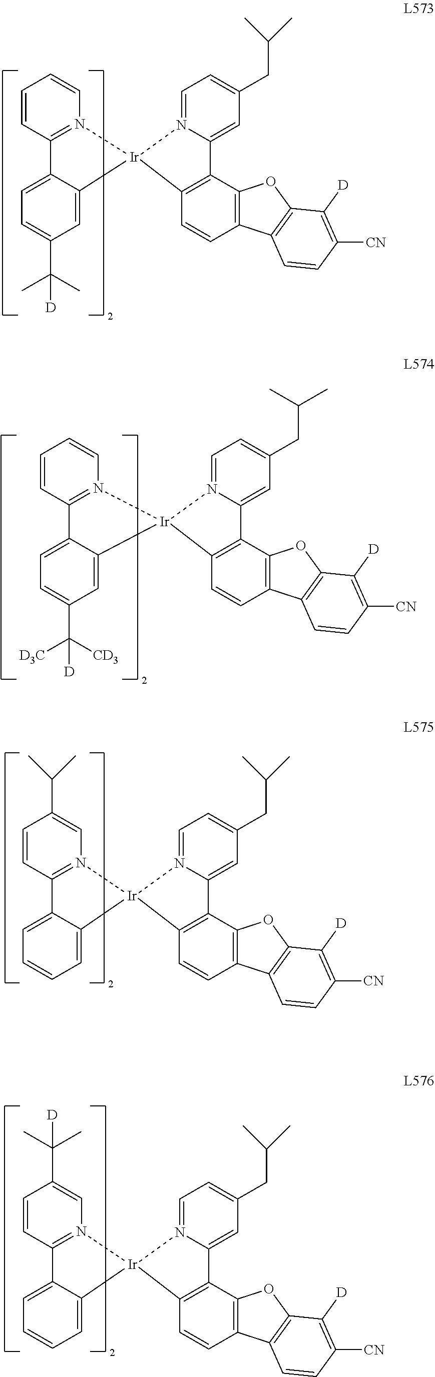

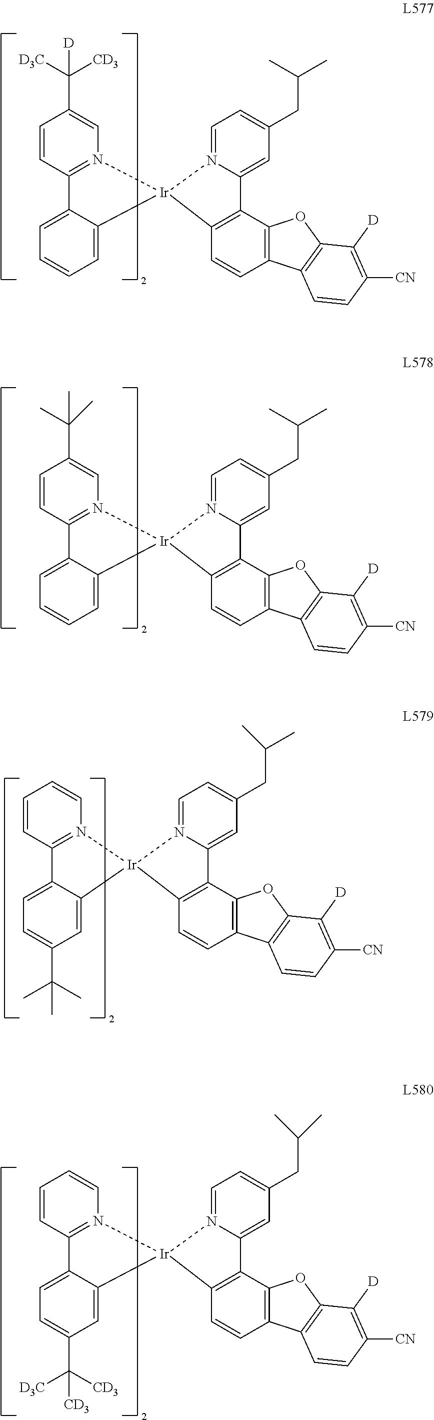

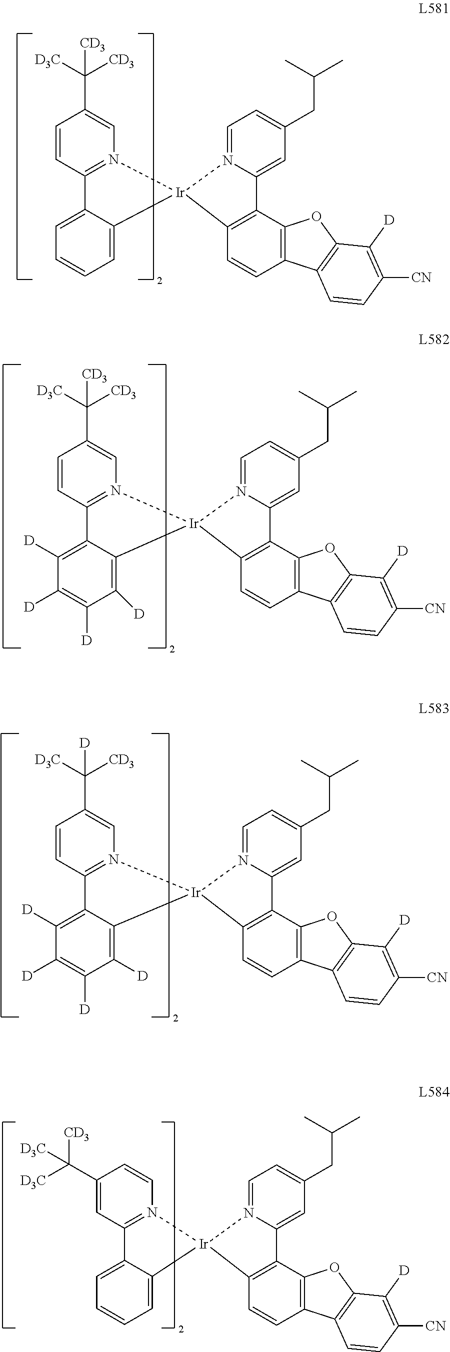

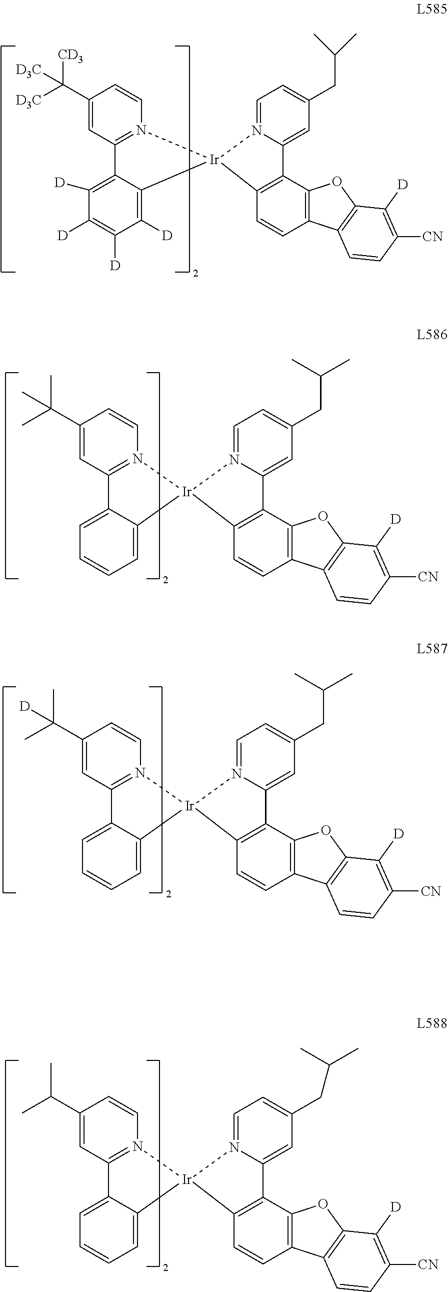

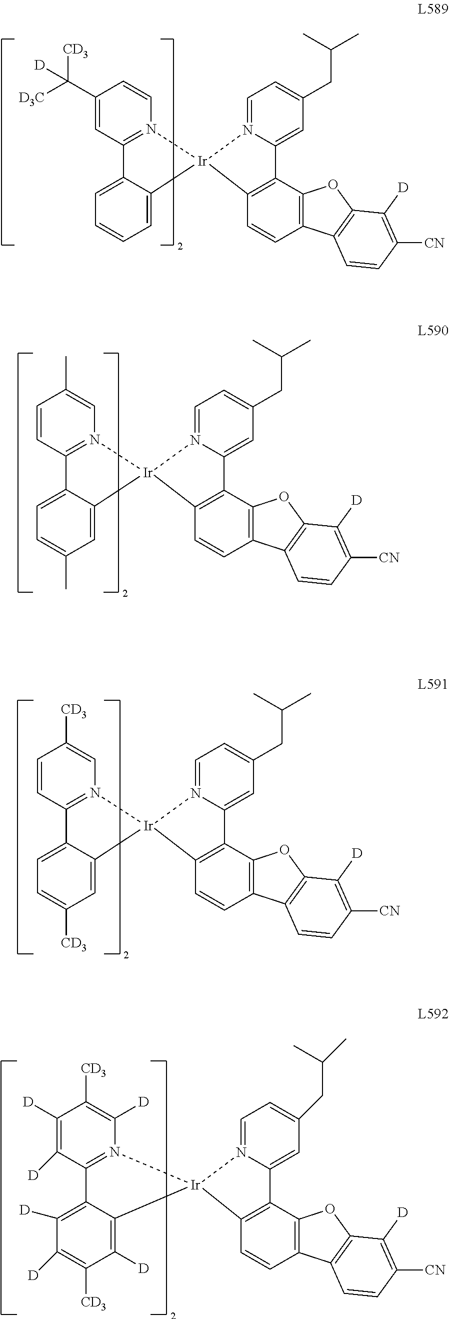

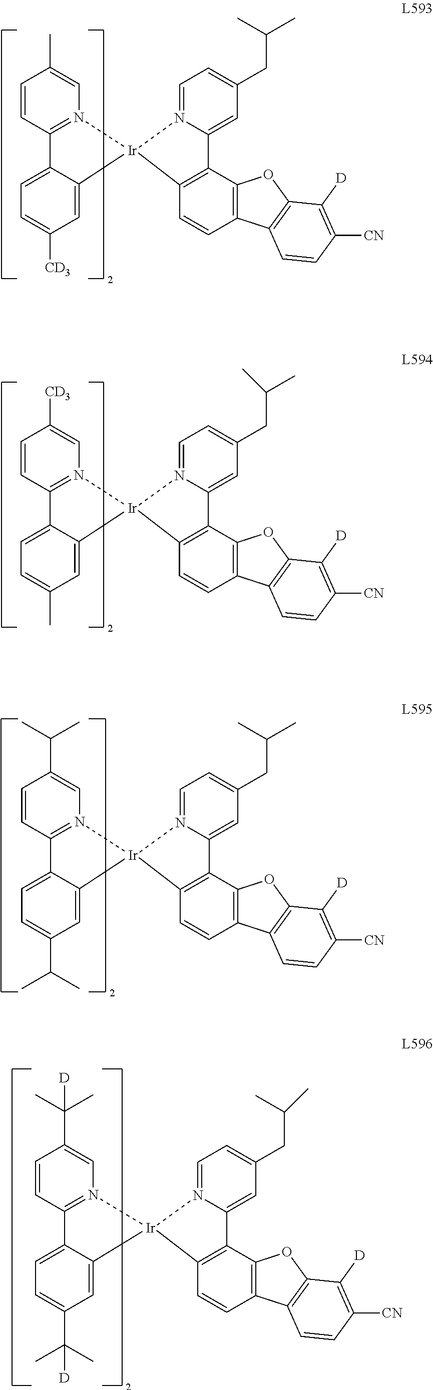

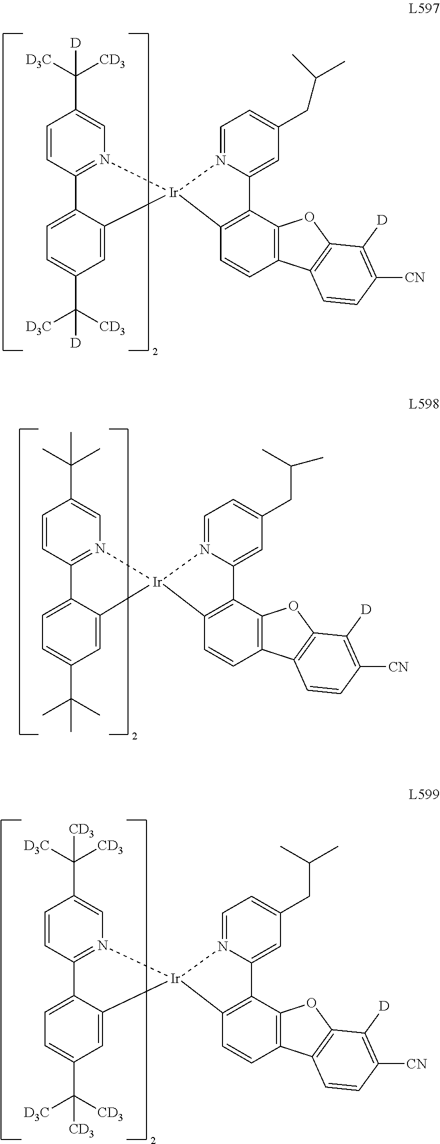

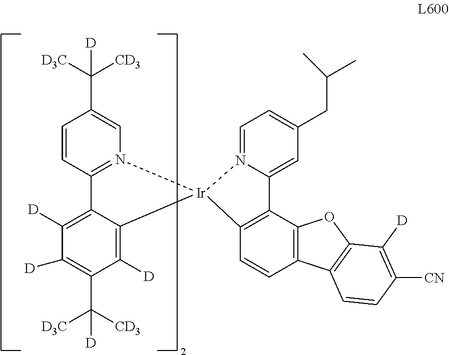

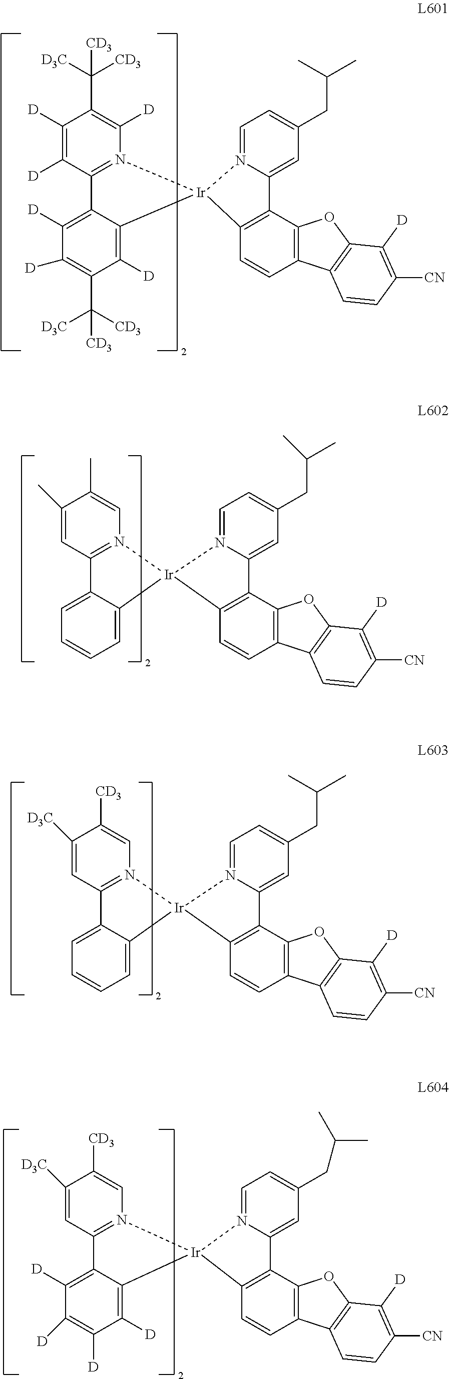

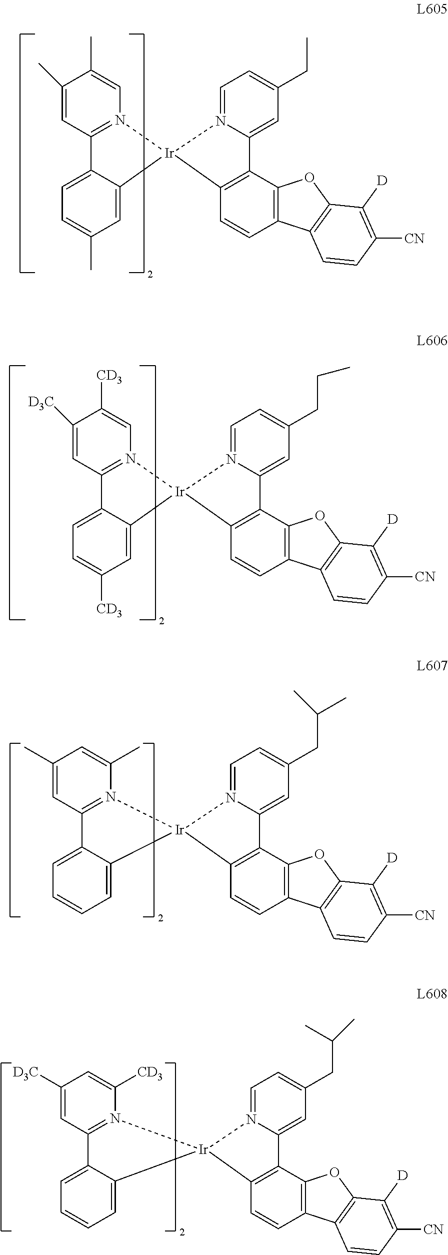

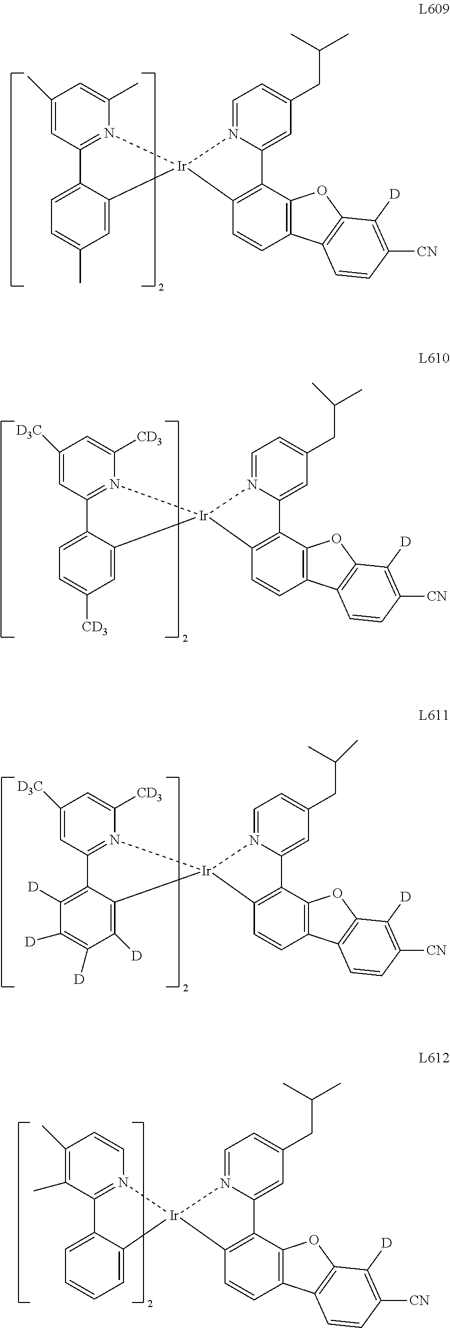

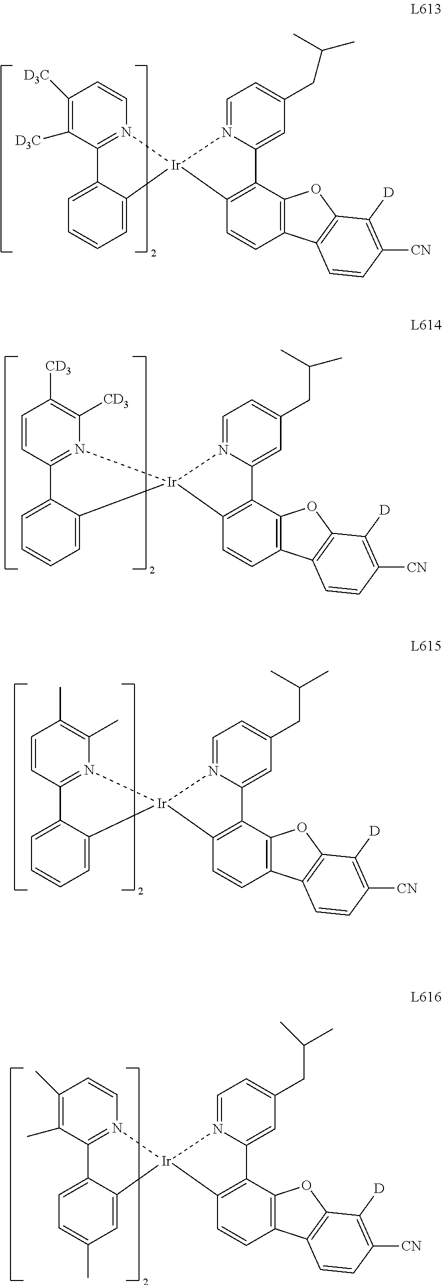

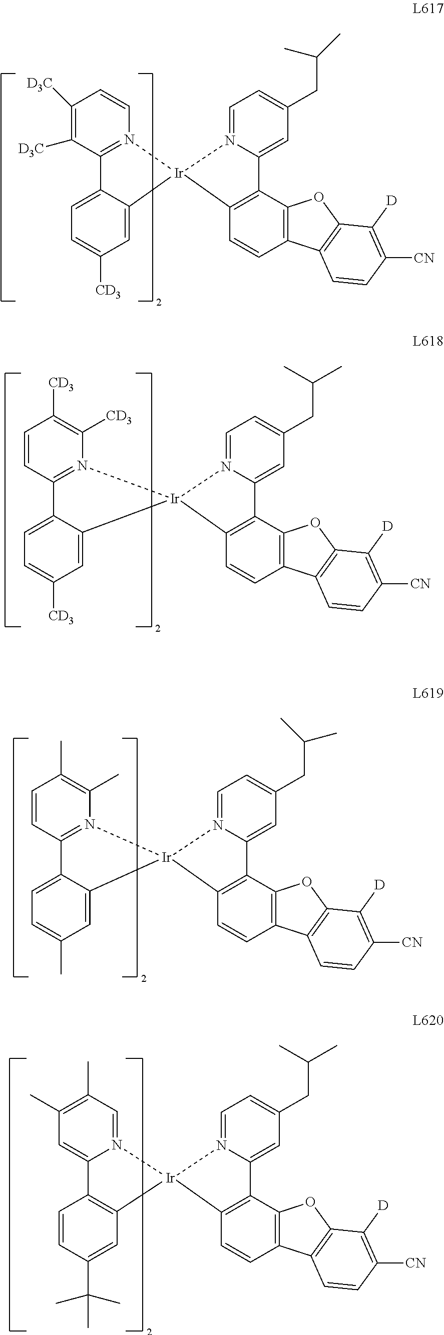

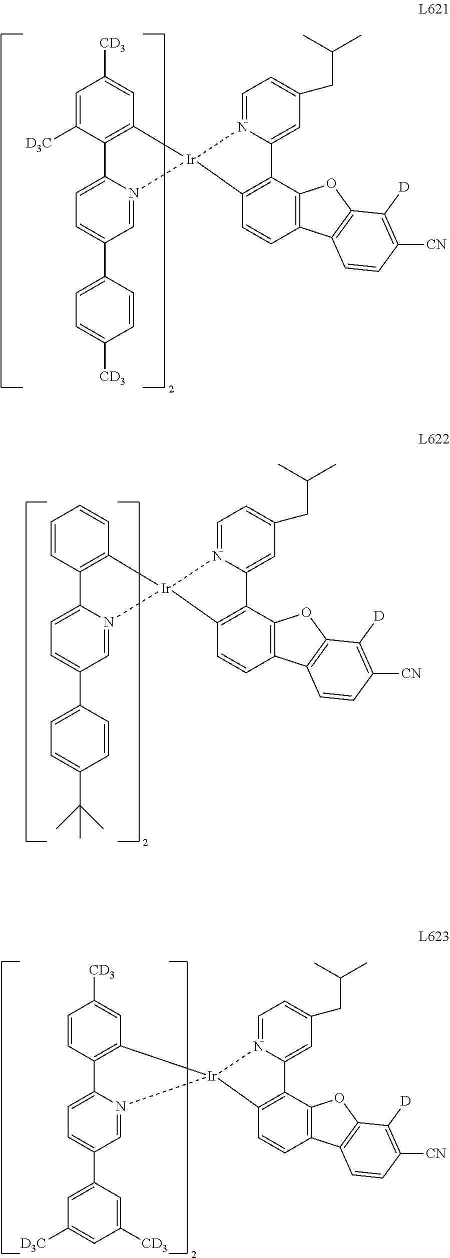

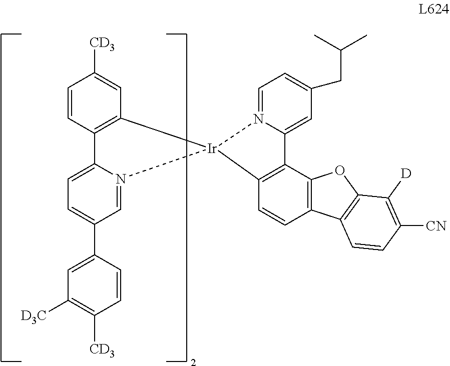

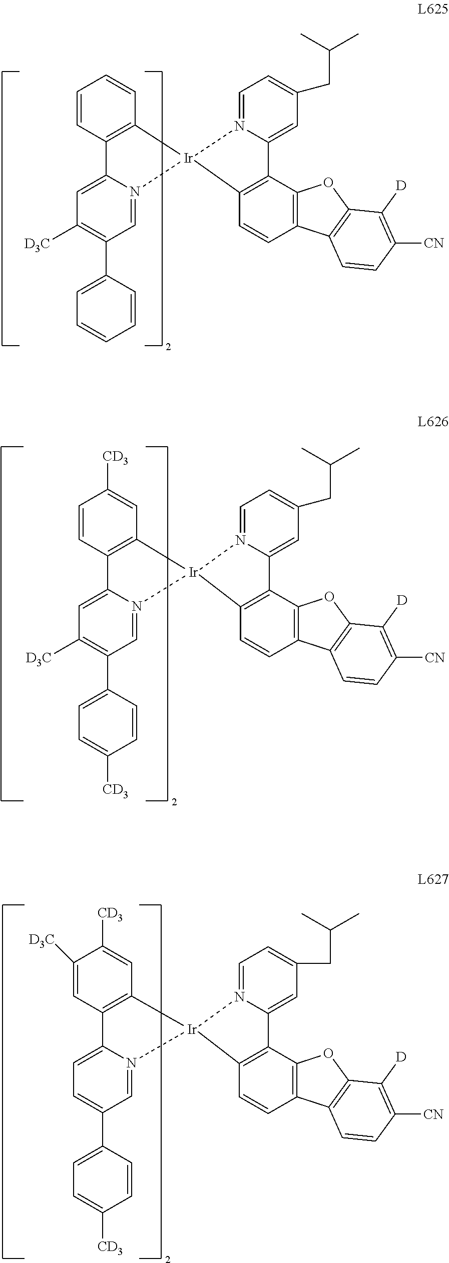

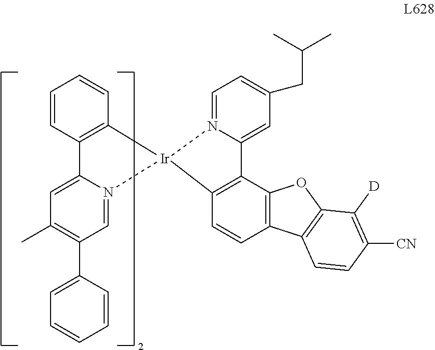

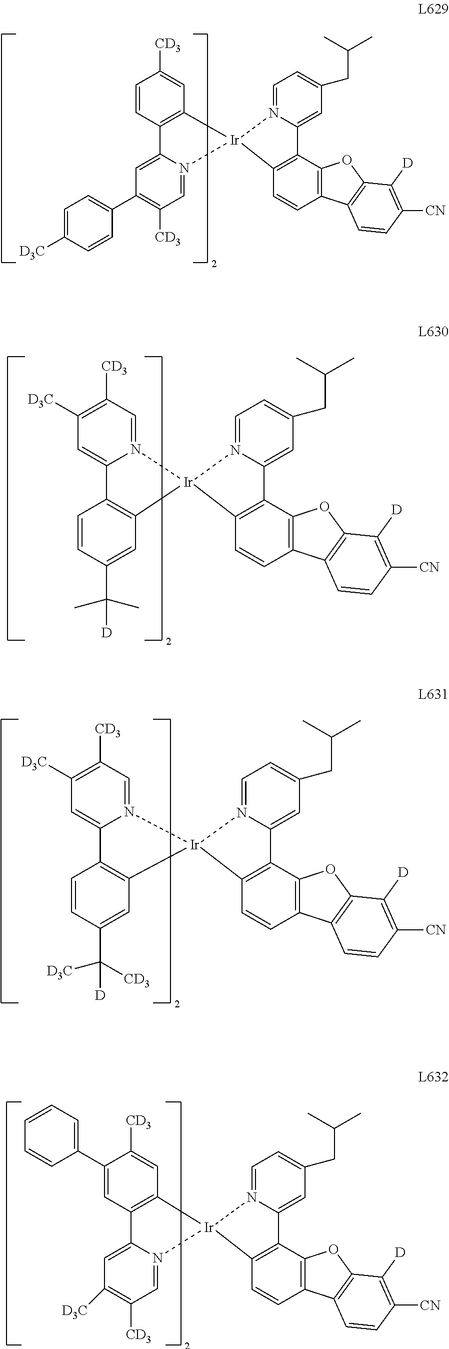

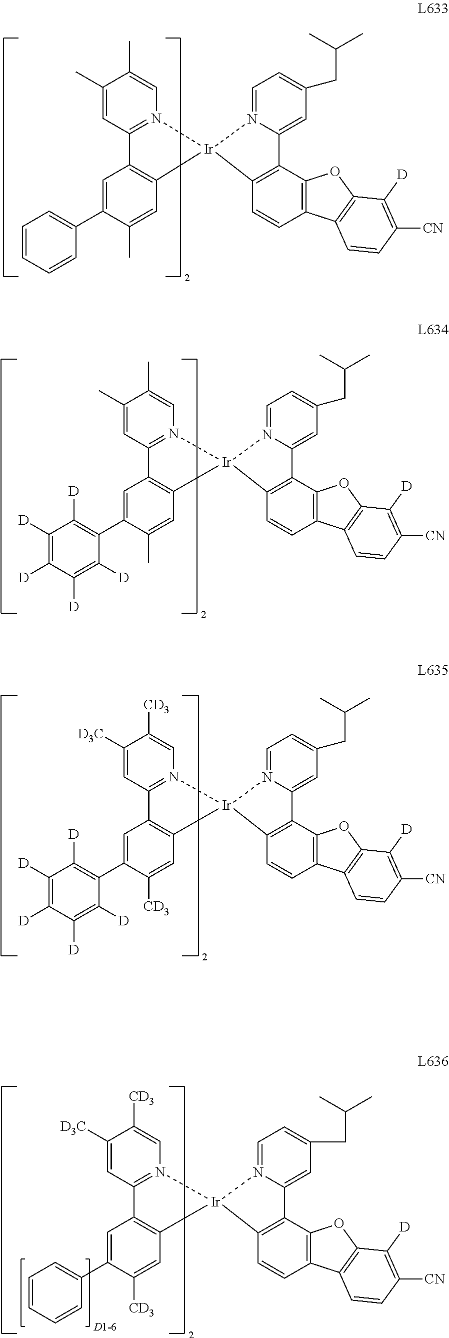

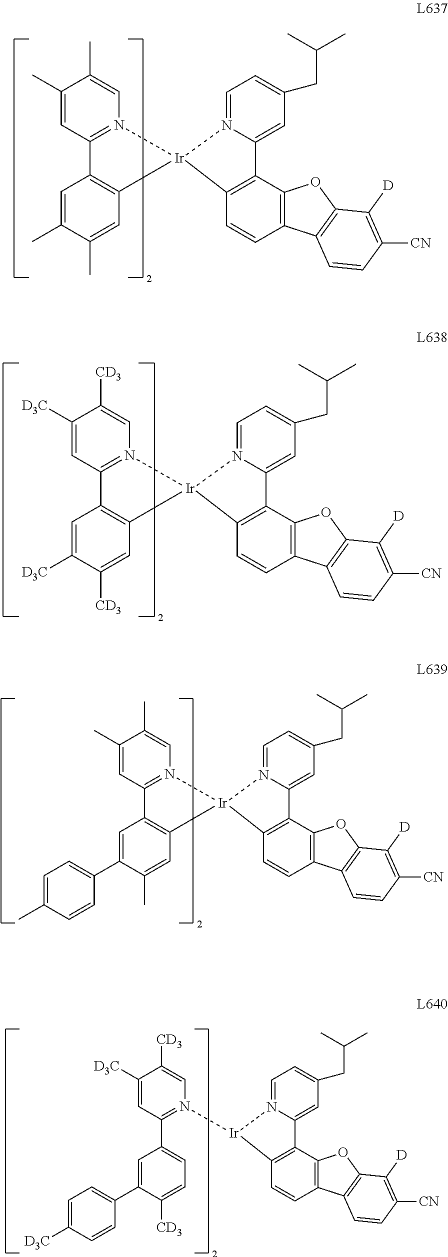

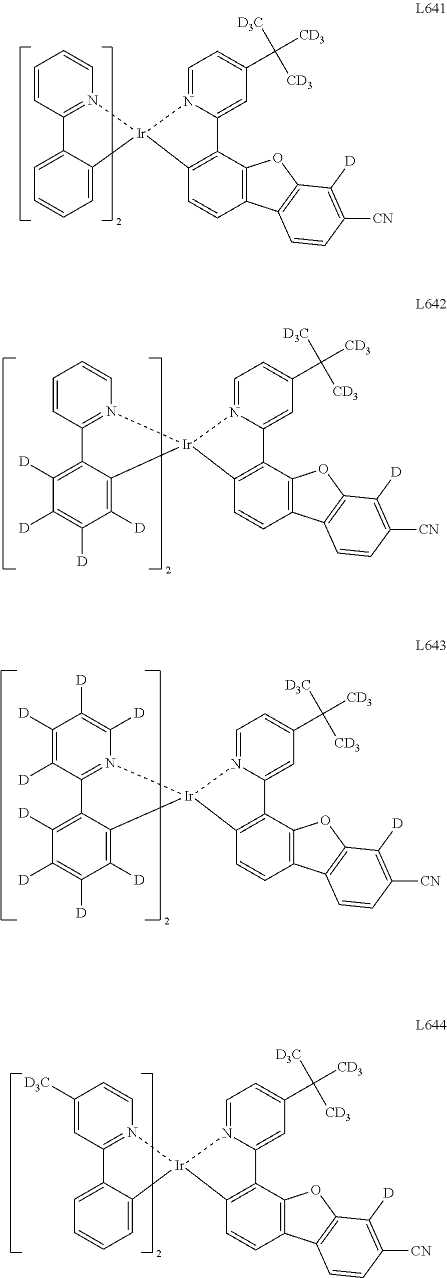

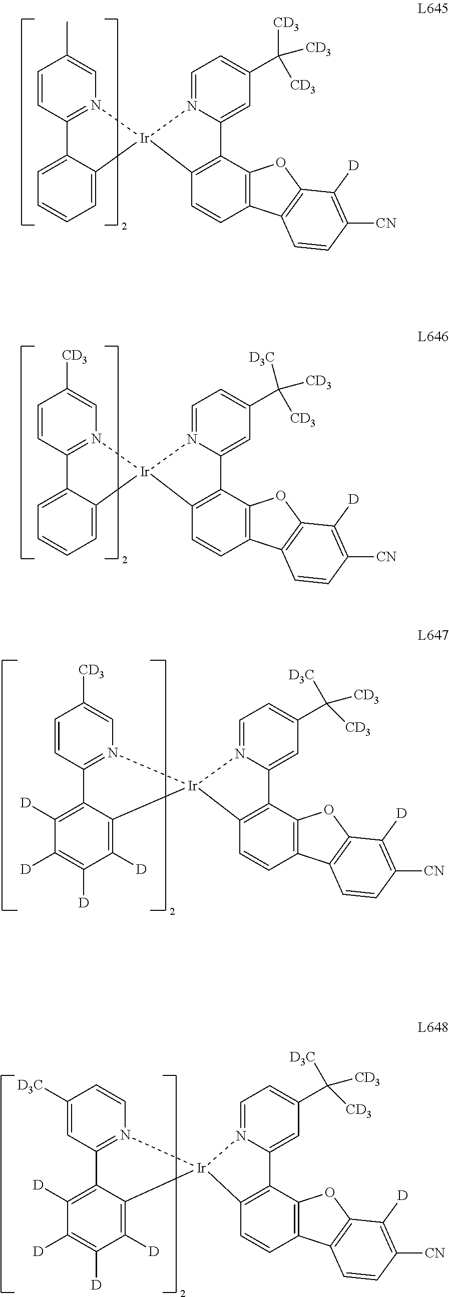

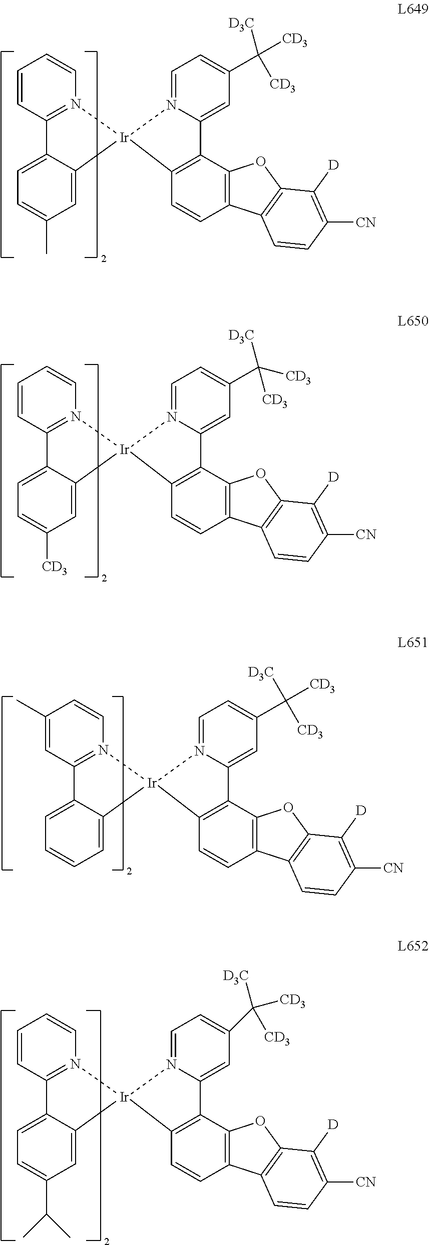

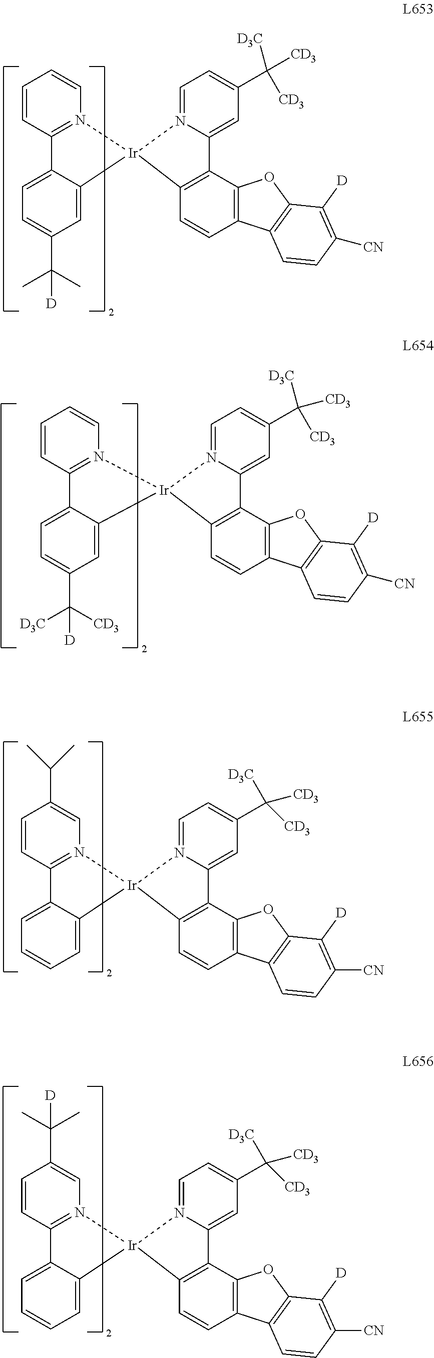

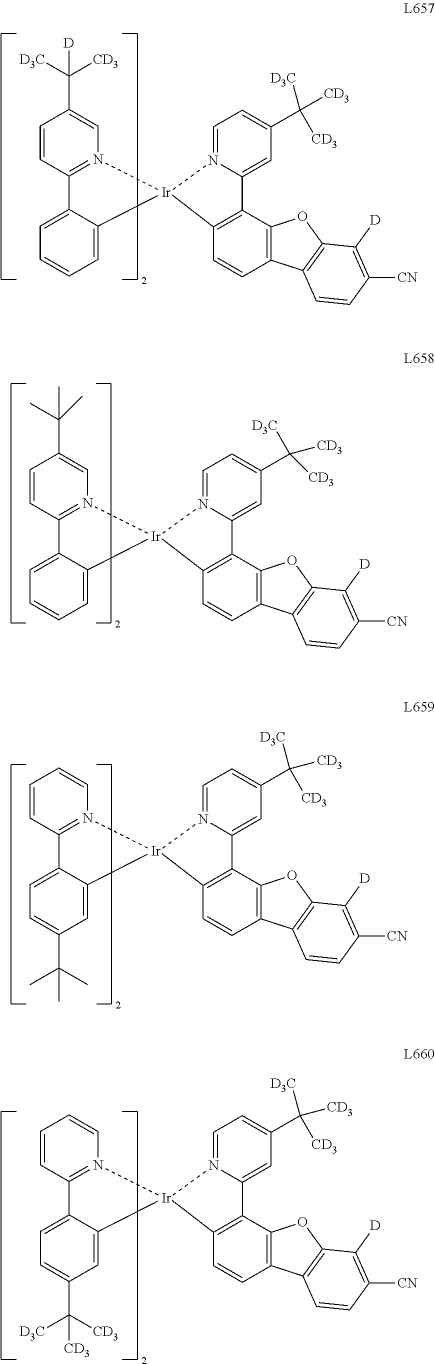

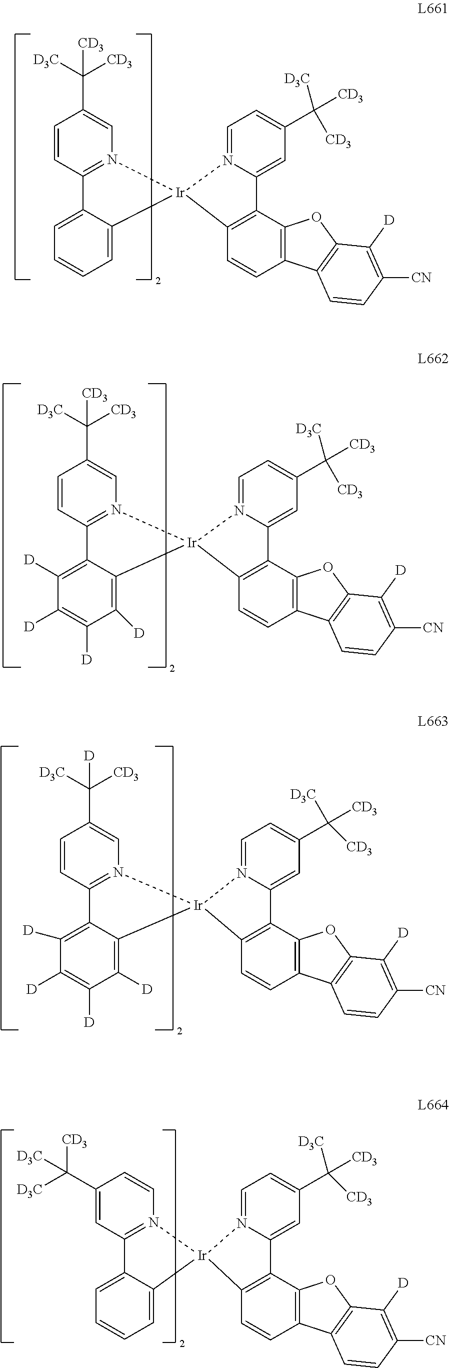

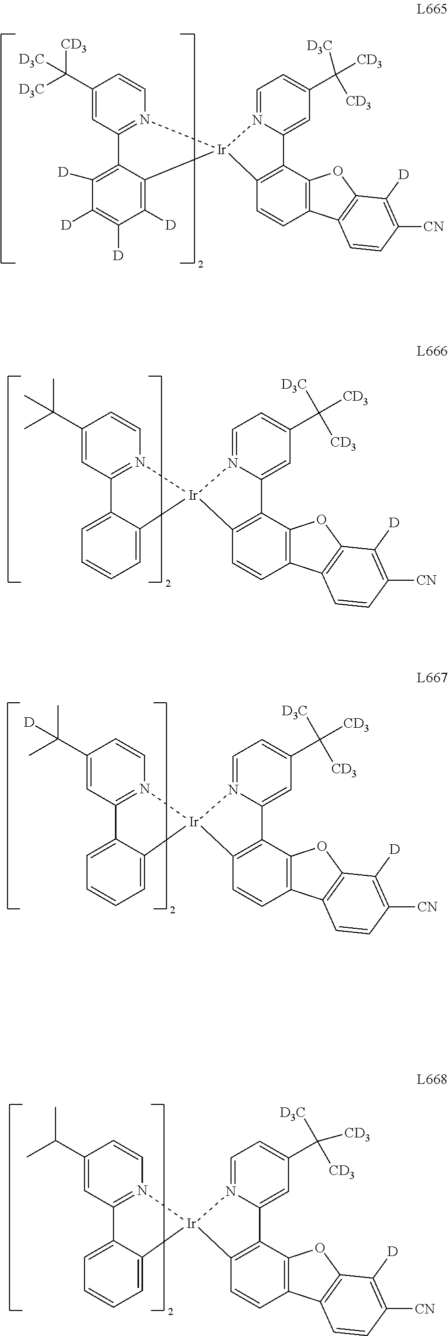

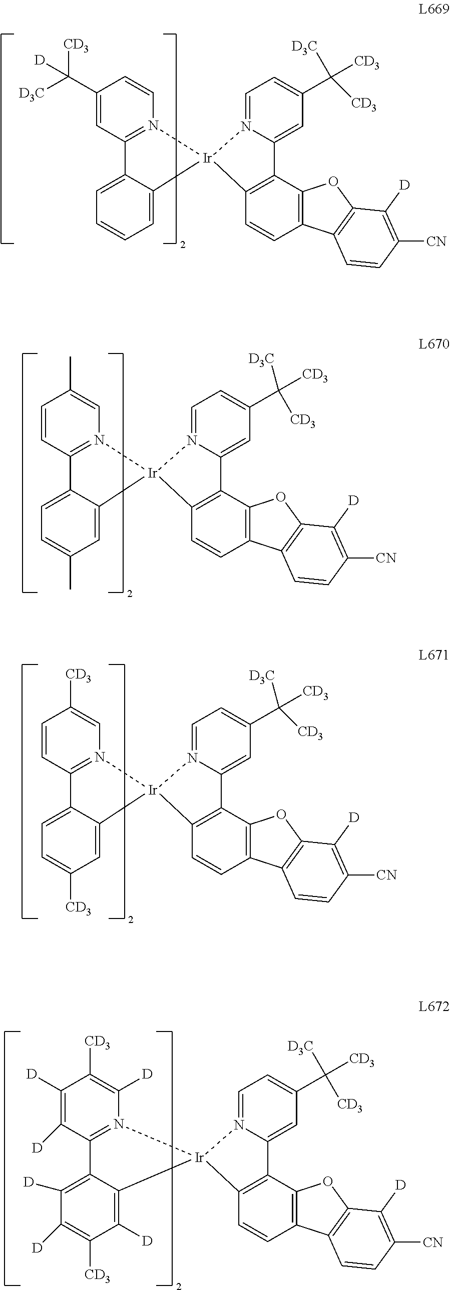

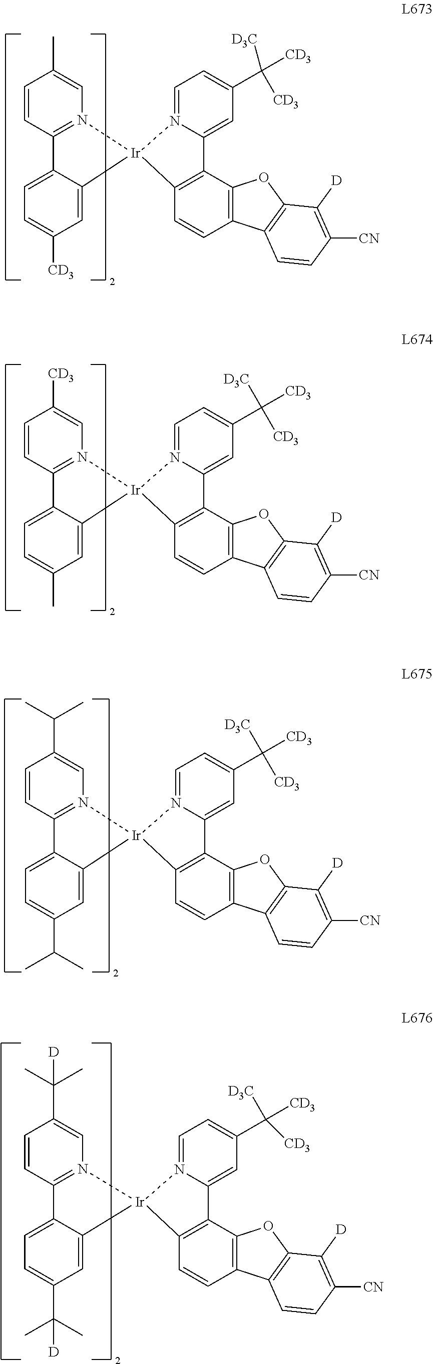

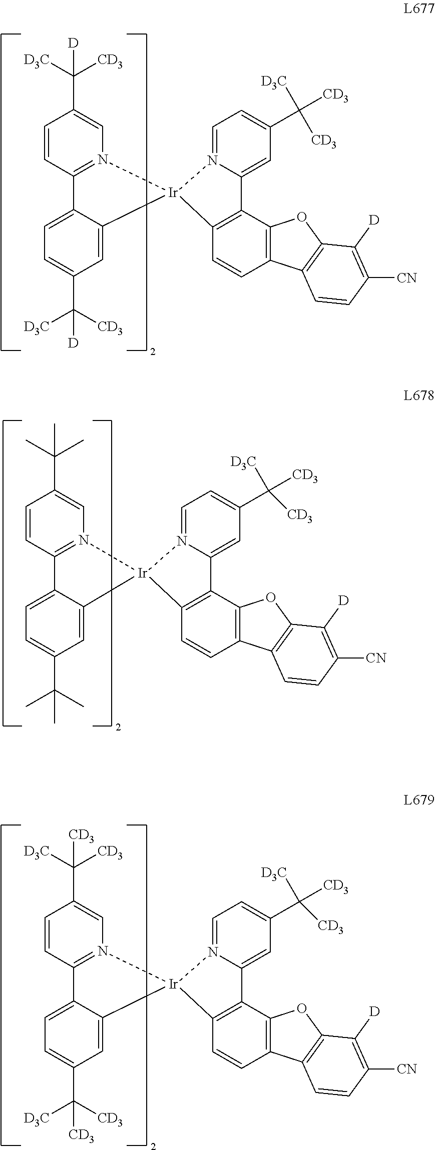

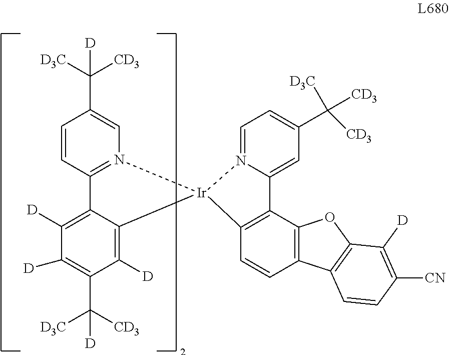

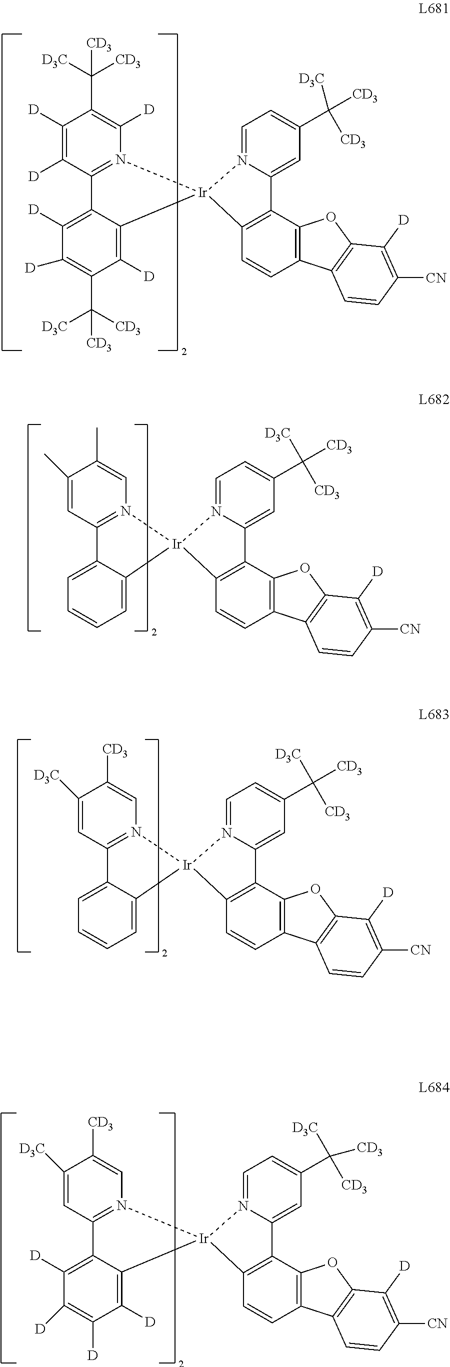

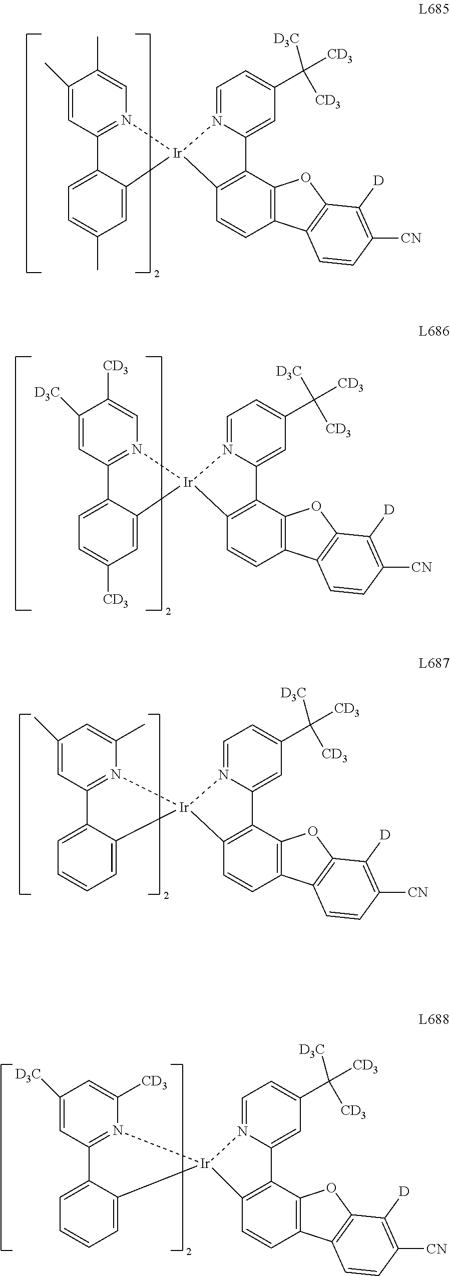

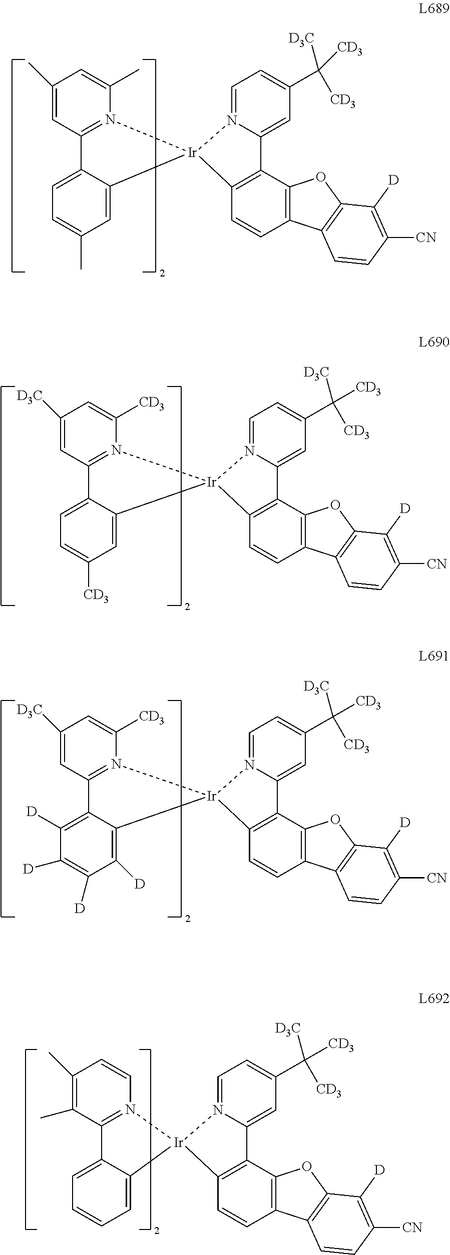

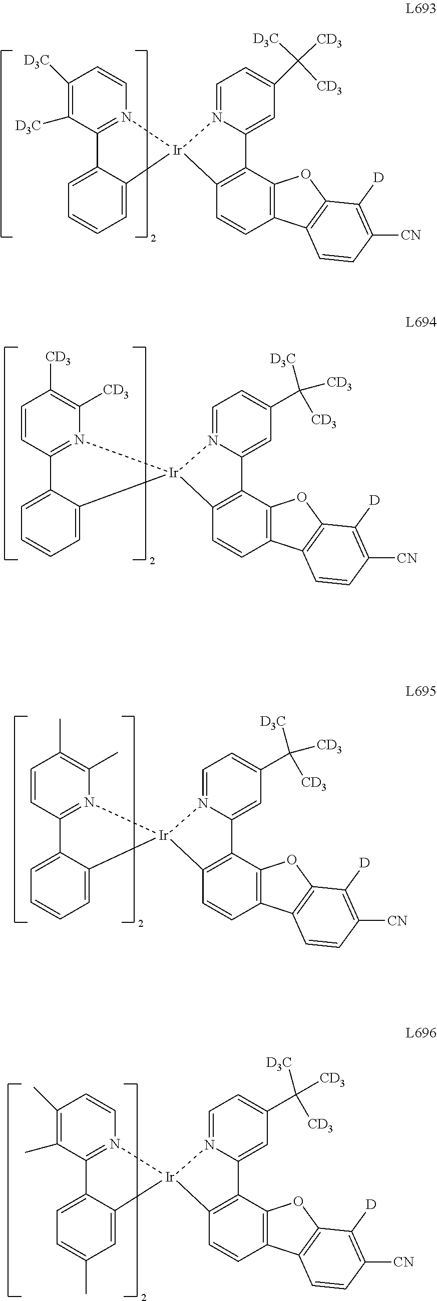

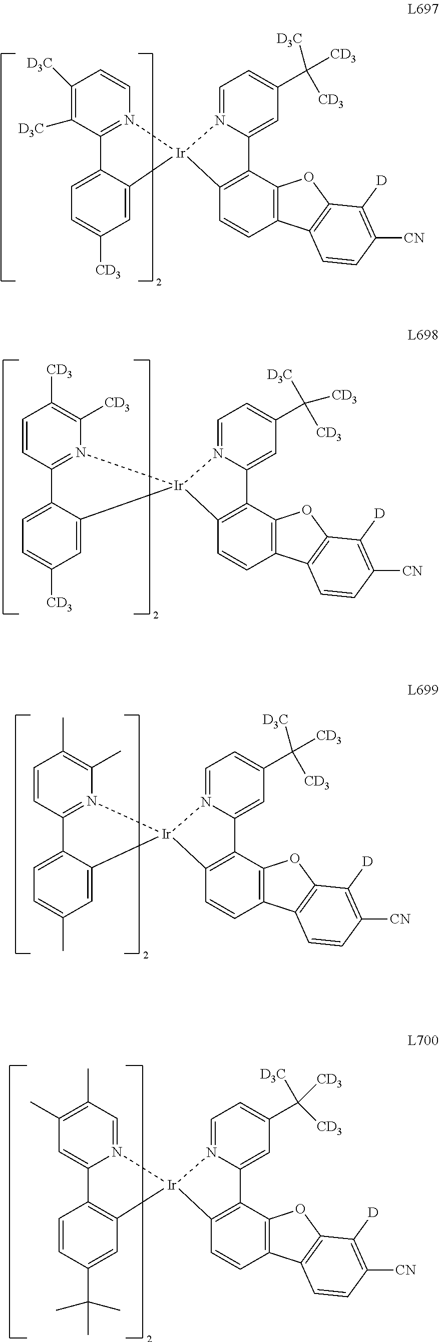

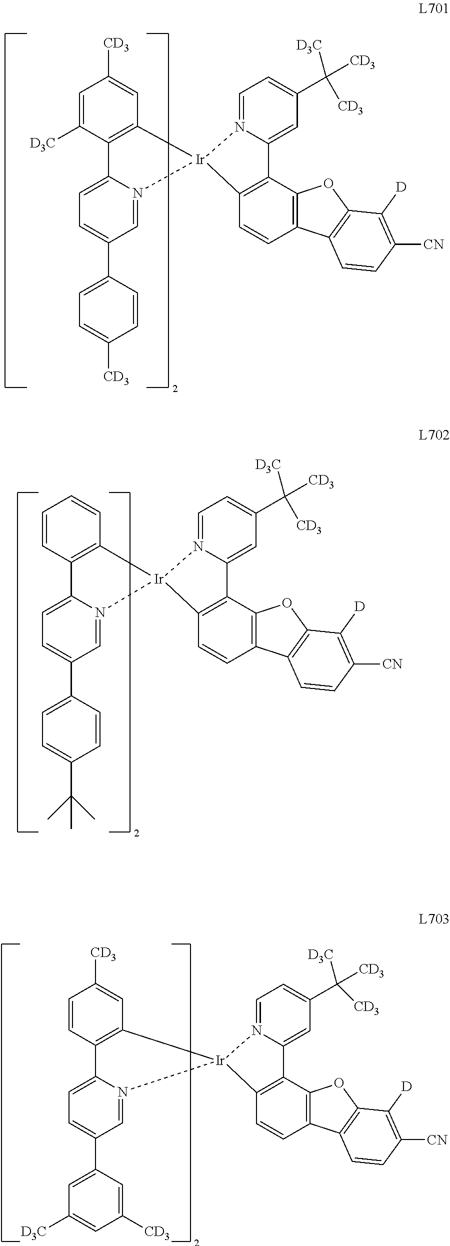

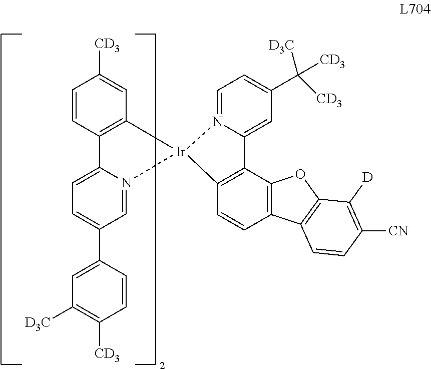

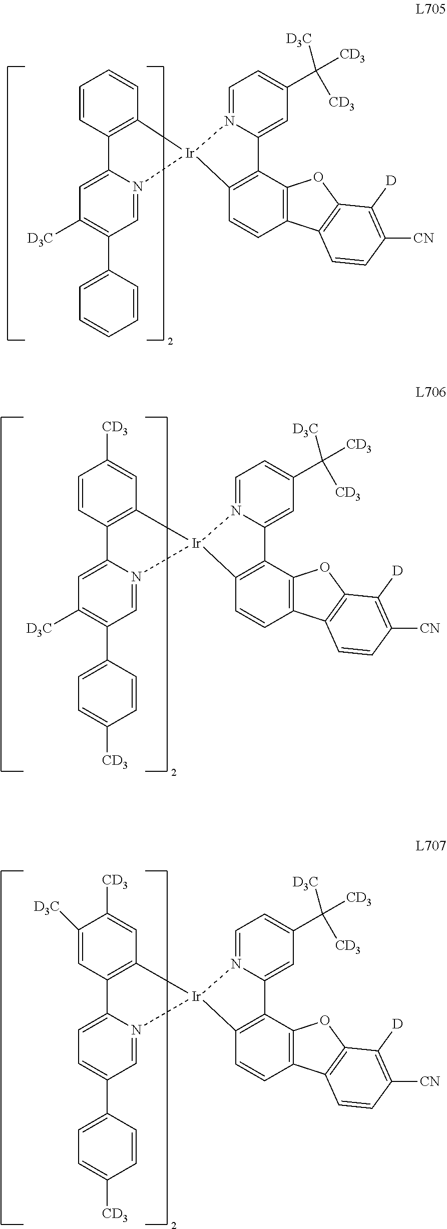

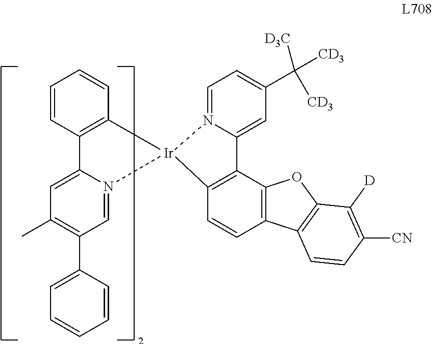

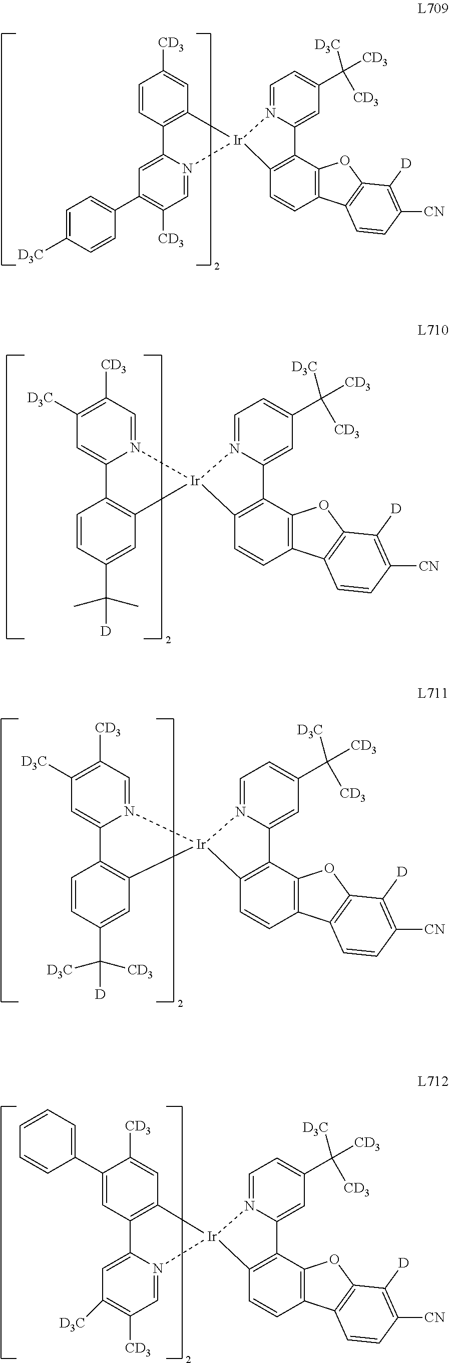

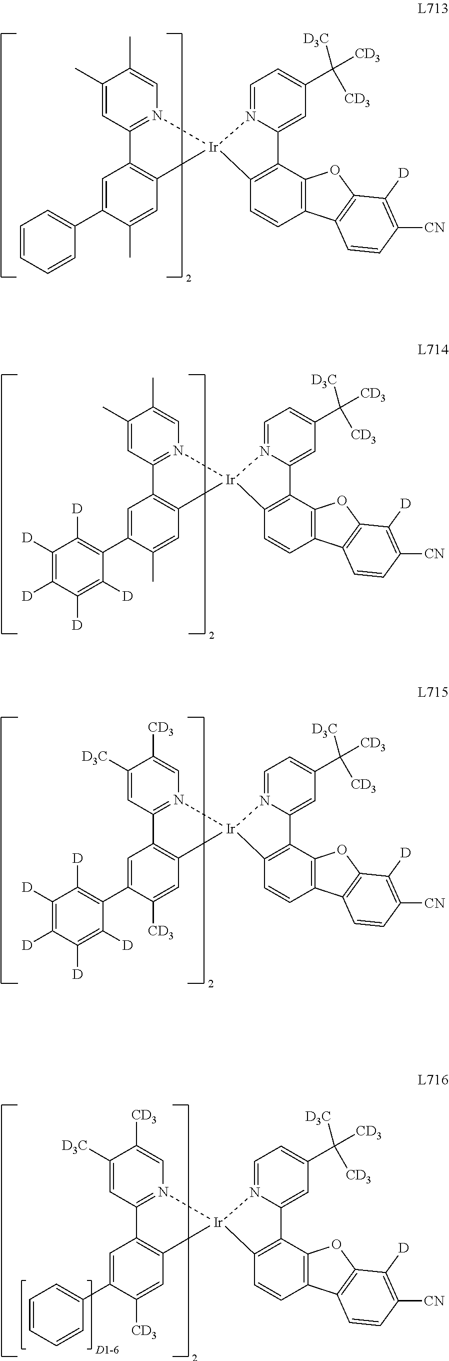

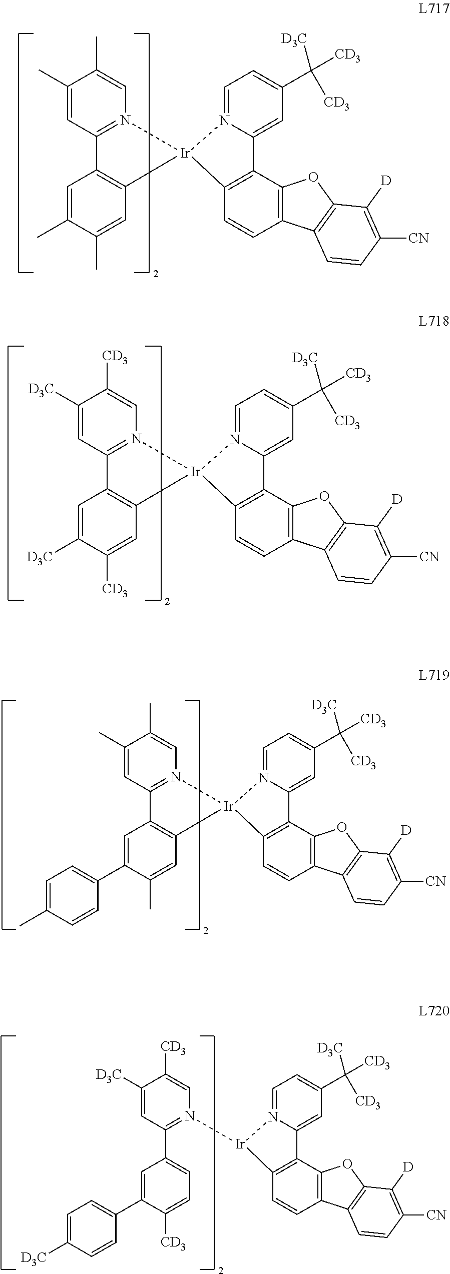

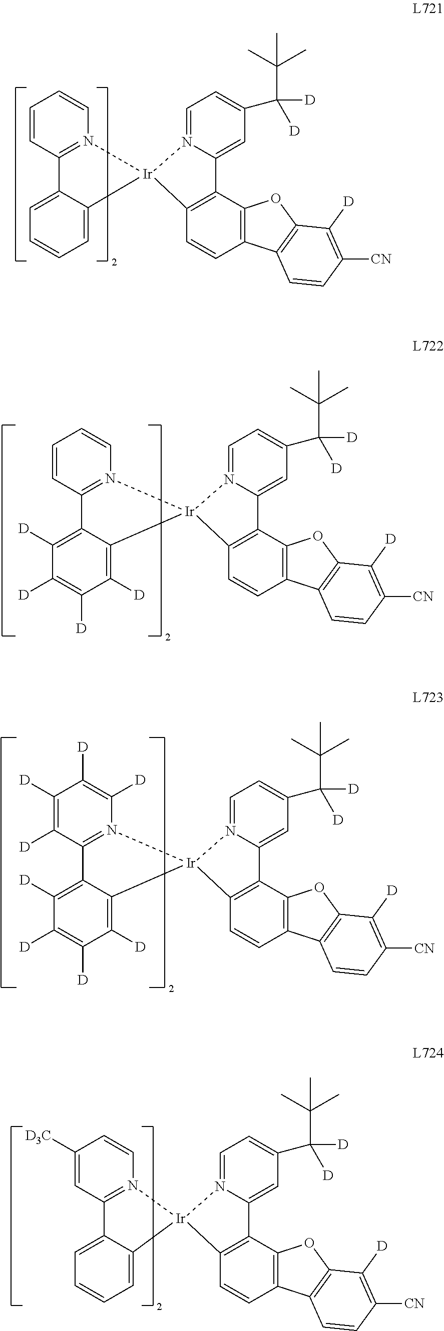

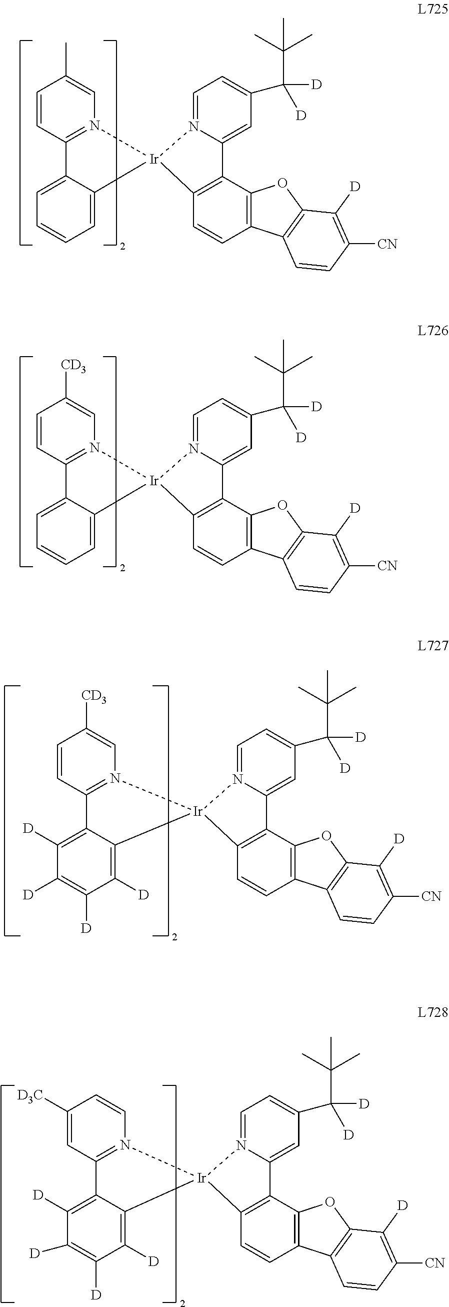

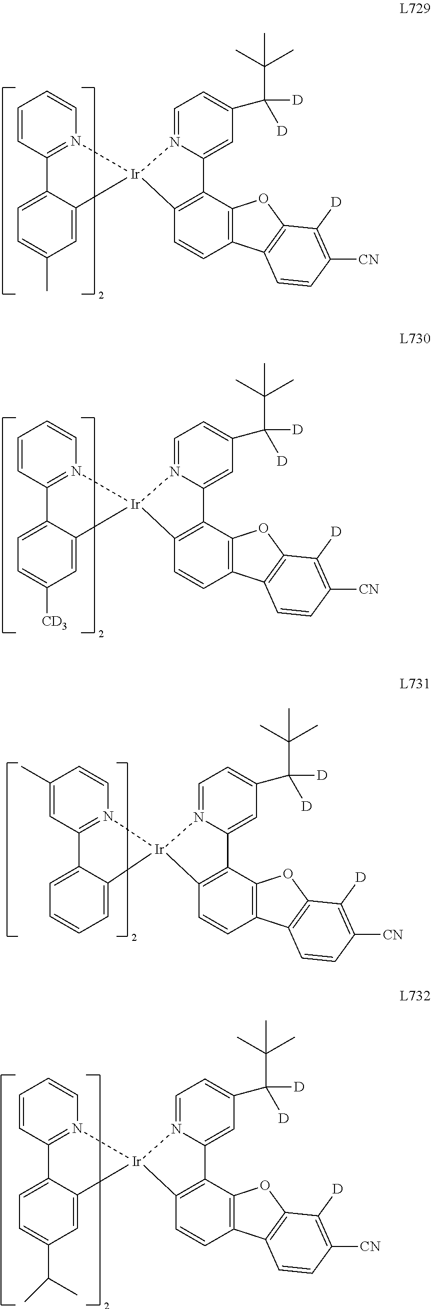

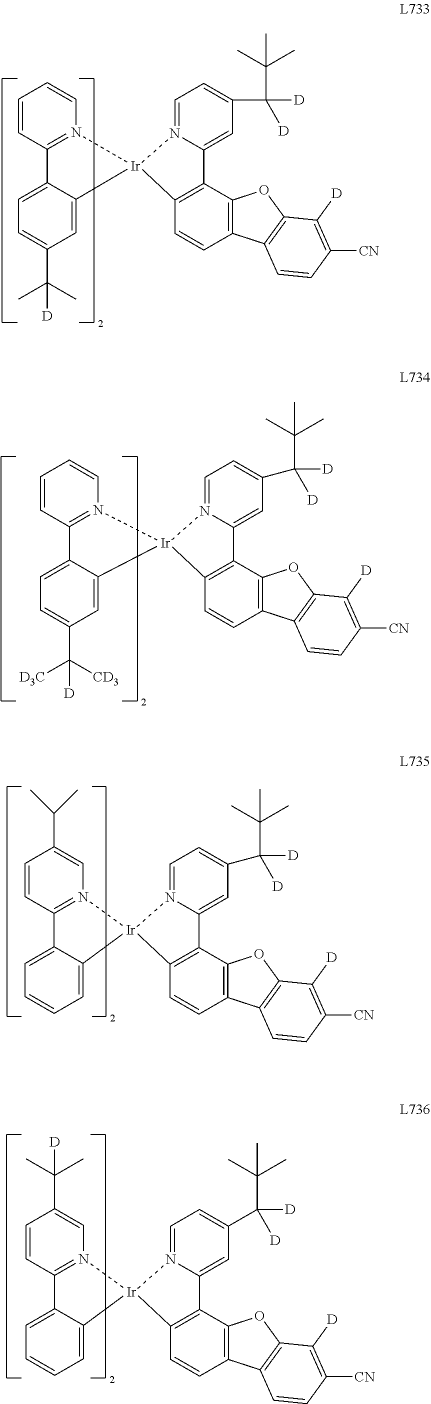

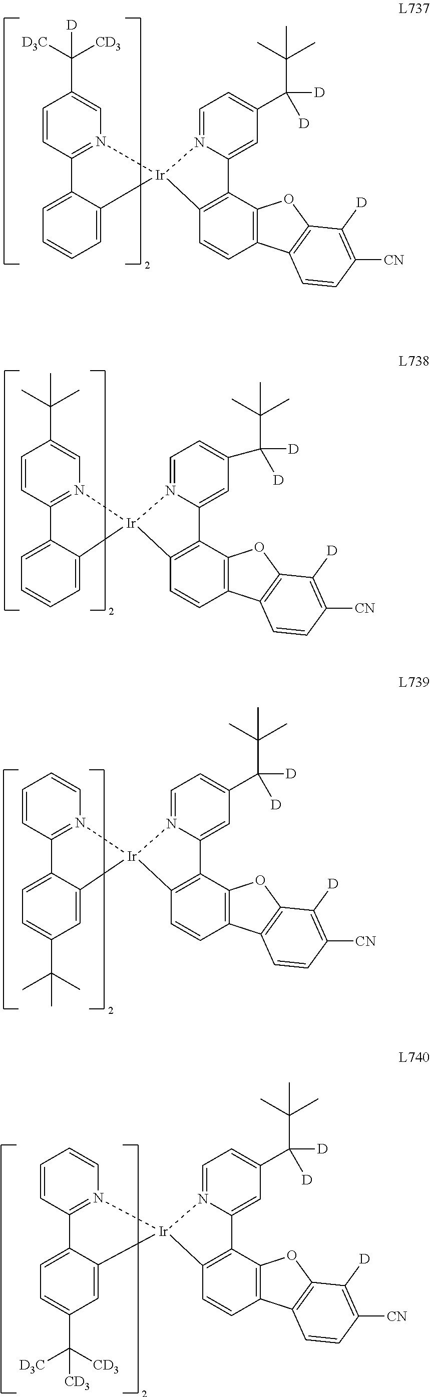

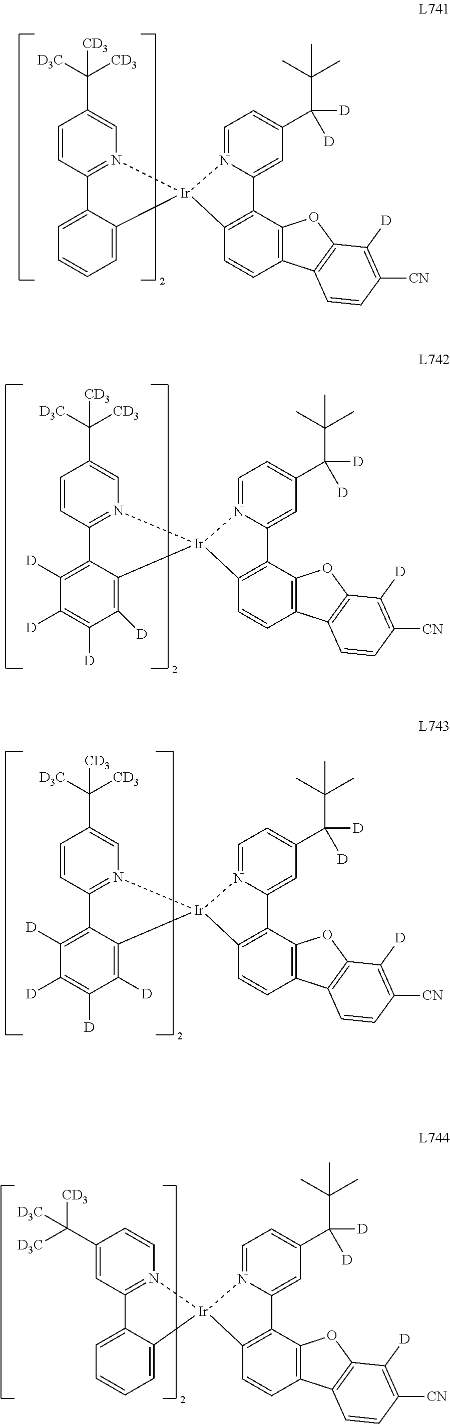

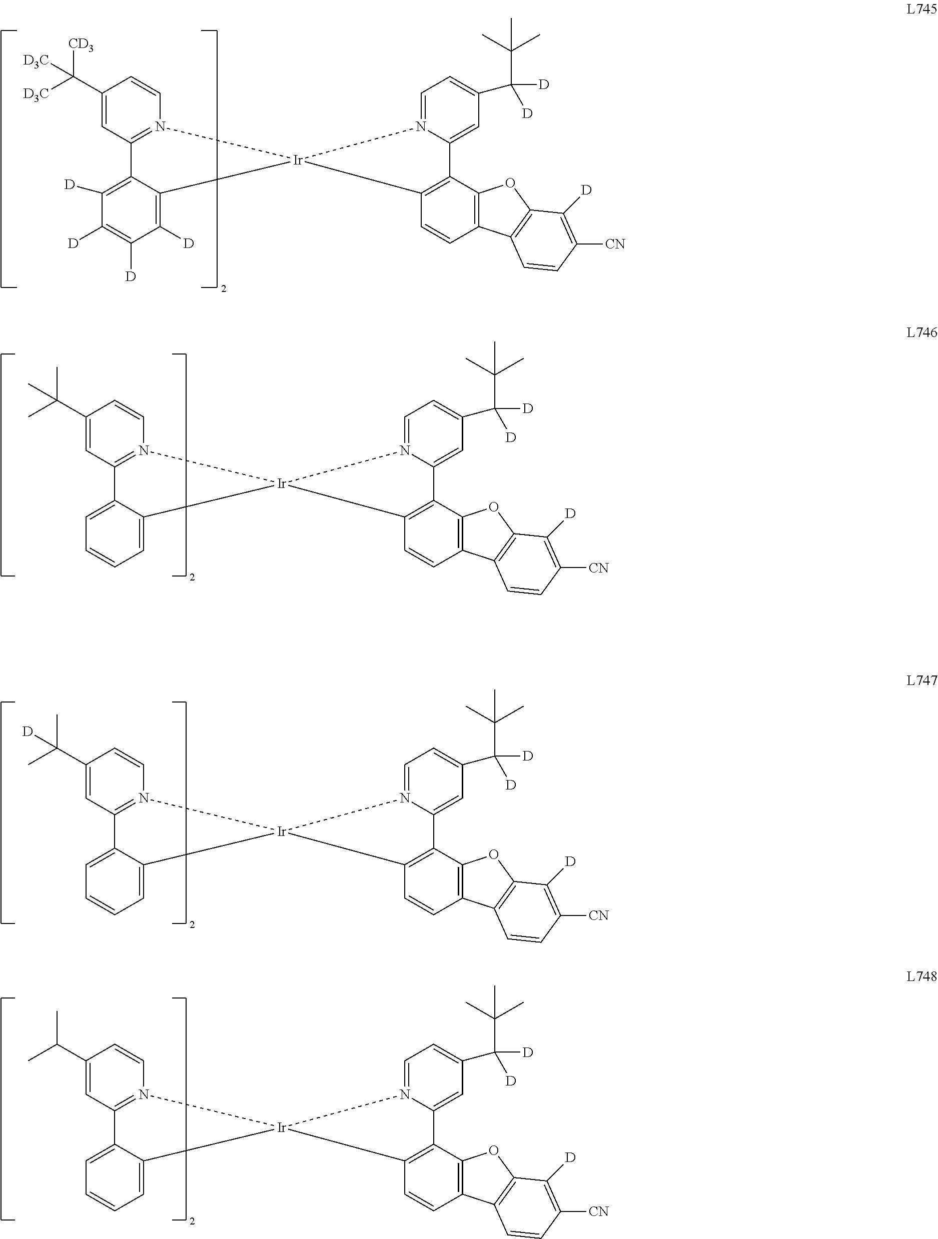

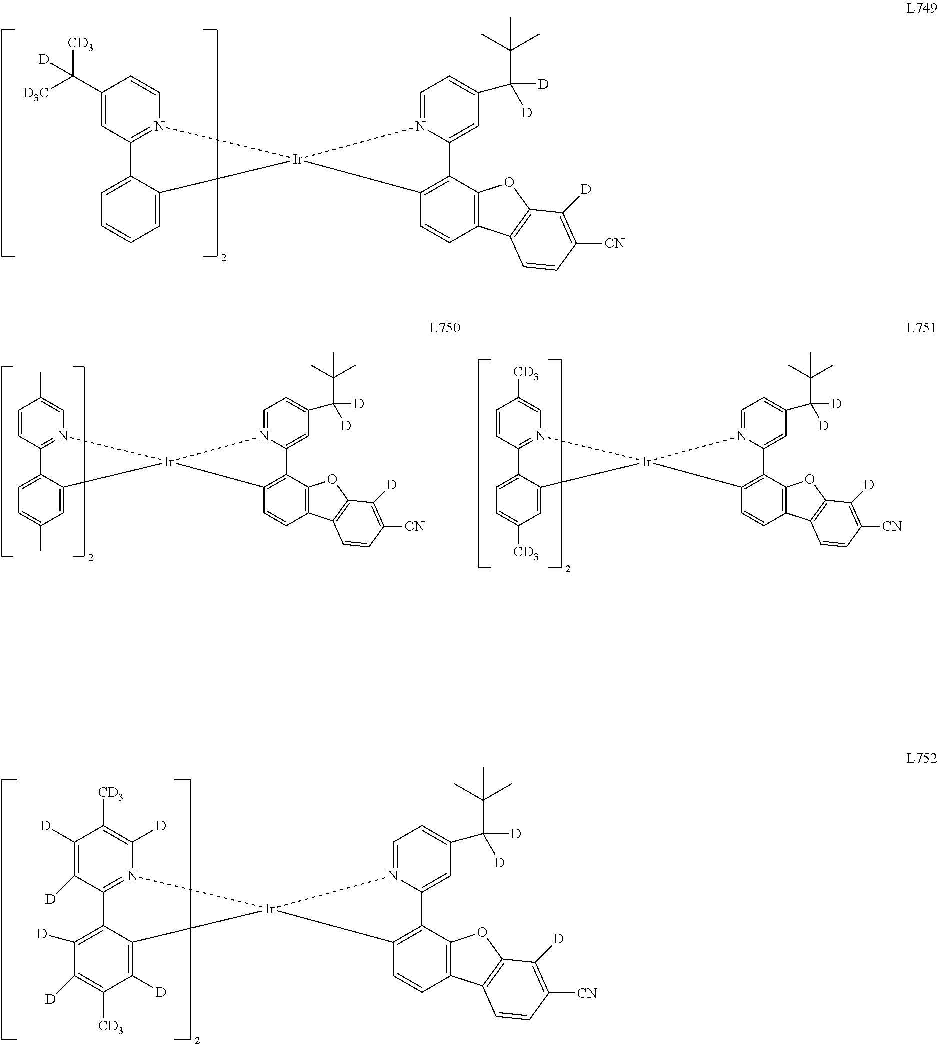

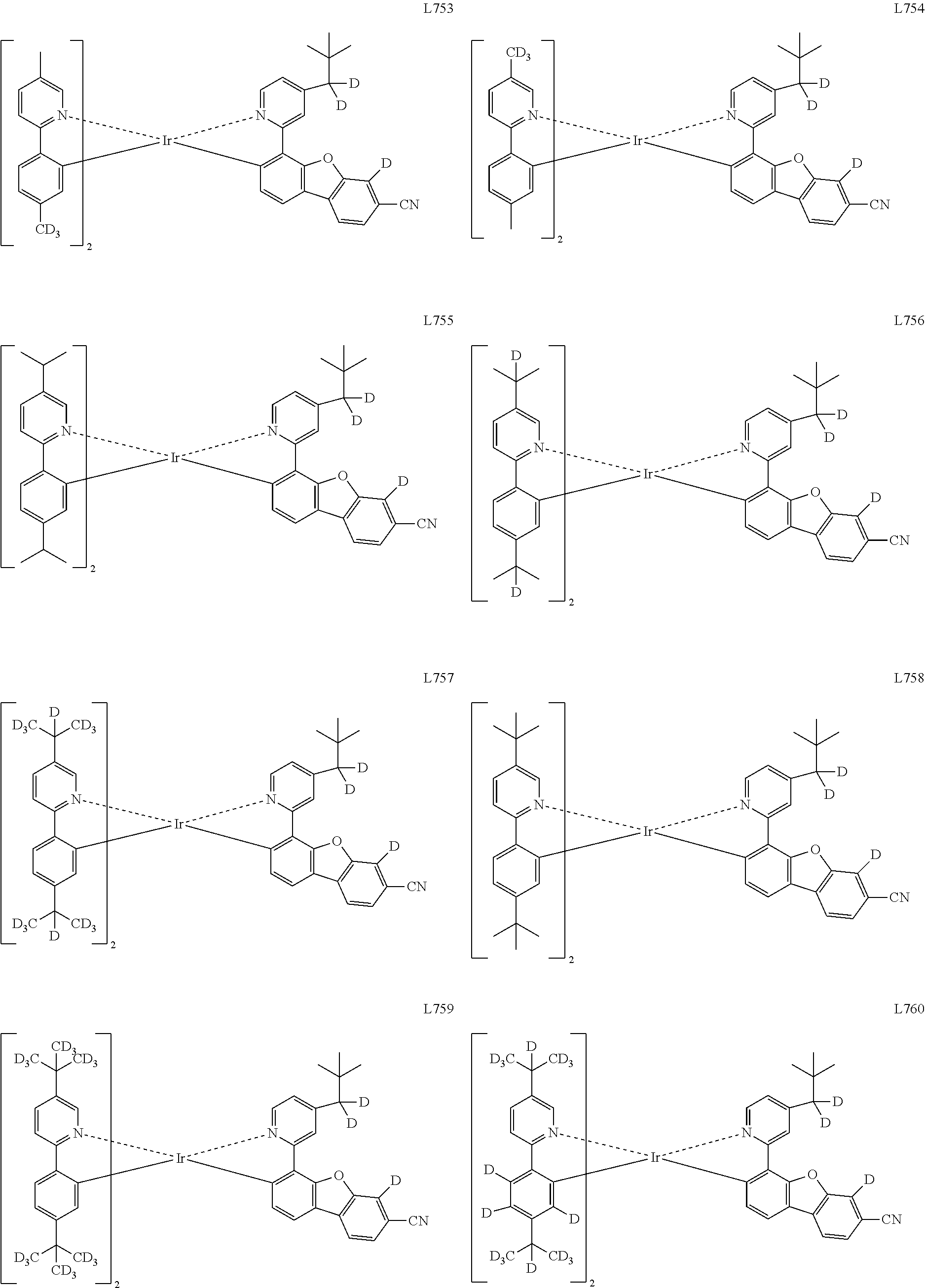

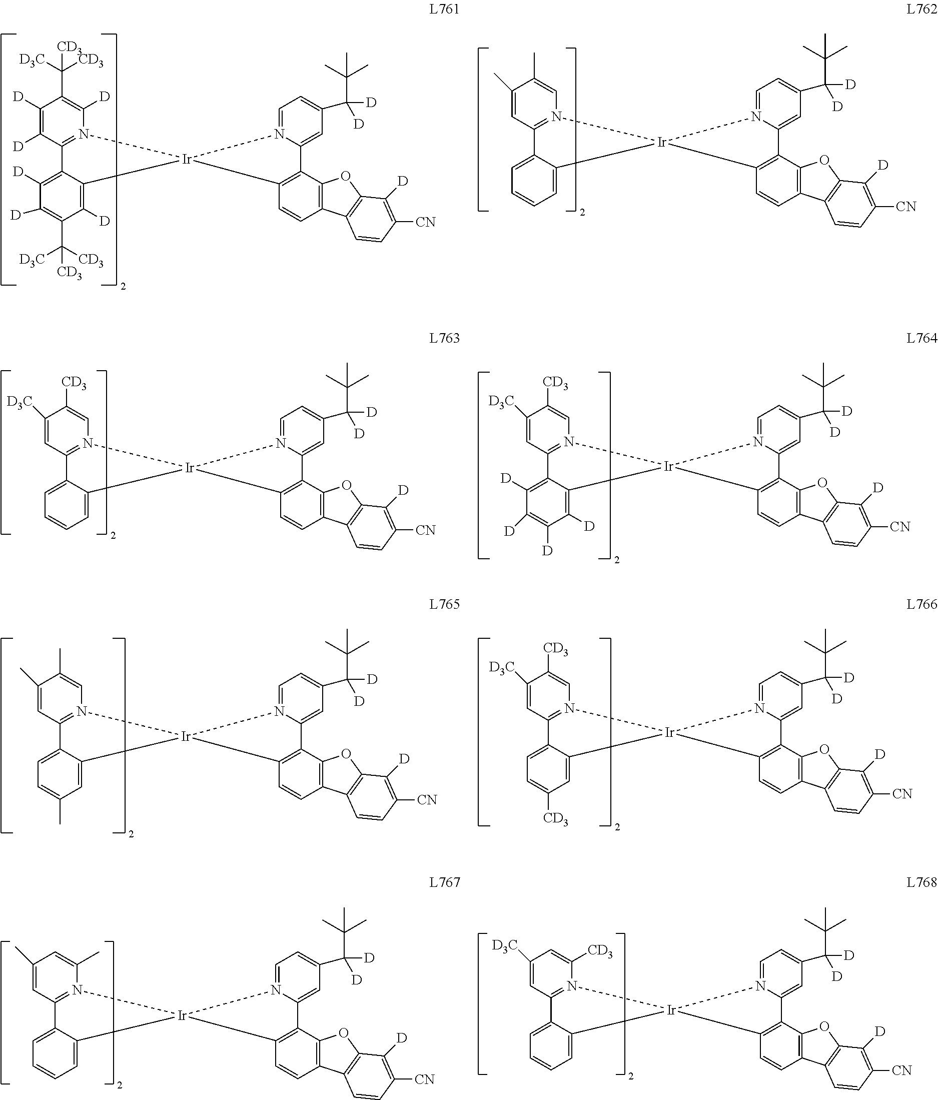

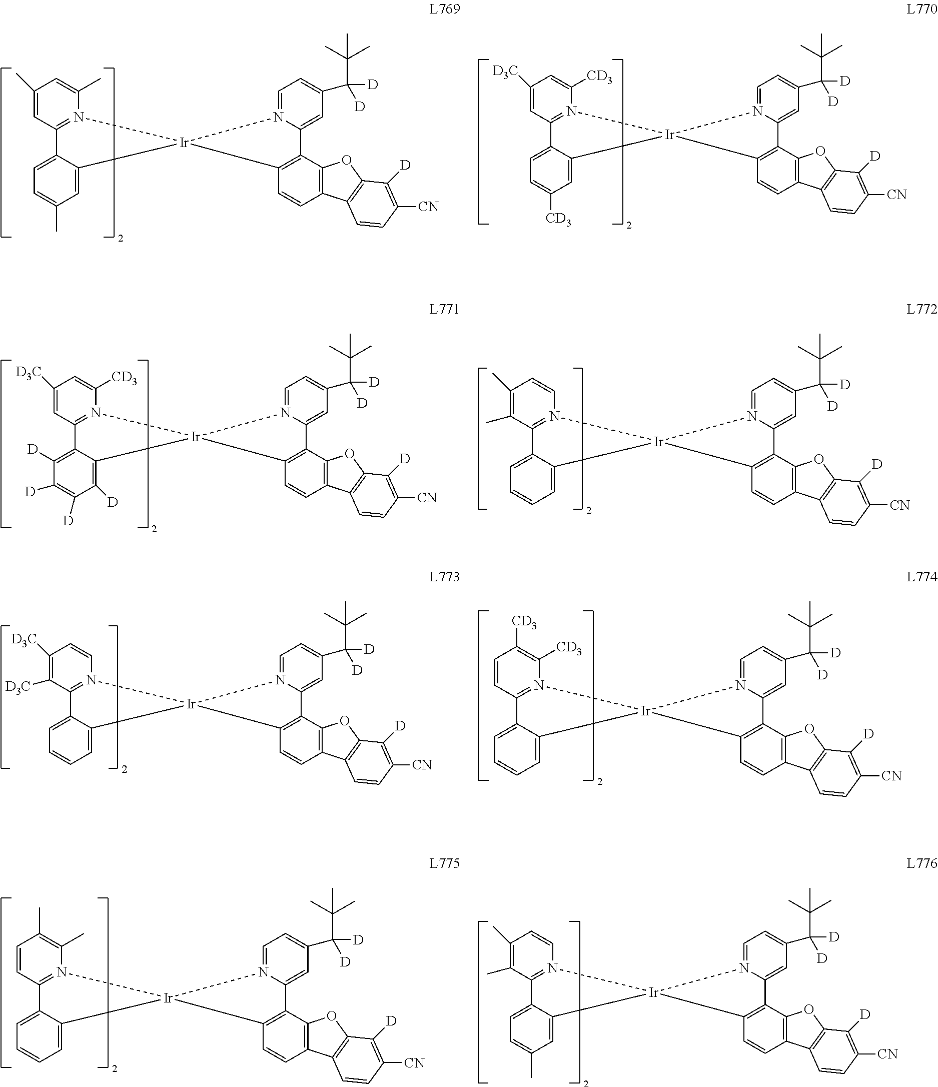

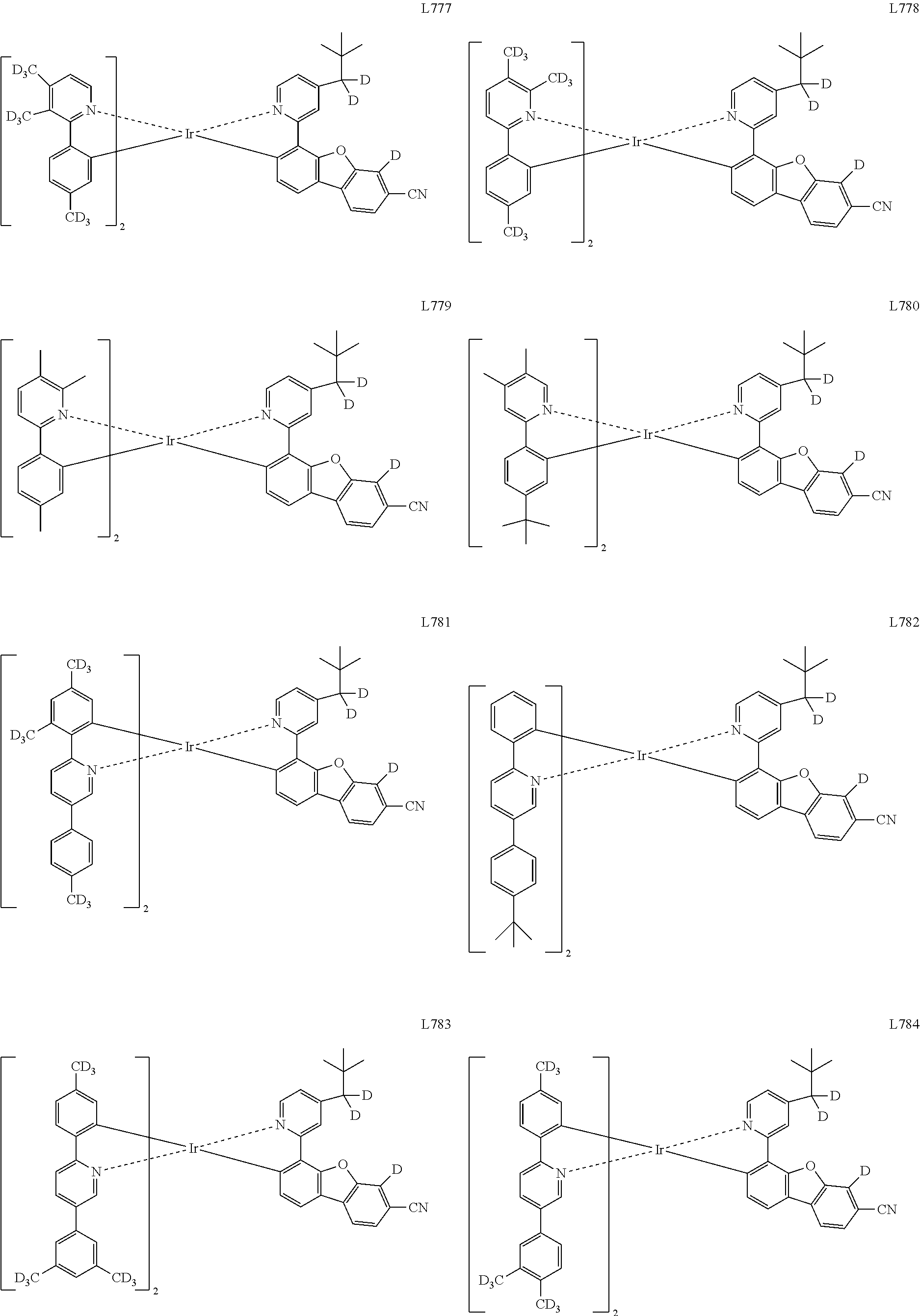

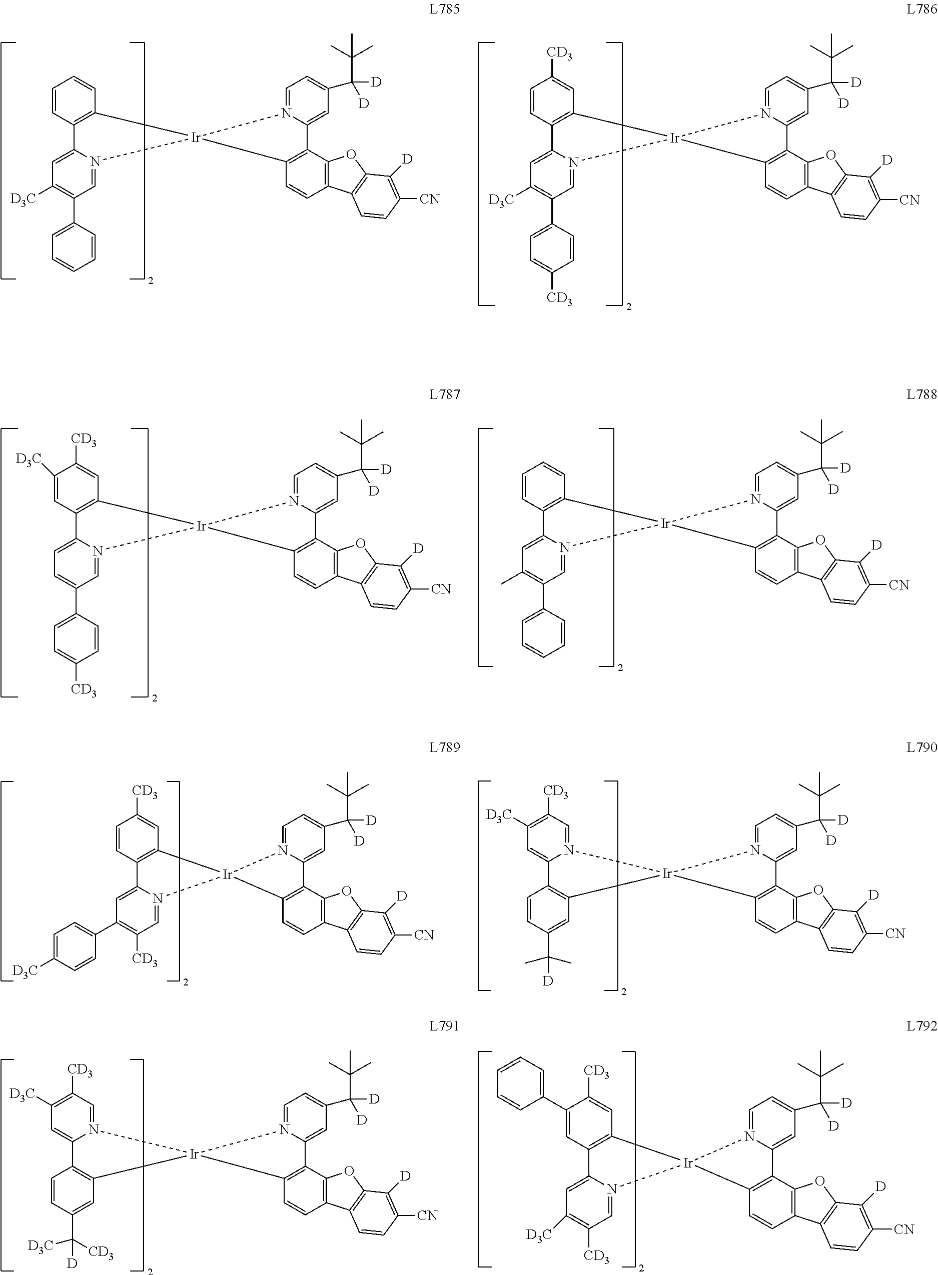

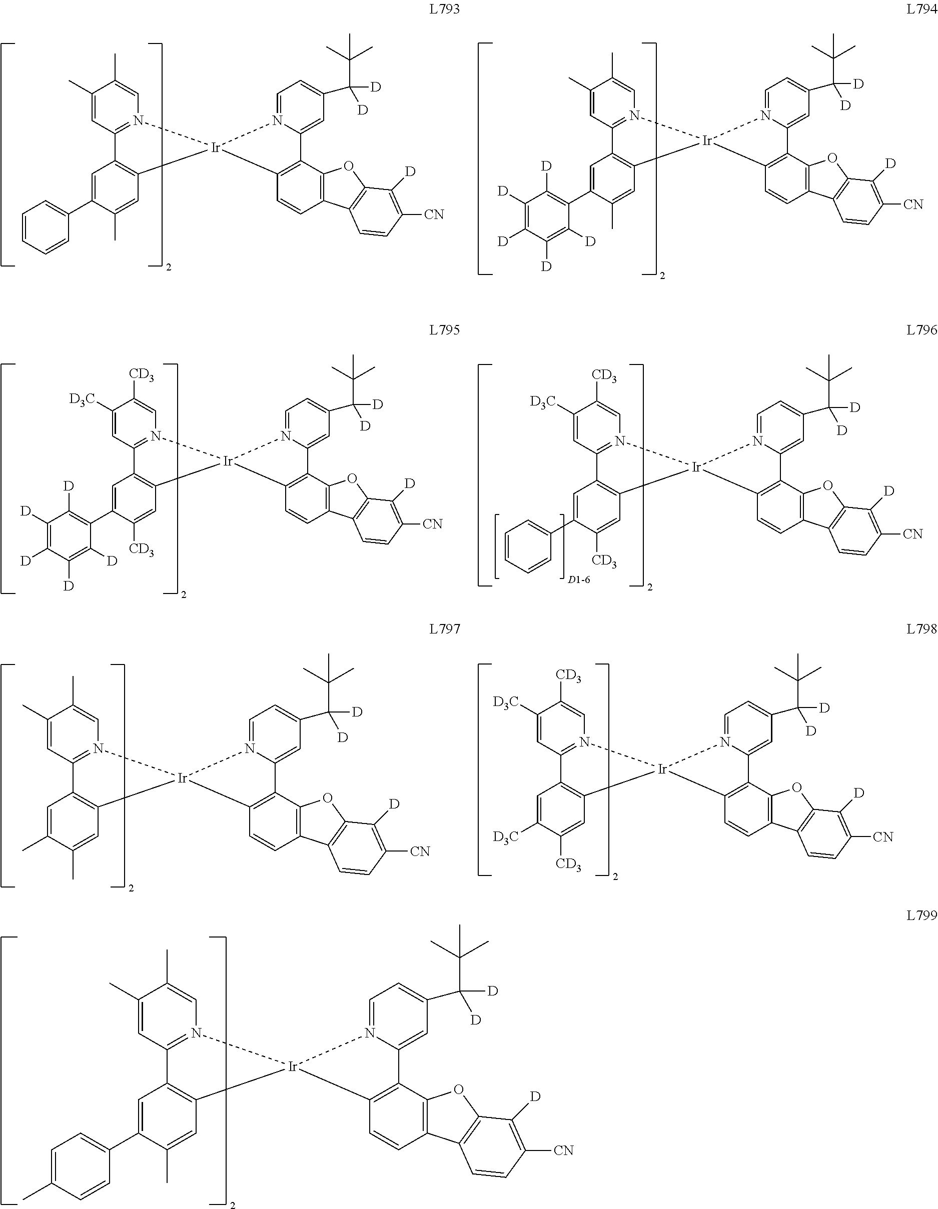

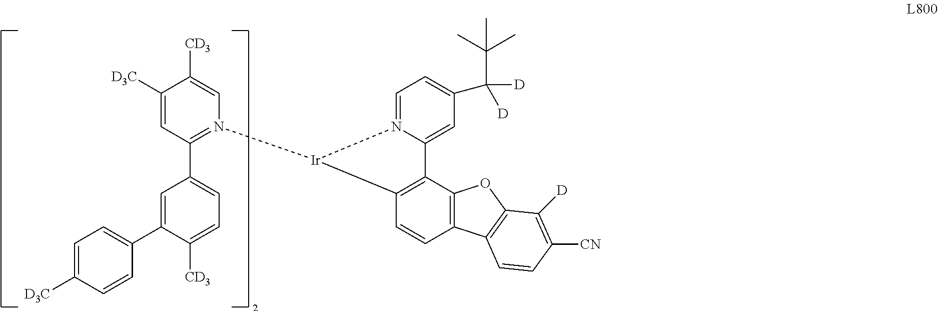

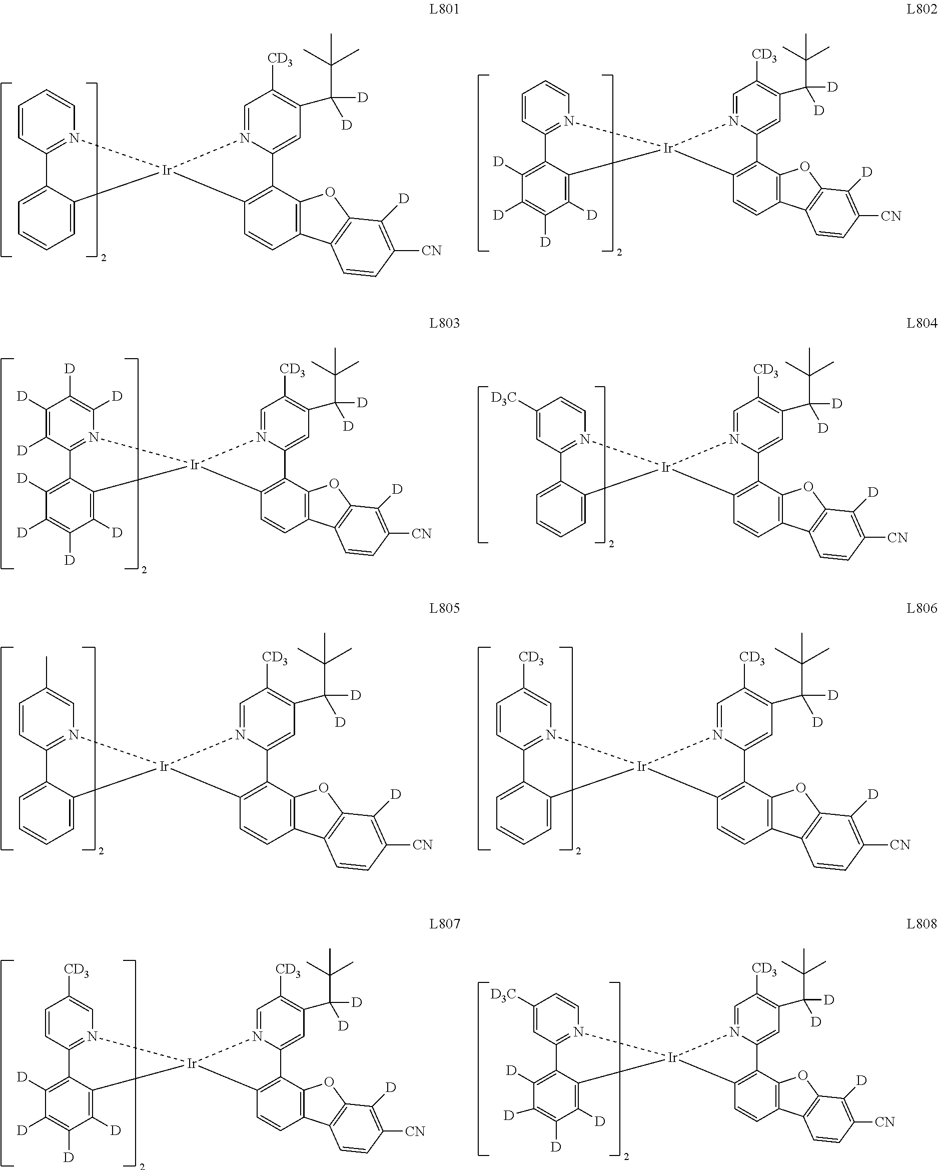

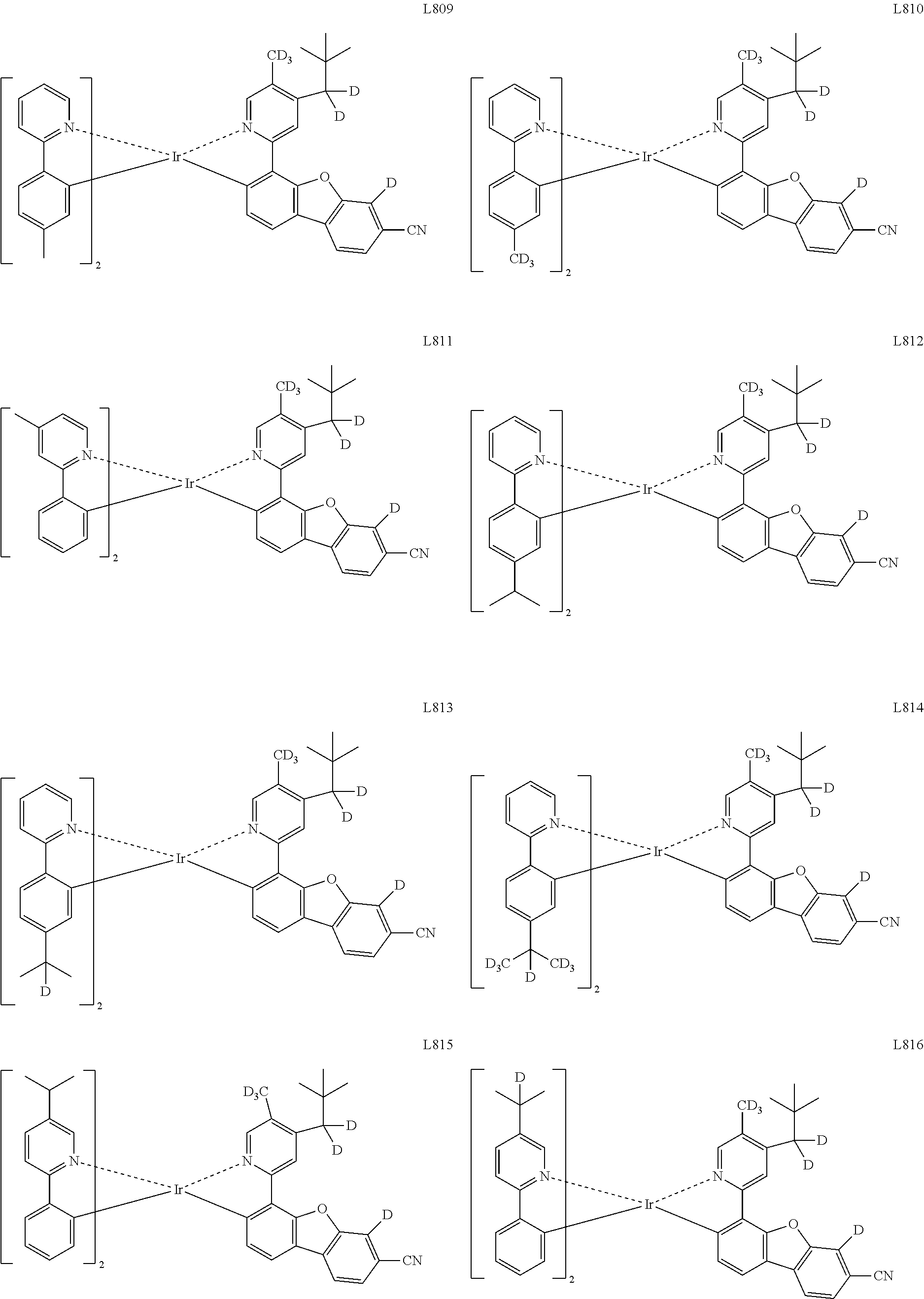

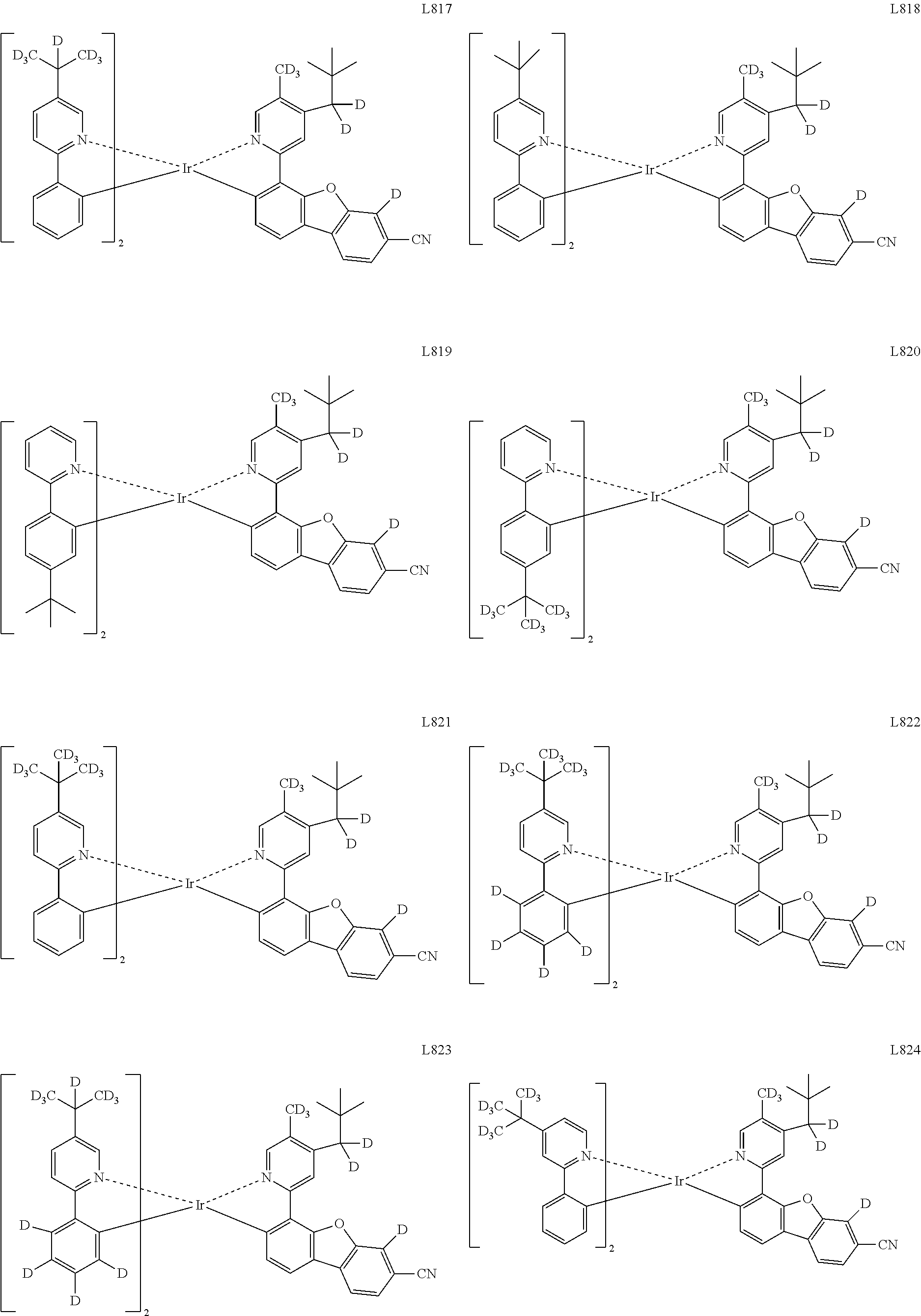

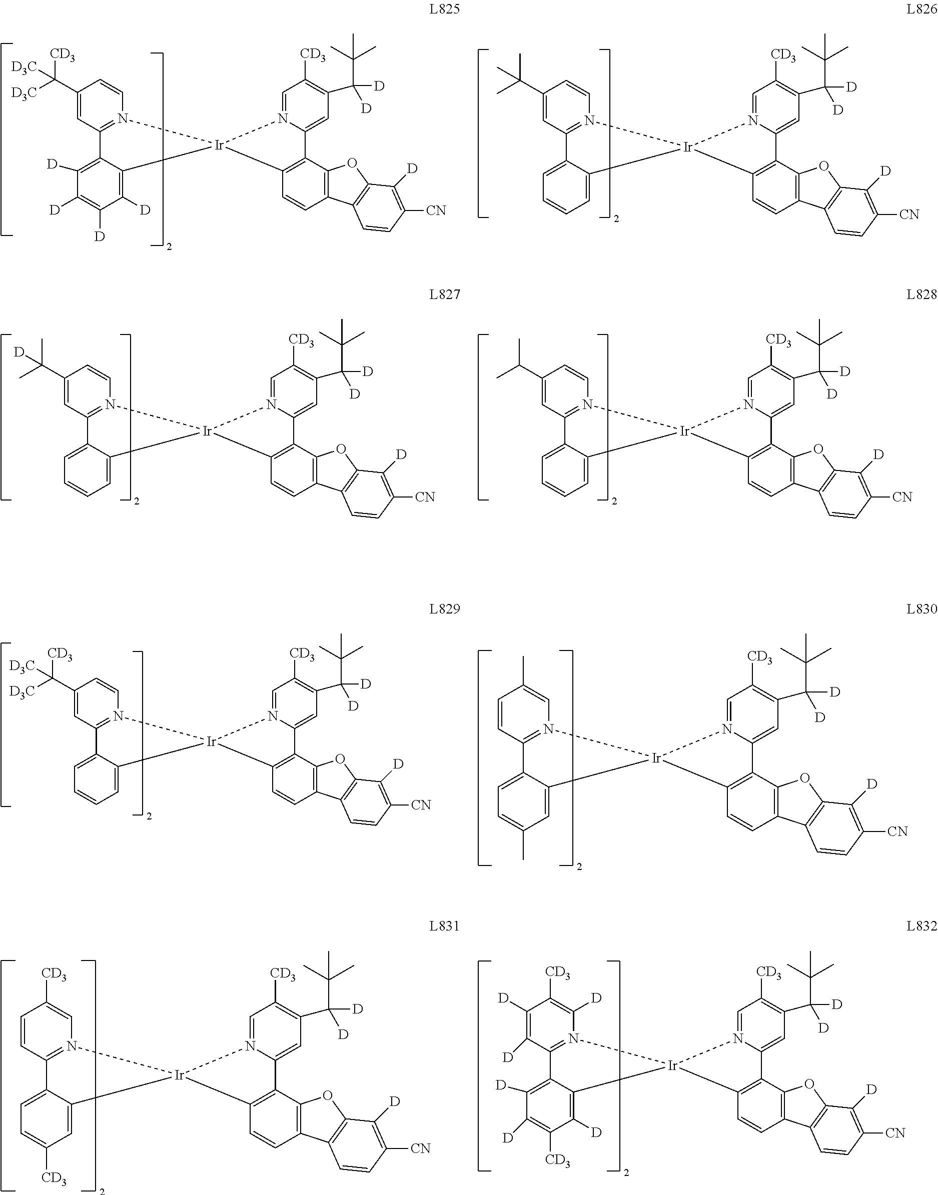

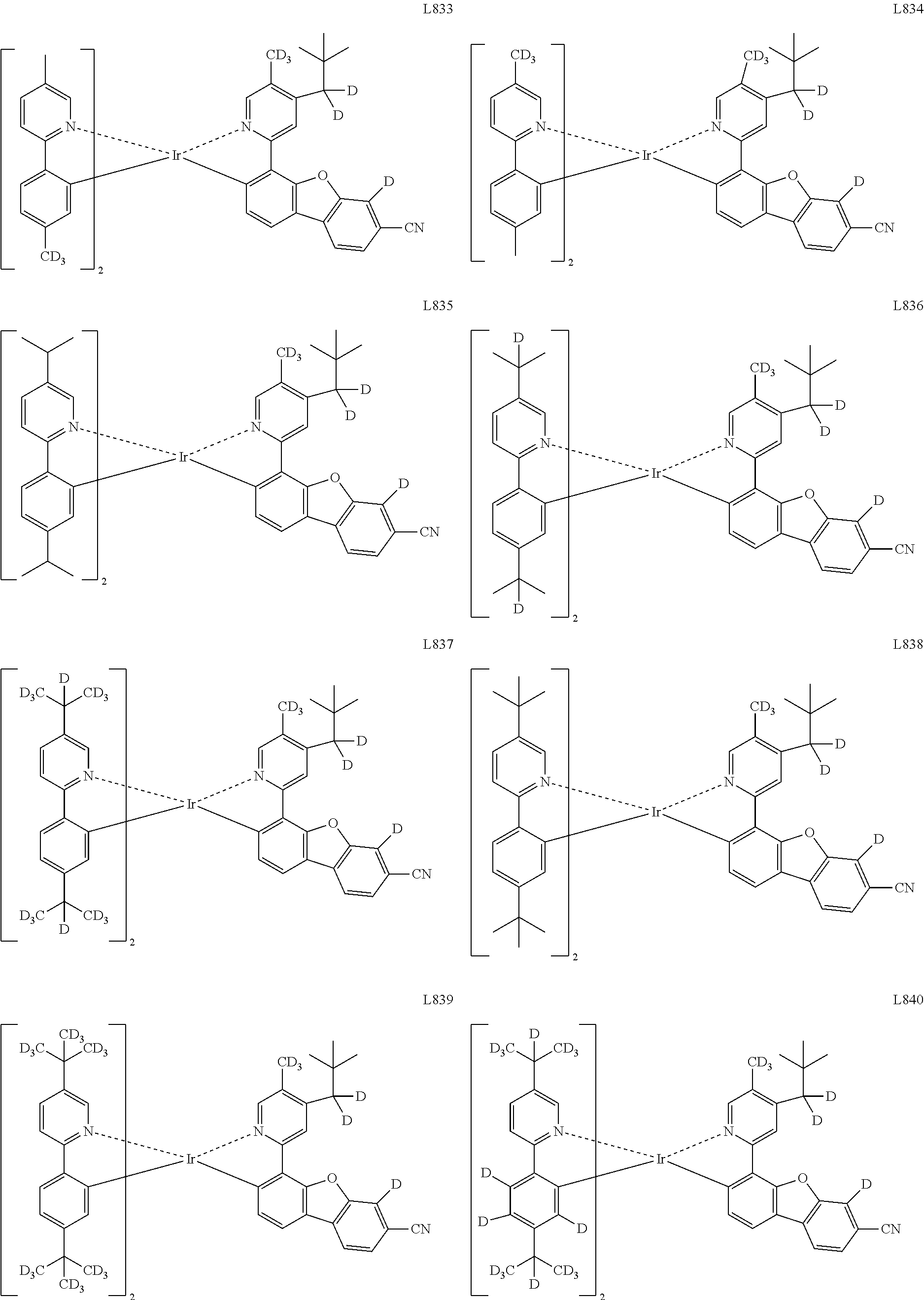

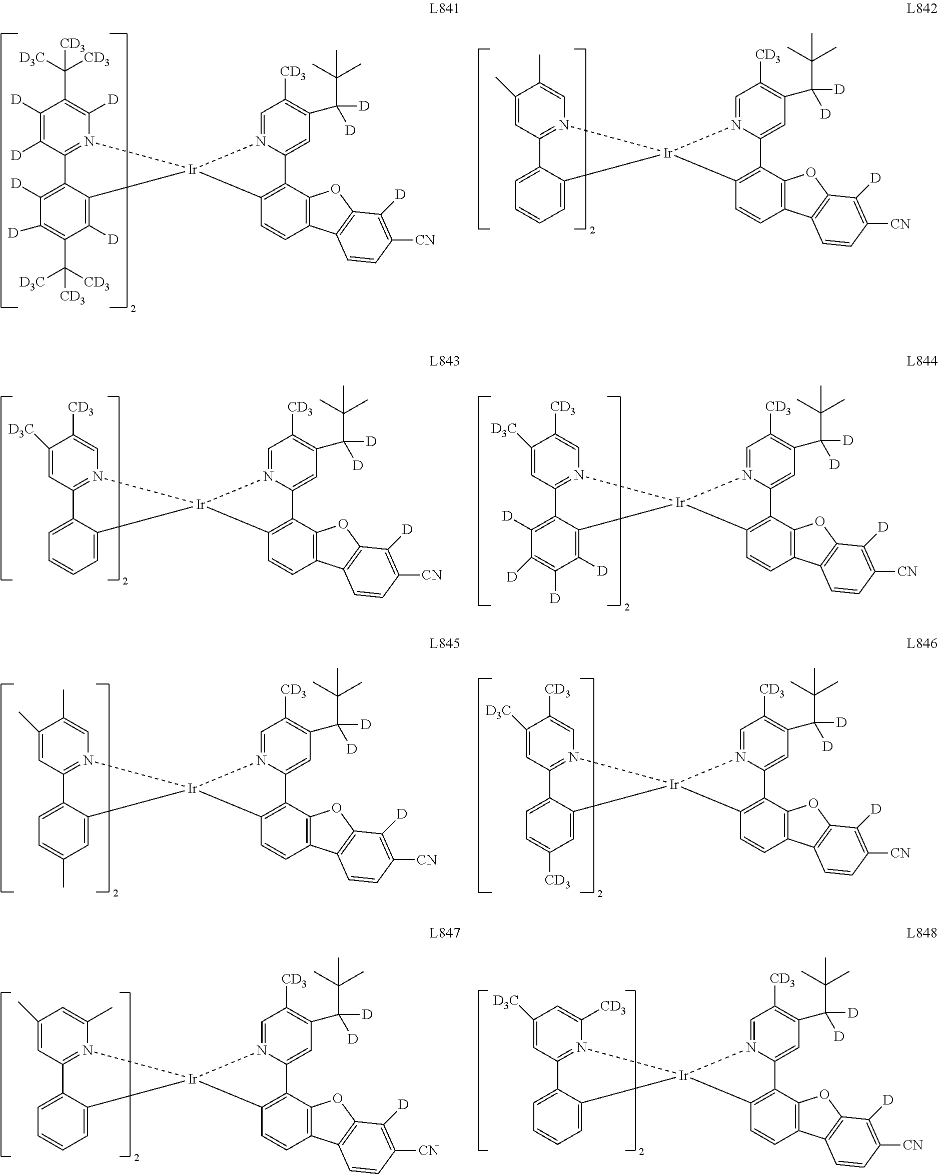

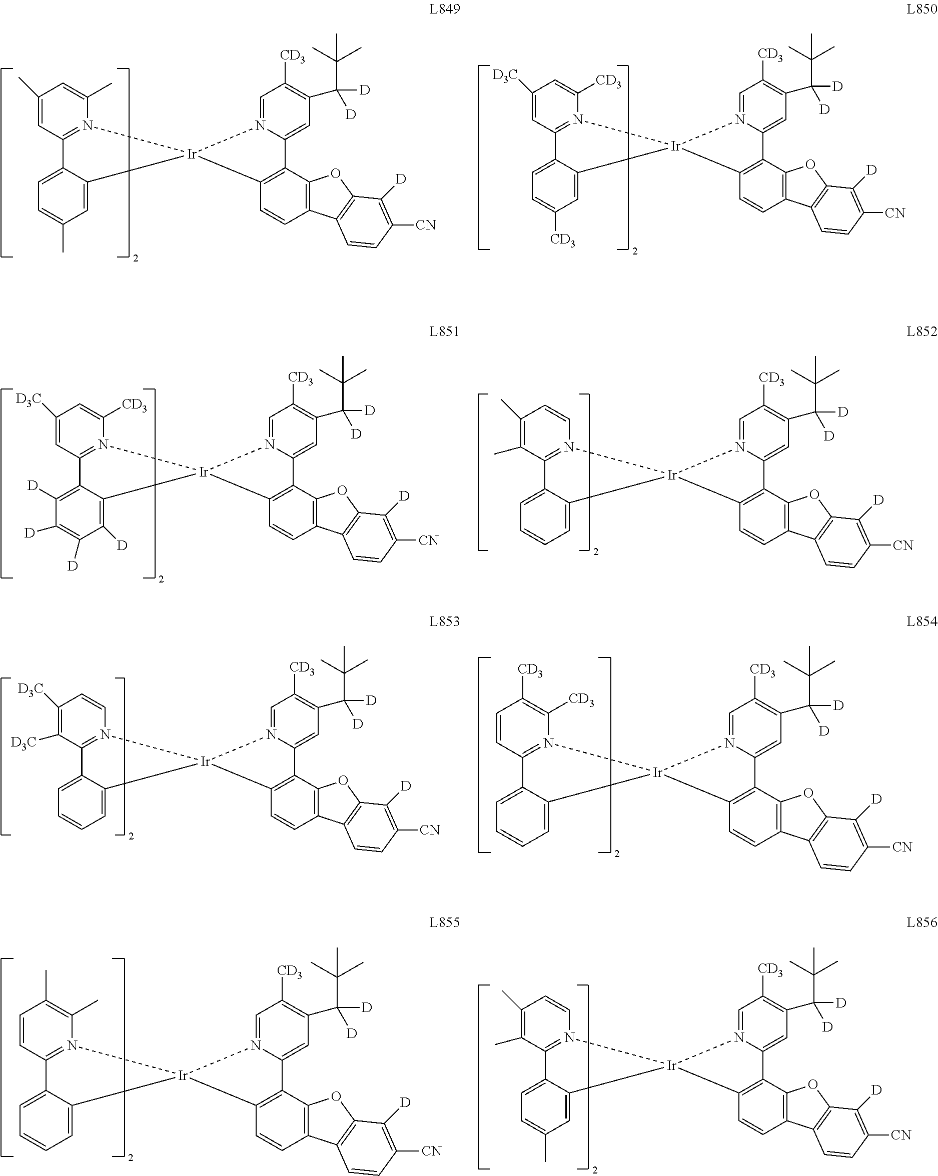

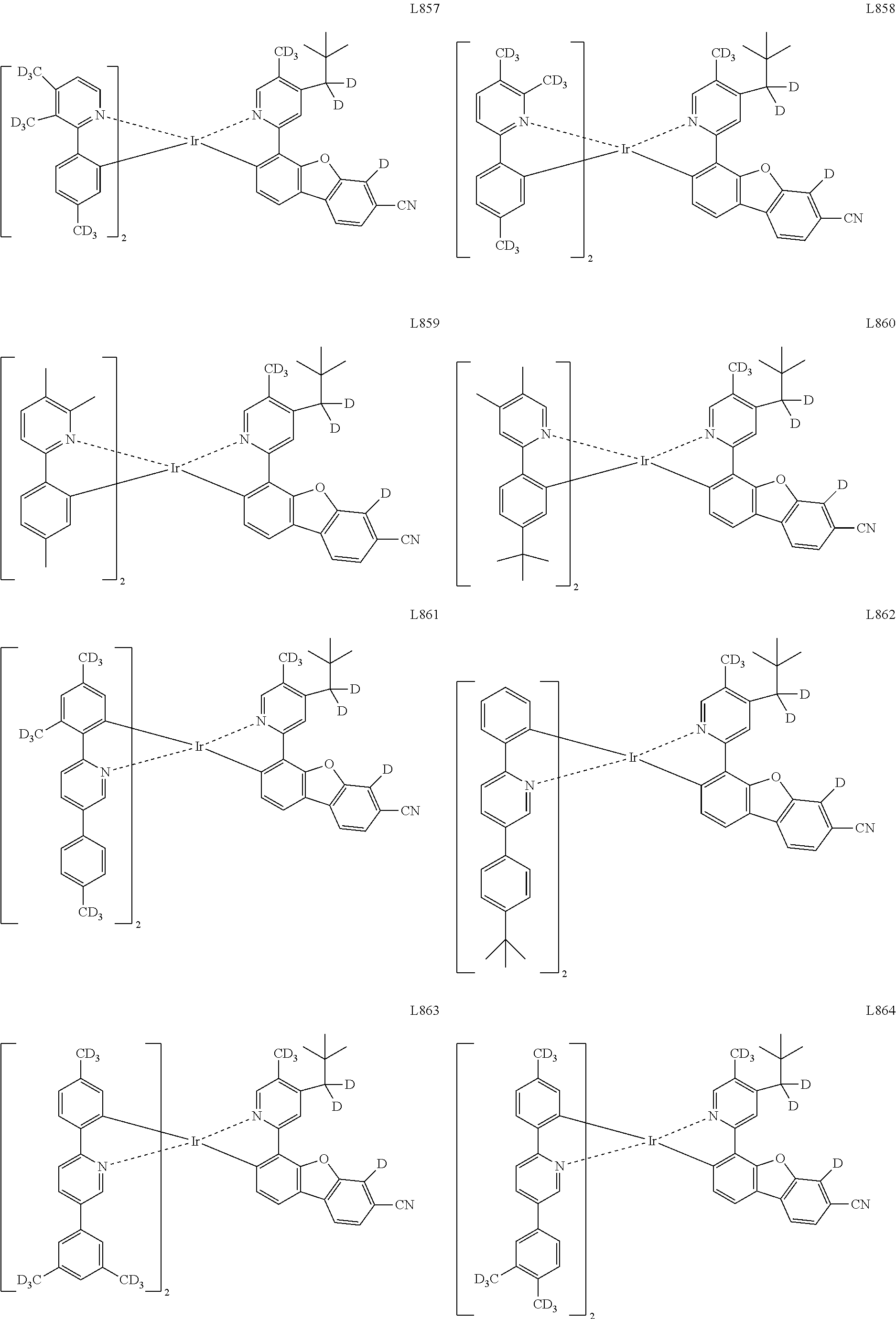

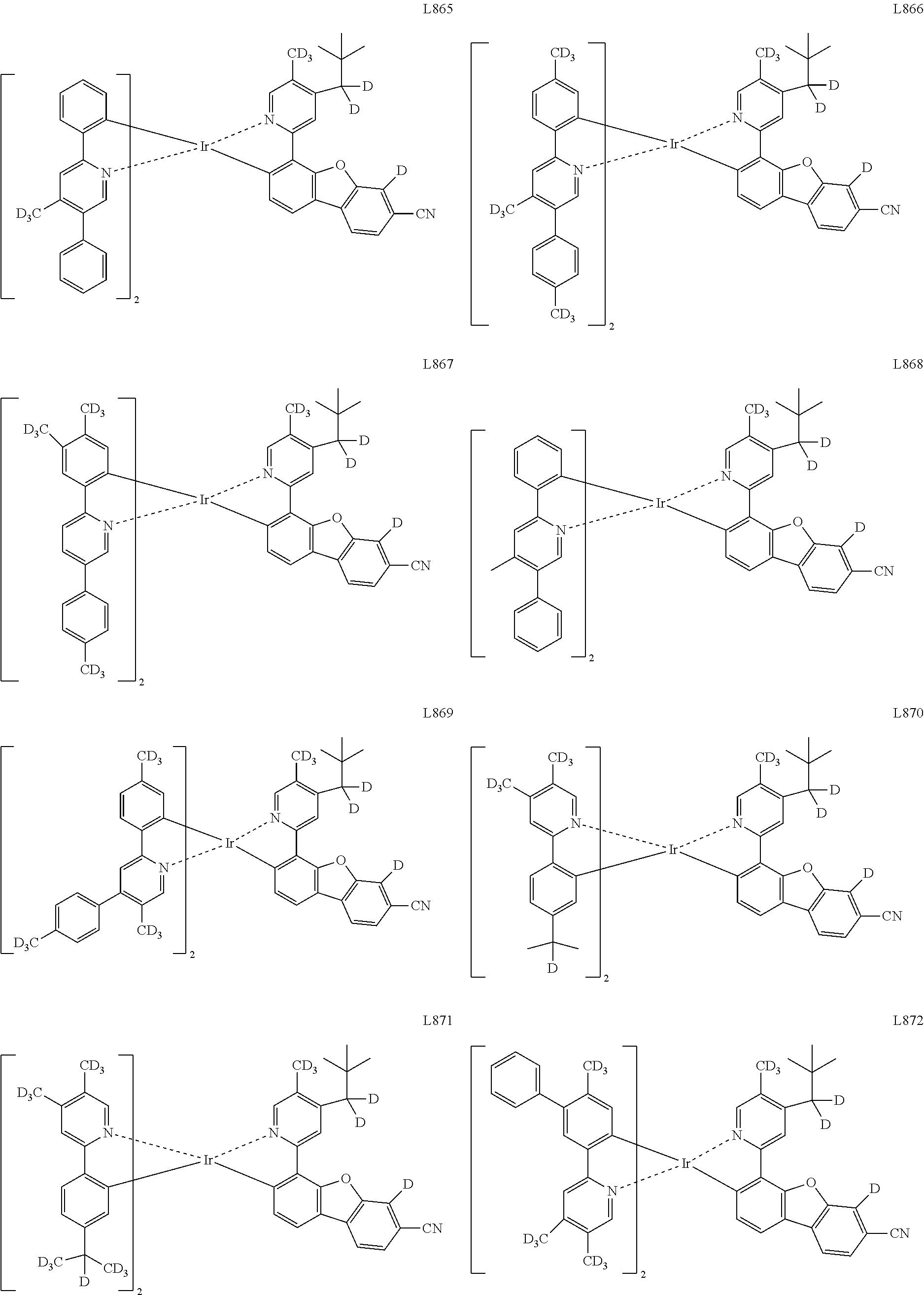

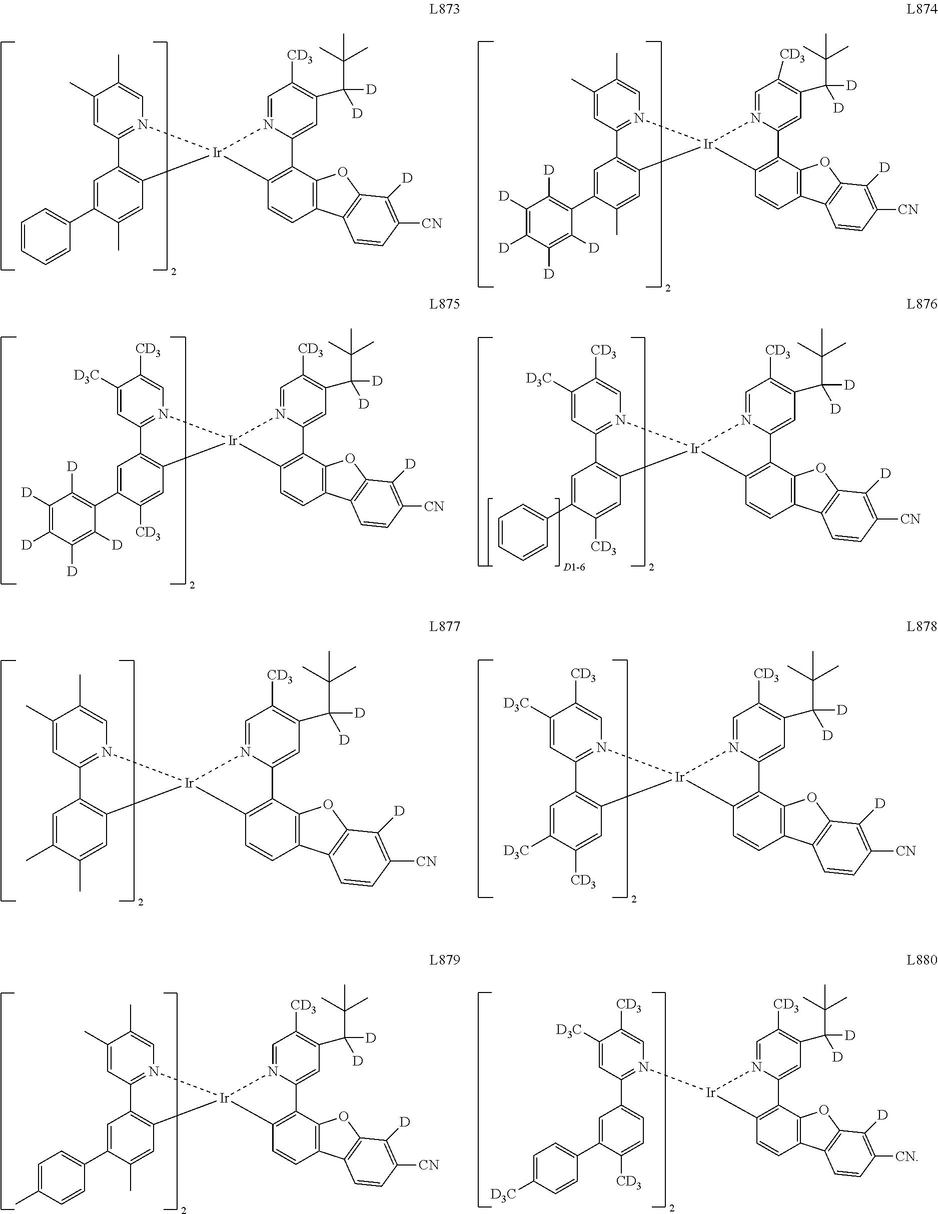

It should be noted that the inventor tested the above structural formulae L001-L880 and found that
the above compounds can significantly improve the luminous efficiency, enhance the service life and reduce the starting voltage after being used in organic electroluminescent devices.

For a second object, the present disclosure provides an organic electroluminescent device, the organic electroluminescent device comprising an organic layer; the organic layer contains an organometallic compound as described above.

Specifically, the organic metal compound may be in a single form or may be present in the organics layer after mixing with other substances.

Further, the organic electroluminescent device comprises a first electrode and a second electrode; the organics layer is disposed between the first electrode and the second electrode; wherein, the organics layer comprising a light-emitting layer, the light-emitting layer comprising an organic metal compound as described above.

Still further, the light-emitting layer comprises main material and dopant material; the dopant material comprises an organic metal compound as described above; and the mass ratio of the main material to the dopant material is (10-99.5):0.5.

Generally, the organic layer further comprises one or more of a hole-injection layer, a hole-transport layer, a layer possessing both hole-injection and hole-transport, an electron-blocking layer, a hole-blocking layer, an electron-transport layer, an electron-injection layer, and a layer possessing both electron-transport and electron-injection; wherein the at least one of the functional layers comprises an organic metal compound as described in the present disclosure.

For a third object, the present disclosure provides an application of an organic electroluminescent device in the preparation of organic light-emitting devices, organic solar cells, electronic paper, organic photoreceptors, or organic thin-film transistor. By introducing an organic metal compound into the light-emitting layer, the device is endowed with superior performance.

Compared with the prior art, the present disclosure provides an organic metal compound and organic electroluminescent devices containing them and applications, the present disclosure has the following beneficial effects:

The organic metal compounds provided by the present disclosure are capable of modulating the electrochemical properties of the compounds through the combination of deuterated and cyano groups at specific positions of specific heterocyclic ligands. When the obtained organic metallic complexes are applied to organic electroluminescent devices, it results in improved luminescence efficiency, increased lifetime and reduced driving voltage of the devices.

### BRIEF DESCRIPTION OF THE ATTACHED DRAWINGS

In order to more clearly illustrate the technical solutions in the specific embodiments or prior art of the present disclosure, the accompanying drawings to be used in the description of the embodiments or prior art will be briefly introduced below, and it will be obvious that the accompanying drawings in the following description are only embodiments of the present disclosure, and to a person of ordinary skill in the art, other accompanying drawings can be obtained based on the provided accompanying drawings without creative labor.

FIG. 1 shows a nuclear magnetic hydrogen spectrum of Intermediate B-01.

FIG. 2 shows a nuclear magnetic hydrogen spectrum of Intermediate B-02.

FIG. 3 shows the mass spectra of Organic Metal Compound L005.

FIG. 4 shows the mass spectra of Organic Metal Compound L006.

FIG. 5 shows the mass spectra of Organic Metal Compound L271.

FIG. 6 shows the mass spectra of Organic Metal Compound L567.

### DETAILED DESCRIPTION

The technical solutions will be described clearly and completely in the following in connection with the implementation examples of the present disclosure and the relevant accompanying drawings. Obviously, the described implementation examples are only a part of the implementation examples of the present disclosure and not all of them. Based on the implementation examples in the present disclosure, all other implementation examples obtained by a person of ordinary skill in the art without making creative labor are within the scope of protection of the present disclosure.

The features and performance of the present disclosure will be described in further detail below in connection with implementation example.

### Compound Implementation Example 1

The implementation example provides an organic metal compound L005, i.e., the compound numbered L005, the specific synthesis steps are as follows:

### 1) Synthesis of Intermediate A-01

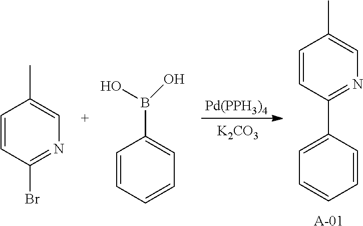

Weigh the Intermediate 2-bromo-4-methylpyridine (58.13 mmol, 10 g), phenylboronic acid (69.76 mmol, 8.51 g), toluene 150 ml, water 150 ml and 75 ml of anhydrous ethanol, and add them to the reaction system, replace the nitrogen twice, add 0.7 g of Pd(PPh₃)₄ and 16 g of potassium carbonate to the reaction system under the protection of nitrogen, set the external temperature of the reaction system to 90° C. and keep stirring at 90° C. for 16 hours. When TLC monitors that the reaction is fully completed, cools the temperature of the reaction system to 25° C., separates the liquid and extract the organic phase, dry the organic phase with anhydrous sodium sulfate, and distill the organic phase under reduced pressure until no liquid flow out, and purify the distilled solids by column chromatography (deploying agent ethyl acetate:petroleum ether=1:30) to obtain Intermediate A-01 (6.59 g, (yield 67%).
Analytical Testing of Intermediate A-01:
HPLC purity: >99.6%;
Mass Spectrometry: Calculated value 169.23; Tested value 169.20.

### 2) Synthesis of Intermediate B-01

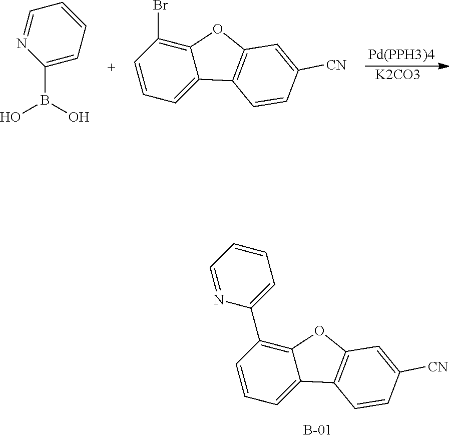

Weigh the Intermediate 2-pyridineboronic acid (40.68 mmol, 5 g), 6-bromodibenzo[b,d]furan-3-carbonitrile (33.90 mmol, 9.22 g), 100 ml of toluene and 100 ml of water, and add them to the reaction system, replace the nitrogen twice, add 0.9 g of Pd(PPh₃)₄ and 17 g of potassium carbonate to the reaction system under the protection of nitrogen. Set the external temperature of the reaction system to 90° C., and keep stirring at 90° C. for 56 h. When TLC monitor that the chemical reaction is fully completed, cool the temperature of the reaction system down to room temperature, separate and extract the organic phase, dry the organic phase with anhydrous sodium sulfate, and the organic phase is distilled under reduced pressure until no liquid flow out, and purify the distilled solids by column chromatography (deploying agent ethyl acetate:petroleum ether=1:3) to obtain intermediate B-01 (6.89 g, yield 75.2%).

Analytical testing of Intermediate B-01:

HPLC purity: >99%;

Mass Spectrometry: Calculated value 270.29; Tested value 270.31.

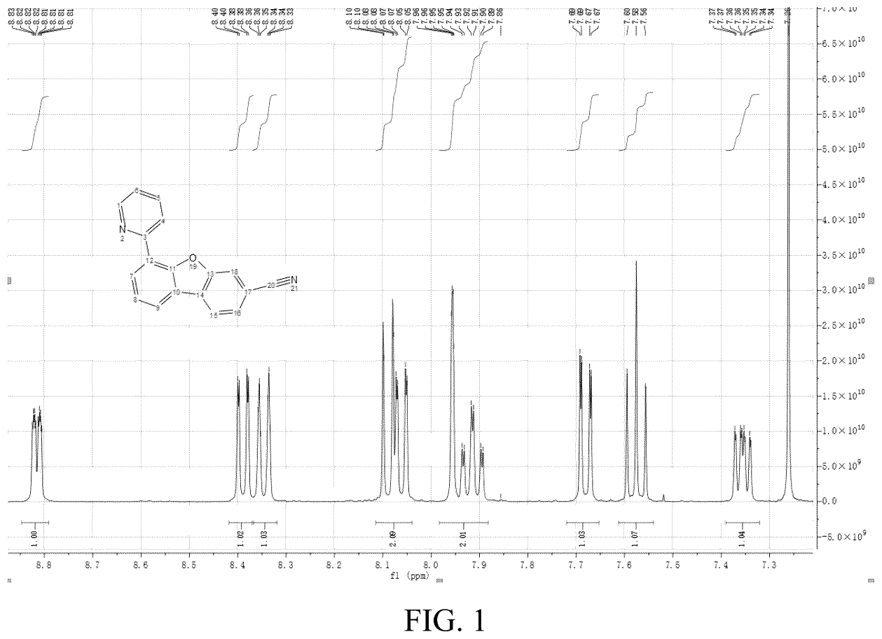

NMR hydrogen spectrum: as in FIG. 1.

### 3) Synthesis of Intermediate B-02

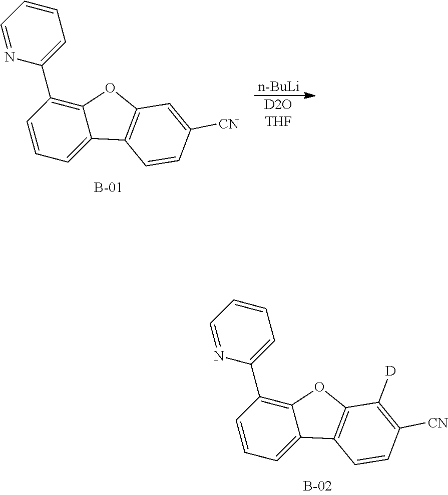

Replace the 2 L reaction flask twice with nitrogen gas, and add 360 ml of tetrahydrofuran and intermediate B-01 (22.20 mmol, 6.0 g) to the reaction flask under nitrogen, lower the temperature of the reaction system to −80° C. and start to drip 2.5 mol/L n-butyllithium (66.6 mmol, 26.6 ml), react for 6 hours at low temperature, 600 ml of heavy water is added dropwise at low temperature, and keep for 30 min at low temperature, the reaction system is naturally warmed back to 25° C., keep stirring for 10 hours, add 300 ml of ethyl acetate to separate the liquid, distill the organic phase under reduced pressure until no liquid flowed out, and purify the distilled solids by column chromatography (deploying agent ethyl acetate:petroleum ether=1:3) to obtain the Intermediate B-02 (4.86 g, yield 81%).

Analytical testing of Intermediate B-02:

HPLC purity: >99%;

Mass Spectrum: Calculated Value 271.30; Tested Value 271.28.

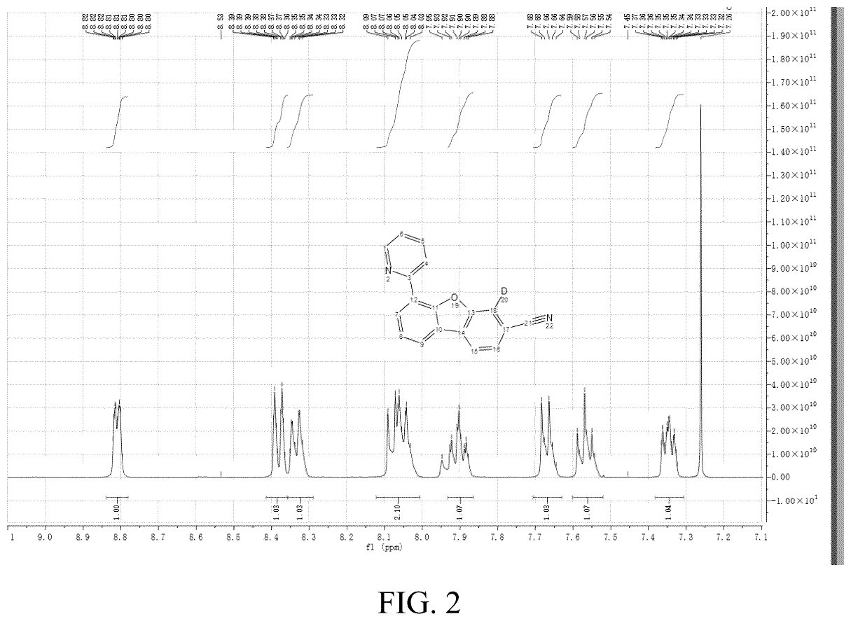

NMR Hydrogen Spectrum: as in FIG. 2.

The present disclosure now encodes some of the group positions of intermediate B-01 as follows:

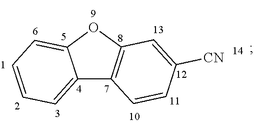 [SMILES: N#Cc1ccc2c(c1)oc1ccccc12]

After theoretical calculations, the Intermediate B-01 has the highest H activity at position number 13, which is the most easily deuterated. From the NMR Hydrogen Spectrum data in FIG. 1, it can be seen that the single peak with chemical shift between 7.9-8.0 corresponds to the hydrogen at position number 13, while in the NMR Hydrogen Spectrum in FIG. 2, the single peak between 7.9-8.0 almost disappear, proving that this position is deuterated.

### 4) Synthesis of Intermediate C-01:

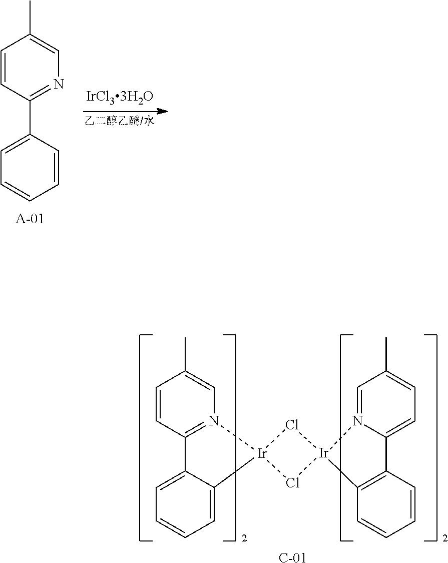

Weigh the Intermediate A-01 (29.55 mmol, 5.0 g) and iridium trichloride trihydrate (11.82 mmol, 4.17 g) under nitrogen protection system, and add them into the reaction system, add the mixture of 150 mL of ethylene glycol ether and 50 mL of pure water, stir at 120° C. for 48 hours under nitrogen protection, and then cool the temperature of the reaction system down to 30° C., and precipitate is precipitated from the solution. Filter the precipitate under reduced pressure, then wash the precipitate with water, anhydrous ethanol and petroleum ether in turn, dry the obtained solid to obtain the Intermediate C-01 (4 g, yield 60%).

### 5) Synthesis of Intermediate C-02:

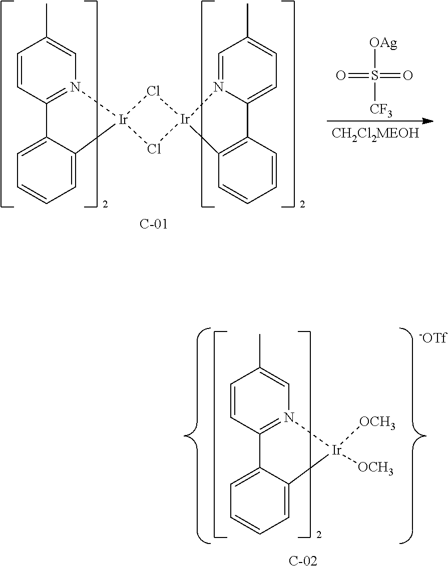

Weigh the Intermediate C-01 (2.66 mmol, 3 g), and add silver trifluoromethanesulfonate (5.85 mmol, 1.5 g), then add 90 mL of dichloromethane to the system, 20 mL of methanol is added, and stir for 56 hours at 25° C. under the protection of nitrogen, when the reaction is over, distill the reaction solution until no liquid flows out, then perform column chromatography (deploying agent: dichloromethane), distill the received solution under reduced pressure until no solid is precipitated and obtain Intermediate C-02 (3.85 g, yield 98%).

### 6) Synthesis of Organic Metal Compound L005

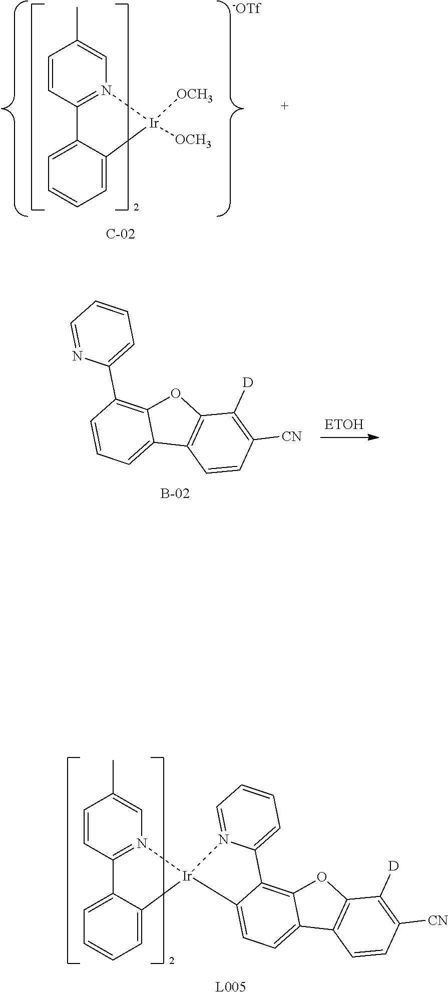

Weigh the Intermediate C-02 (4.06 mmol, 3 g), and the Intermediate B-02 (12.18 mmol, 3.31 g) is added to the Intermediate C-02, then add 90 mL anhydrous ethanol to the reaction system, reflux at 90° C. for 24 hours under the protection of nitrogen, when the reaction is finished, cool the temperature of the reaction system to 25° C. After filtration of the solution under reduced pressure, wash the filter cake with anhydrous ethanol and petroleum ether (60-90) ° C. in turn, and then dry in vacuum at 80° C. After drying, the solids are chromatographed on silica gel column (deploying agent: dichloromethane), the filtrate is concentrated and the solid is precipitated to obtain the Organic Metal Compound L005 (1.59 g, yield 49%).

Analytical Testing of Organic Metal Compound L005:

HPLC purity: >99.8%;

HMOM: −5.38 ev, LUMO: −2.60 ev.

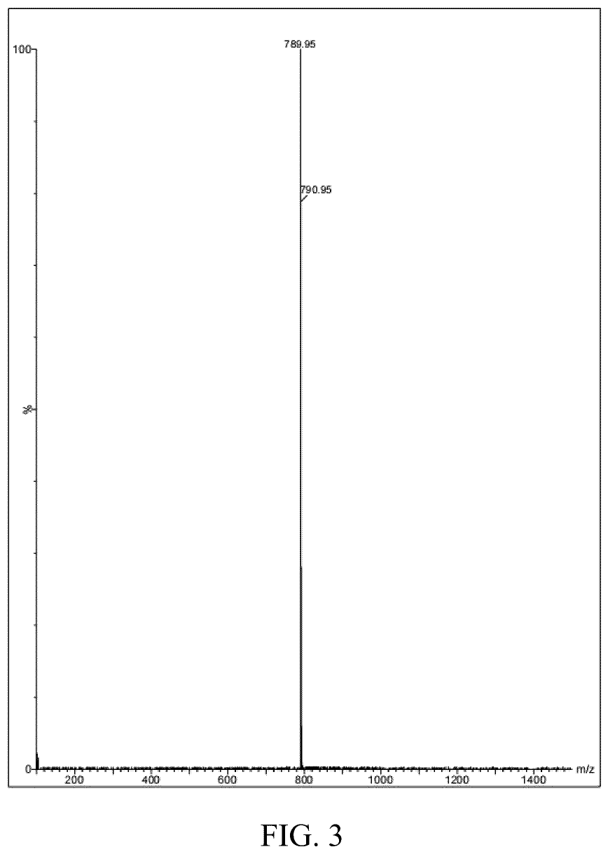

Mass Spectrometry: Calculated Value 789.94; Tested Value 789.95, as shown in FIG. 3.

In this implementation example, the organic metal compounds are used in the preparation of organic electroluminescent device products.

### Compound Implementation Example 2

The present implementation example provides an organic metal compound L006, i.e., the compound numbered L006, the specific synthesis steps are as follows:

### 1) Synthesis of Intermediate A-02

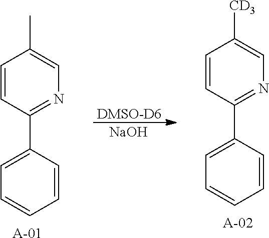

Weigh the Intermediate A-01 (59.09 mmol, 10 g) and 99.42 g of deuterated DMSO and add them into the reaction system, then heat the reaction system up to 80° C., and when all the Intermediate A-01 is dissolved in deuterated DMSO solution, weigh 7 g of sodium hydroxide and add into the reaction system, and heat the reaction system up to 120° C., stir for 72 hours, and then cool down the temperature of the reaction system to 50° C., distill the reaction solution under reduced pressure until no liquid flow out, and purify the distilled solid by column chromatography (deploying agent ethyl acetate:petroleum ether=1:40) to obtain Intermediate A-02 (8.65 g, yield 85%).

Analytical Testing of Intermediate A-02:

HPLC purity: >99%;

Mass Spectrometry: Calculated value 172.25; Tested value 172.20.

### 2) Synthesis of Intermediate D-01

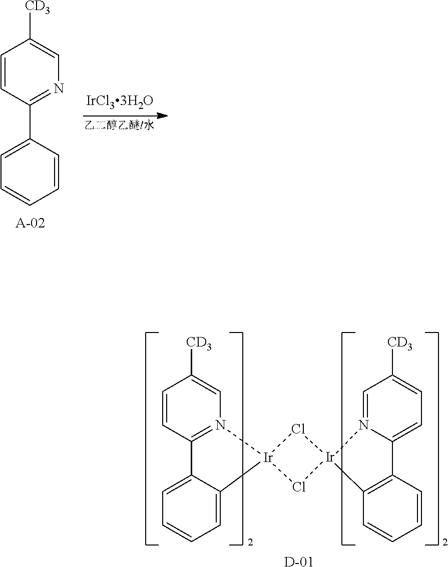

Weigh the Intermediate A-02 (34.83 mmol, 6.0 g) and iridium trichloride trihydrate (13.93 mmol, 4.91 g) and add them to the reaction system under nitrogen protection, add a mixture of 180 mL of ethylene glycol ethyl ether and 60 mL of pure water to the reaction system, and stir at 120° C. for 56 hours under nitrogen protection, and then cool down the temperature of the reaction system to 30° C., and precipitation from the solution. Filter the precipitate under reduced pressure, wash with water, anhydrous ethanol and petroleum ether in turn, and dry the solid obtained to obtain Intermediate D-01 (5.08 g, yield 64%).

### 3) Synthesis of Intermediate D-02

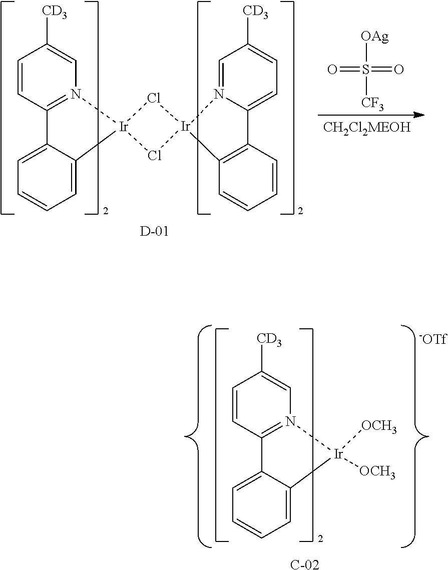

Weigh the Intermediate D-01 (2.63 mmol, 3 g), and silver trifluoromethanesulfonate (5.79 mmol, 1.5 g) is added in it, then add 90 mL of dichloromethane to the system, and add 30 mL of methanol to the system, and stir for 56 h at 25° C. under the protection of nitrogen, at the end of the reaction, distill the reaction solution until no liquid comes out, and perform column chromatography (unfolding agent: dichloromethane), and distill the receiving liquid under reduced pressure until no solid precipitated out and obtain Intermediate D-02 (3.84 g, yield 98%).

### 4) Synthesis of Organic Metal Compound L006

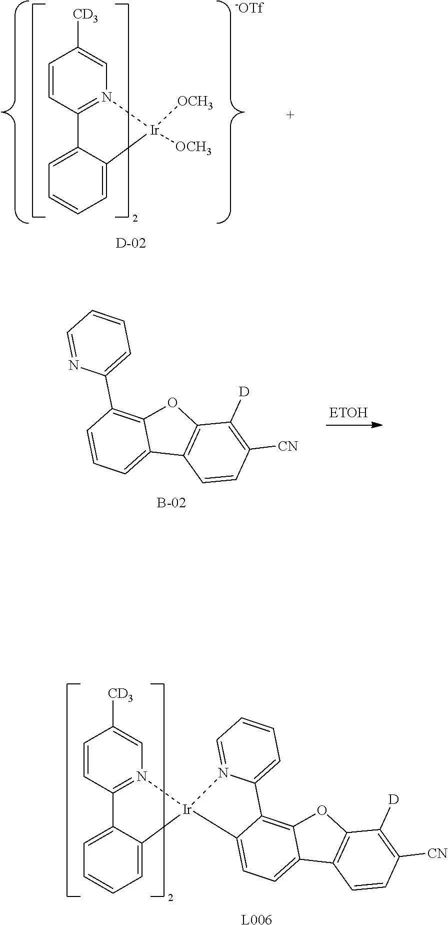

Weigh the Intermediate D-02 (4.03 mmol, 3 g), and the Intermediate B-02 (12.08 mmol, 3.28 g) is added to the Intermediate D-02, then 60 mL of anhydrous ethanol is added to the system, and refluxed at 90° C. for 24 h under the protection of nitrogen, when the reaction is finished, filter under reduced pressure, and the filter cake is sequentially washed with anhydrous ethanol and petroleum ether (60-90) ° C. in turn, and then dry in vacuum at 80° C. After drying, the solid are chromatographed on silica gel column (developing agent: dichloromethane), the filtrate is concentrated and the solid is precipitated to obtain the Organic Metal Compound L006 (1.26 g, yield 39%).

Analytical Testing of the above Organic Metal Compound L006:

HPLC purity: >99.8%;

HMOM: −5.35 ev, LUMO: −2.65 ev;

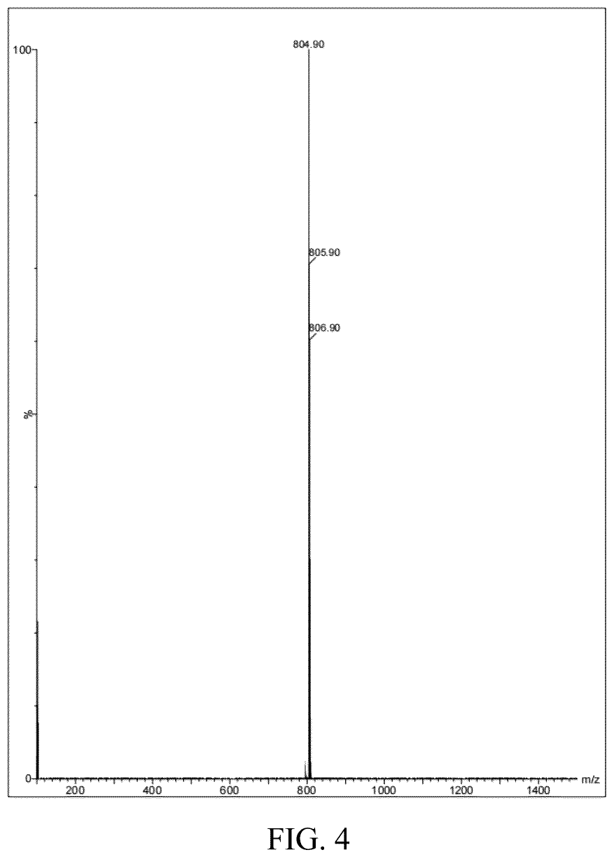

Mass Spectrometry: Calculated Value is 804.98; Test Value is 804.90, as shown in FIG. 4.

In this implementation example, the organic metal compounds are used in the preparation of organic electroluminescent device products.

### Compound Implementation Example 3

The present implementation example provides an organic metal compound L271, i.e., the compound numbered L271, the specific synthesis steps are as follows:

### 1) Synthesis of Intermediate E-01

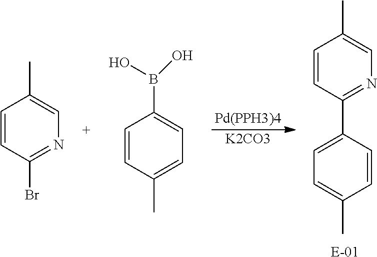

Weigh the Intermediate 2-bromo-4-methylpyridine (29.07 mmol, 5 g), 4-methylphenylboronic acid (34.88 mmol, 4.74 g), 80 mL of toluene, 80 mL of water, 75 mL of anhydrous ethanol and add them to the reaction system, replace the nitrogen for two times, add 0.5 g of Pd(PPh₃)₄ and 12 g of potassium carbonate to the reaction system under nitrogen protection, and set the external temperature of the reaction system to 90° C., and keep stirring at 90° C. for 18 hours. When TLC monitors that the reaction is fully completed, cools the temperature of the reaction system to 30° C., separates the liquid, extracts the organic phase, and dry the organic phase with anhydrous sodium sulfate, and distill the organic phase under reduced pressure until no liquid flows out, and purify the distilled solid by column chromatography (developing agent ethyl acetate:petroleum ether=1:20) to obtain Intermediate E-01 (4.31 g, yield 81%).

Analytical Testing of the Intermediate E-01:

HPLC purity: >99.5%;

Mass Spectrometry: Calculated Value is 169.32; Test Value is 169.20.

### 2) Synthesis of Intermediate E-02

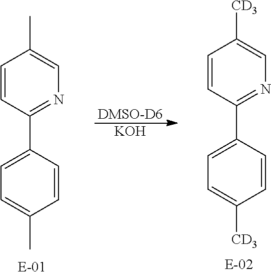

Weigh the Intermediate E-01 (21.83 mmol, 4 g) and 36.73 g of deuterated DMSO and then add them to the reaction system, and heat the reaction system to 80° C. After the Intermediate E-01 is completely dissolved in the deuterated DMSO solution, 3.67 g of potassium hydroxide is weighed and added to the reaction system, heat the reaction system to 120° C. and stir for 72 hours, cool the temperature of the reaction system down to 50° C., and distill the reaction solution under reduced pressure until no liquid flowed out. Purify the distilled solid by column chromatography (developing agent ethyl acetate:petroleum ether=1:15) to obtain Intermediate E-02 (3.14 g, yield 76%).

Analytical Testing of the Intermediate E-02:

HPLC purity: >99.5%;

Mass Spectrometry: Calculated value is 189.29; test value is 189.20.

### 3) Synthesis of Intermediate F-01

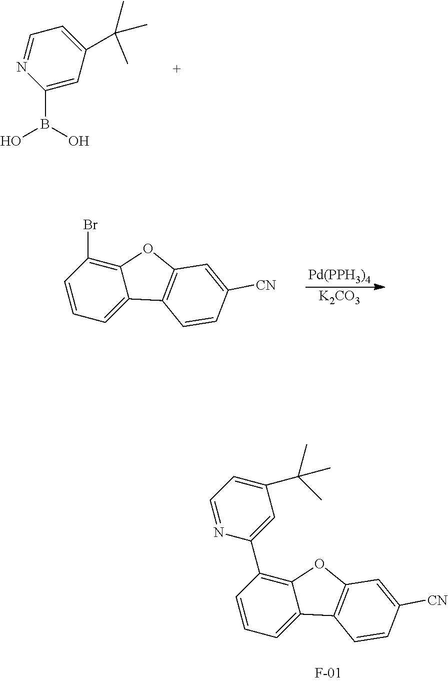

Weigh the intermediate 4-tert-butyl-2-pyridine boric acid (33.51 mmol, 6 g), 6-bromodibenzo[b,d]furan-3-cyano (16.76 mmol, 4.56 g), 120 mL of toluene, 120 mL of water and add them to the reaction system, replace nitrogen gas twice, and add 1 g of Pd(PPh₃)₄ and 6.95 g of potassium carbonate to the reaction system under nitrogen protection. Set the external temperature of the reaction system to 90° C., and keep stirring at 90° C. for 48 hours. When TLC monitors that the reaction is fully completed, cools the reaction system to 25° C. separates the liquid, extracts the organic phase, and dry the organic phase with anhydrous sodium sulfate and distilled under reduced pressure until no liquid flows out, and purify the distilled solid by column chromatography (developing agent ethyl acetate:petroleum ether=1:1) to obtain intermediate F-01 (3.39 g, yield 62%).

Analytical Testing of the Intermediate F-01:

HPLC purity: >99.2%;

Mass Spectrometry: Calculated Value is 326.40; Test Value is 326.36.

### 4) Synthesis of Intermediate F-02

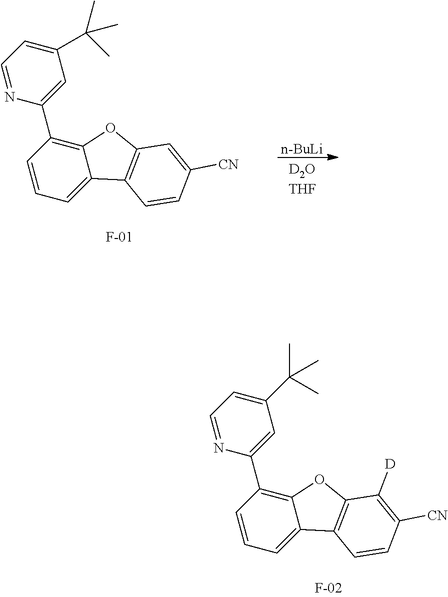

Replace the 2 L reaction flask twice with nitrogen gas, and add 180 ml of tetrahydrofuran and the Intermediate F-01 (9.19 mmol, 3.0 g) to the reaction flask under nitrogen. lower the temperature of the reaction system to −80° C., and start to drip 2.5 mol/L of n-butyl lithium (27.5 mmol, 11 ml), react for 6 hours at low temperature. 300 ml of heavy water is added dropwise at low temperature. Keep for 30 min at low temperature, then the reaction system is naturally warmed back to 25° C., keep stirring for 10 hours. 100 ml of ethyl acetate is added to separate the liquid, distill the organic phase under reduced pressure until no liquid flowed out, and purify the distilled solid by column chromatography (developing agent ethyl acetate:petroleum ether=1:3) to obtain intermediate F-02 (2.8 g, yield 93%).

Analytical Testing of the Intermediate F-02:

HPLC purity: >99.1%;

Mass Spectrometry: Calculated Value is 327.41; Test Value is 327.38.

### 5) Synthesis of Intermediate E-03

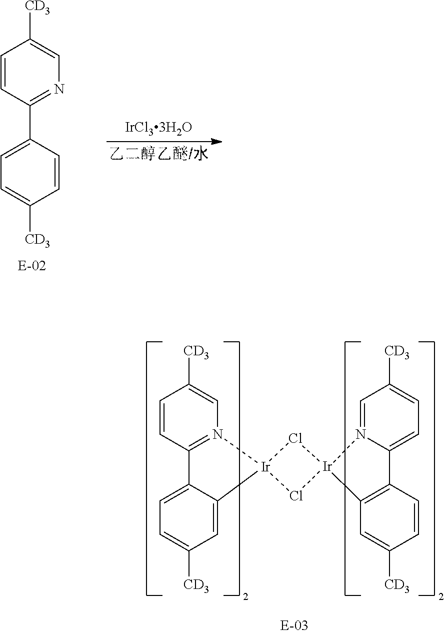

Under the nitrogen protection system, weigh the intermediate E-02 (15.85 mmol, 3 g) and iridium trichloride trihydrate (7.92 mmol, 2.79 g) and add them into the reaction system. Add a mixed solution of 90 mL of ethylene glycol ether and 30 mL of purified water to the reaction system, then stir the mixture at 120° C. for 56 hours under nitrogen protection, then cool the temperature of the reaction system down to 30° C., and the precipitate is precipitated from the solution. Filter the precipitate under reduced pressure, then wash the precipitate with water, anhydrous ethanol and petroleum ether in turn, dry the obtained solid to obtain Intermediate E-03 (3.26 g, yield of 68%).

### 6) Synthesis of Intermediate E-04

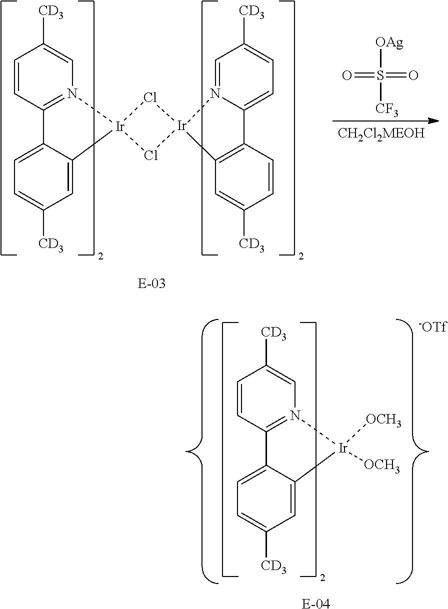

Weigh the Intermediate E-03 (2.48 mmol, 3 g), add silver trifluoromethanesulfonate (6.21 mmol, 1.59 g), then add 90 mL of dichloromethane to the system, then add 30 mL of methanol, and stir at 25° C. for 56 hours under nitrogen. After the reaction is finished, distill the reaction liquid until no liquid flowed out, and then perform column chromatography (deploying agent: dichloromethane), distill the receiving solution under reduced pressure until no solid precipitated to obtain Intermediate E-04 (3.75 g, yield 97%).

### 7) Synthesis of Organic Metal Compound L271

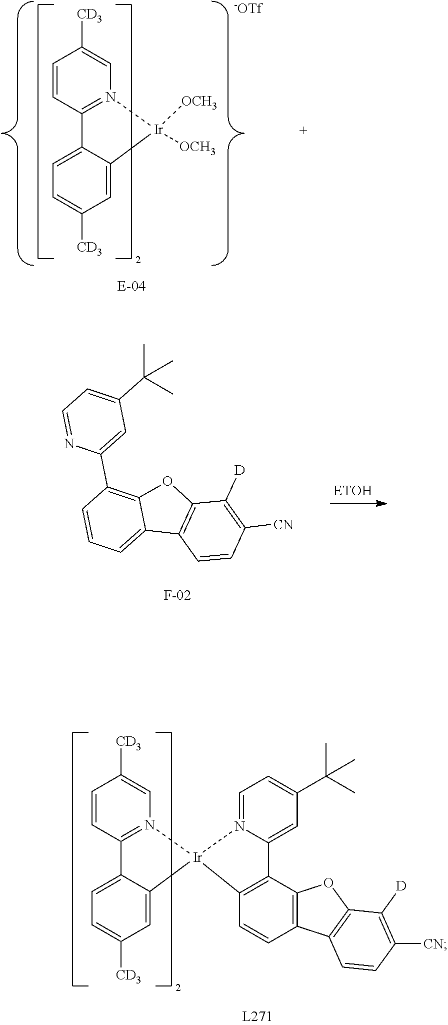

Weigh the Intermediate E-04 (2.57 mmol, 2 g) and add intermediate F-02 (7.70 mm, 2.52 g) to the Intermediate E-04, then add 40 mL of anhydrous ethanol to the reaction system. Reflux at 90° C. for 24 hours under nitrogen protection, When the reaction is over and filtered under reduced pressure. The filter cake is washed with anhydrous ethanol and petroleum ether (60-90) ° C. in turn, and dried in vacuum at 80° C. After drying, the solid is chromatographed with silica gel column (developing agent: dichloromethane), the filtrate is concentrated and the solid is precipitated to obtain the organic metal compound L271 (1.43 g, yield 62%).

Analytical Testing of the Organic Metal Compound L271:

HPLC purity: >99.6%;

HMOM: −5.33 ev, LUMO: −2.49 ev;

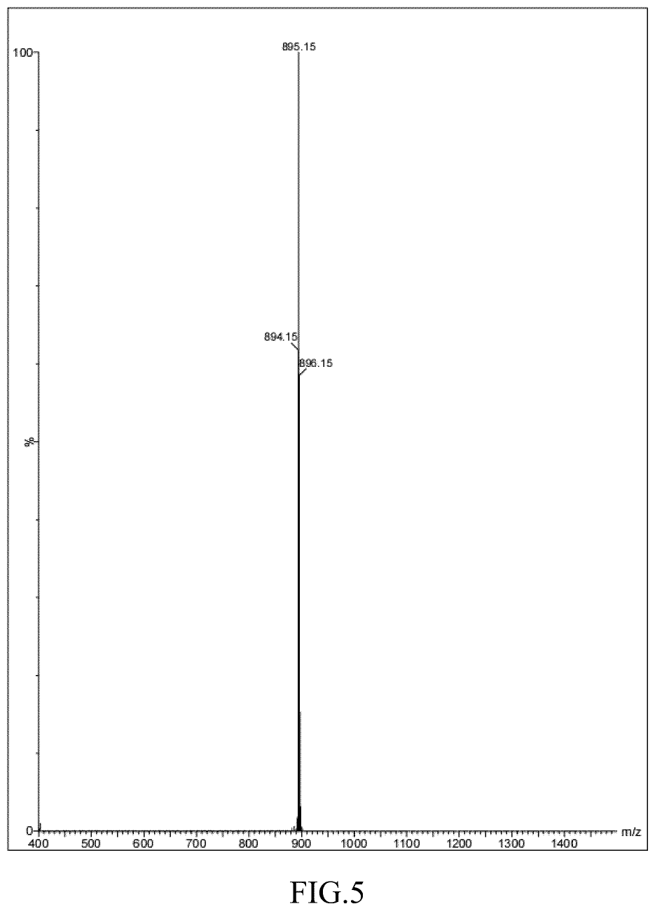

Mass Spectrometry: Calculated Value is 895.18; Test Value is 895.15, as shown in FIG. 5.

In this implementation example, the organic metal compounds are used in the preparation of organic electroluminescent device products.

### Compound Implementation Example 4

The present implementation example provides an organic metal compound L567, i.e., the compound numbered L567, the specific synthesis steps are as follows:

### 1) Synthesis of Intermediate G-01

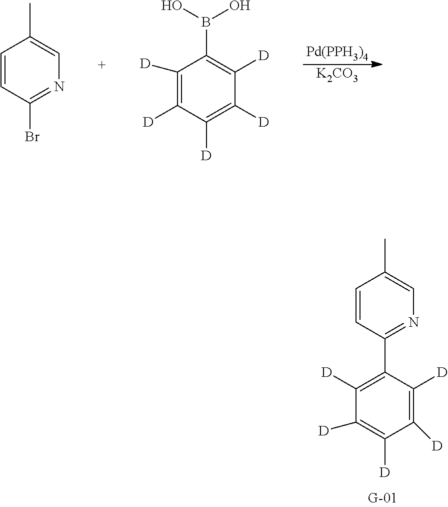

Weigh the Intermediate 2-bromo-4-methylpyridine (29.07 mmol, 5 g), Dibenzylboronic acid (34.88 mmol, 4.43 g), 100 mL of toluene, 100 mL of water, 50 mL of anhydrous ethanol are added to the reaction system, replace the nitrogen for two times, add 0.6 g of Pd(PPh₃)₄ and 12 g of potassium carbonate to the reaction system under nitrogen protection, and set the external temperature of the reaction system to 90° C., and keep stirring at 90° C. for 18 hours. When TLC monitors that the reaction is fully completed, cools the reaction system to 30° C., separates the liquid, extracts the organic phase, and dry the organic phase with anhydrous sodium sulfate, and distill the organic phase under reduced pressure until no liquid flows out, and purify the distilled solid by column chromatography (developing agent ethyl acetate:petroleum ether=1:25) to obtain Intermediate G-01 (4.51 g, yield 89%).

Analytical Testing of the Intermediate G-01:

HPLC purity: >99.6%;

Mass Spectrometry: Calculated Value is 174.26; Test Value is 174.33.

### 2) Synthesis of Intermediate G-02

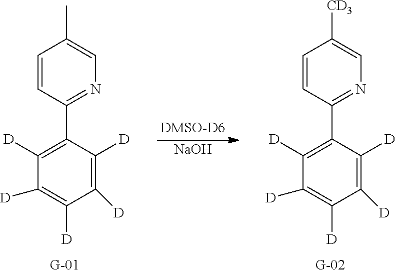

Weigh the Intermediate G-01 (22.95 mmol, 4 g) and 51.51 g of deuterated DMSO and add them to the reaction system, then warm the reaction system up to 80° C. until the Intermediate G-01 is completely dissolved in deuterated DMSO solution, weigh 1.2 g of sodium hydroxide and add to the reaction system, then warm up the reaction system to 120° C. and stir for 72 hours, and then cool the temperature of the reaction system down to 50° C., distill the reaction solution under reduced pressure until no liquid flowed out, and purify the distilled solid by column chromatography (developing agent ethyl acetate:petroleum ether=1:25) to obtain Intermediate G-02 (3.54 g, 87% yield).

Analytical Testing of the Intermediate G-02:

HPLC purity: >99.7%;

Mass Spectrometry: Calculated Value is 177.28; Test Value is 177.30.

### 3) Synthesis of Intermediate H-01

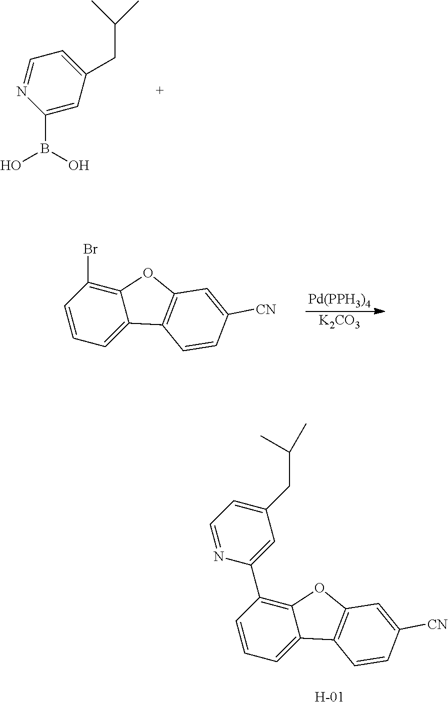

Weigh the Intermediate (4-isobutylpyridin-2-yl)boronic acid (55.86 mmol, 10 g), 6-bromodibenzo [b,d]furan-3-carbonitrile (27.93 mmol, 7.60 g), 200 mL of toluene and 200 mL of water and add them to the reaction system, replace the nitrogen for two times, add 1.4 g of Pd(PPh₃)₄ and 11.58 g of potassium carbonate to the reaction system under the protection of nitrogen, set the external temperature of the reaction system to 90° C., and keep stirring at 90° C. for 48 hours. When TLC monitors that the reaction is fully completed, cools the temperature of the reaction system to 25° C., separates the liquid, extracts the organic phase, and dry the organic phase with anhydrous sodium sulfate, and distill the organic phase under reduced pressure until no liquid flows out, and purify the distilled solid by column chromatography (developing agent ethyl acetate: petroleum ether=1:1) to obtain Intermediate H-01 (5.10 g, 56% yield).

Analytical Testing of the Intermediate H-01:

HPLC purity: >99.3%;

Mass Spectrometry: Calculated Value is 326.40; Test Value is 326.36.

### 4) Synthesis of Intermediate H-02

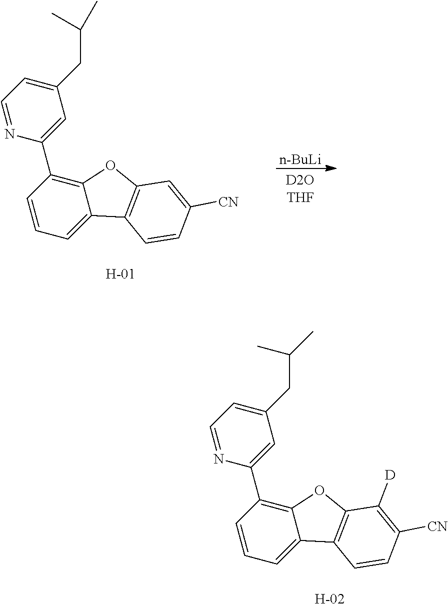

Replace the 2 L reaction flask twice with nitrogen gas, and add 300 ml of tetrahydrofuran and Intermediate H-01 (15.32 mmol, 5.0 g) to the reaction flask under nitrogen. Lower the temperature of the reaction system to −80° C., and start to drip 2.5 mol/L of n-butyl lithium (45.98 mmol, 18.4 ml), react for 6 hours at low temperature. 500 ml of heavy water is added dropwise at low temperature, and keep the low temperature for 30 min, then the reaction system is naturally warmed to 25° C., stir for 10 hours. Add 200 ml of ethyl acetate to separate the reaction liquid, distill the organic phase under reduced pressure until no liquid flowed out, and purify the distilled solid by column chromatography (developing agent ethyl acetate:petroleum ethet=1:3) to obtain Intermediate H-02 (4.11 g, yield 82%).

Analytical Testing of the Intermediate H-02:

HPLC purity: >99.1%;

Mass Spectrometry: Calculated Value is 327.41; Test Value is 327.38.

### 5) Synthesis of Intermediate G-03

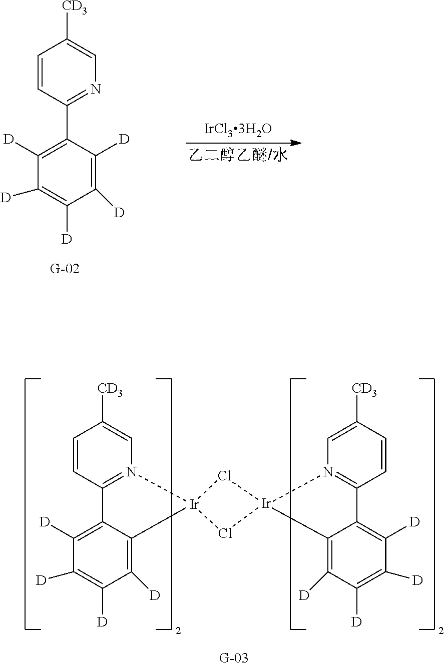

Under the nitrogen protection system, weigh the intermediate G-02 (16.92 mmol, 3 g) and iridium trichloride trihydrate (7.92 mmol, 2.38 g) and add them to the reaction system, and add a mixed solution of 90 mL of ethylene glycol ethyl ether and 30 mL of pure water to the reaction system,
then stir the mixture at 120° C. for 56 hours under nitrogen protection, then cool the temperature of the reaction system down to 30° C., and precipitate is precipitated from the solution. Filter the precipitate under reduced pressure, then wash the precipitate with water, anhydrous ethanol and petroleum ether in turn, dry the obtained solid to obtain Intermediate G-03 (2.54 g, yield 65%);

### 6) Synthesis of Intermediate G-04

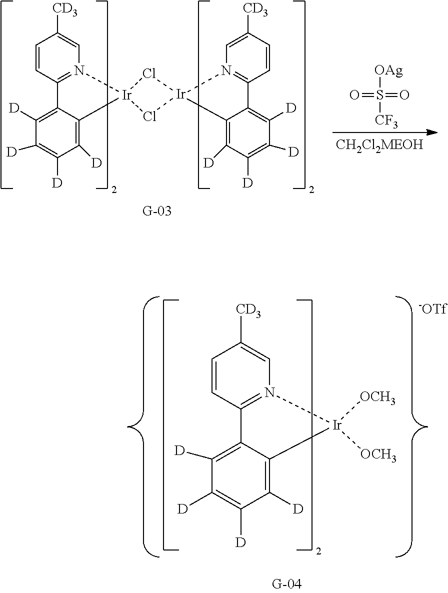

Weigh the Intermediate G-03 (2.16 mmol, 2.5 g) and silver trifluoromethanesulfonate (5.40 mmol, 1.39 g) is added to the Intermediate G-03, and then add 75 mL of dichloromethane to the system, then add 28 mL of methanol, and stir at 25° C. for 56 hours under nitrogen. When the reaction is over, distill the reaction liquid until no liquid flowed out, then perform column chromatography (deploying agent: dichloromethane), distill the received solution under reduced pressure until no solid precipitated and obtain Intermediate G-04 (3.17 g, yield 97%).

### 7) Synthesis of Organic Metal Compound L567

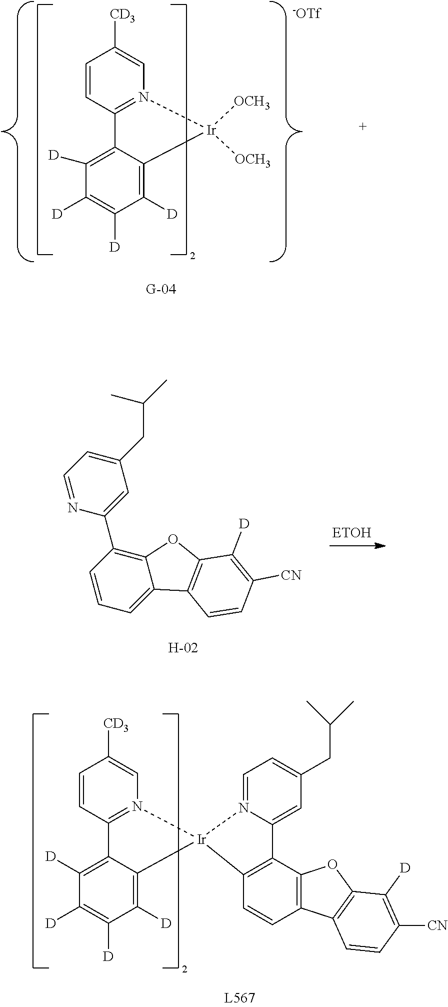

Weigh the Intermediate G-04 (3.97 mmol, 3 g) and the Intermediate H-02 (11.92 mmol, 3.9 g) is added to the IntermediateG-04, then add 60 mL of anhydrous ethanol to the system. Reflux at 80° C. for 24 h under the protection of nitrogen. When the reaction is finished, filter under reduced pressure, and wash the filter cake with anhydrous ethanol and petroleum ether (60-90) ° C. in turn, and then dry in vacuum at 60° C. After drying, the solids are chromatographed on silica gel column (developing agent: dichloromethane), the filtrate is concentrated and the solid is precipitated to obtain the Organic Metal Compound L567 (1.8 g, yield 52%).

Analytical Testing of the Organic Metal Compound L567:

HPLC purity: >99.70%;

HMOM: −5.33 ev, LUMO: −2.44 ev;

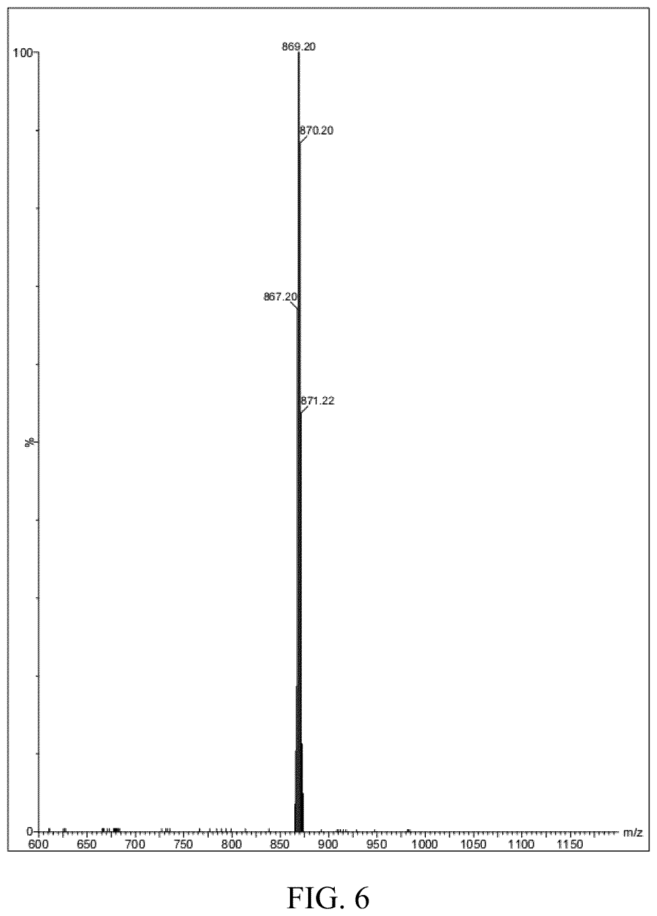

Mass Spectrometry: Calculated Value is 869.14; Test Value is 869.20, as shown in FIG. 6.

In the implementation example, the organic metal compounds are used in the preparation of organic electroluminescent device products.

The other compounds are synthesized in the same way as described above and will not be repeated here, the mass spectra and molecular formulae of the other selected synthetic embodiments are shown in Table 1 below:

TABLE 1
Statistics of molecular formulae, mass spectrometry calculated values
and mass spectrometry tested values of selected substances

| | | Mass | Mass |
|---|---|---|---|
| Compound | Molecular | Spectrometry | Spectrometry |
| Number | Formula | Calculated Values | Test Value |
| L010 | C₄₂H₂₂D₇IrN₄O | 804.98 | 805.03 |
| L043 | C₄₄H₂₀D₁₃IrN₄O | 839.07 | 839.10 |
| L094 | C₄₇H₂₁D₁₈IrN₄O | 886.18 | 886.14 |
| L158 | C₄₉H₁₅D₂₈IrN₄O | 924.30 | 924.26 |
| L166 | C₄₅H₂₈D₇IrN₄O | 847.06 | 847.10 |
| L199 | C₅₉H₂₆D₃₇IrN₄O | 1073.62 | 1073.58 |
| L250 | C₄₆H₃₀D₇IrN₄O | 861.09 | 861.03 |
| L335 | C₄₈H₃₄D₇IrN₄O | 889.14 | 889.20 |
| L351 | C₄₆H₁₈D₁₉IrN₄O | 873.16 | 873.21 |
| L422 | C₅₁H₁₉D₂₈IrN₄O | 952.35 | 952.39 |
| L478 | C₅₁H₂₁D₂₆IrN₄O | 950.34 | 950.31 |
| L485 | C₄₅H₂₇D₈IrN₄O | 848.07 | 848.10 |
| L546 | C₆₁H₂₅D₂₆IrN₄O | 1074.48 | 1074.39 |
| L566 | C₄₆H₃₀D₇IrN₄O | 861.09 | 861.02 |
| L623 | C₆₂H₃₄D₁₉IrN₄O | 1081.47 | 1081.50 |
| L667 | C₅₀H₃₃D₁₂IrN₄O | 922.23 | 922.20 |
| L739 | C₅₃H₄₈D₃IrN₄O | 955.25 | 955.30 |
| L830 | C₅₀H₃₉D₆IrN₄O | 916.69 | 916.20 |

The present disclosure also provides an organic electroluminescent device, the organic electroluminescent device is made from an organic metal compound, more specifically is made from the organic metal compound shown in chemical formula 1.

### Device Implementation Example 1

The organic electroluminescent devices are prepared using the compound L005 prepared in Example 1, the specific steps are as follows:

1) Take a transparent glass with anode material ITO on the surface as a substrate, and then ultrasonically clean it with deionized water, acetone, and ethanol for 15 minutes each, respectively, and then process it in a plasma cleaner for 2 minutes; next, vaporize a hole-injection material HI-01 on the substrate with an anode by vacuum evaporation to form a hole-injection layer with a thickness of 100 Å.

2) Vaporize the hole transfer material HT-01 on the hole injection layer by vacuum vapor deposition to form a hole transfer layer with a thickness of 900 Å.

3) Vaporize the electron-blocking material EB-01 on the hole-transporting layer by vacuum vapor deposition to form an electron-blocking layer with a thickness of 200 Å.

4) To vaporize a light-emitting body material GH-02:GH-03=1:1 and a doping material L005 in a mass ratio of 90:10 on the electron barrier layer by vacuum evaporation to form a light-emitting layer with a thickness of 400 Å.

5) Mixing and vaporizing an electron transport material ET-01 and Liq in a mass ratio of 50:50 on the light-emitting layer by vacuum vapor deposition to form an electron transport layer with a thickness of 40 Å.

6) To vaporize an electron-injecting material LiF on the electron-transporting layer by vacuum vapor deposition to form an electron-injecting layer with a thickness of 150 Å.

7) Vaporize the cathode material Al on the electron injection layer by vacuum evaporation to 10 form a cathode with a thickness of 1000 Å, and obtain the organic electroluminescent device.

Other device implementation examples and device comparative examples compared with device implementation example 1, except that the light-emitting layer main material and dopant material are different, the manufacturing method is the same as that of device implementation example 1, and other device implementation examples will not to be elaborated here, as shown in Table 2.

TABLE 2
The light-emitting layer materials of all the implementation examples and comparative examples

| | Light-emitting | Light-emitting | | Light-emitting | Light-emitting |
|---|---|---|---|---|---|
| Implementation | Layer Main | layer dopant | Comparative | Layer Main | layer dopant |
| Example | Material | material | Example | Material | material |
| Device | GH-02:GH-03 = 1:1 | L005 | Device | GH-02:GH-03 = 1:1 | GD-1 |
| Implementation | | | Comparative | | |
| Example 1 | | | Example 1 | | |
| Device | GH-01 | L006 | Device | GH-01 | GD-2 |
| Implementation | | | Comparative | | |
| Example 2 | | | Example 2 | | |
| Device | GH-01 | L271 | Device | GH-01 | GD-3 |
| Implementation | | | Comparative | | |
| Example 3 | | | Example 3 | | |
| Device | GH-01 | L567 | Device | GH-01 | GD-4 |
| Implementation | | | Comparative | | |
| Example 4 | | | Example 4 | | |
| Device | GH-01 | L010 | Device | GH-01 | GD-5 |
| Implementation | | | Comparative | | |
| Example 5 | | | Example 5 | | |
| Device | GH-01 | L043 | Device | GH-01 | GD-6 |
| Implementation | | | Comparative | | |
| Example 6 | | | Example 6 | | |
| Device | GH-02:GH-03 = 1:1 | L094 | Device | GH-02:GH-03 = 1:1 | GD-7 |
| Implementation | | | Comparative | | |
| Example 7 | | | Example 7 | | |
| Device | GH-02:GH-03 = 1:1 | L158 | Device | GH-02:GH-03 = 1:1 | GD-8 |
| Implementation | | | Comparative | | |
| Example 8 | | | Example 8 | | |
| Device | GH-02:GH-03 = 1:1 | L166 | Device | GH-02:GH-03 = 1:1 | GD-9 |
| Implementation | | | Comparative | | |
| Example 9 | | | Example 9 | | |
| Device | GH-02:GH-03 = 1:1 | L199 | Device | GH-02:GH-03 = 1:1 | GD-10 |
| Implementation | | | Comparative | | |
| Example 10 | | | Example 10 | | |
| Device | GH-02:GH-03 = 1:1 | L250 | Device | GH-02:GH-03 = 1:1 | GD-11 |
| Implementation | | | Comparative | | |
| Example 11 | | | Example 11 | | |
| Device | GH-02:GH-03 = 1:1 | L335 | Device | GH-02:GH-03 = 1:1 | GD-12 |
| Implementation | | | Comparative | | |
| Example 12 | | | Example 12 | | |
| Device | GH-02:GH-03 = 1:1 | L351 | Device | GH-02:GH-03 = 1:1 | GD-13 |
| Implementation | | | Comparative | | |
| Example 13 | | | Example 13 | | |
| Device | GH-02:GH-03 = 1:1 | L422 | Device | GH-02:GH-03 = 1:1 | GD-14 |
| Implementation | | | Comparative | | |
| Example 14 | | | Example 14 | | |
| Device | GH-02:GH-03 = 1:1 | L478 | Device | GH-02:GH-03 = 1:1 | GD-15 |
| Implementation | | | Comparative | | |
| Example 15 | | | Example 15 | | |
| Device | GH-02:GH-03 = 1:1 | L485 | Device | GH-02:GH-03 = 1:1 | GD-16 |
| Implementation | | | Comparative | | |
| Example 16 | | | Example 16 | | |
| Device | GH-02:GH-03 = 1:1 | L546 | Device | GH-02:GH-03 = 1:1 | GD-17 |
| Implementation | | | Comparative | | |
| Example 17 | | | Example 17 | | |
| Device | GH-02:GH-03 = 1:1 | L566 | Device | GH-02:GH-03 = 1:1 | GD-18 |
| Implementation | | | Comparative | | |
| Example 18 | | | Example 18 | | |
| Device | GH-02:GH-03 = 1:1 | L623 | Device | GH-02:GH-03 = 1:1 | GD-19 |
| Implementation | | | Comparative | | |
| Example 19 | | | Example 19 | | |
| Device | GH-02:GH-03 = 1:1 | L667 | Device | GH-02:GH-03 = 1:1 | GD-20 |
| Implementation | | | Comparative | | |
| Example 20 | | | Example 20 | | |
| Device | GH-02:GH-03 = 1:1 | L739 | Device | GH-02:GH-03 = 1:1 | GD-21 |
| Implementation | | | Comparative | | |
| Example 21 | | | Example 21 | | |
| Device | GH-02:GH-03 = 1:1 | L830 | Device | GH-02:GH-03 = 1:1 | GD-22 |
| Implementation | | | Comparative | | |
| Example 22 | | | Example 22 | | |

The structure of the above devices is as follows:

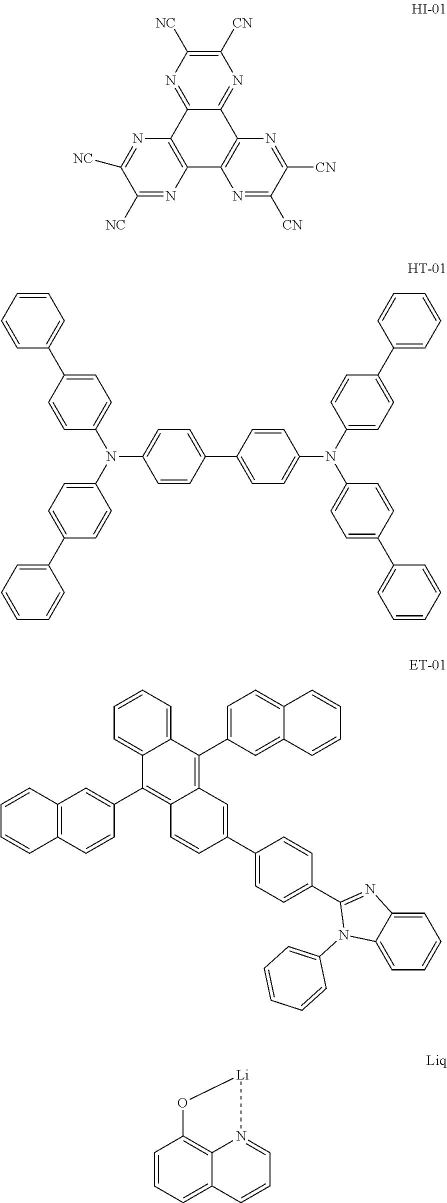

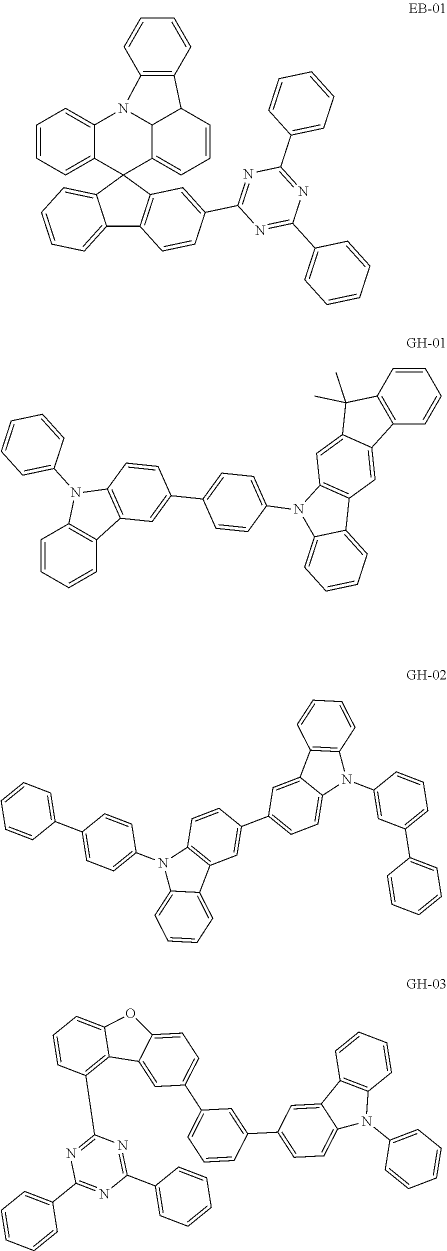 [SMILES: C1=CC2c3ccccc3N3c4ccccc4C4(C(=C1)C23)c1ccccc1-c1ccc(-c2nc(-c3ccccc3)nc(-c3ccccc3)n2)cc14 ; CC1(C)c2ccccc2-c2cc3c4ccccc4n(-c4ccc(-c5ccc6c(c5)c5ccccc5n6-c5ccccc5)cc4)c3cc21 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2nc(-c3ccccc3)nc(-c3cccc4oc5ccc(-c6cccc(-c7ccc8c(c7)c7ccccc7n8-c7ccccc7)c6)cc5c34)n2)cc1]

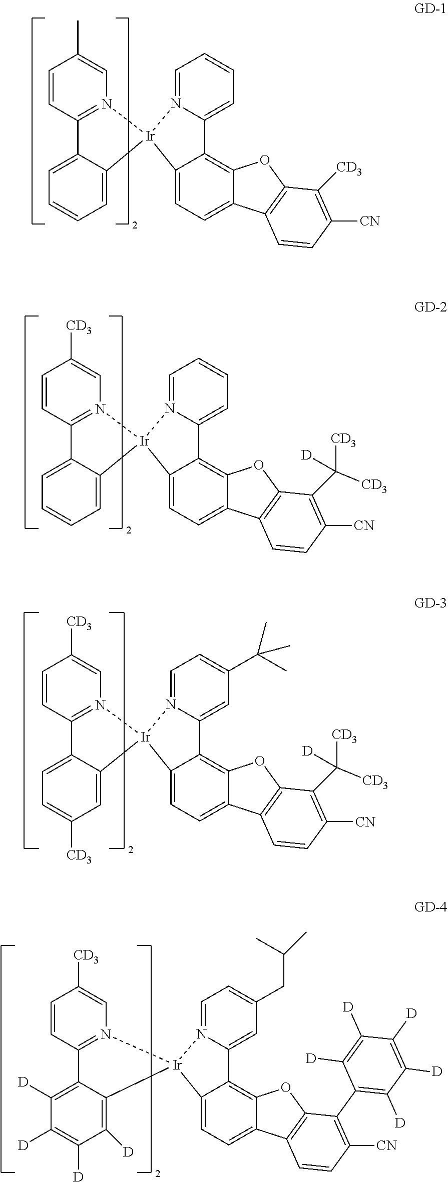

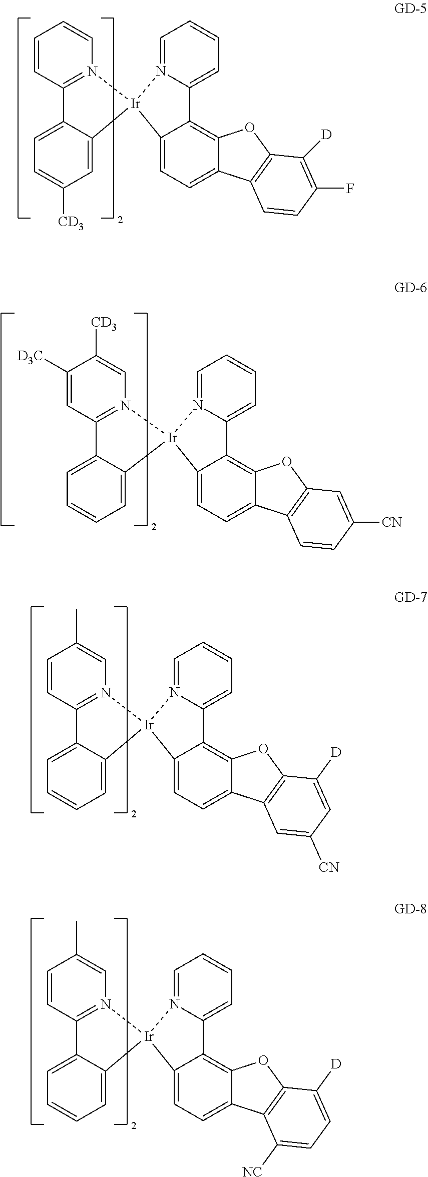

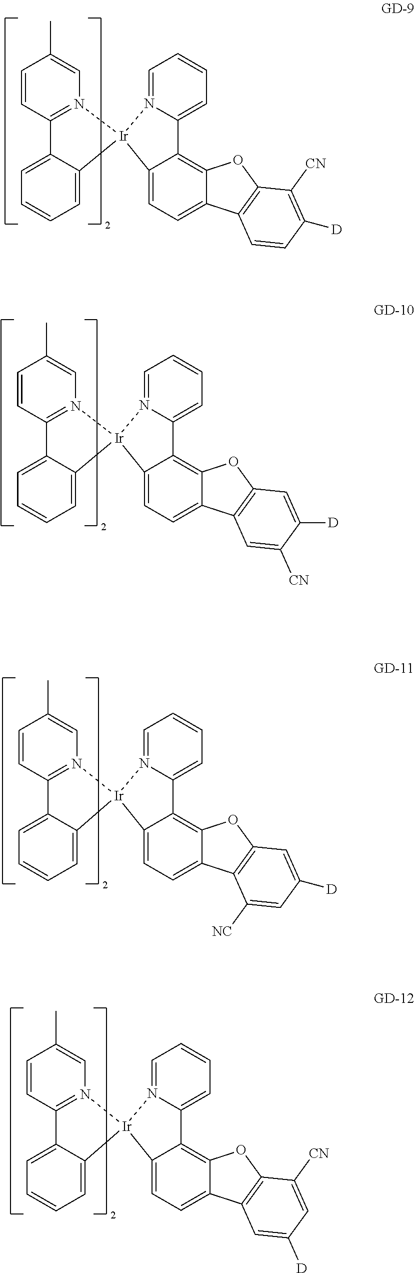

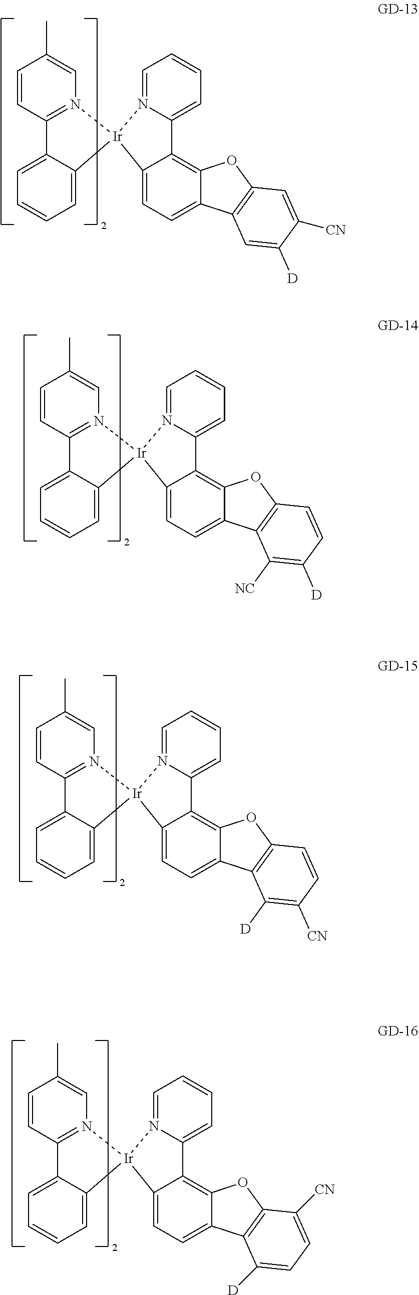

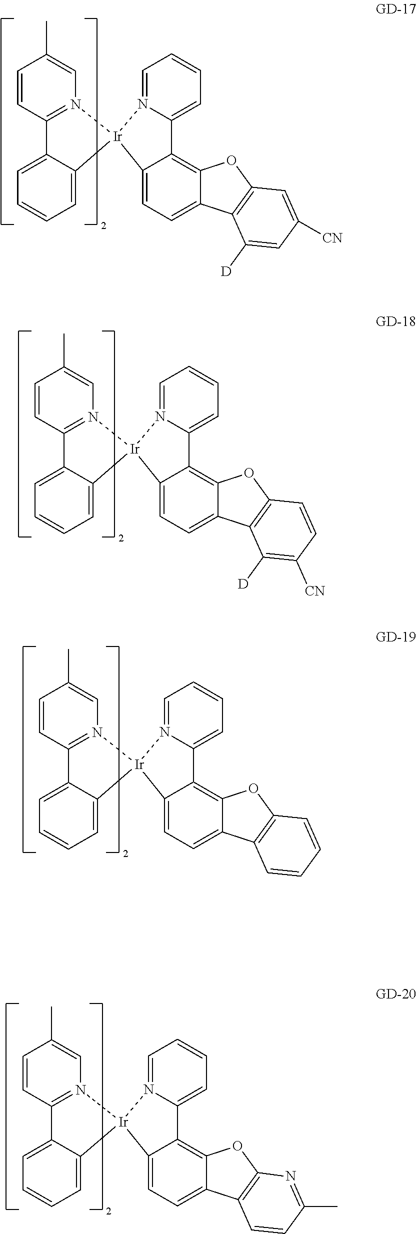

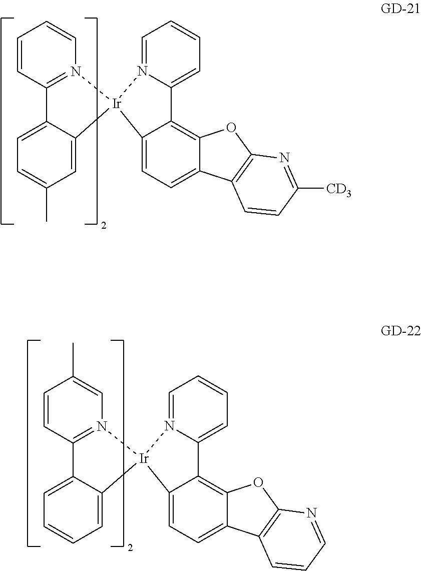

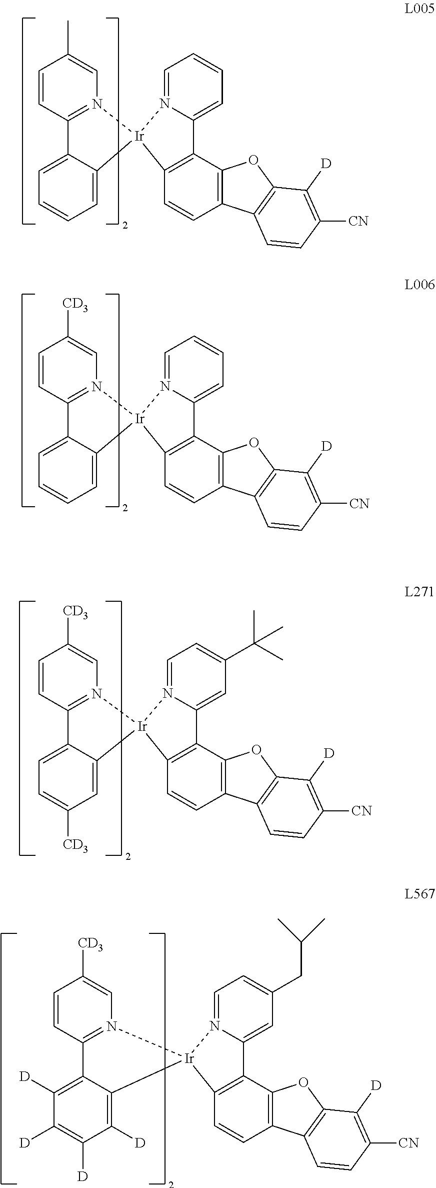

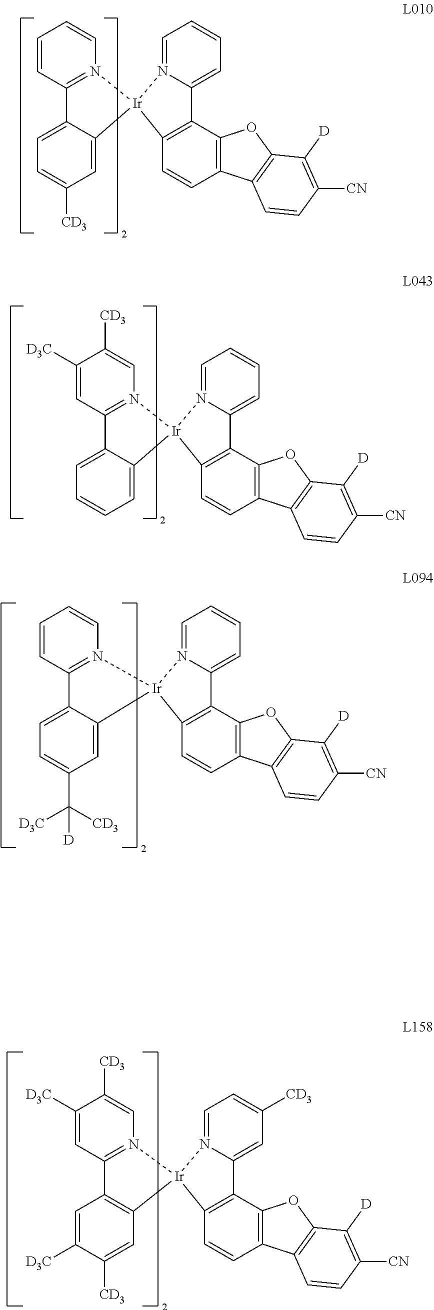

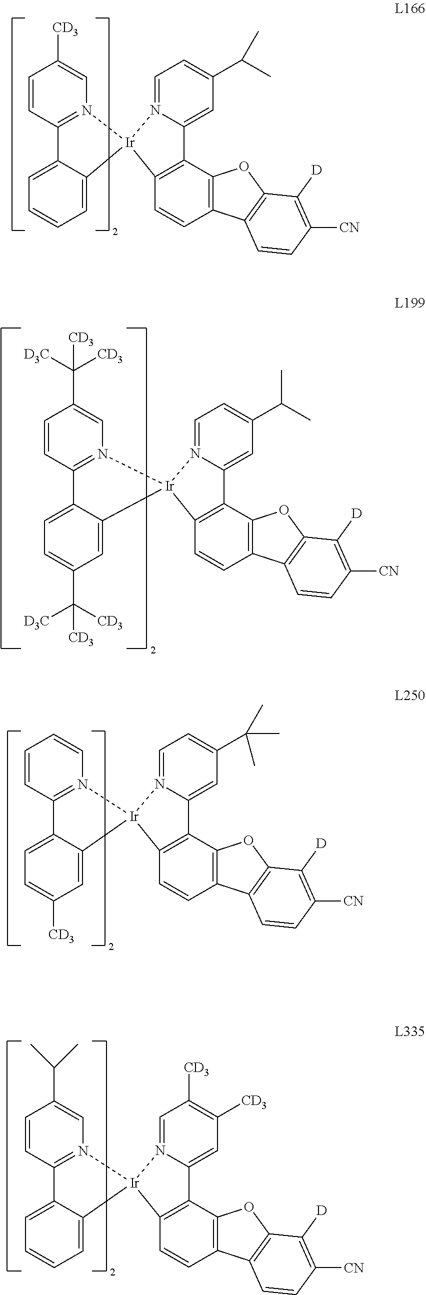

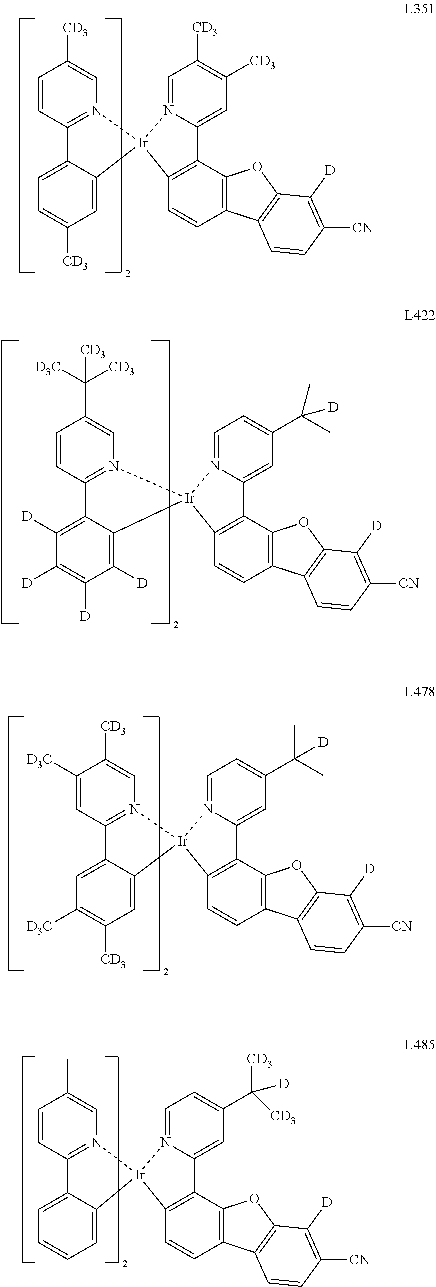

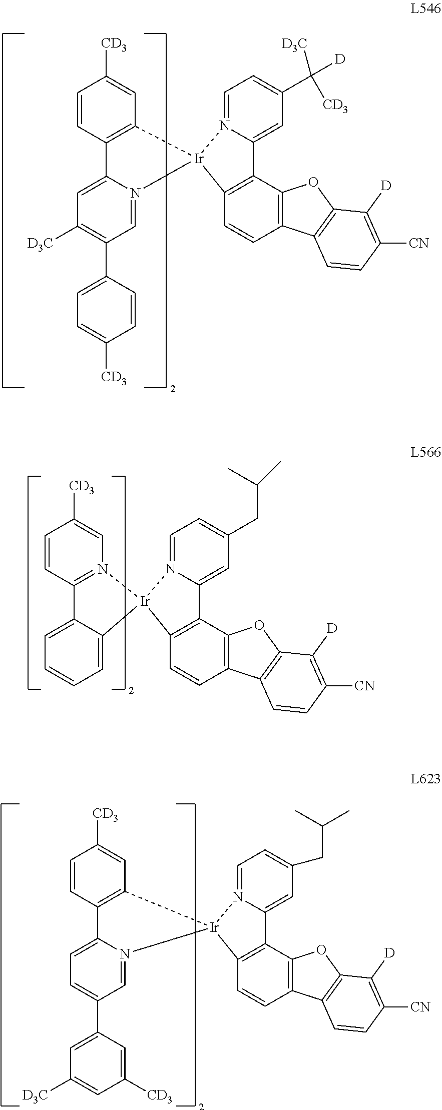

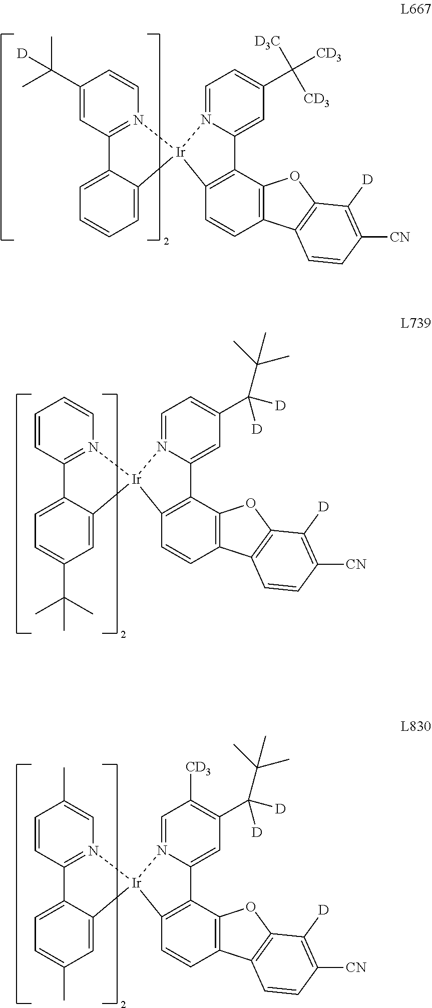

In addition, the organic electroluminescent devices obtained from the above-mentioned device Implementation Example 1 to 22 and the device Comparative Examples 1-22 are tested for various performances under the current density of 10 mA/cm², and the test results are shown in Table 3

TABLE 3
Detection results of organic electroluminescent devices in Device Implementation
Examples 1-22 and Device Comparative Examples 1-22

| Test | Device Implementation Example Data | | | | Device Comparative Examples data | | | |
|---|---|---|---|---|---|---|---|---|
| Conditions | Device | Drive | Current | Age | Device | Drive | Current | Age |
| Current Density | Implementation | Voltage | Efficiency | T₉₇ | Comparative | Voltage | Efficiency | T₉₇ |
| (mA/cm²) | Example | (V) | (cd/A) | (h) | Example | (V) | (cd/A) | (h) |
| 10.00 | Implementation | 3.21 | 177.2 | 1465 | Comparative | 3.58 | 100.2 | 960 |
| | Example 1 | | | | Example 1 | | | |
| 10.00 | Implementation | 3.19 | 174.1 | 1398 | Comparative | 3.60 | 98.7 | 930 |
| | Example 2 | | | | Example 2 | | | |
| 10.00 | Implementation | 3.23 | 175.3 | 1421 | Comparative | 3.55 | 104.5 | 879 |
| | Example 3 | | | | Example 3 | | | |
| 10.00 | Implementation | 3.23 | 172.9 | 1386 | Comparative | 3.47 | 117.5 | 667 |
| | Example 4 | | | | Example 4 | | | |
| 10.00 | Implementation | 3.18 | 169.6 | 1398 | Comparative | 3.65 | 99.8 | 798 |
| | Example 5 | | | | Example 5 | | | |
| 10.00 | Implementation | 3.20 | 175.1 | 1210 | Comparative | 3.78 | 120.4 | 902 |
| | Example 6 | | | | Example 6 | | | |
| 10.00 | Implementation | 3.21 | 174.0 | 1354 | Comparative | 3.69 | 107.7 | 869 |
| | Example 7 | | | | Example 7 | | | |
| 10.00 | Implementation | 3.19 | 169.9 | 1346 | Comparative | 3.87 | 112.4 | 704 |
| | Example 8 | | | | Example 8 | | | |
| 10.00 | Implementation | 3.25 | 170.7 | 1436 | Comparative | 3.79 | 107.9 | 698 |
| | Example 9 | | | | Example 9 | | | |
| 10.00 | Implementation | 3.26 | 173.6 | 1356 | Comparative | 3.98 | 99.5 | 905 |
| | Example 10 | | | | Example 10 | | | |
| 10.00 | Implementation | 3.25 | 171.8 | 1298 | Comparative | 3.67 | 88.8 | 606 |
| | Example 11 | | | | Example 11 | | | |
| 10.00 | Implementation | 3.20 | 172.8 | 1325 | Comparative | 3.65 | 99.4 | 905 |
| | Example 12 | | | | Example 12 | | | |
| 10.00 | Implementation | 3.19 | 175.1 | 1387 | Comparative | 3.56 | 98.5 | 887 |
| | Example 13 | | | | Example 13 | | | |
| 10.00 | Implementation | 3.23 | 168.9 | 1367 | Comparative | 3.78 | 113.4 | 934 |
| | Example 14 | | | | Example 14 | | | |
| 10.00 | Implementation | 3.26 | 174.6 | 1288 | Comparative | 3.75 | 120.5 | 946 |
| | Example 15 | | | | Example 15 | | | |
| 10.00 | Implementation | 3.18 | 173.5 | 1304 | Comparative | 3.60 | 115.8 | 939 |
| | Example 16 | | | | Example 16 | | | |
| 10.00 | Implementation | 3.22 | 172.9 | 1316 | Comparative | 3.59 | 109.5 | 970 |
| | Example 17 | | | | Example 17 | | | |
| 10.00 | Implementation | 3.22 | 168.5 | 1299 | Comparative | 3.98 | 112.7 | 876 |
| | Example 18 | | | | Example 18 | | | |
| 10.00 | Implementation | 3.19 | 172.6 | 1356 | Comparative | 3.79 | 106.5 | 898 |
| | Example 19 | | | | Example 19 | | | |
| 10.00 | Implementation | 3.21 | 174.5 | 1405 | Comparative | 4.05 | 120.6 | 906 |
| | Example 20 | | | | Example 20 | | | |
| 10.00 | Implementation | 3.21 | 176.0 | 1410 | Comparative | 3.79 | 104.5 | 994 |
| | Example 21 | | | | Example 21 | | | |
| 10.00 | Implementation | 3.20 | 175.3 | 1289 | Comparative | 4.05 | 97.4 | 809 |
| | Example 22 | | | | Example 22 | | | |

As can be seen from Table 3:

1. By comparing the comparative example compounds GD-1, GD-2, GD-3, GD-4, GD-5, GD-6, GD-19 with the organic metal compounds L005, L006, L271, L567, L010, L043 of the present disclosure, it can be seen that by changing the combination of substituents on dibenzofuran, the compounds of the present disclosure after changing the composition of substituents on dibenzofuran, and the compounds after changing F to —CN are replaced as doping materials for the luminescent layer. Compared with the organic electroluminescent devices using comparative example compounds, the driving voltage of the prepared organic electroluminescent devices has a significantly reduced, and the current efficiency and lifetime are significantly improved.

2. By comparing the comparative example compounds GD-7, GD-8, GD-9, GD-10, GD-b11, GD-12, GD-13, GD-14, GD-15, GD-16, GD-17, GD-18 with the organic metal compound L005 of the present disclosure, it is shown that the positions of D and cyano groups of the compounds of the present disclosure are doped materials as the luminescent layer. Compared with the organic electroluminescent devices using the comparative example compounds, the driving voltage is significantly reduced, and the current efficiency and lifetime are significantly improved.

3. Compared with the organic electroluminescent device prepared using the organic metal compound as luminescent layer dopant material and the organic electroluminescent device prepared using the Comparative Compound Examples 1-22 as light-emitting layer dopant material, the driving voltage is significantly reduced, and the current efficiency and the lifespan are significantly improved.

The foregoing description of the disclosed embodiments enables those skilled in the art to realize or use the present disclosure. Various modifications to these embodiments will be apparent to those skilled in the art, and the general principles defined herein may be realized in other embodiments without departing from the spirit or scope of the present disclosure. Accordingly, the present disclosure will not be limited to these embodiments shown herein, but will be subject to the broadest scope consistent with the principles and novel features disclosed herein.

1. An organic metal compound, wherein the structural formula of the organic metal compound is Ir (L₁)ₘ(L₂)ₙ; and both L₁ and L₂ are ligands, which are respectively: 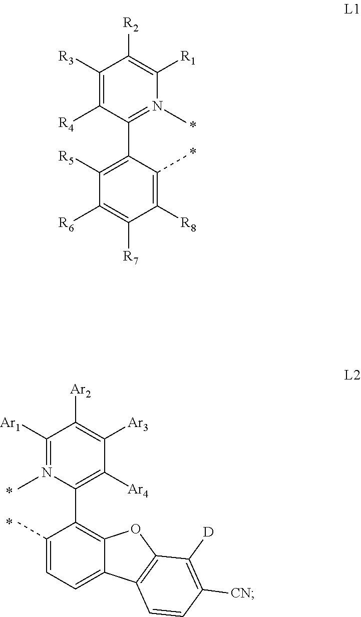
wherein, the * is the linking key;
R₁-R₈ are each independently selected from —H, -D, -T, —F, —CN, —CH₃, —CD₃, —CT₃, —CF₃, —CH₂F, —CHF₂, substituted or unsubstituted C₂-C₆ alkyl, substituted or unsubstituted C₆-C₁₀ aryl,
Ar₁-Ar₄ are each independently selected from —H, -D, -T, —F, —CN, —CH₃, —CD₃, —CT₃, —CF₃, —CH₂F, —CHF₂, substituted or unsubstituted C₂-C₆ alkyl.

2. The organic metal compound according to claim 1, wherein the alkyl groups in R₁-R₈ and Ar₁-Ar₄ are each independently selected from one of substituted or unsubstituted straight-chain alkyl, substituted or unsubstituted branched-chain alkyl, and substituted or unsubstituted cycloalkyl.

3. The organic metal compound according to claim 1, wherein the organic metal compound Ir (L₁)ₘ(L₂)ₙ is represented by any one of the following formulae L001-L880:

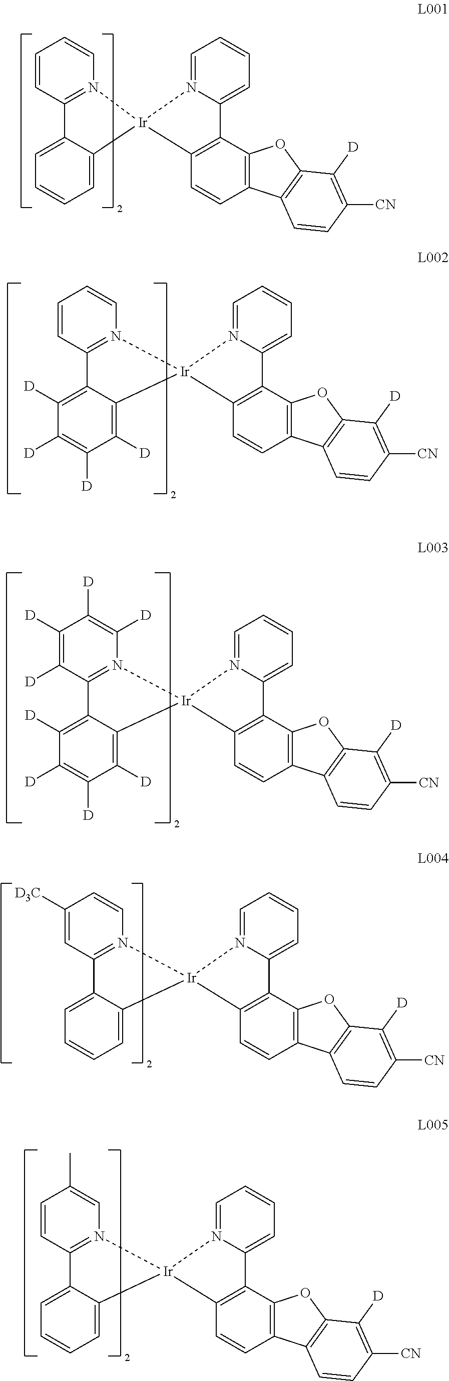

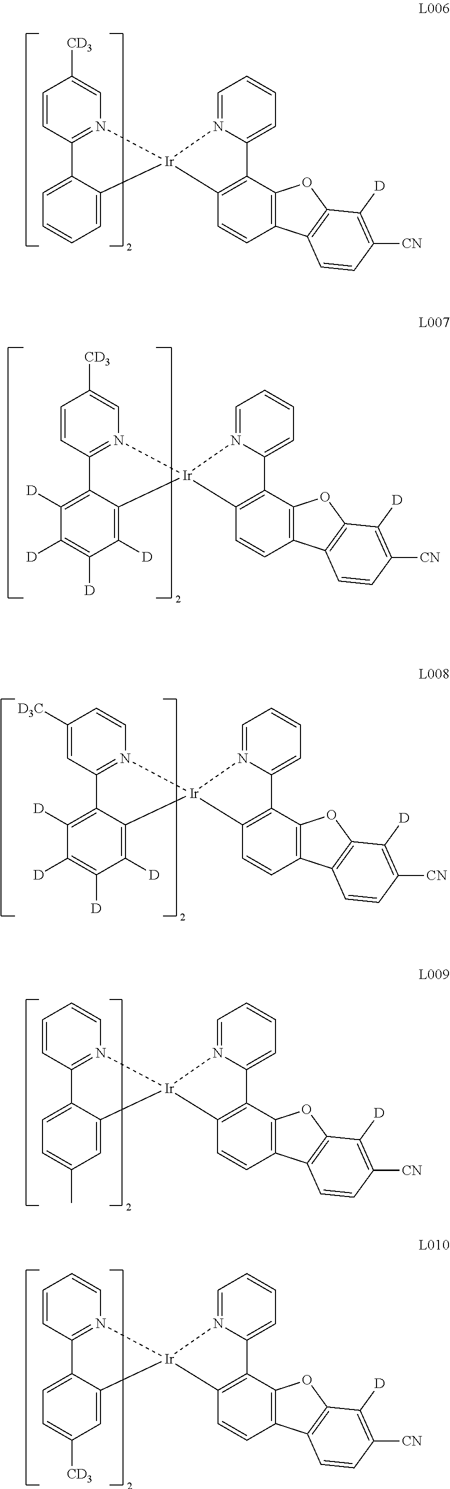

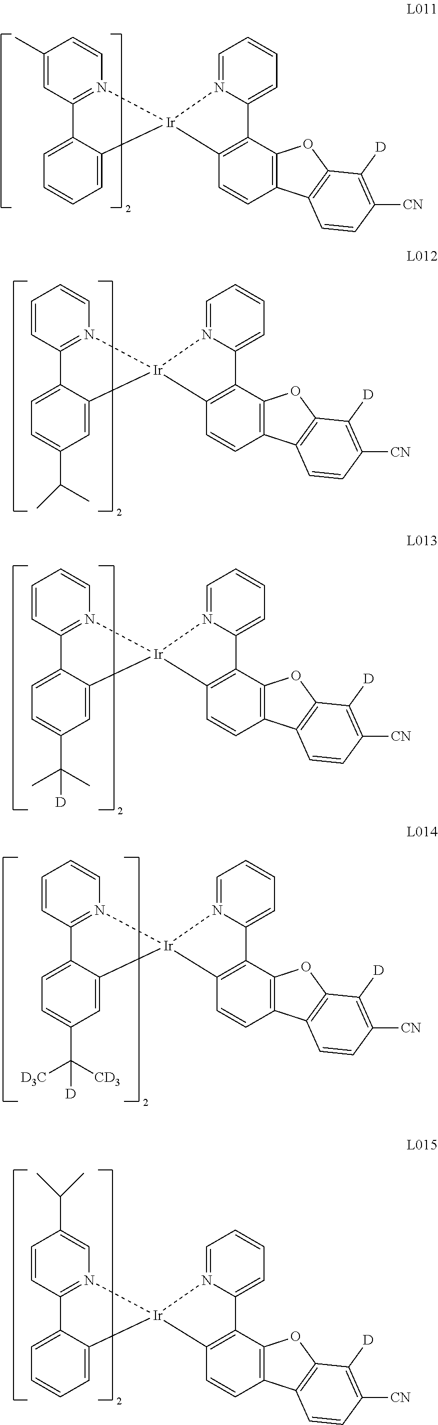

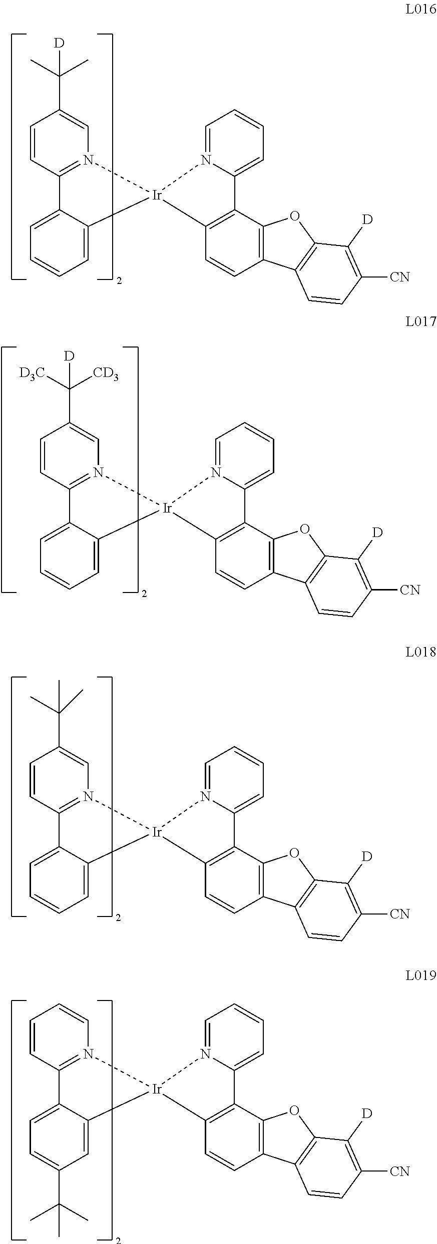

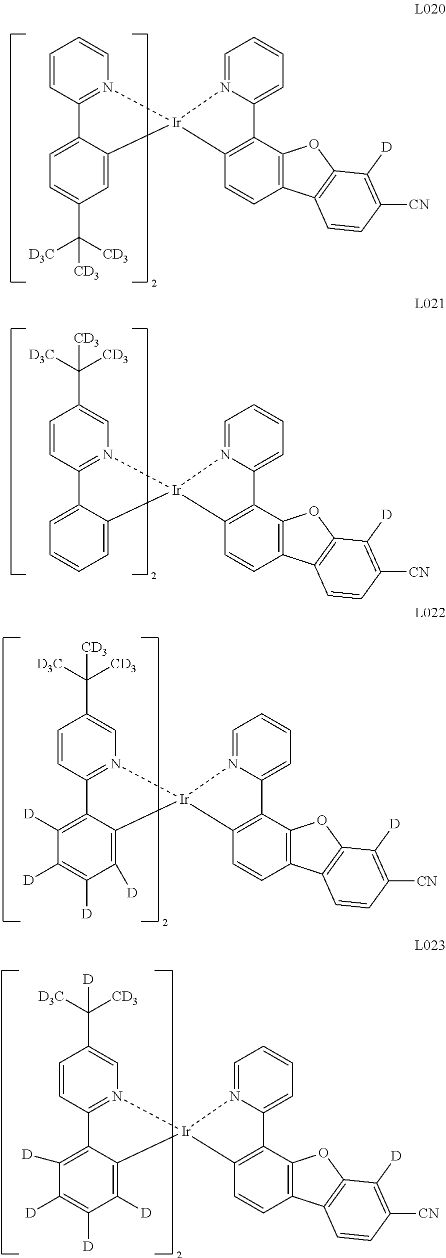

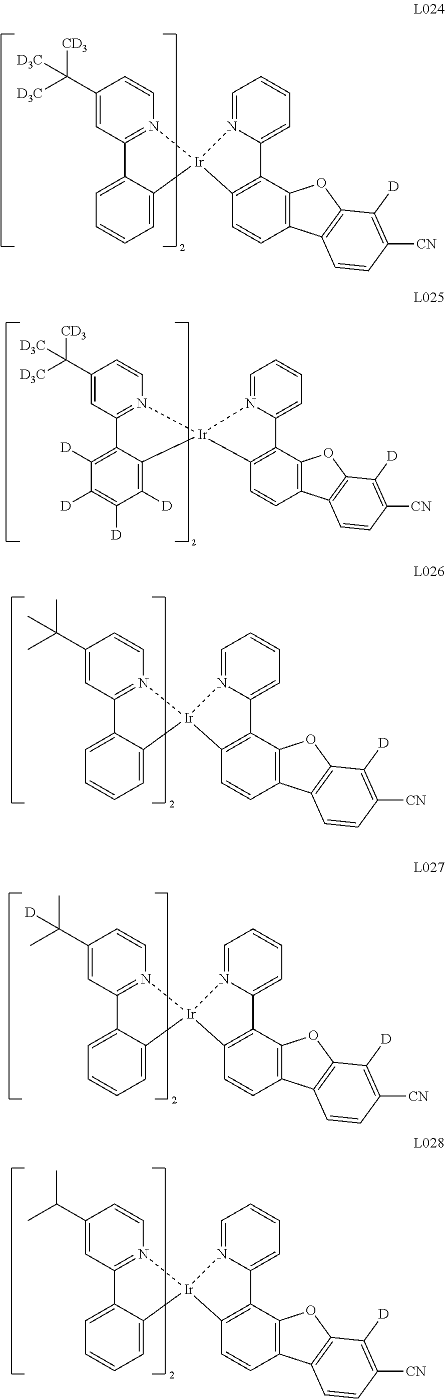

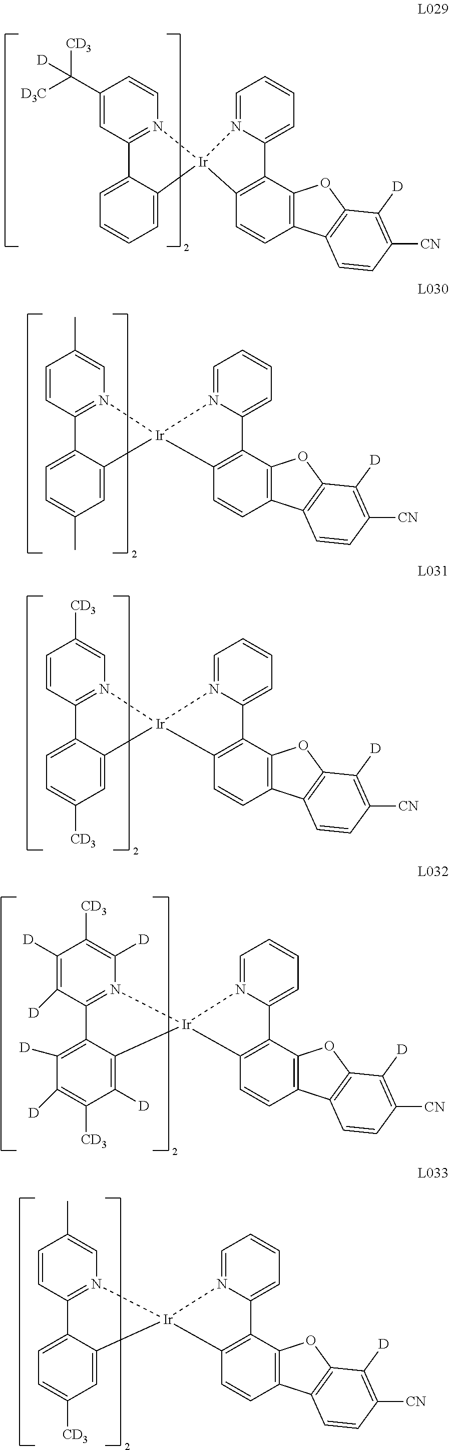

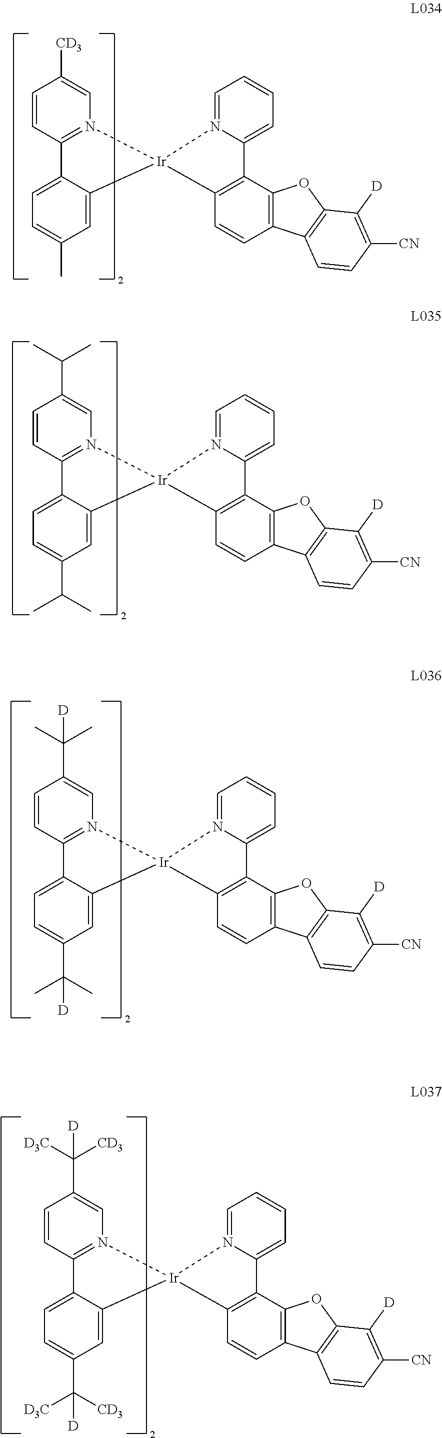

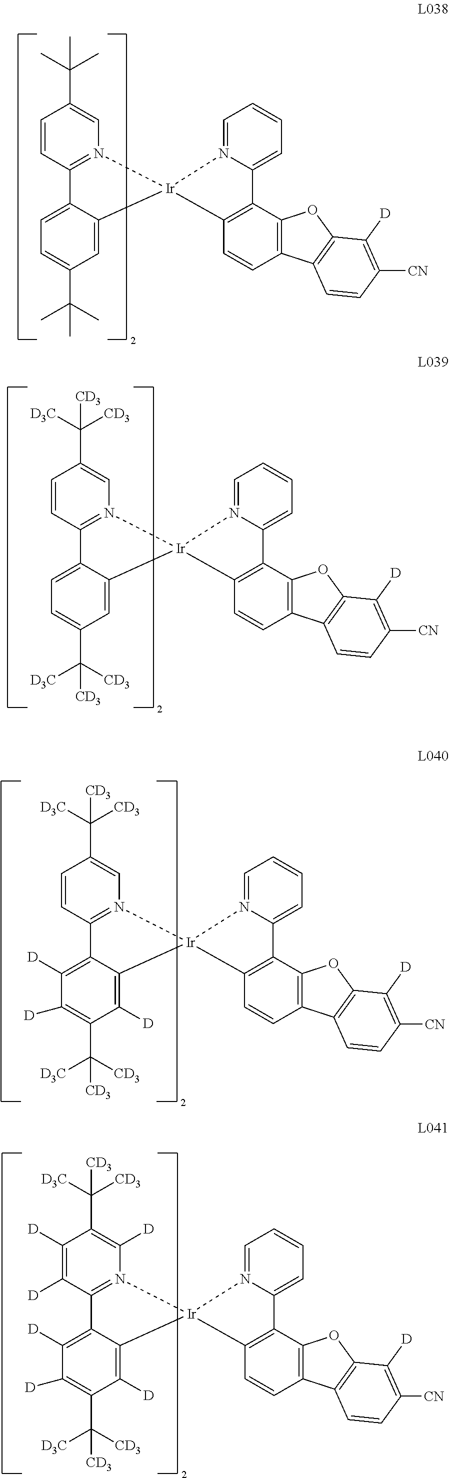

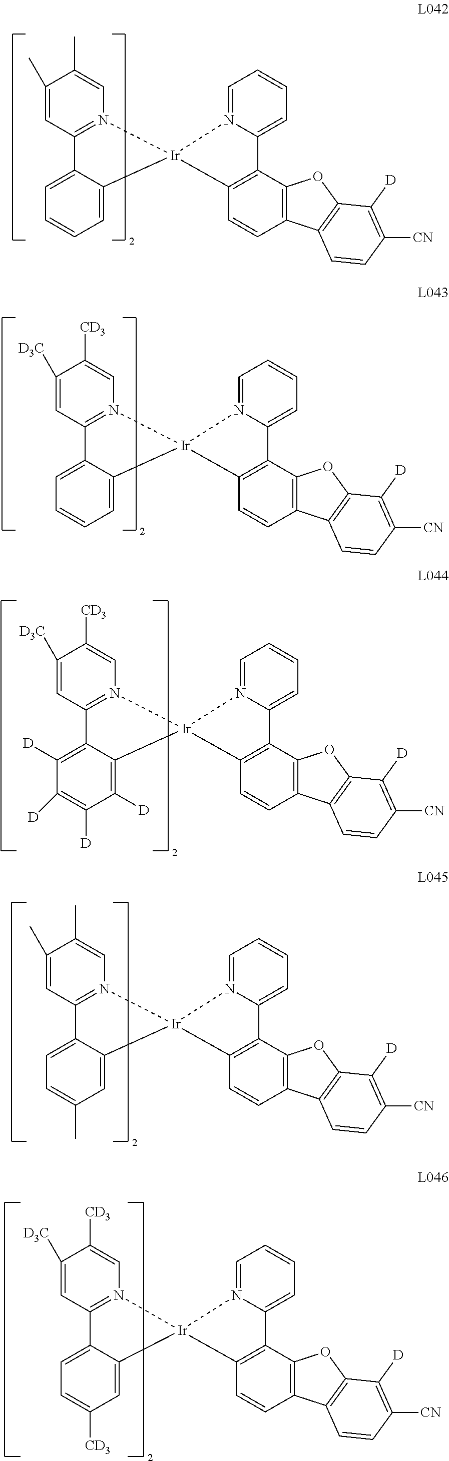

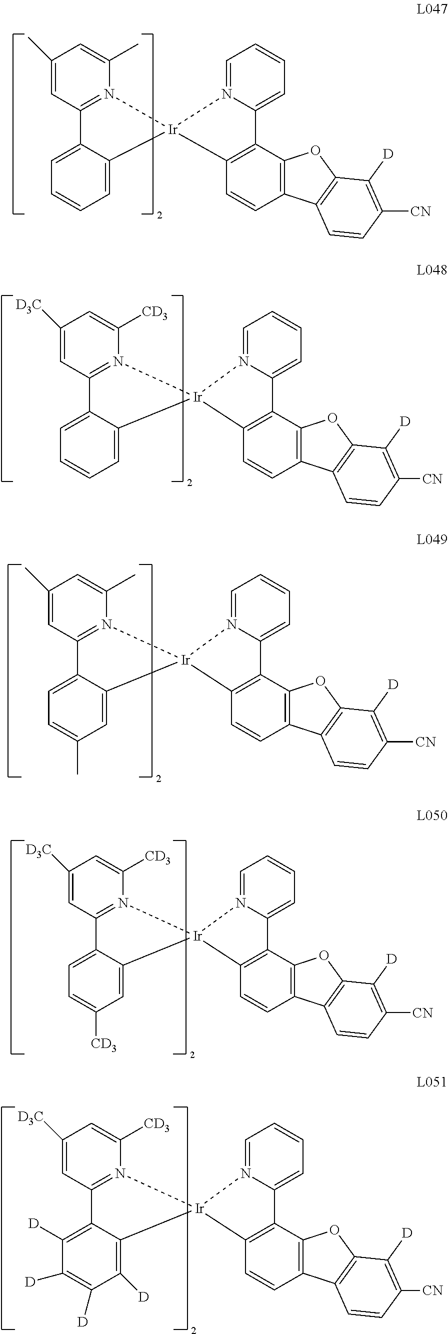

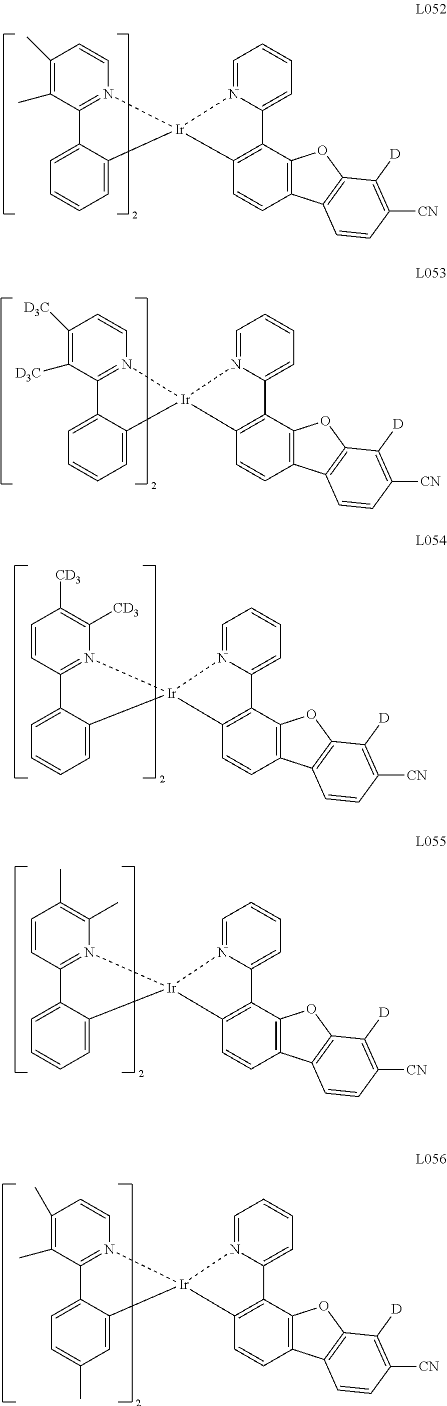

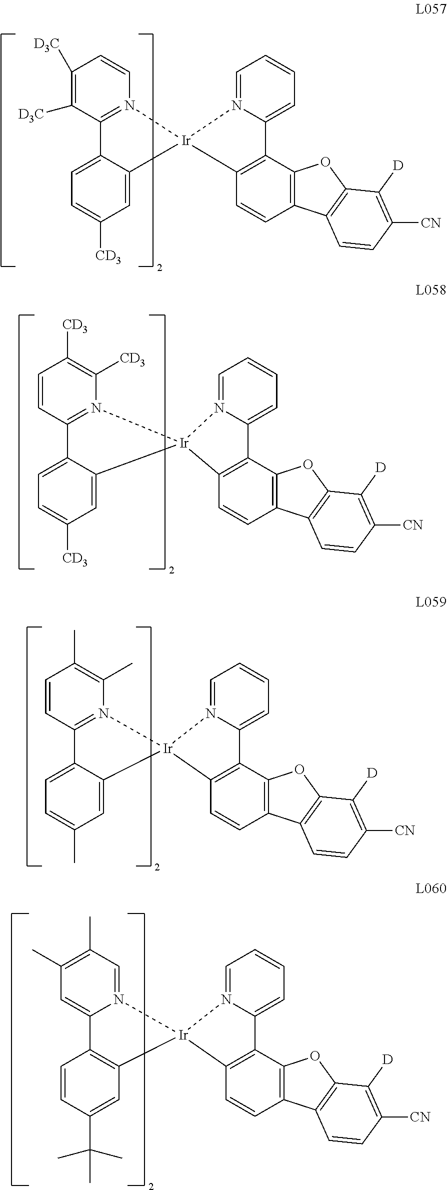

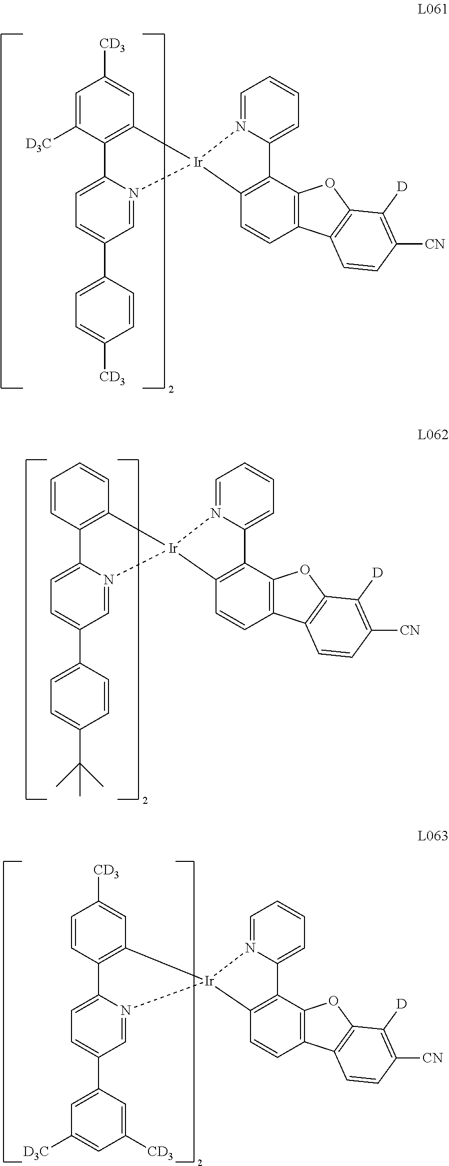

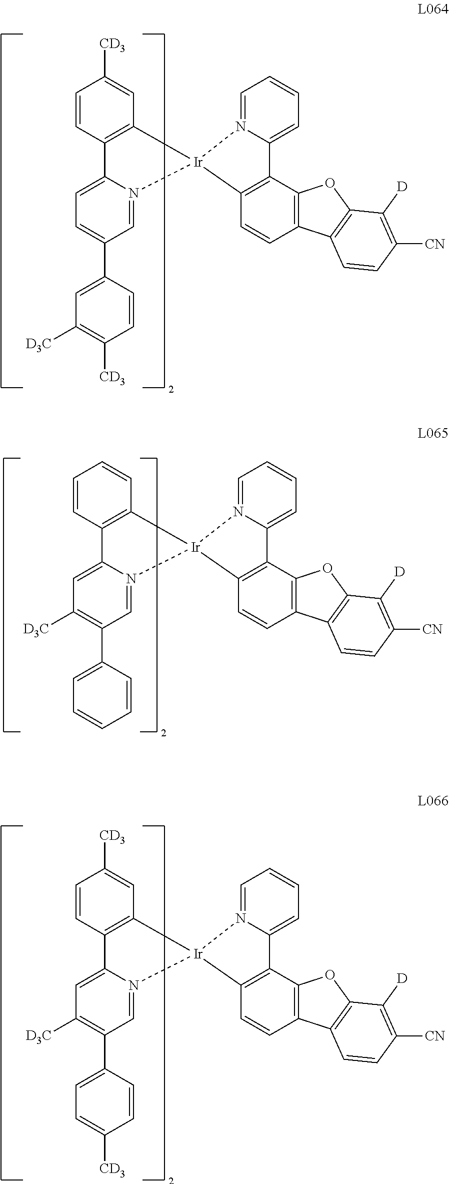

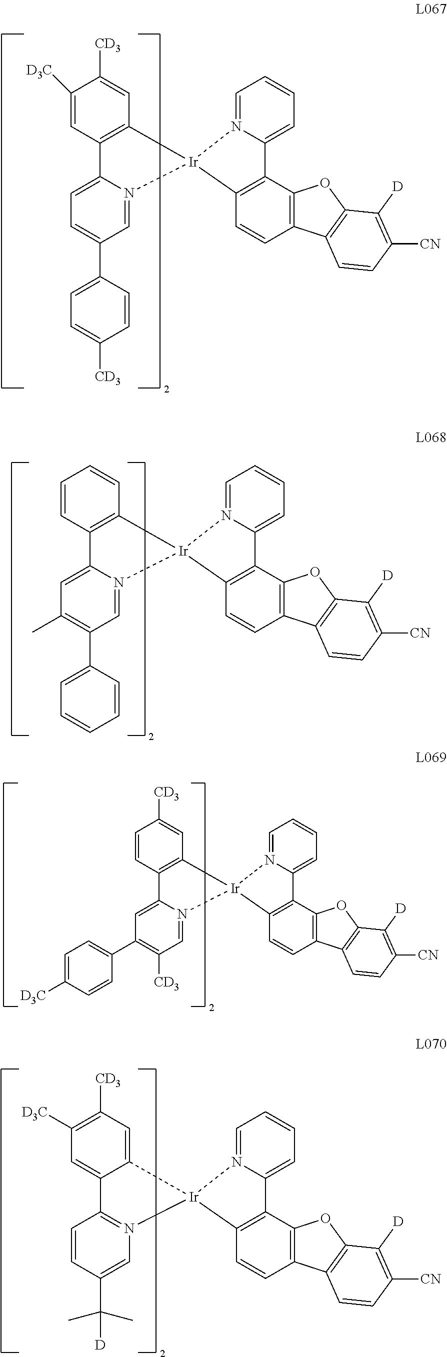

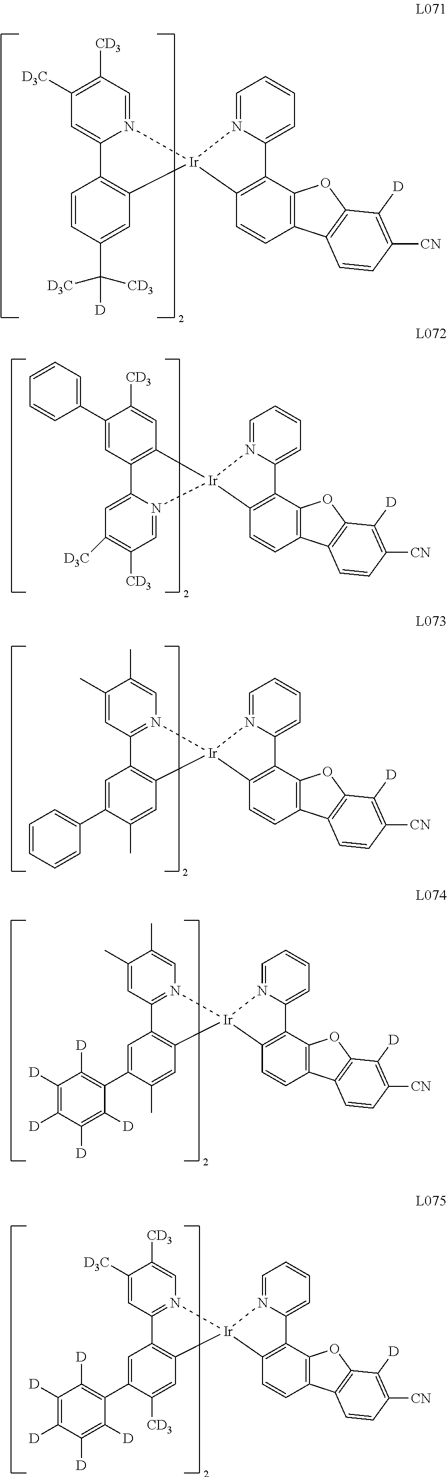

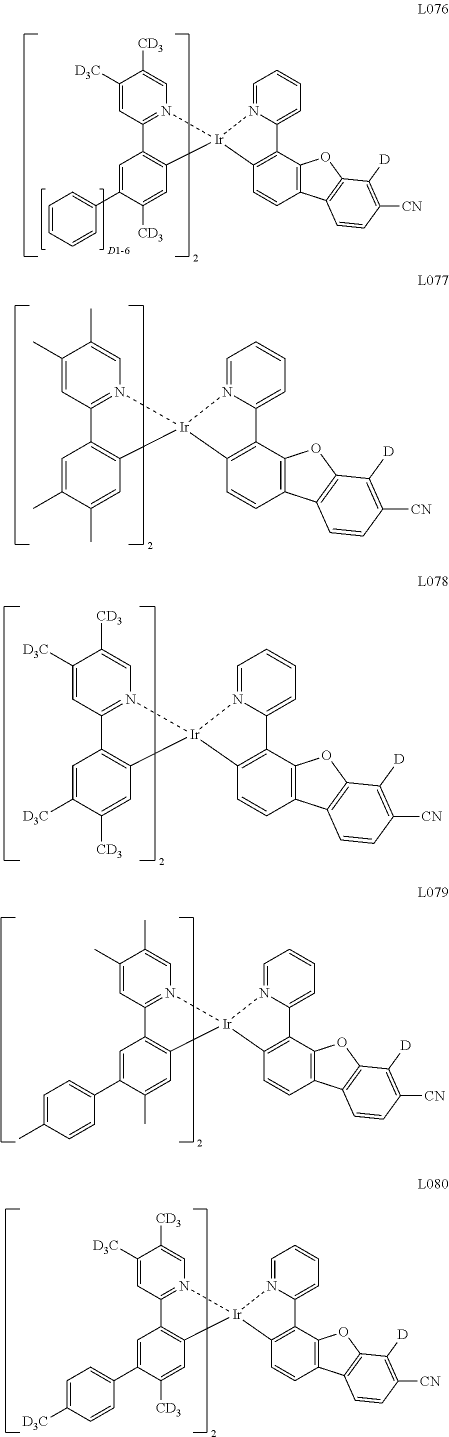

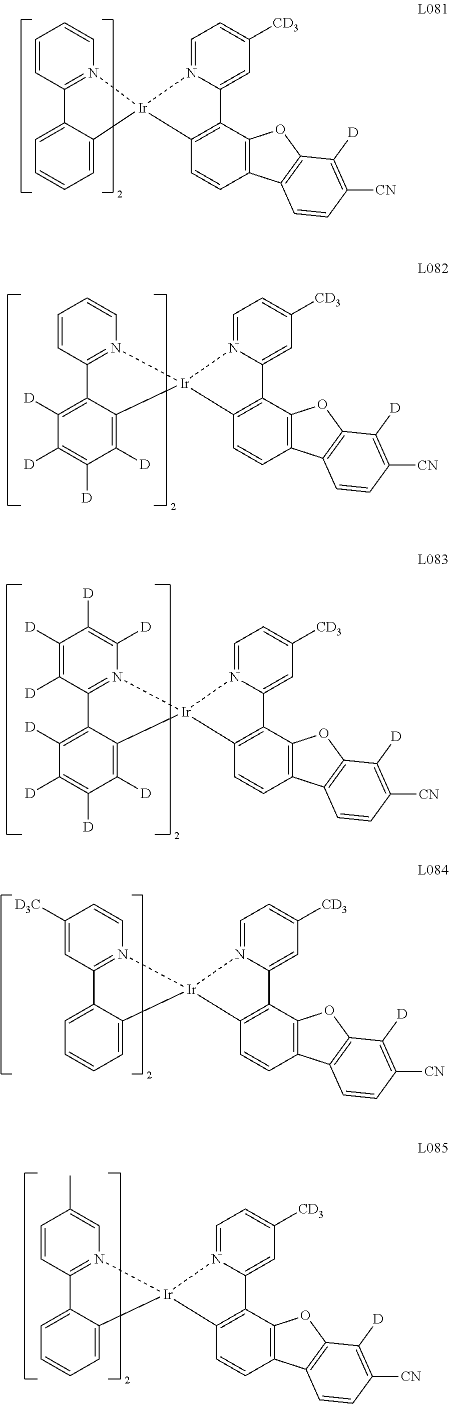

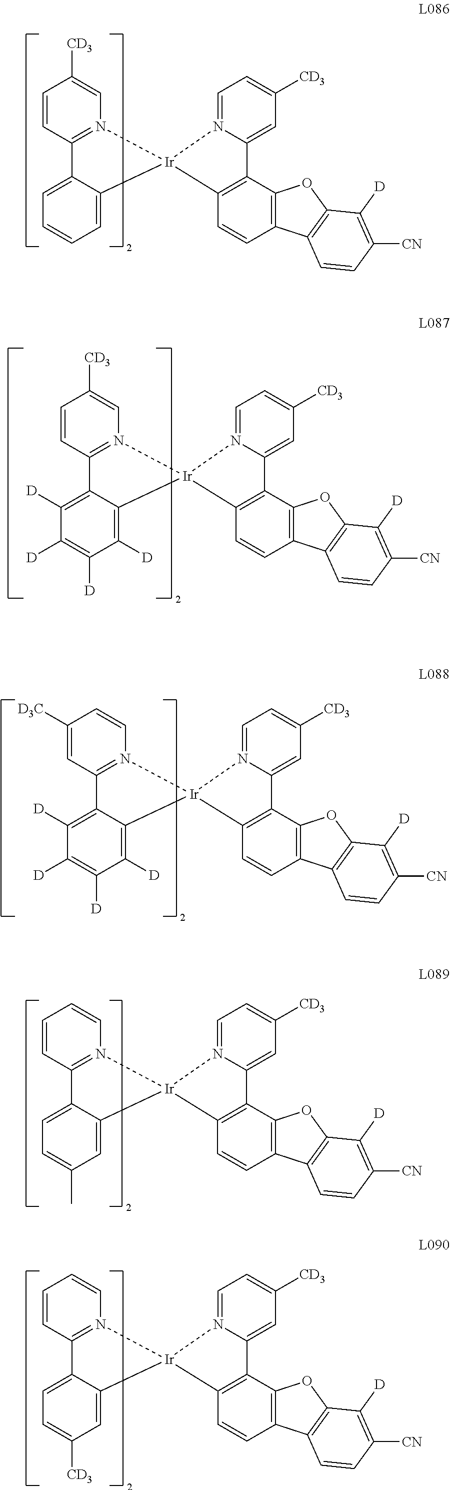

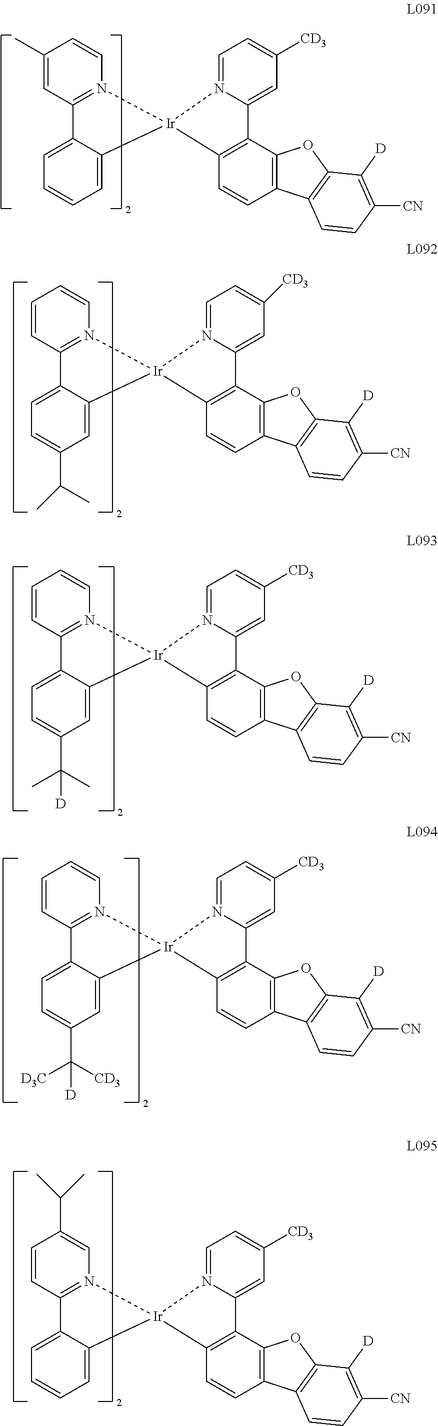

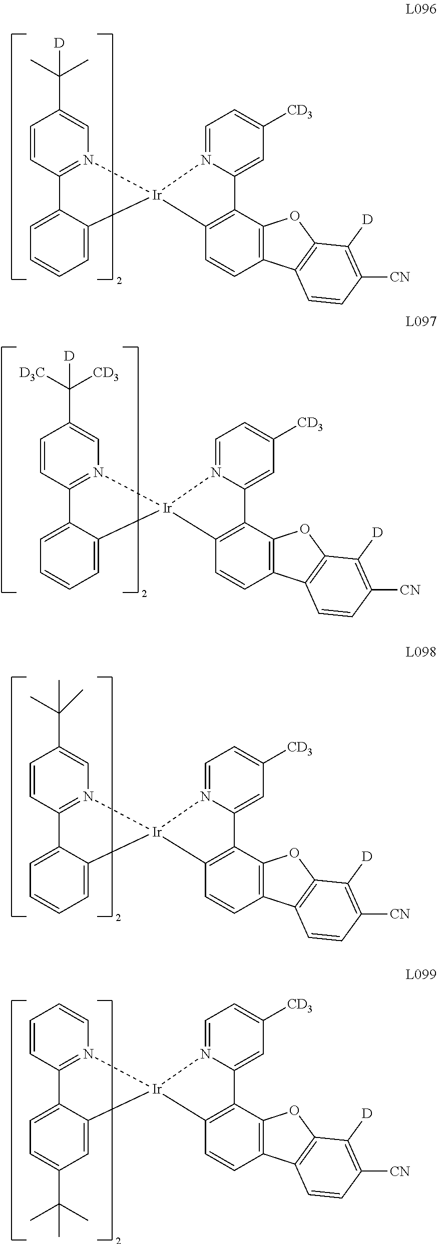

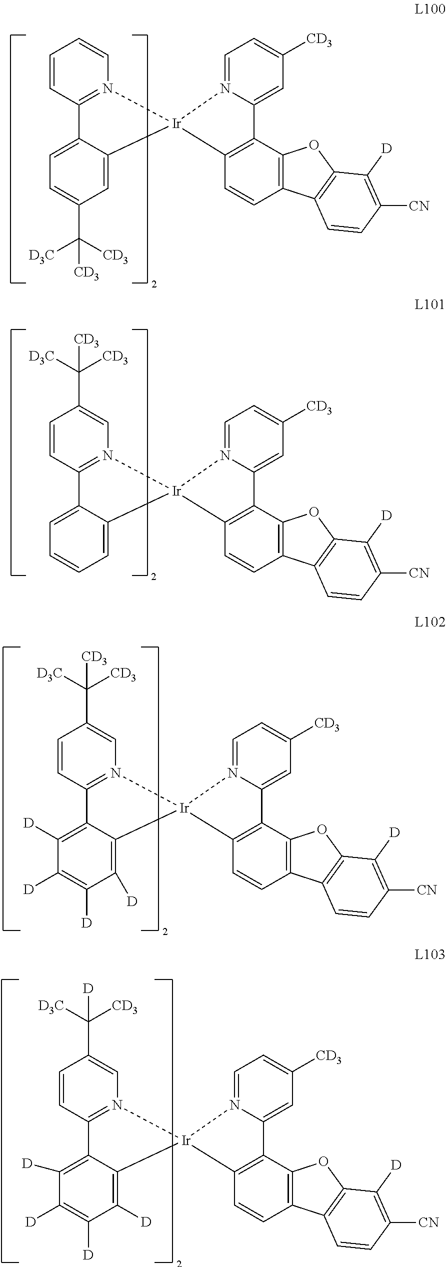

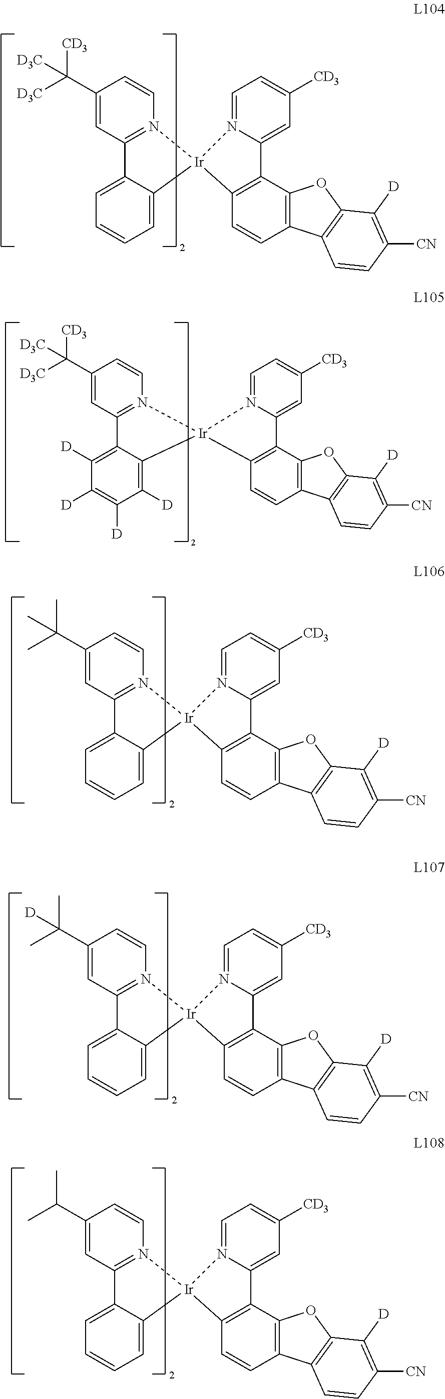

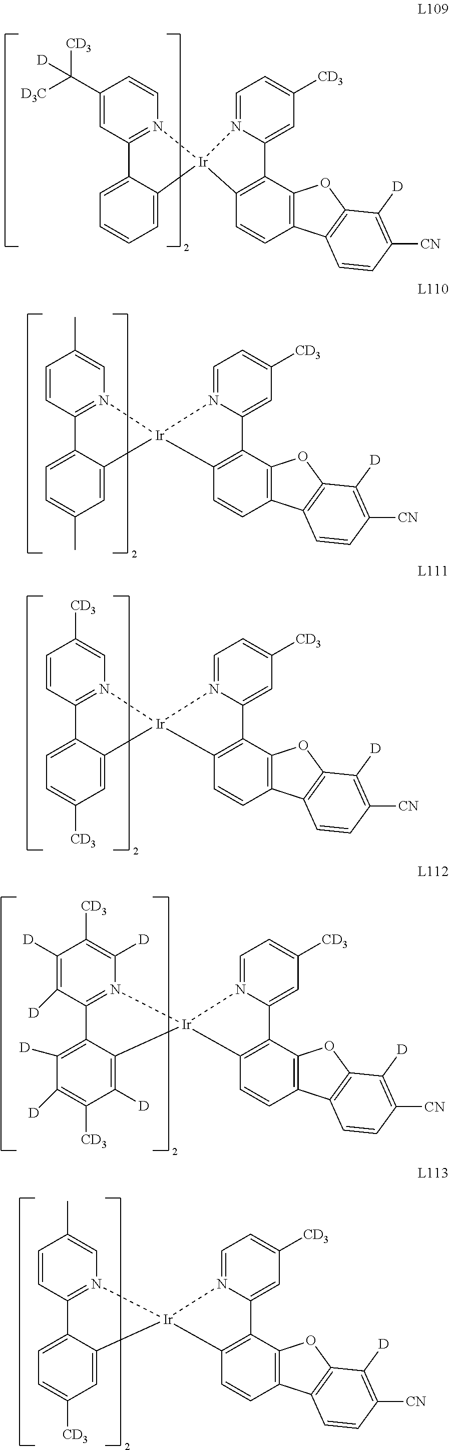

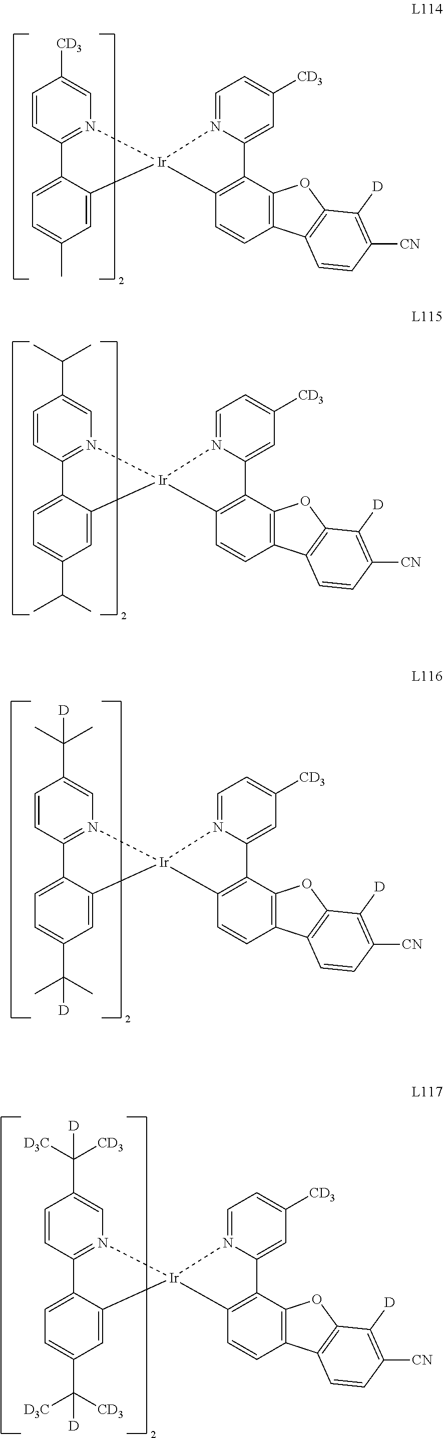

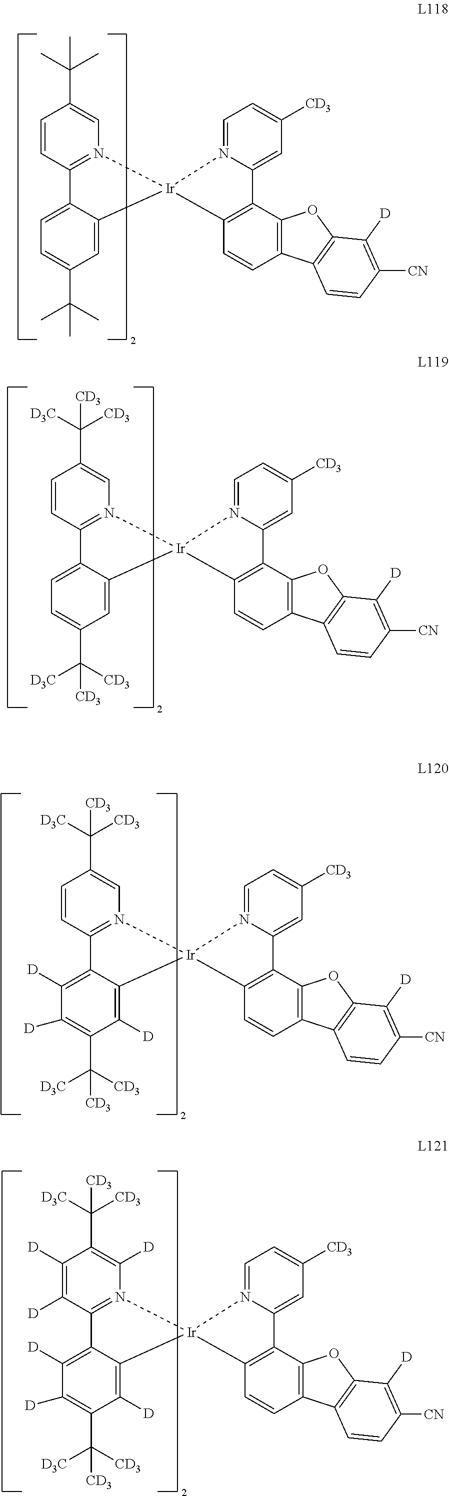

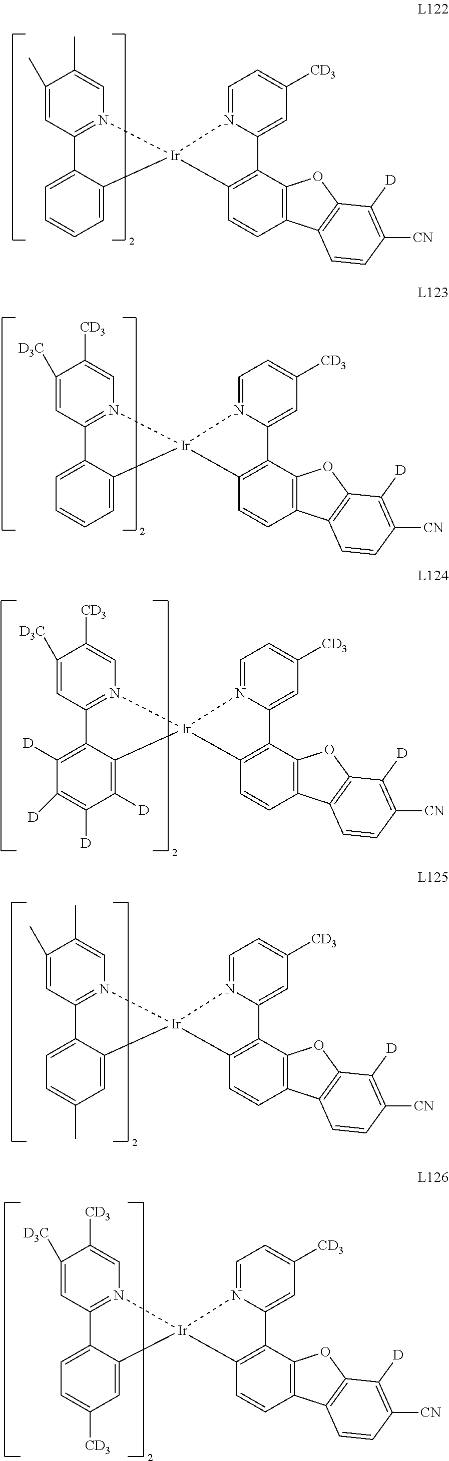

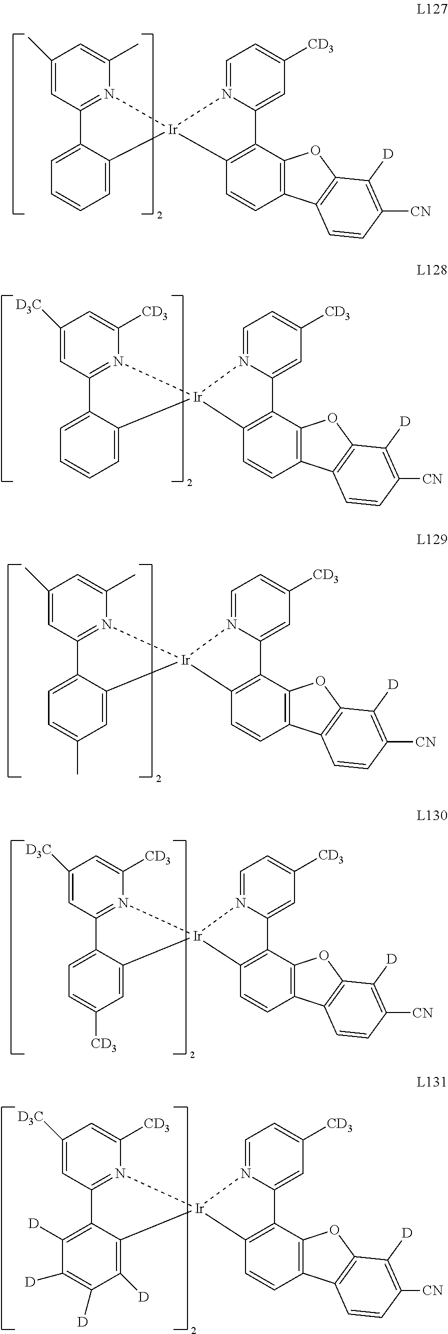

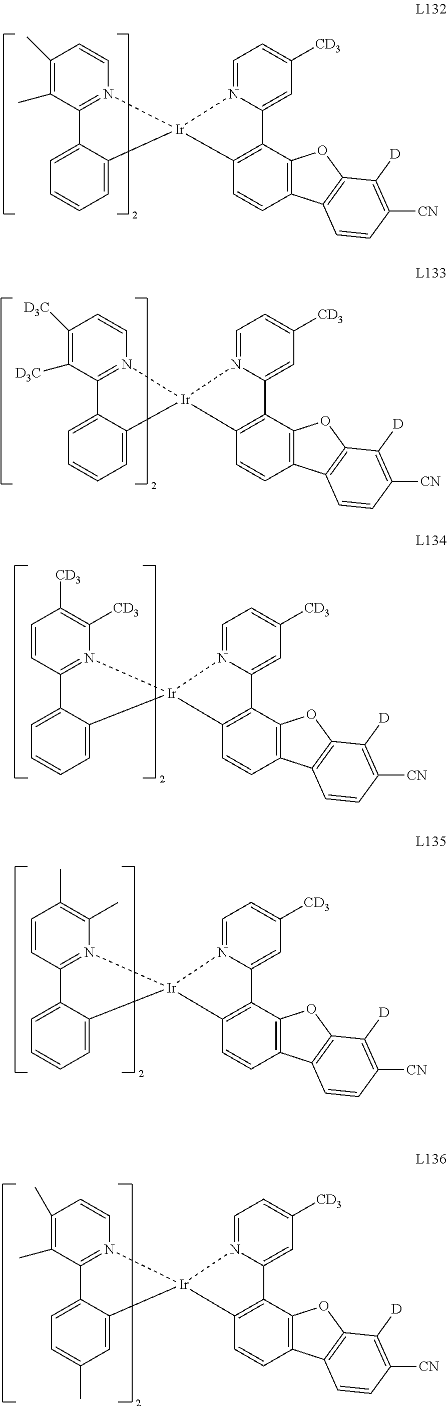

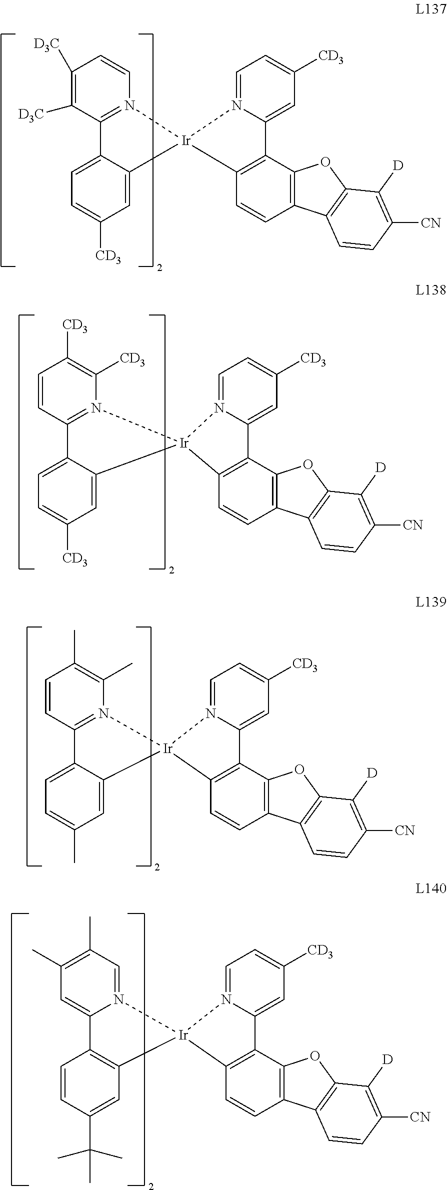

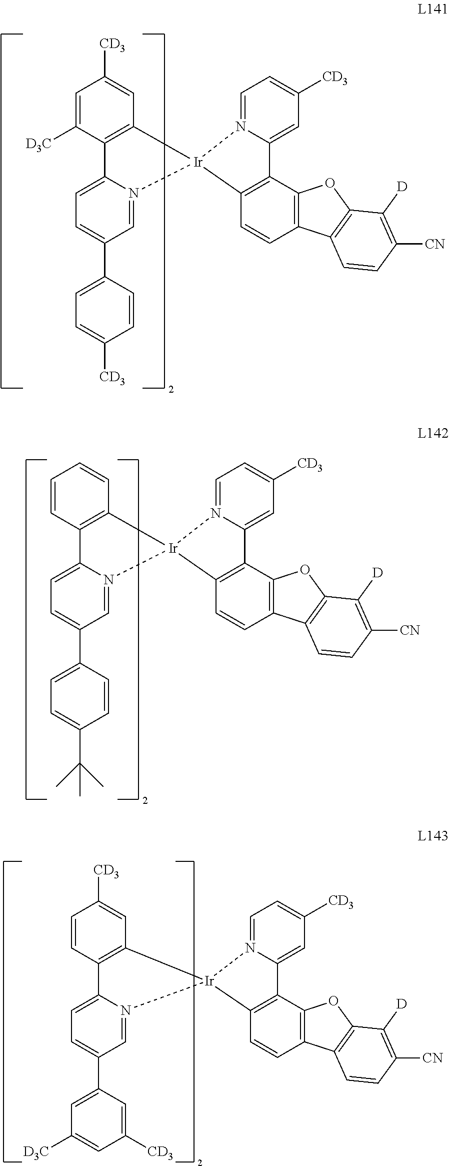

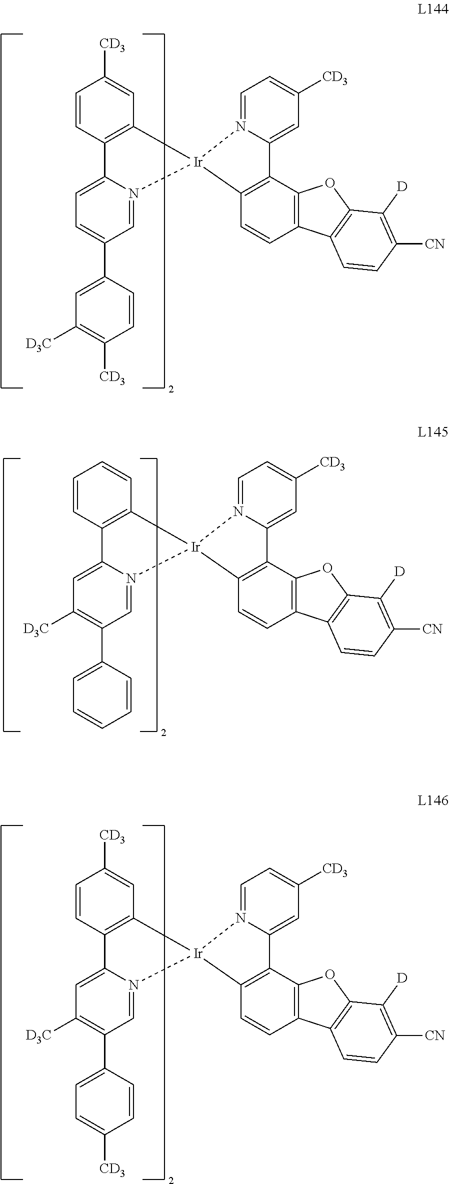

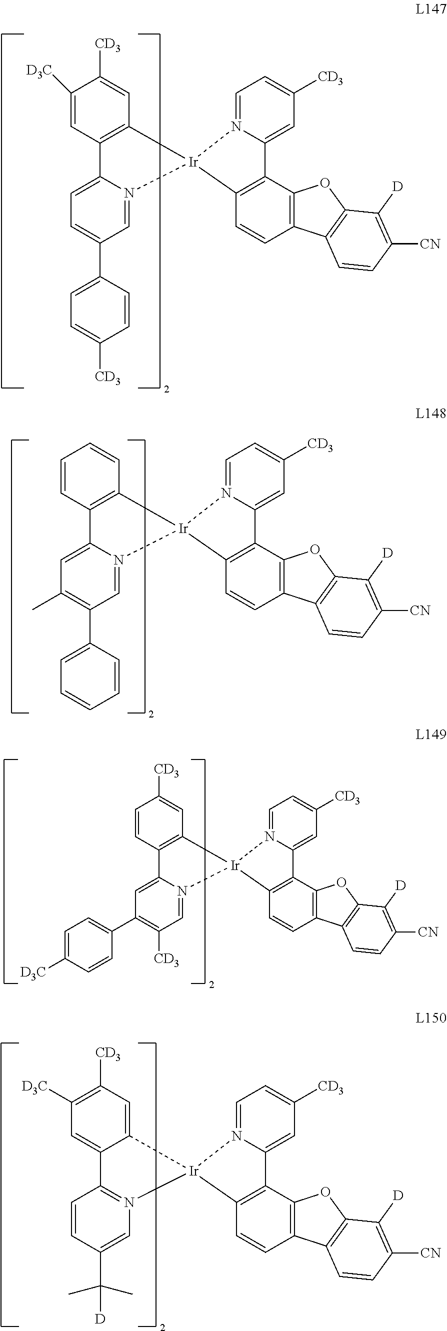

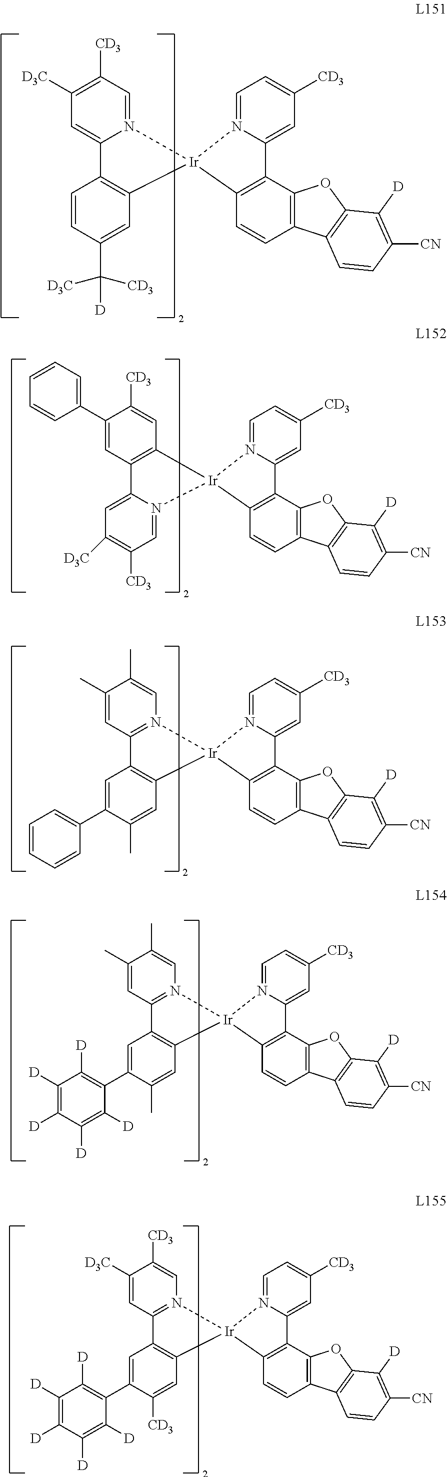

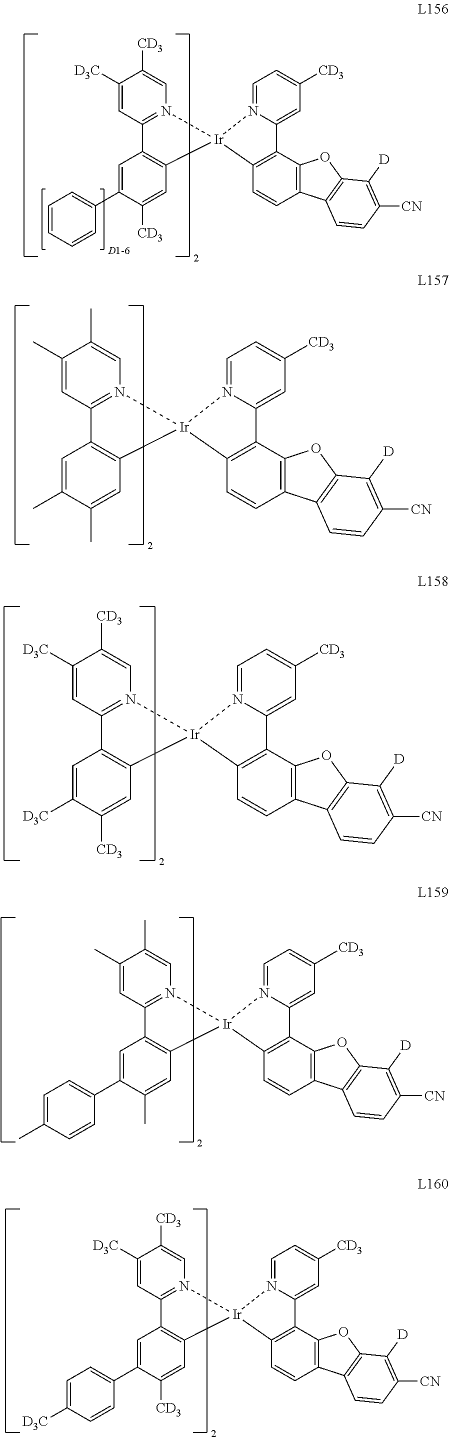

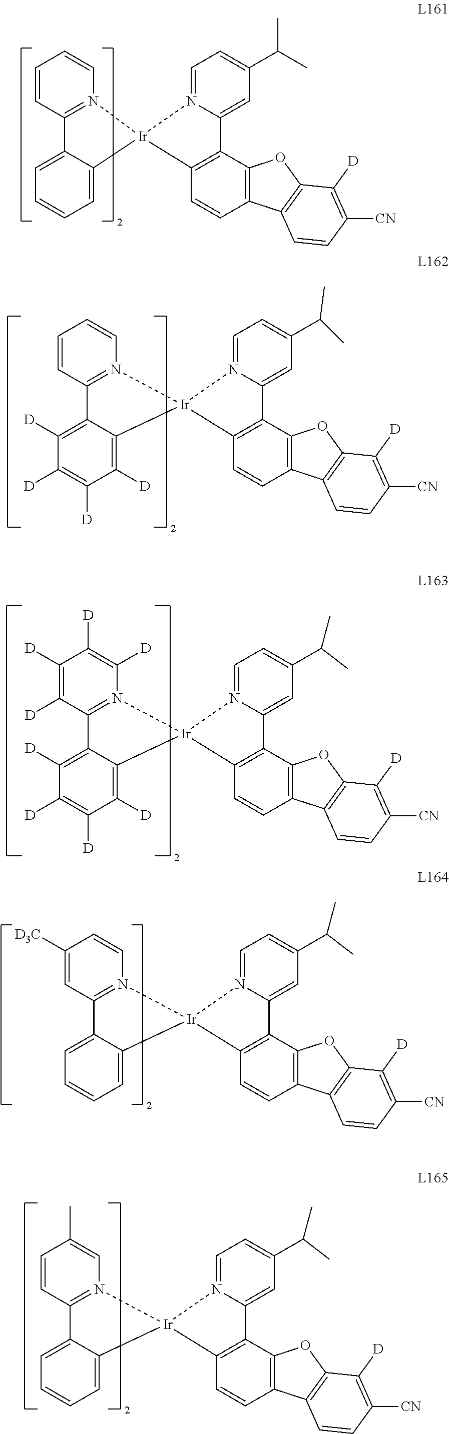

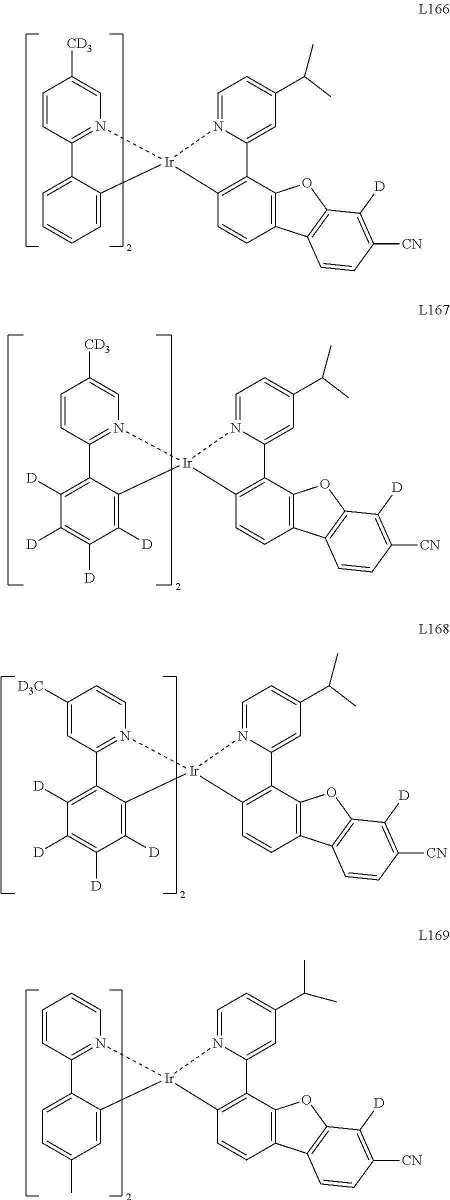

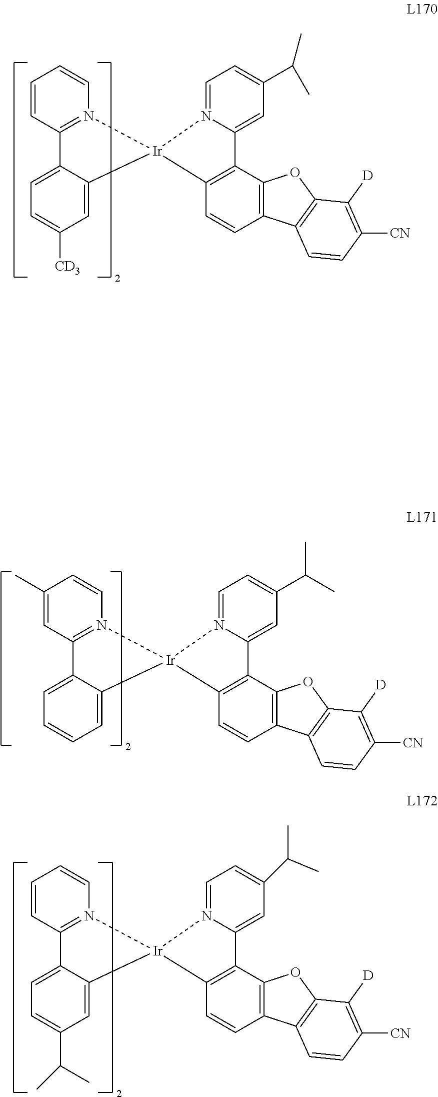

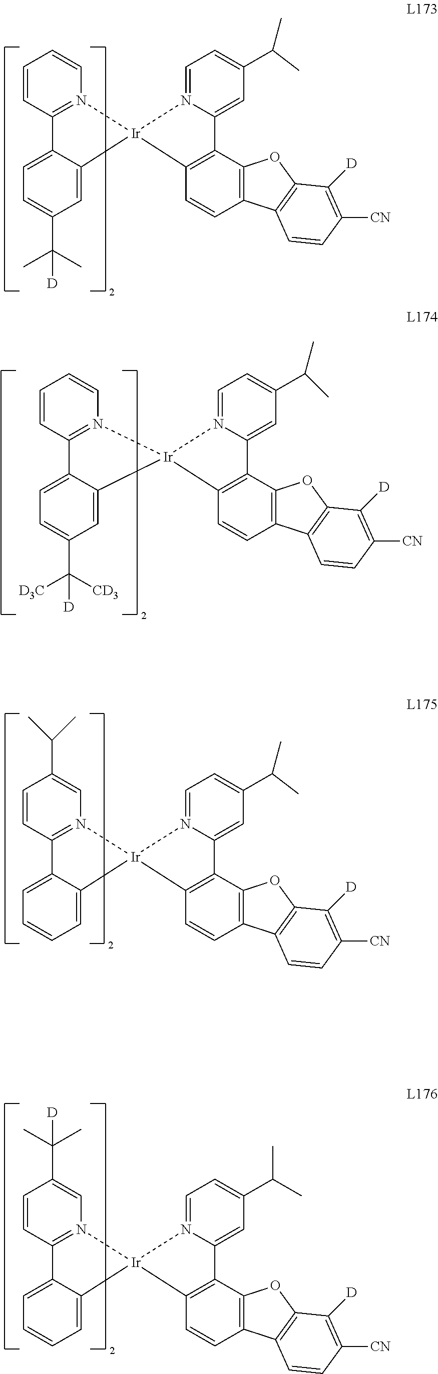

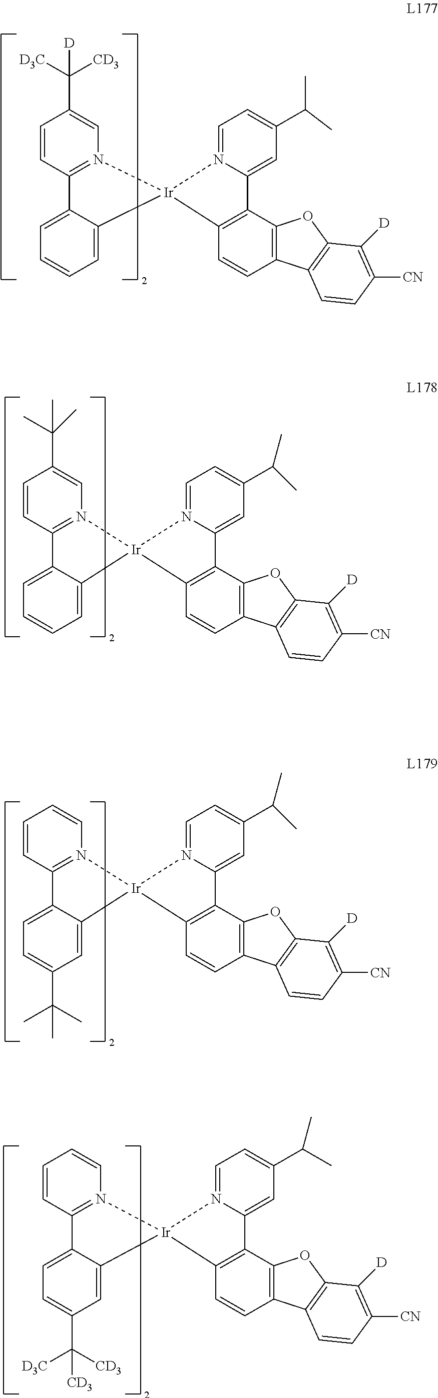

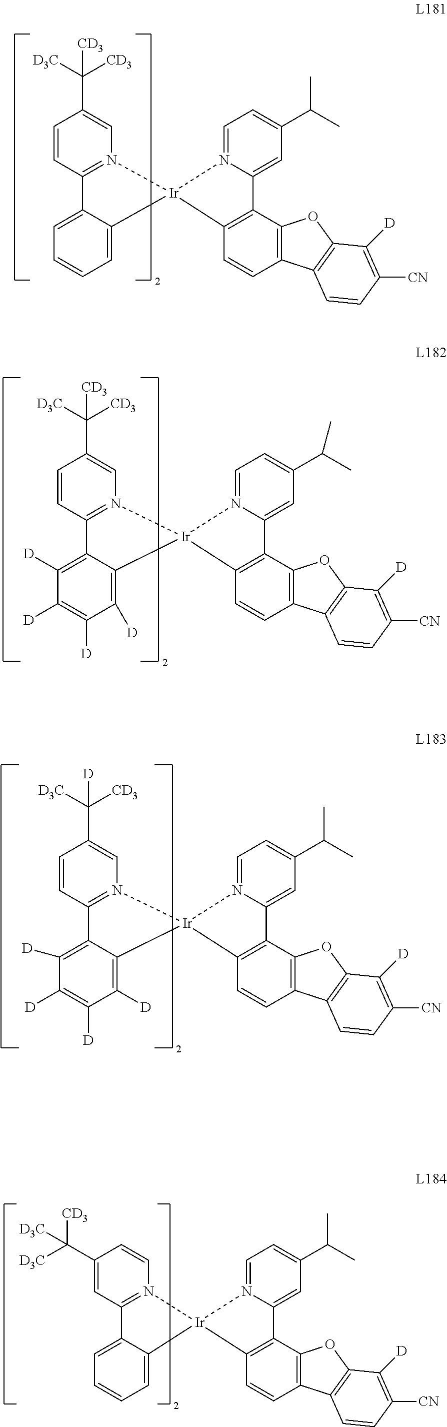

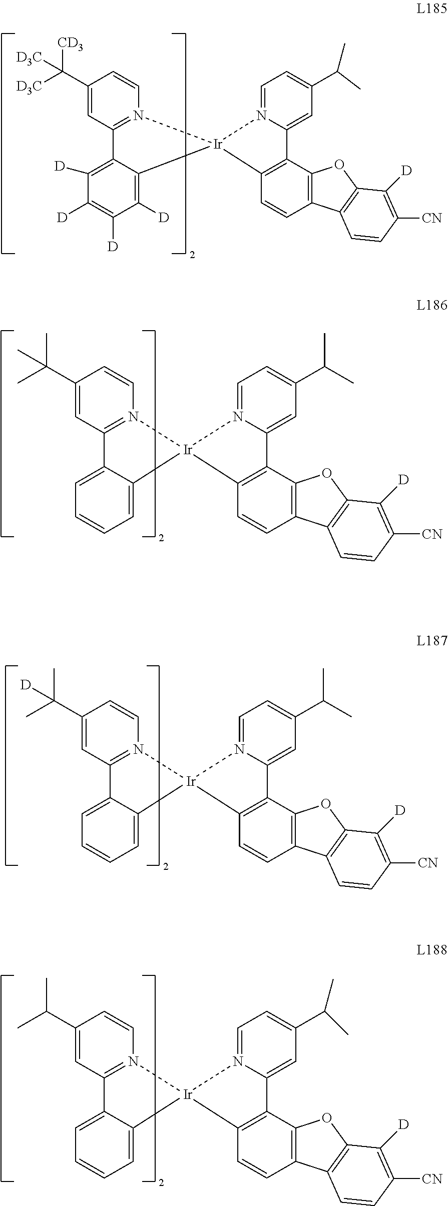

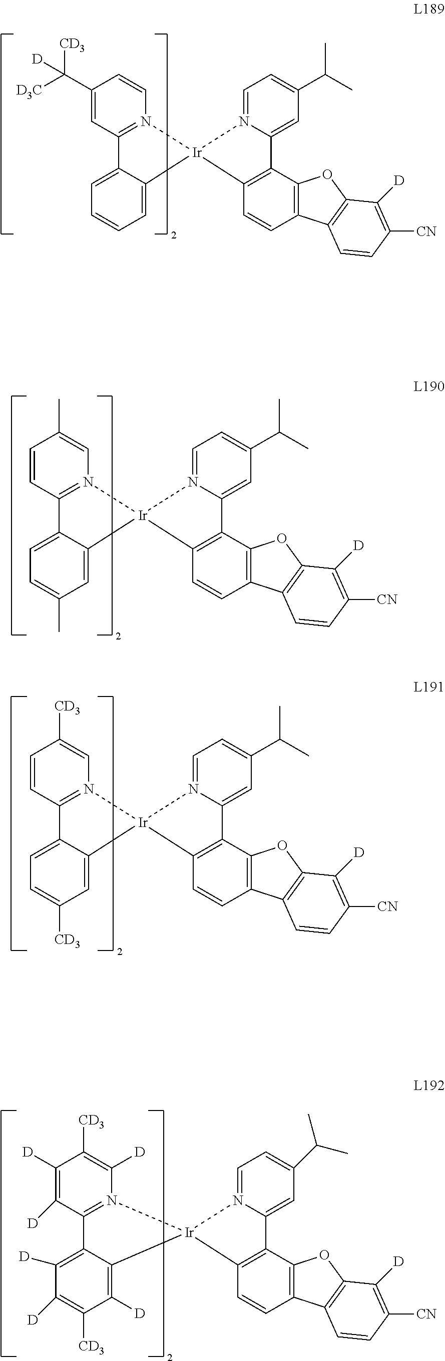

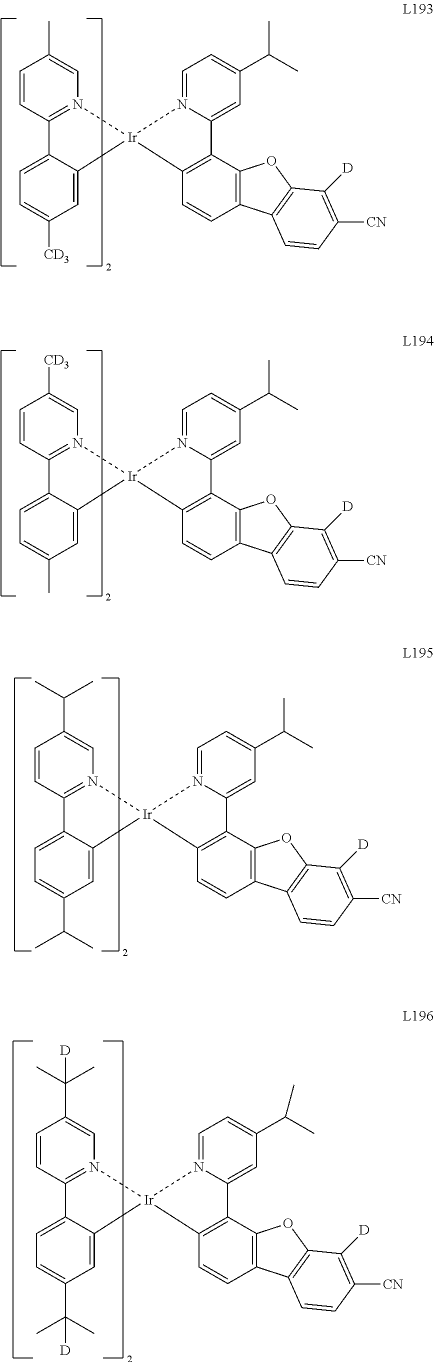

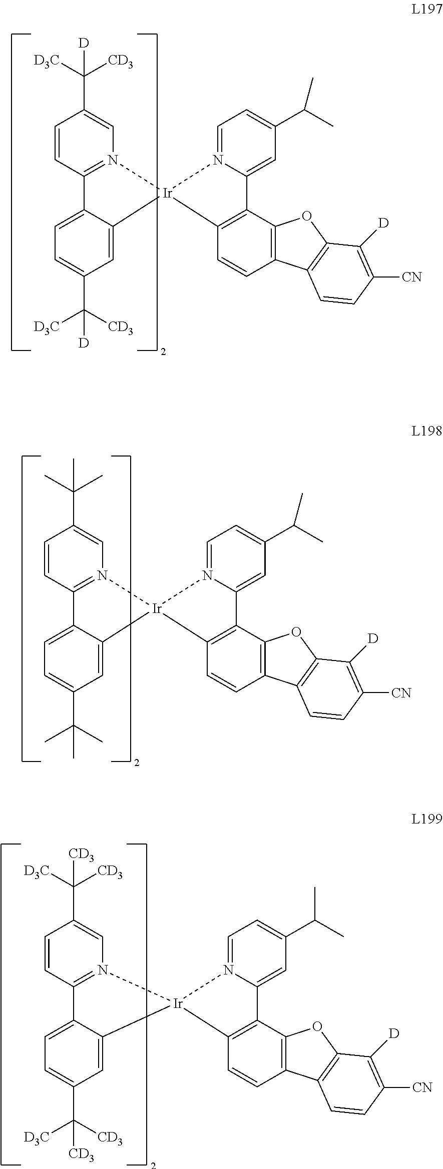

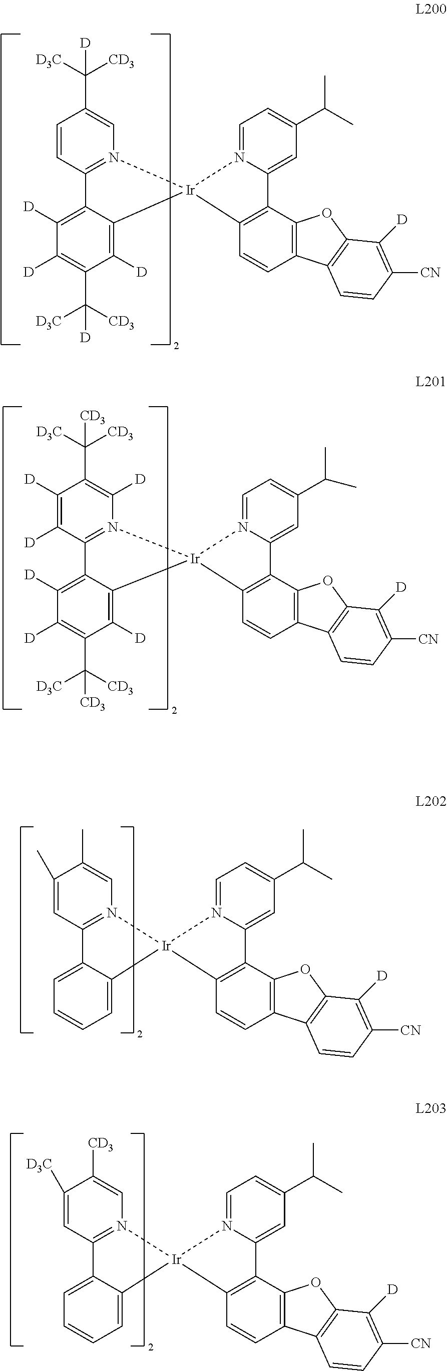

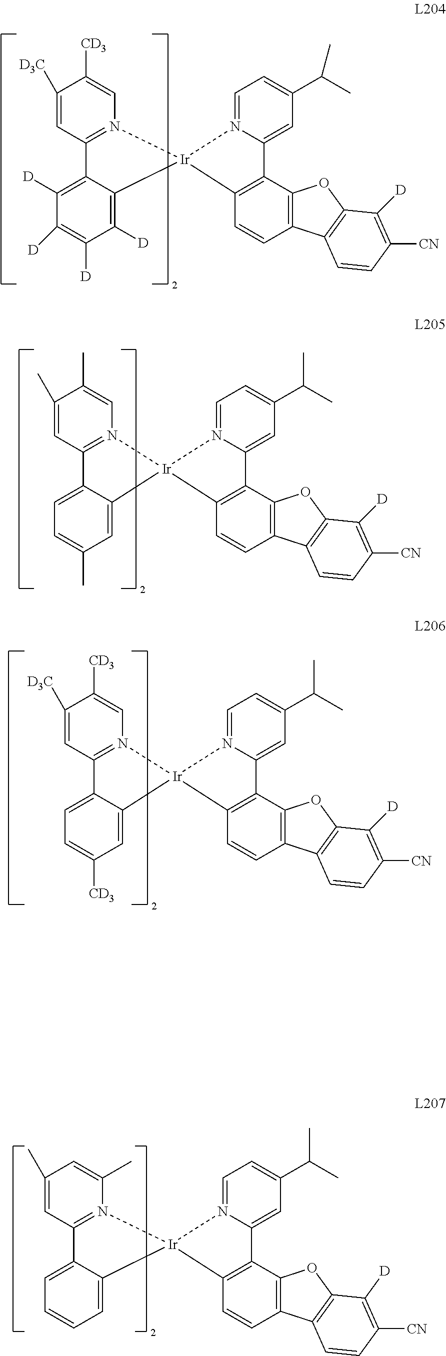

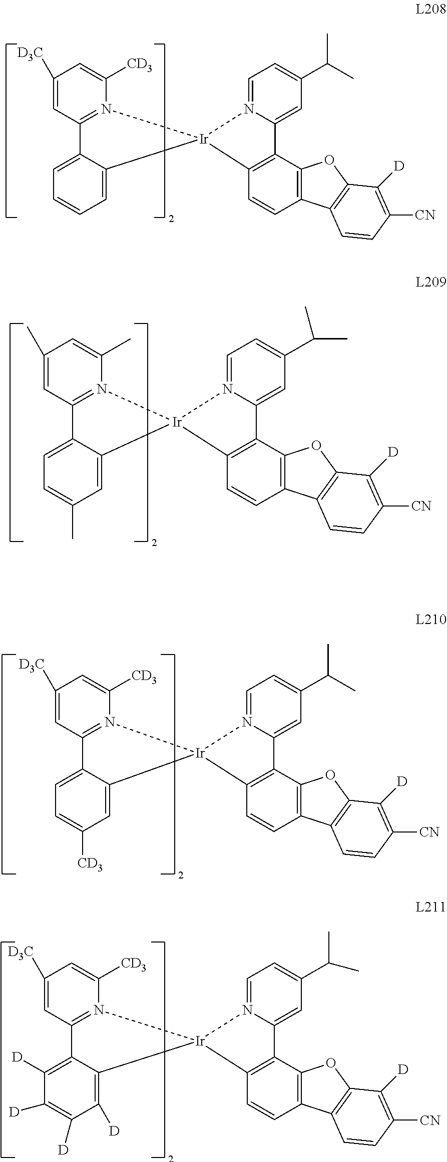

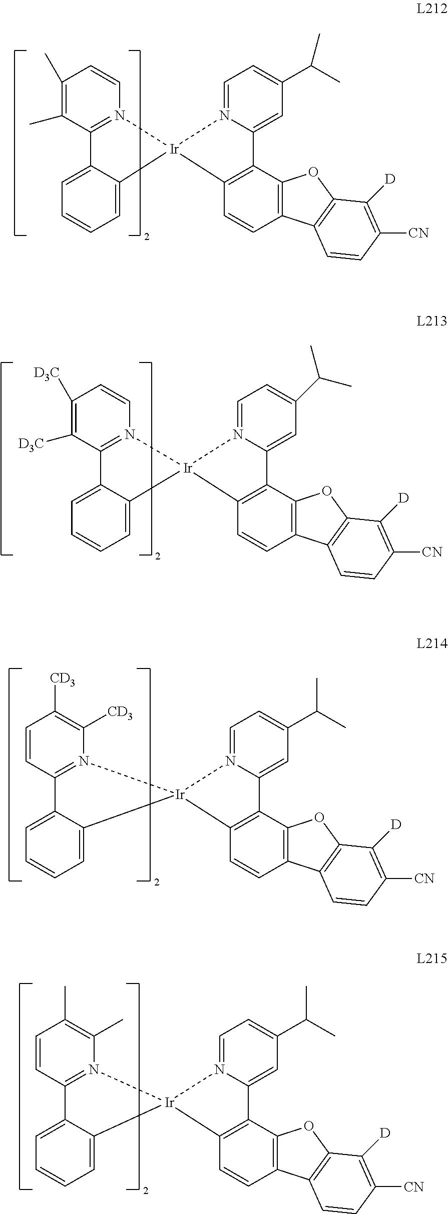

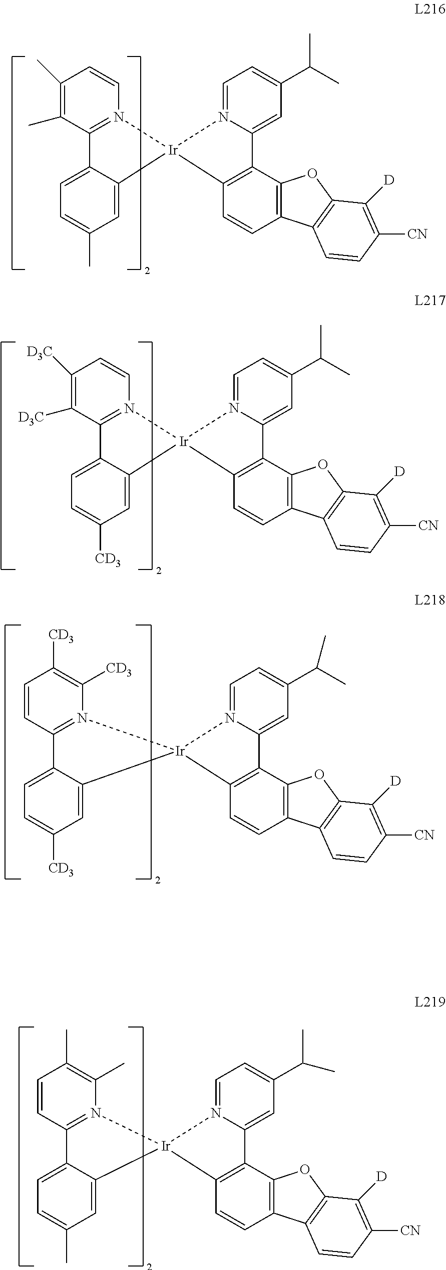

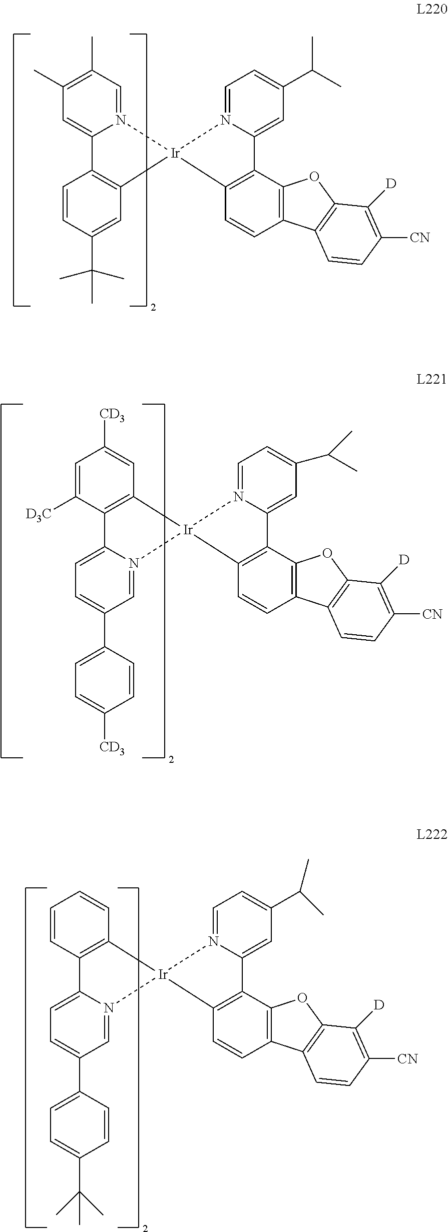

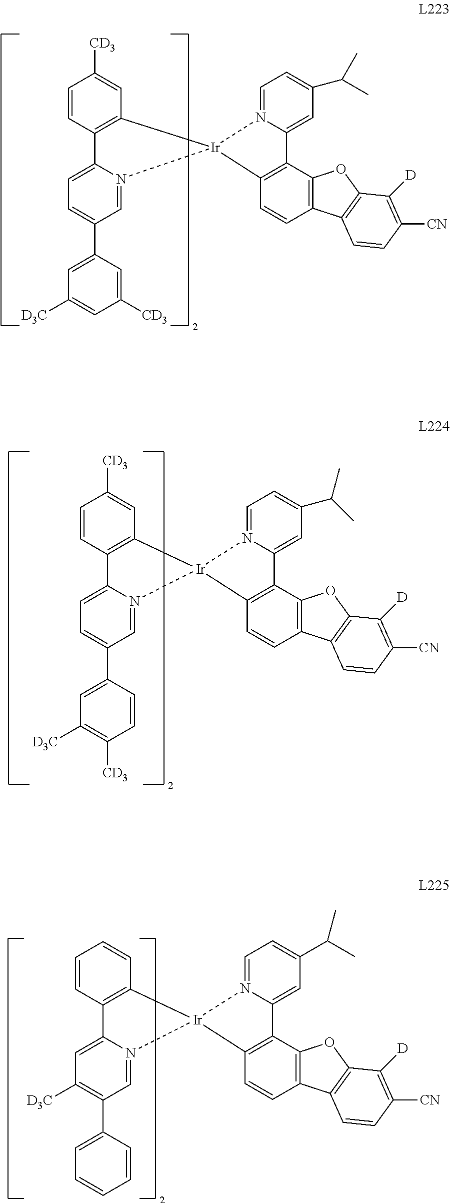

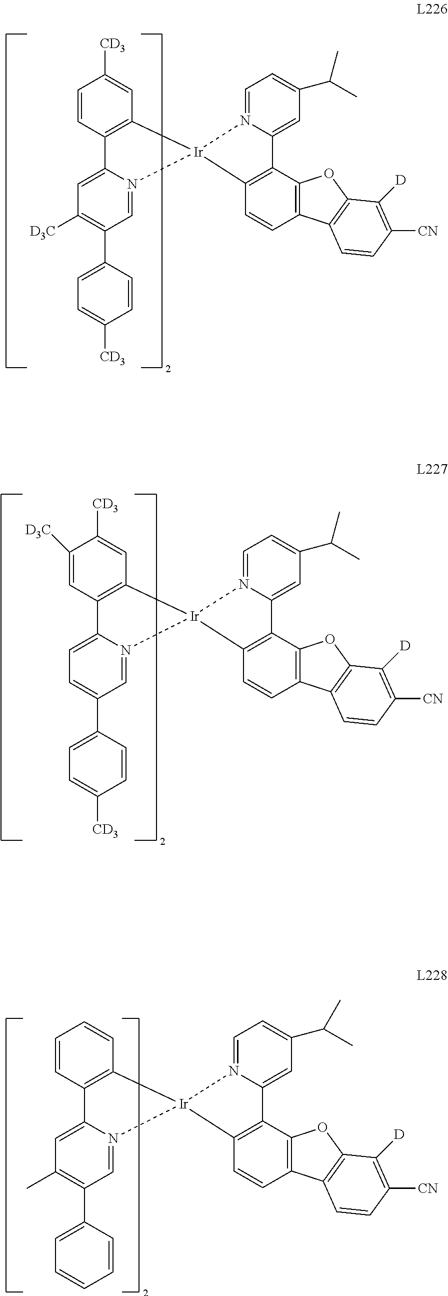

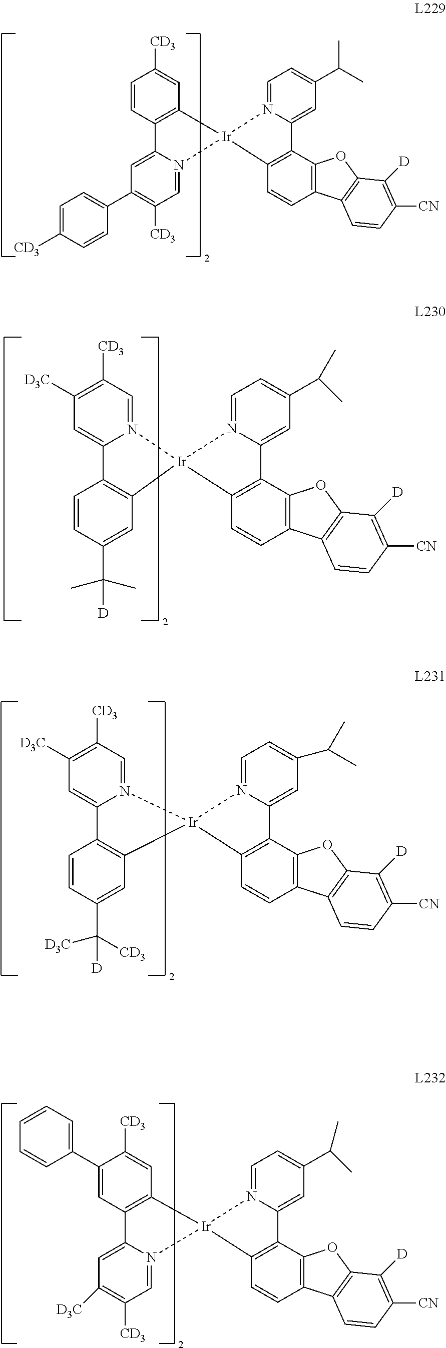

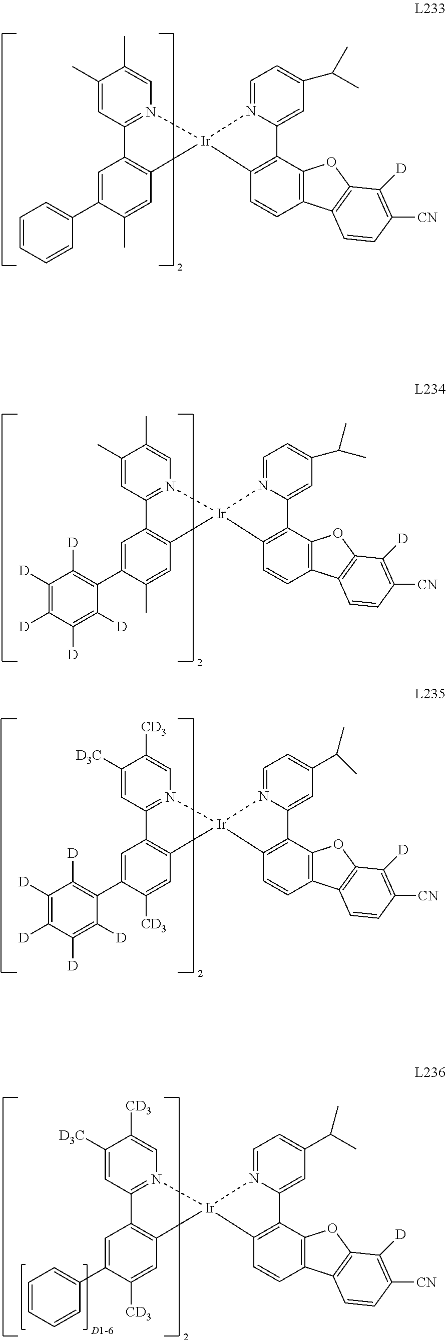

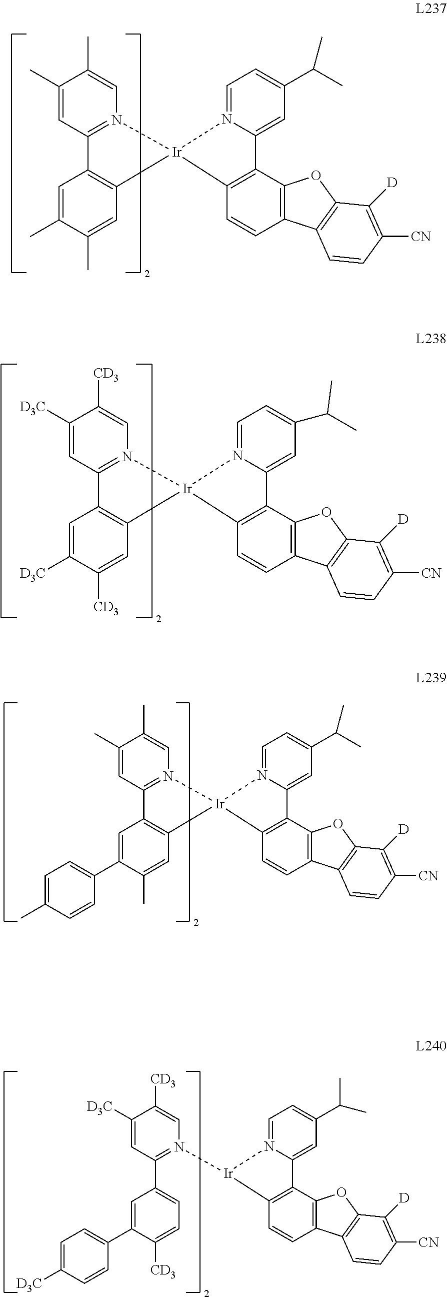

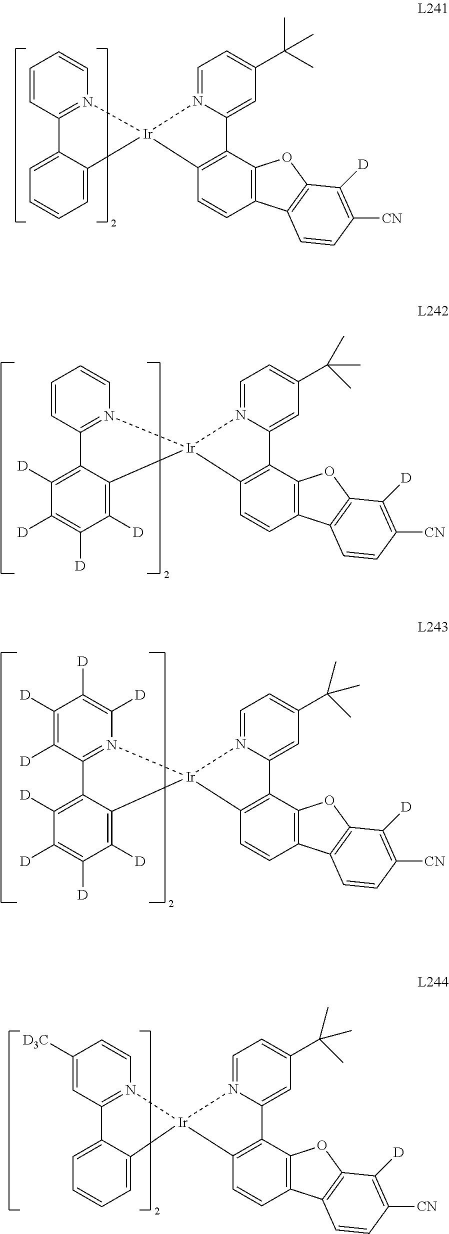

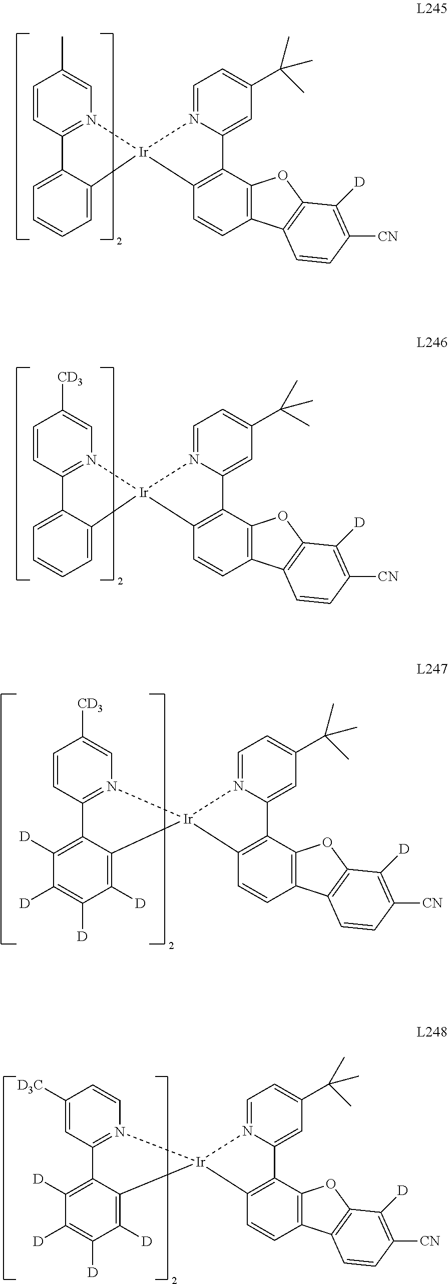

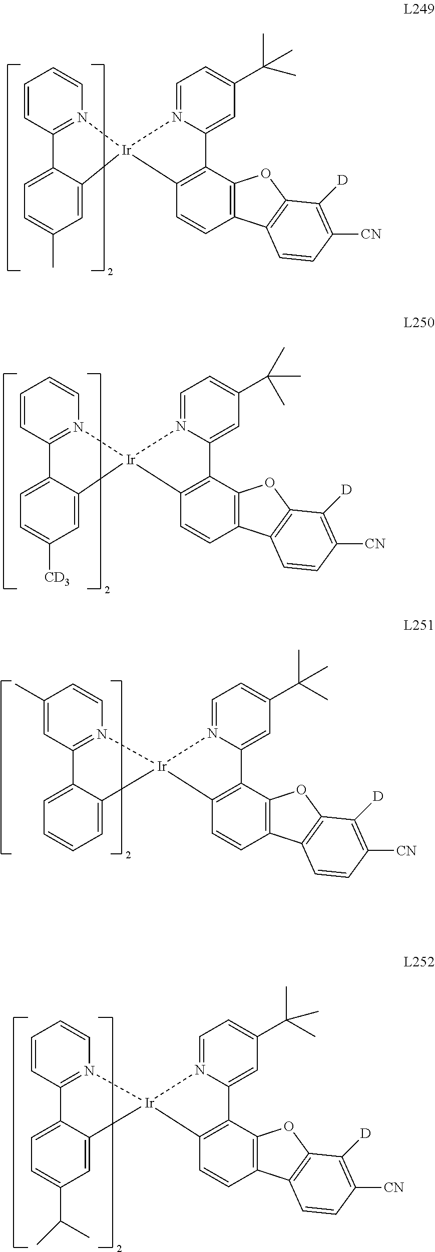

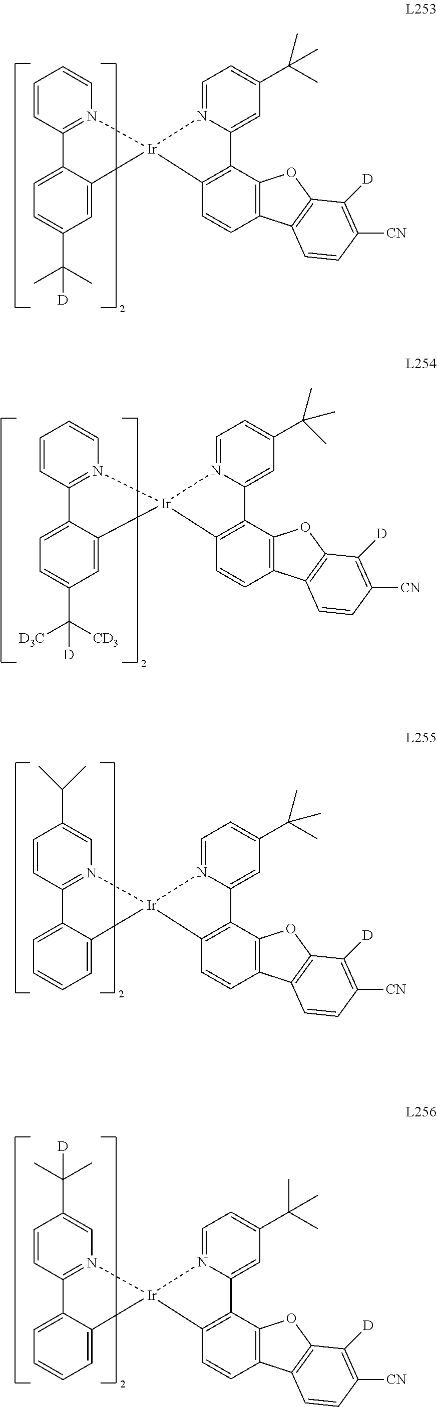

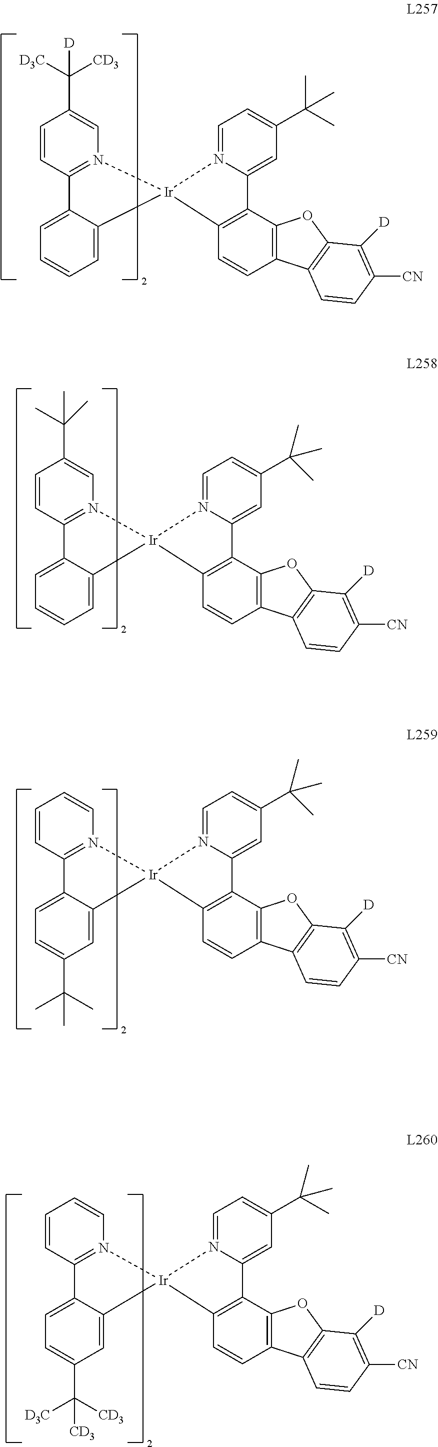

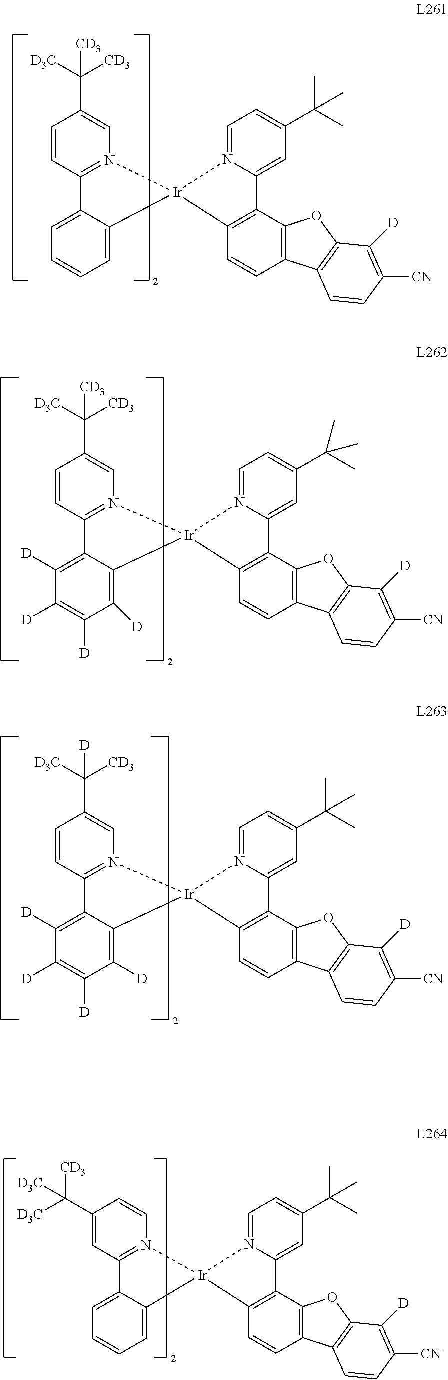

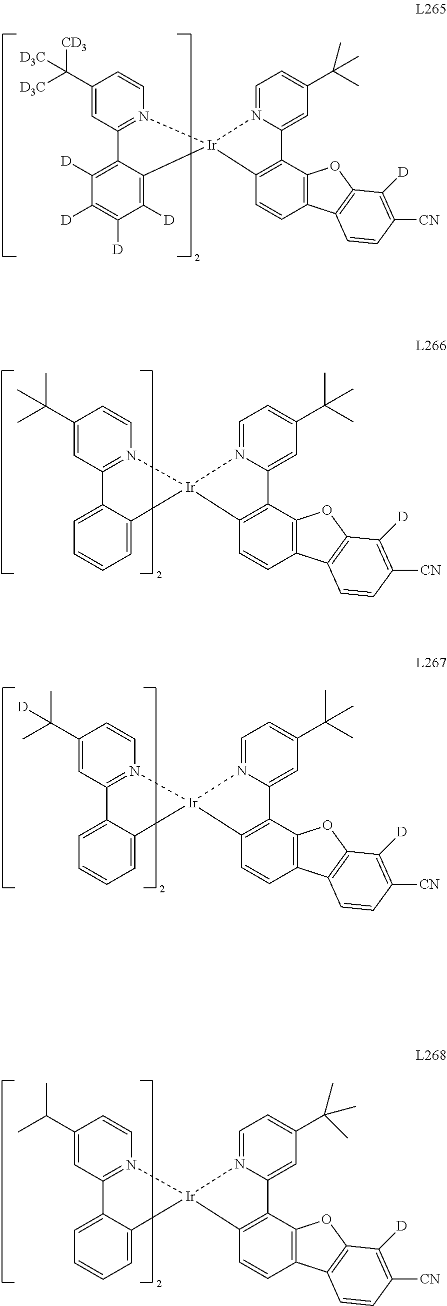

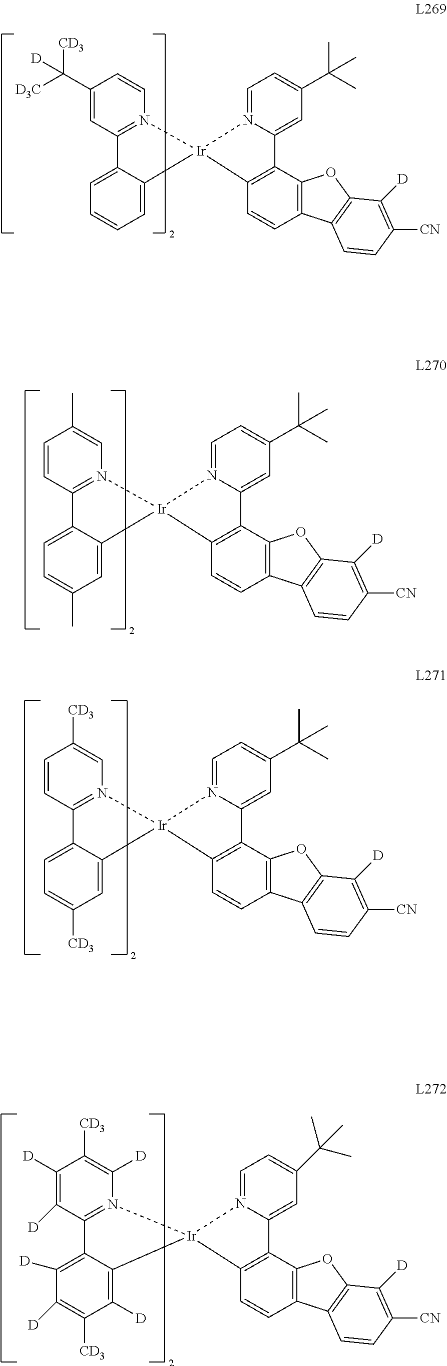

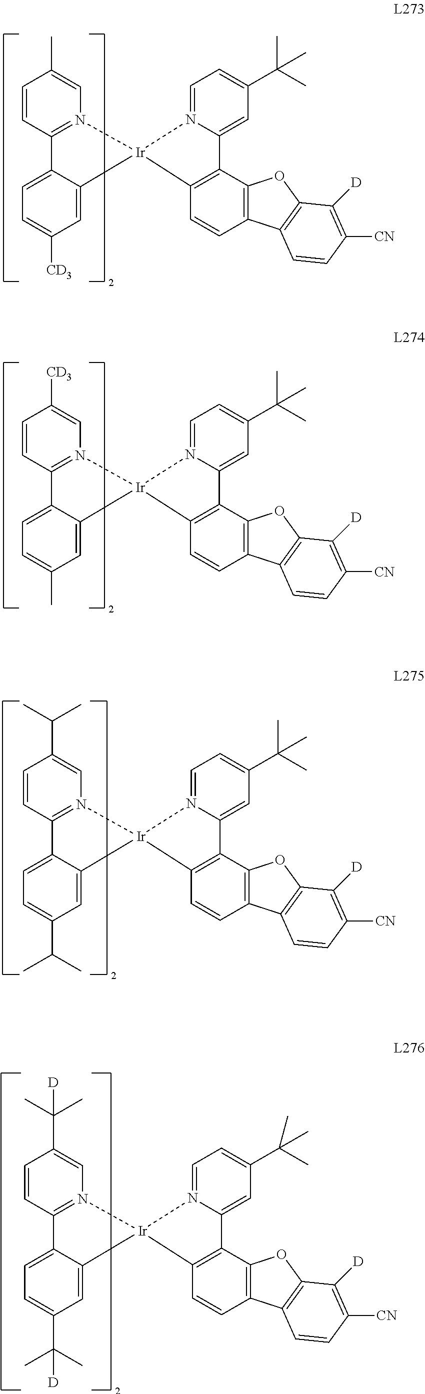

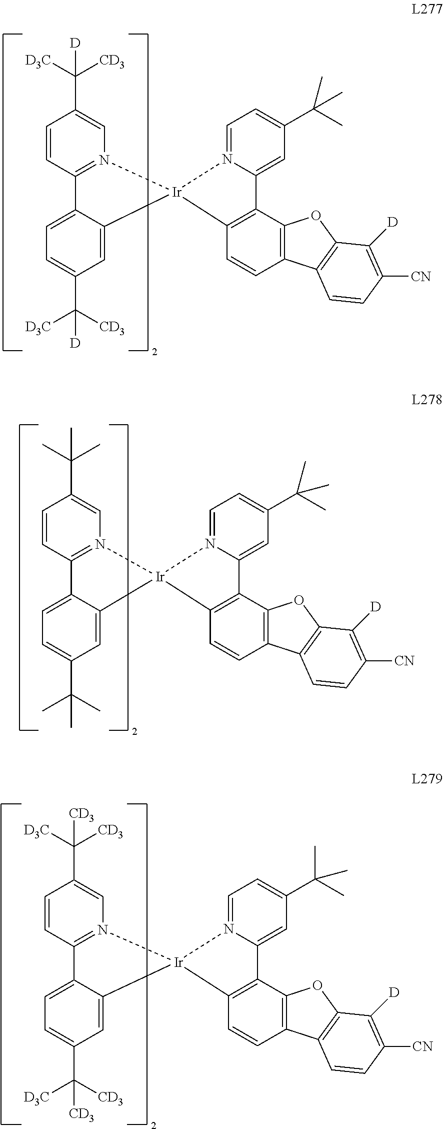

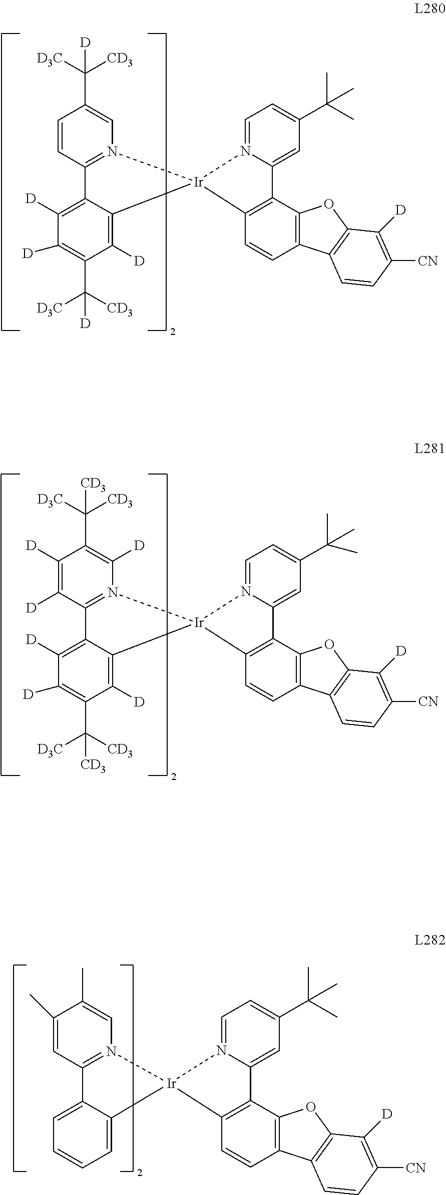

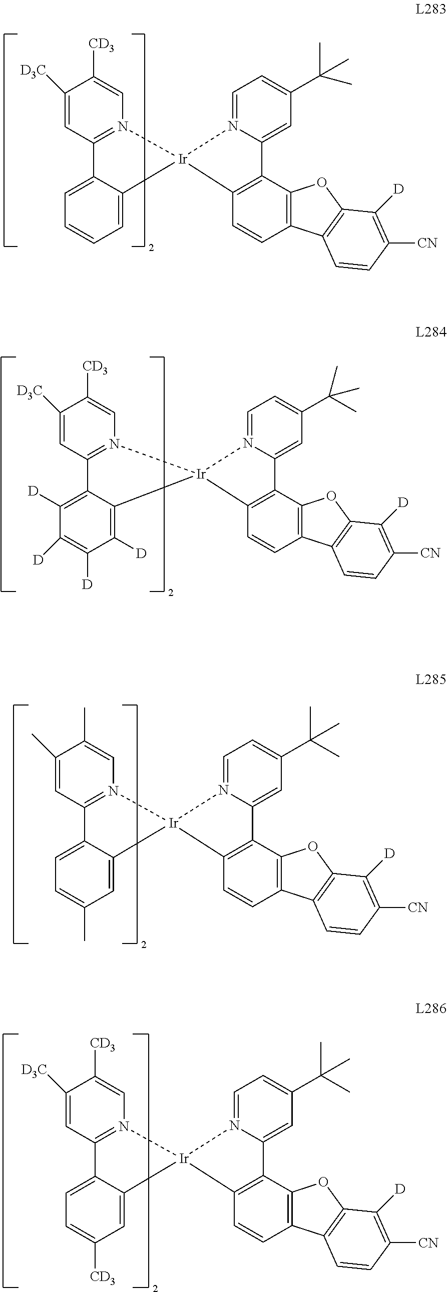

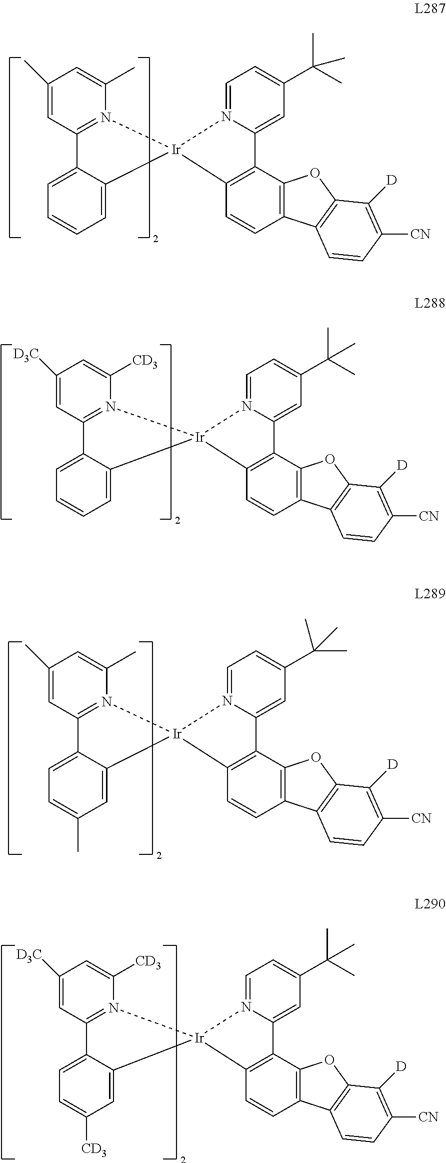

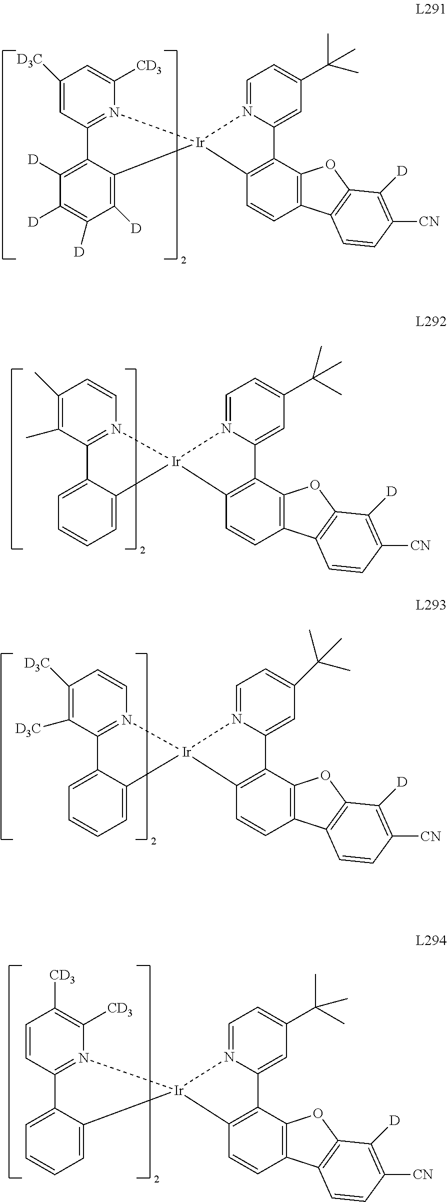

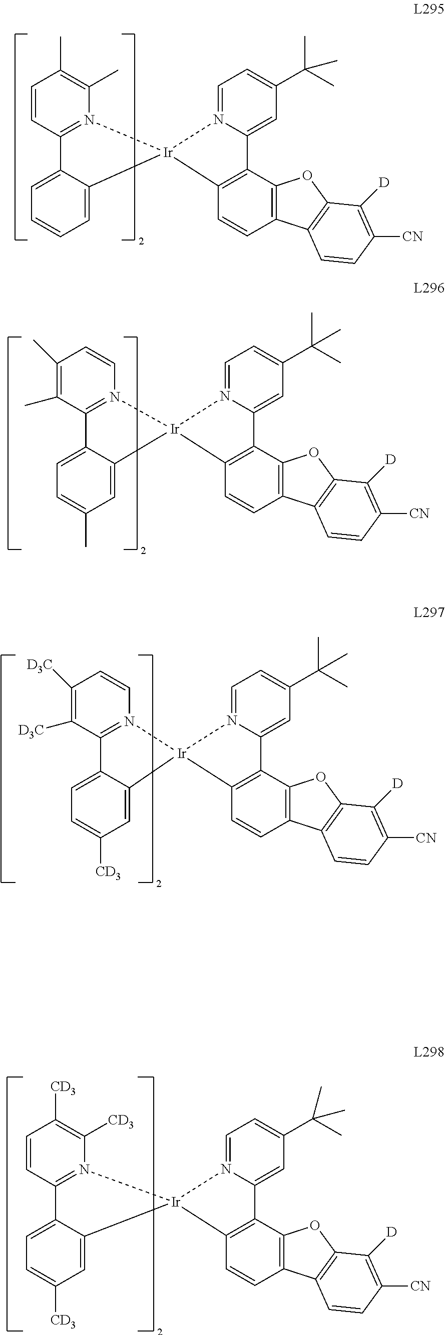

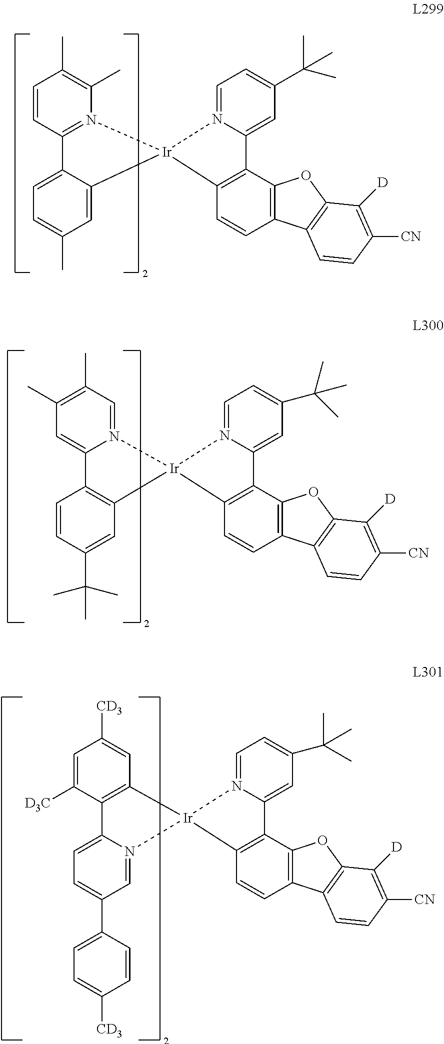

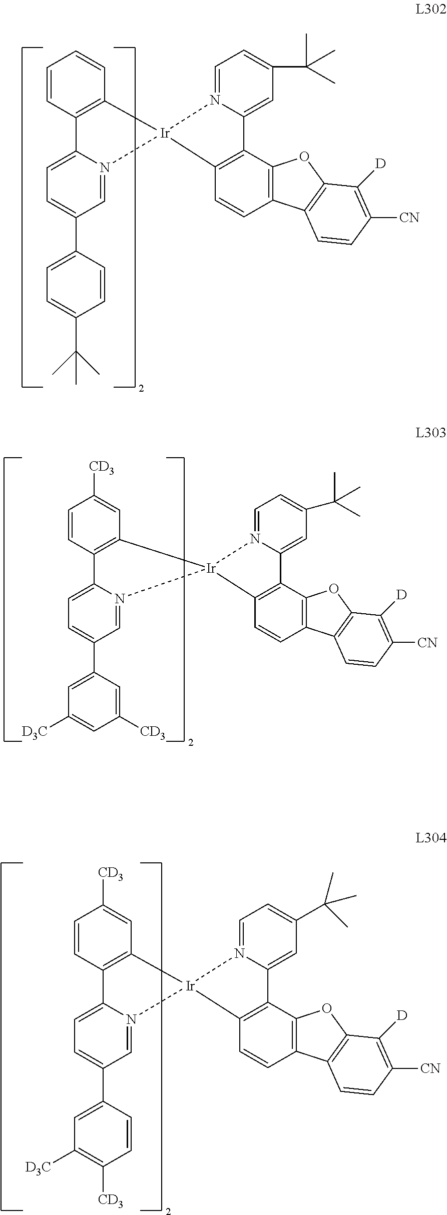

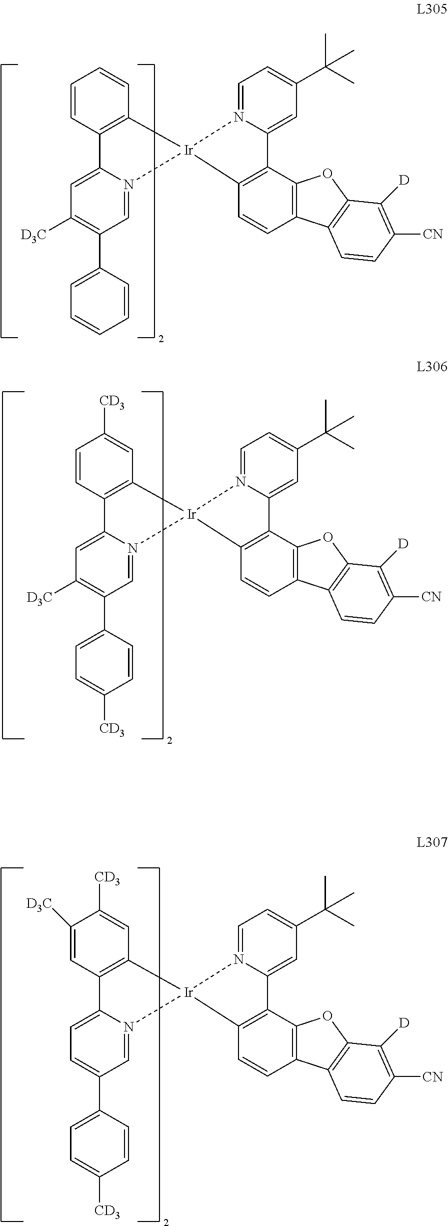

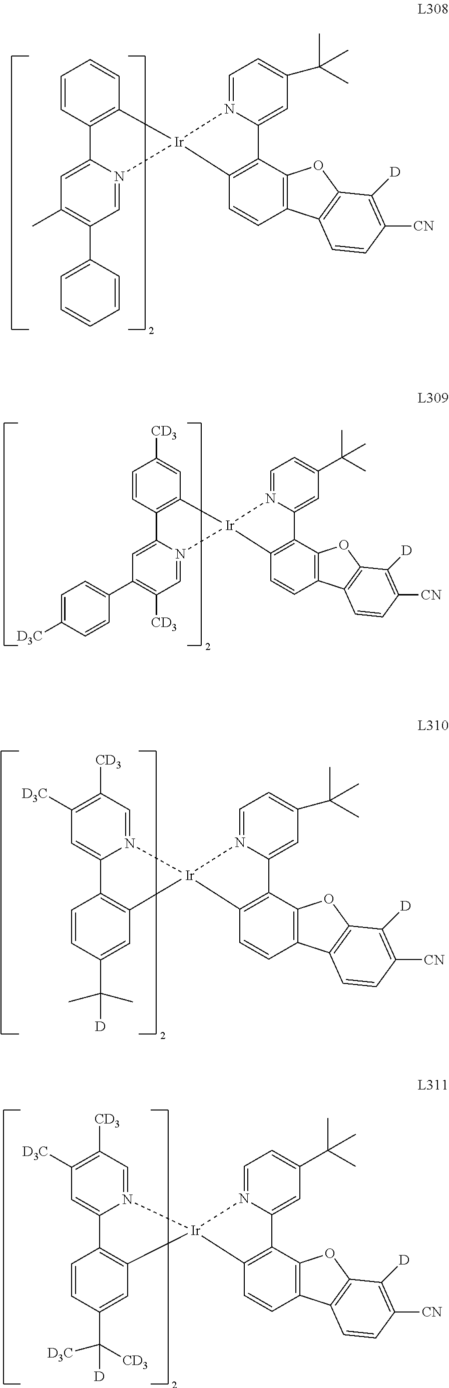

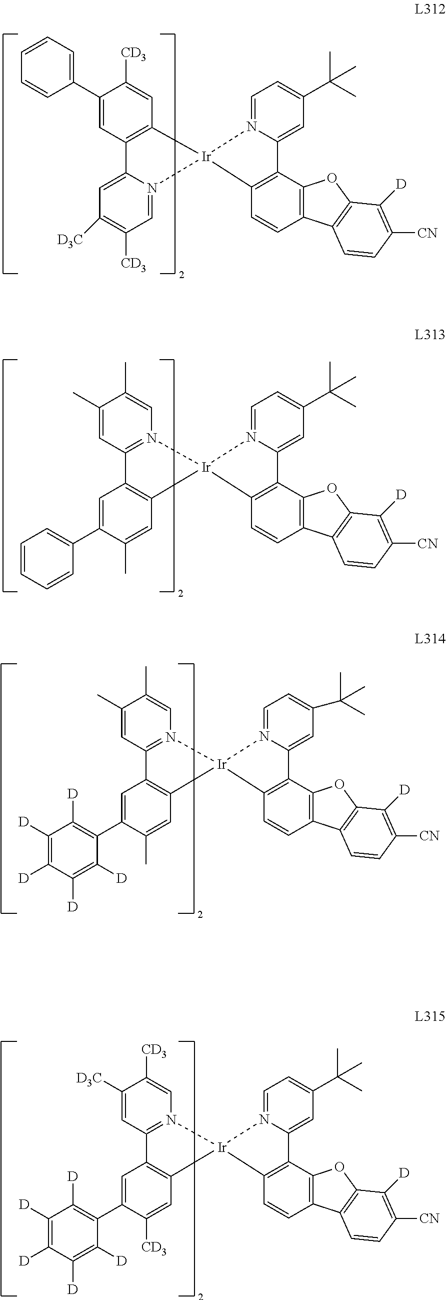

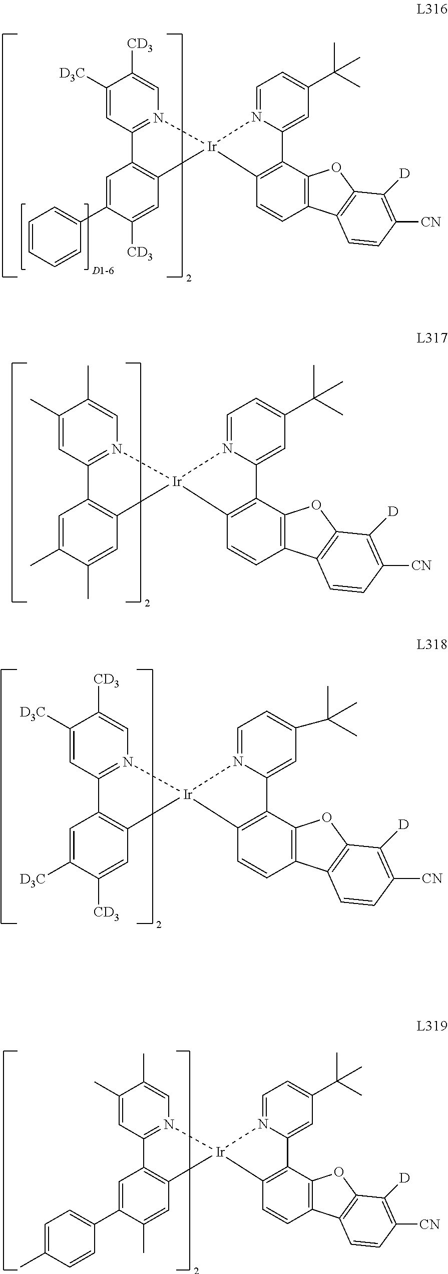

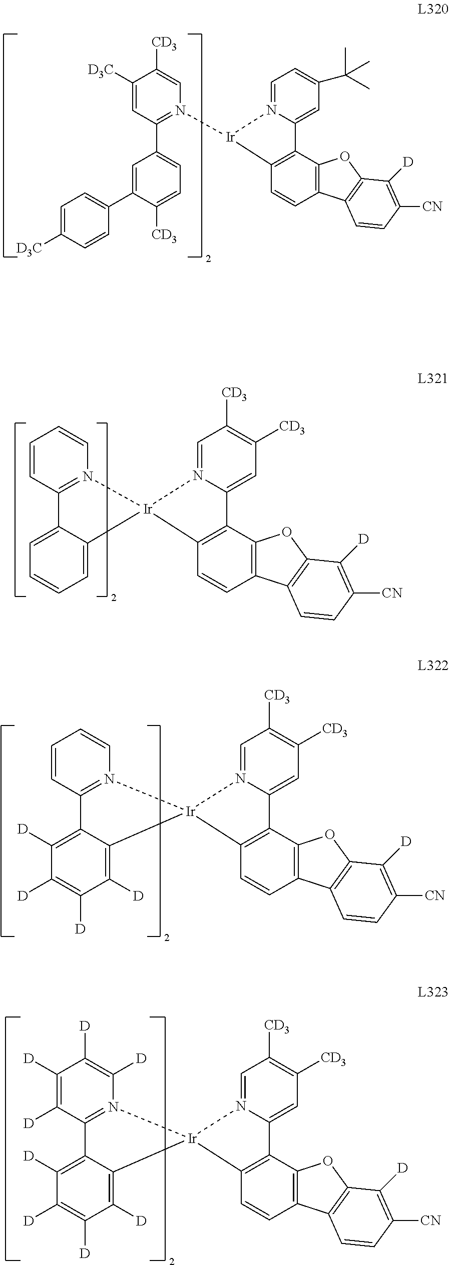

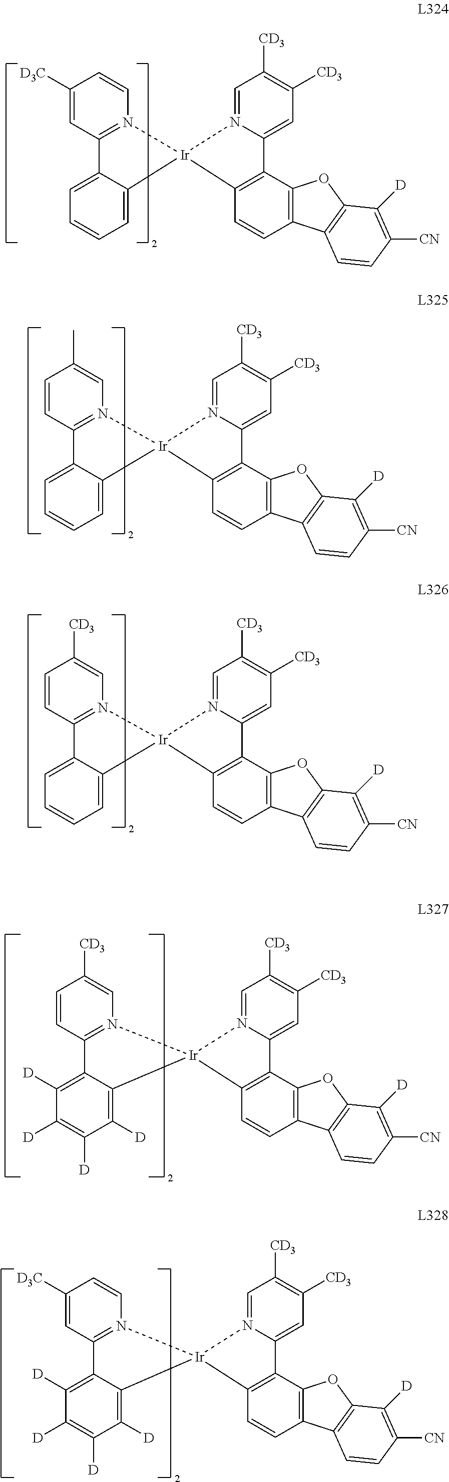

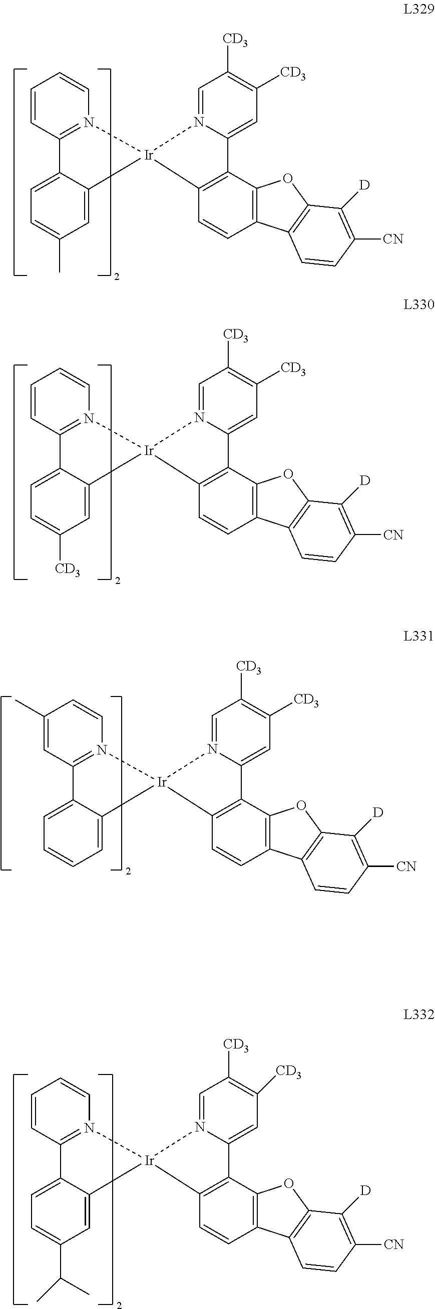

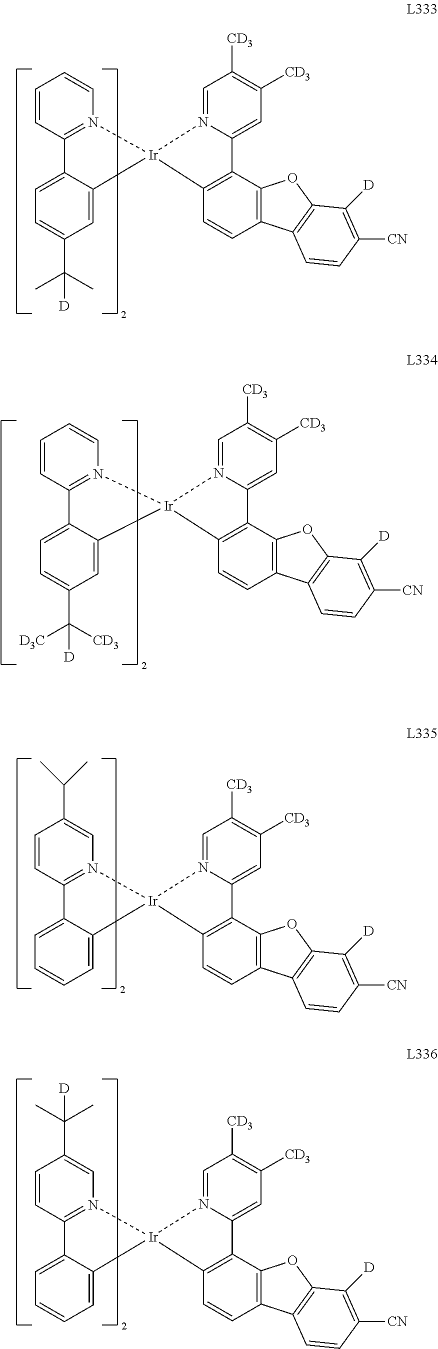

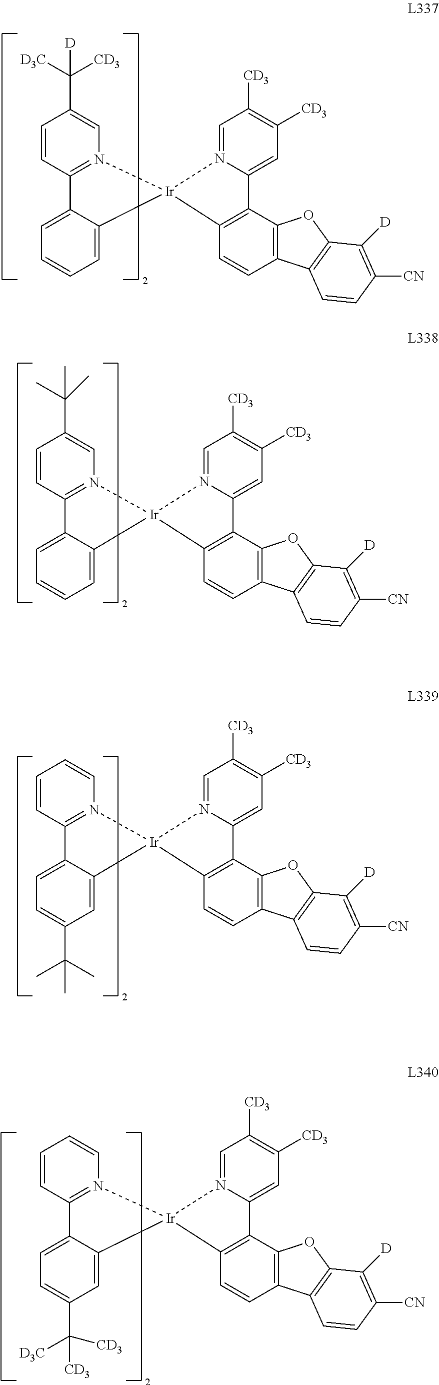

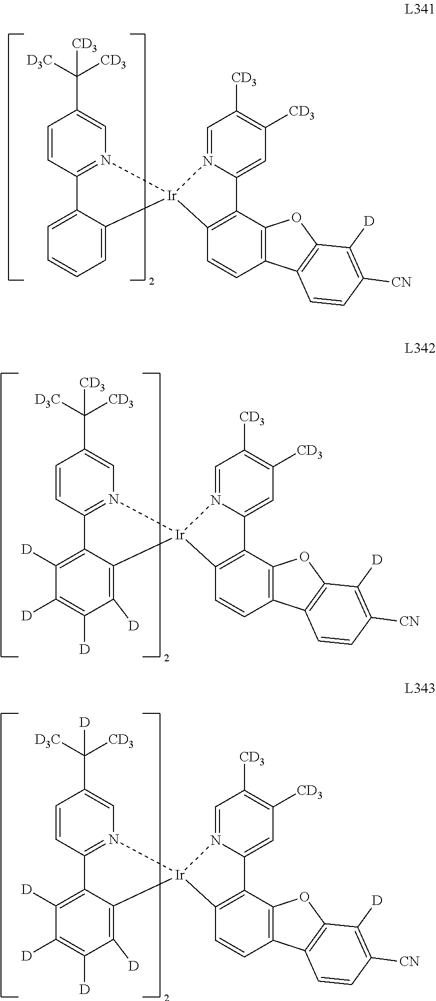

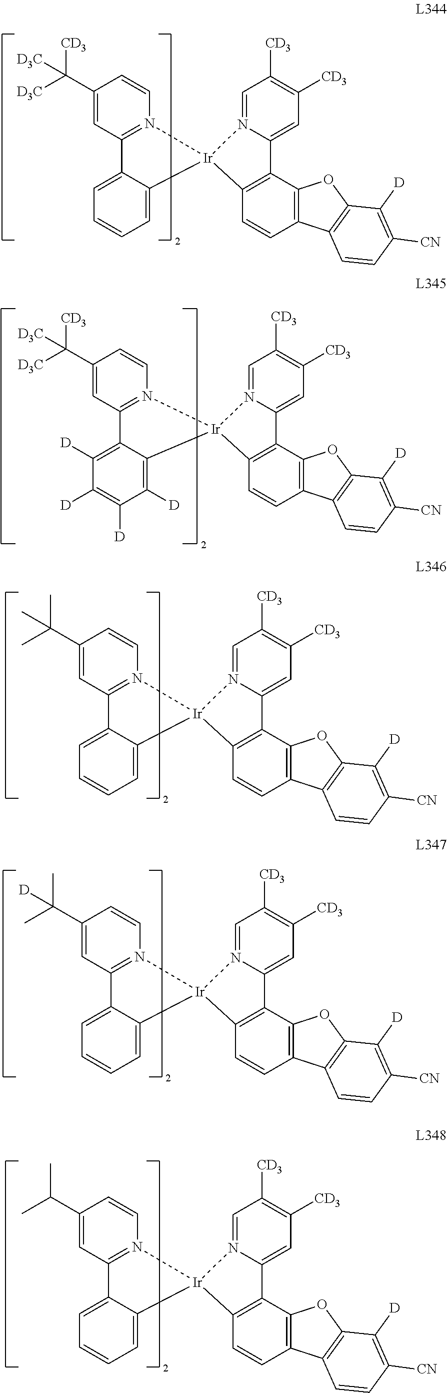

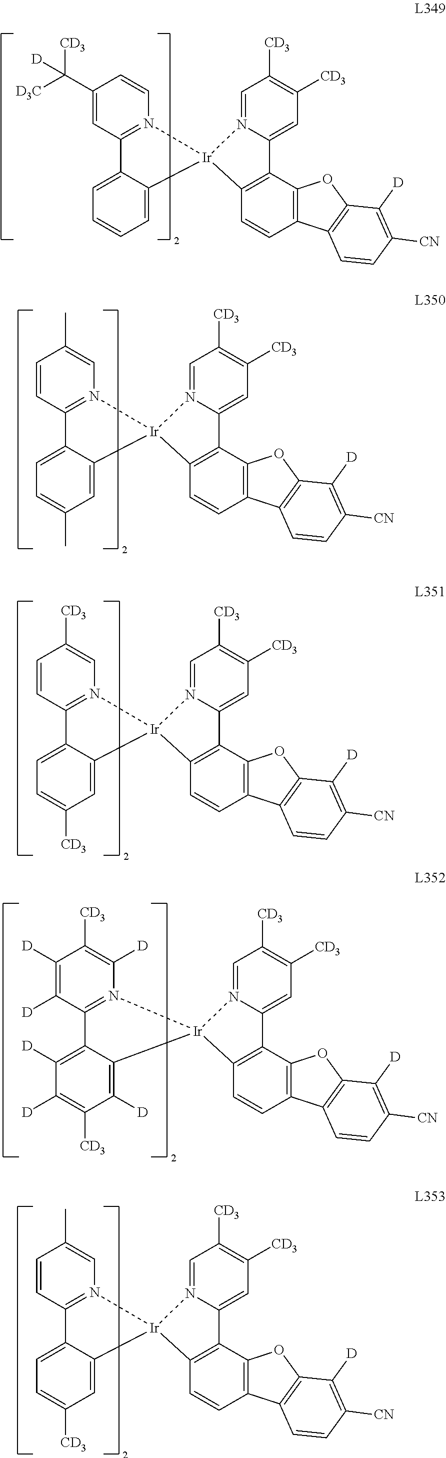

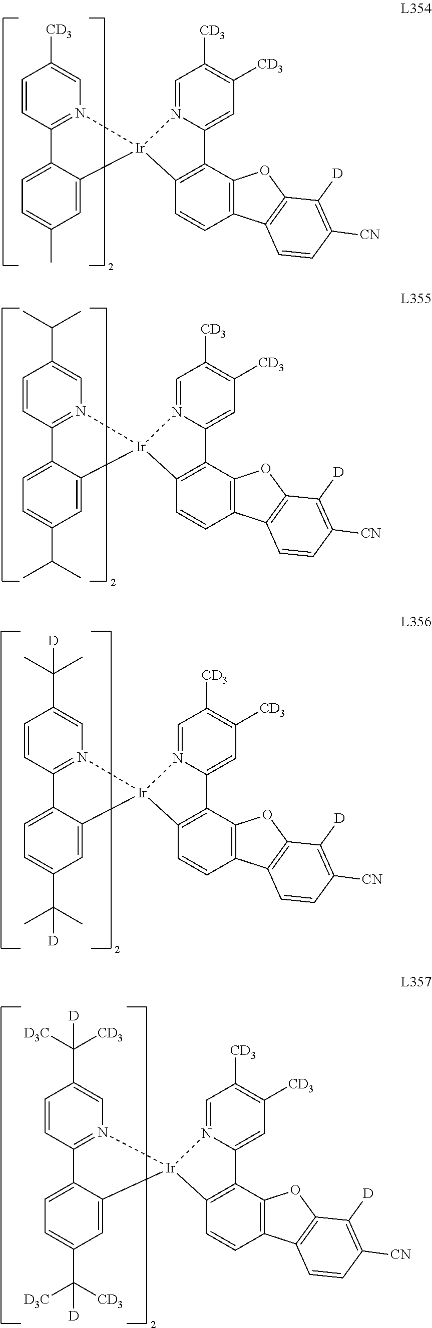

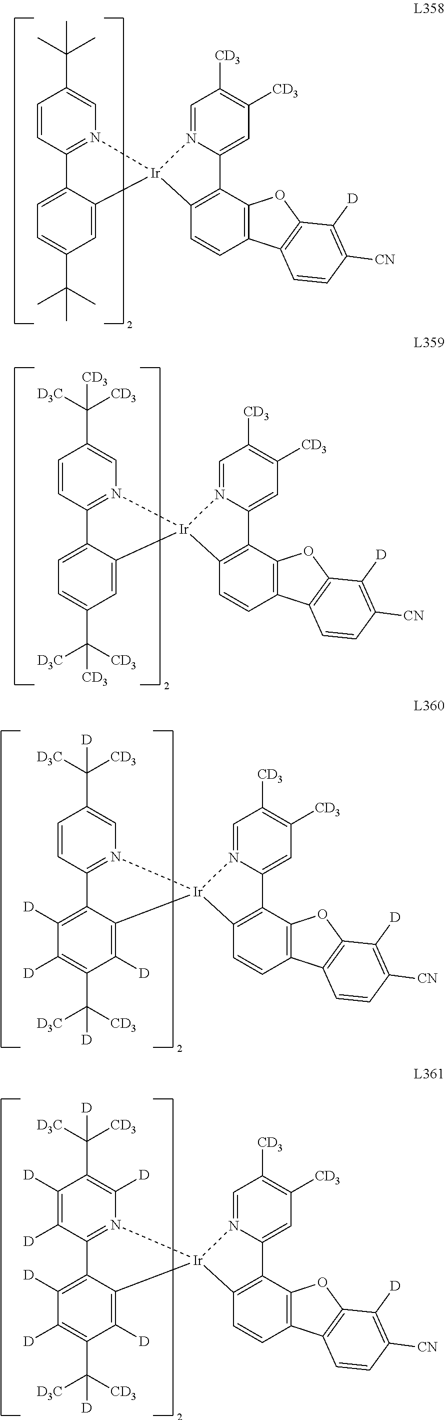

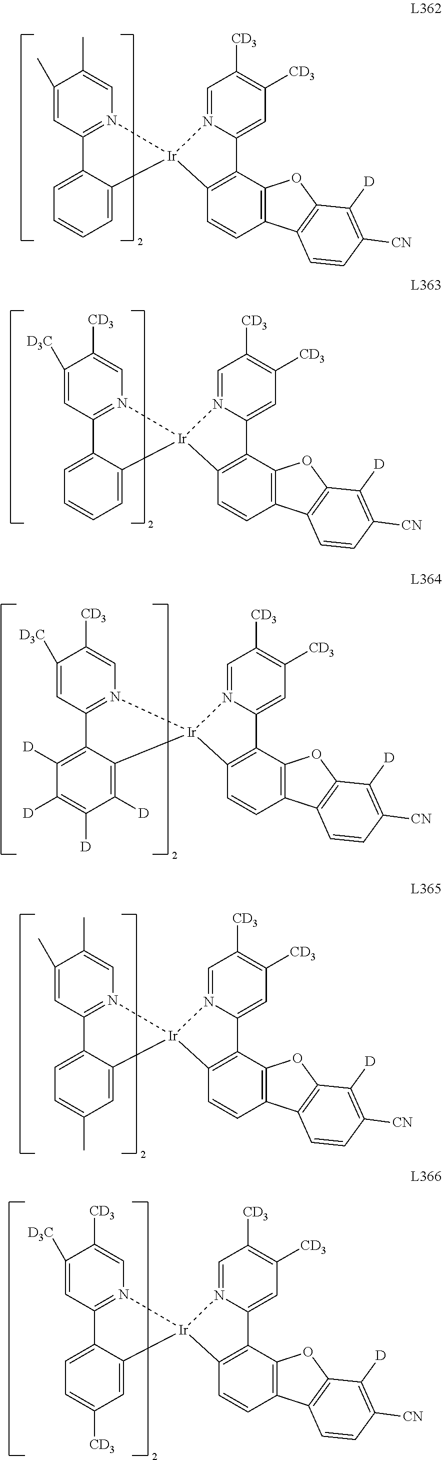

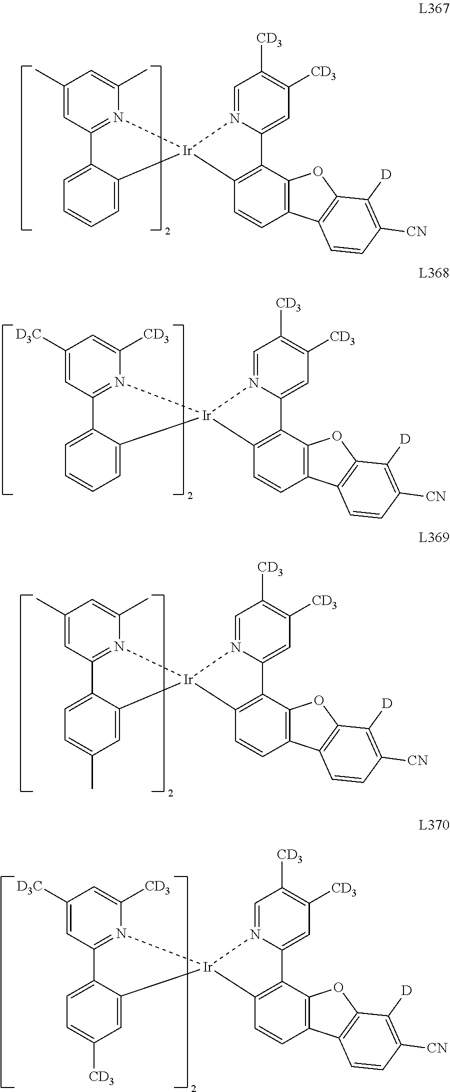

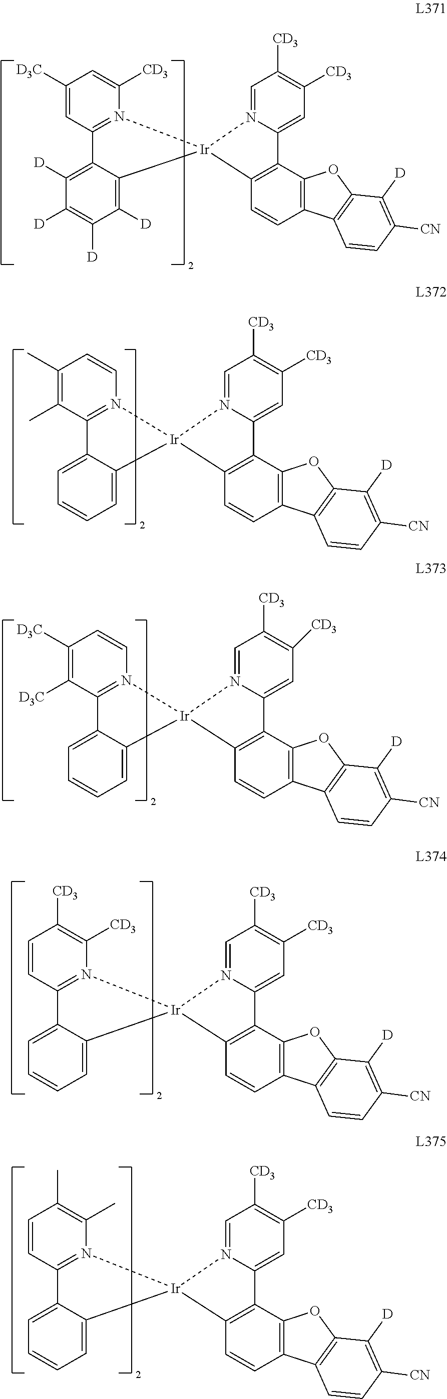

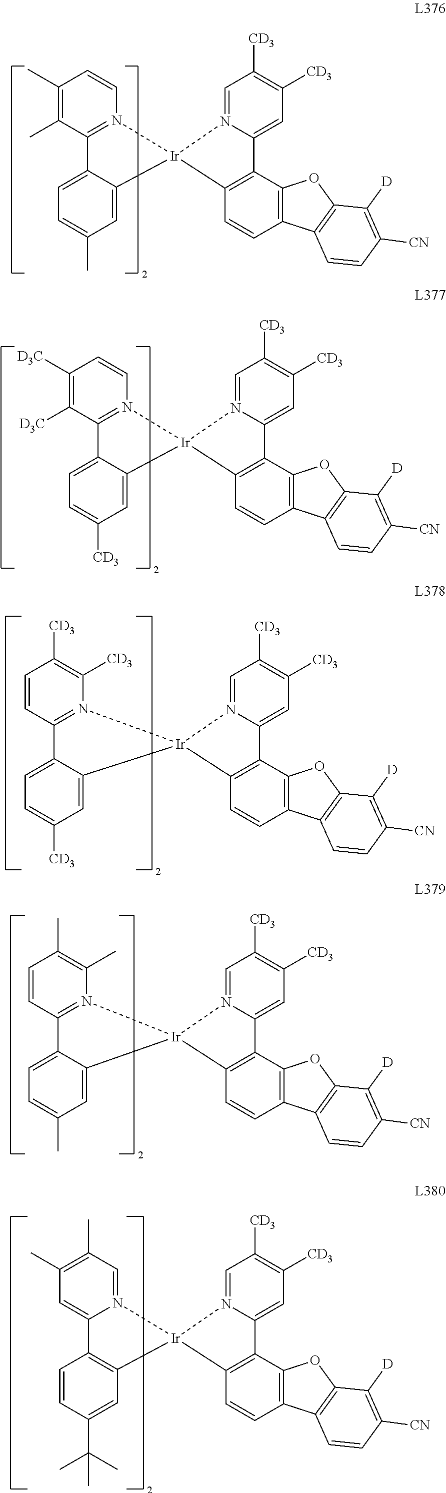

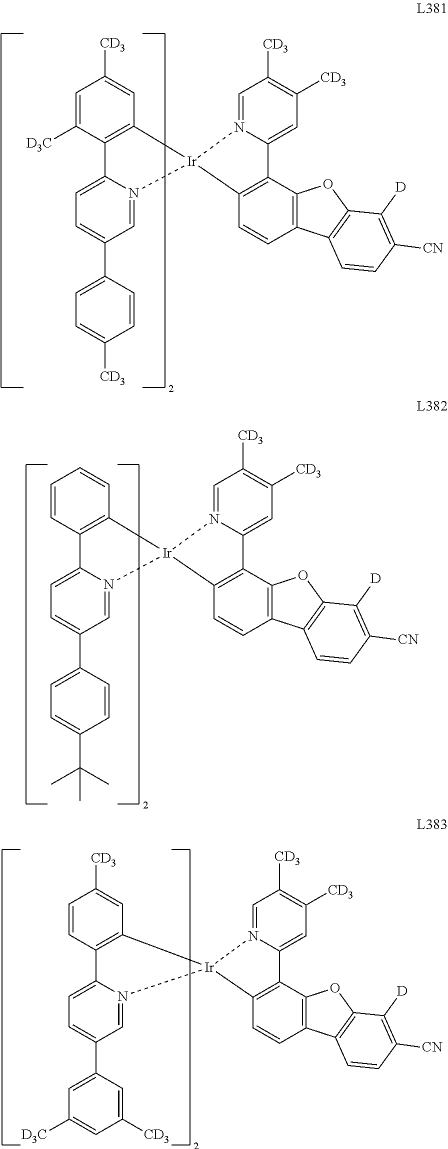

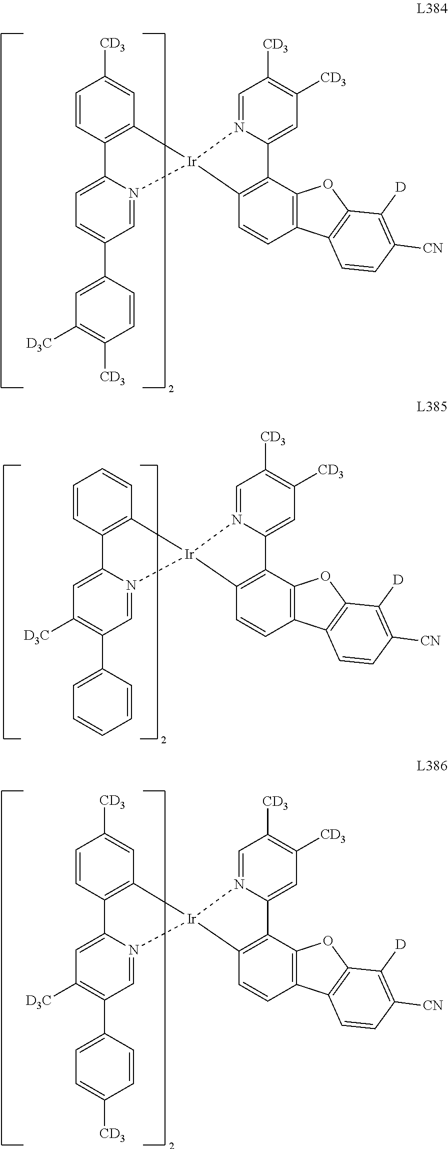

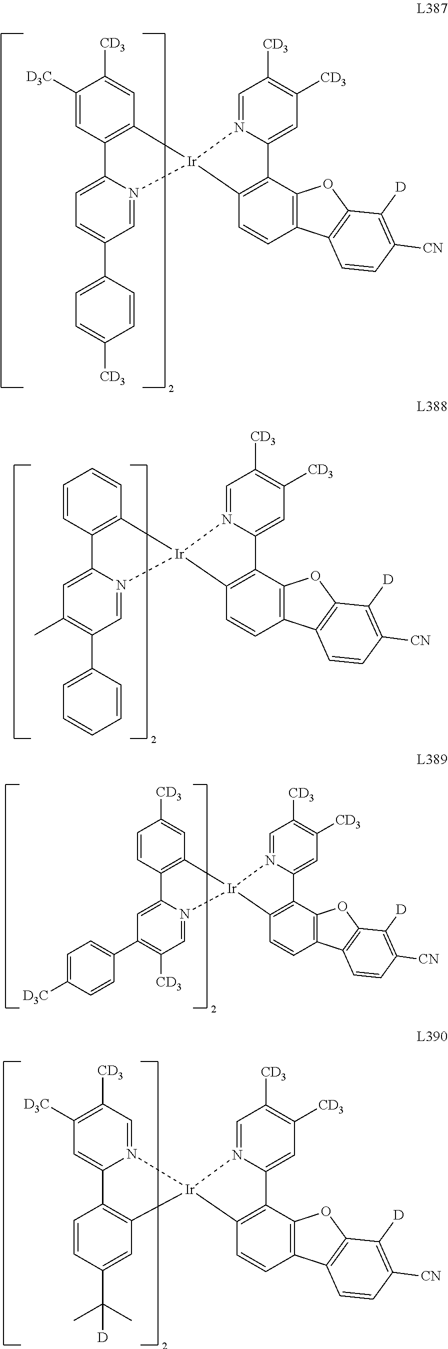

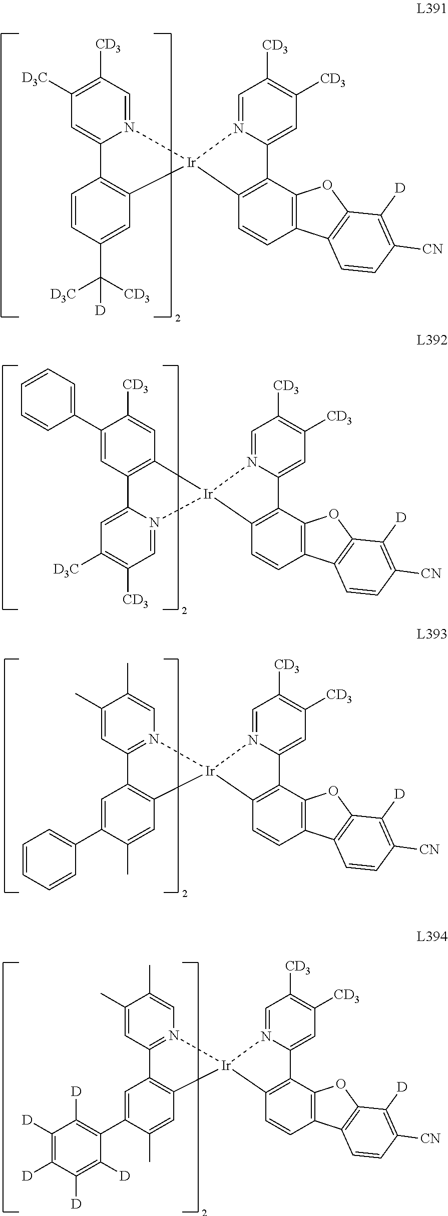

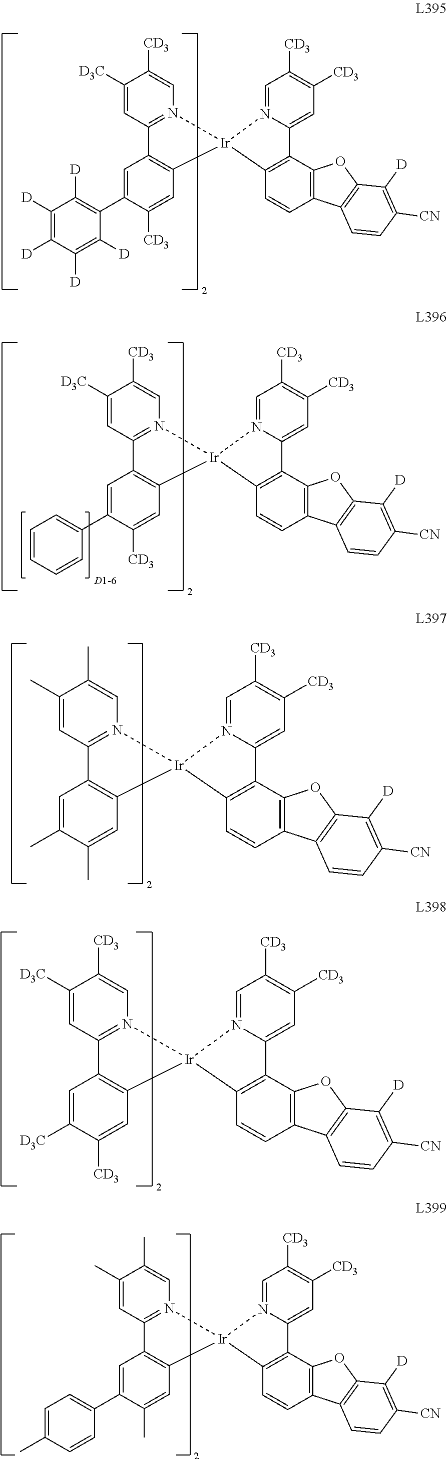

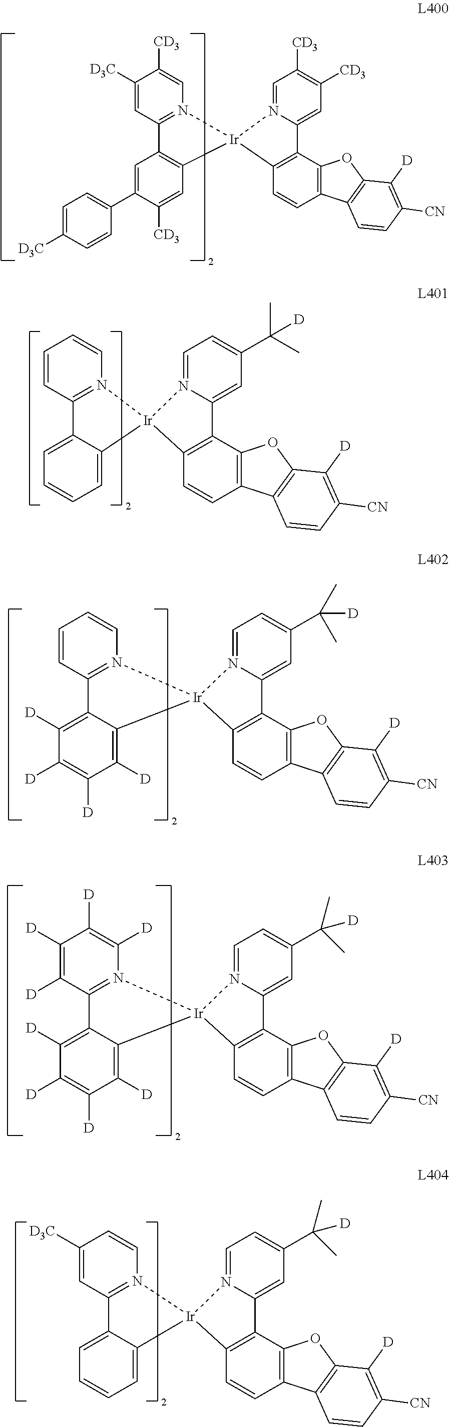

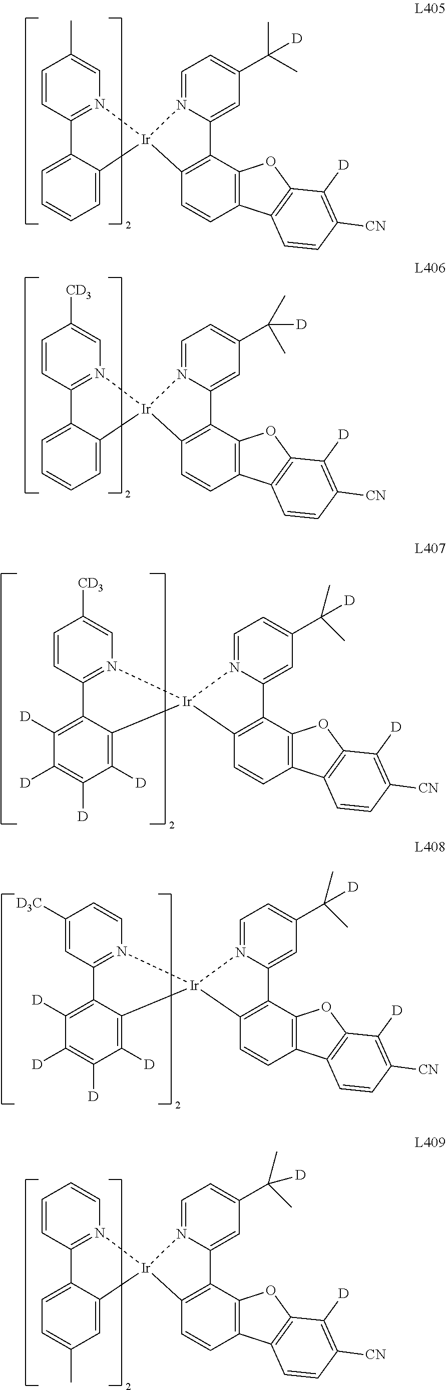

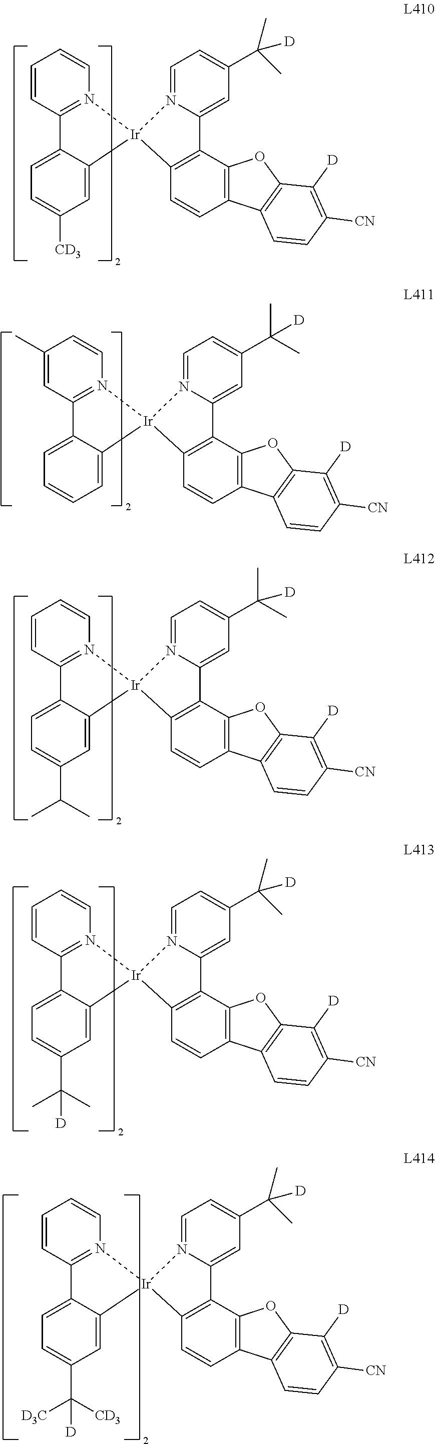

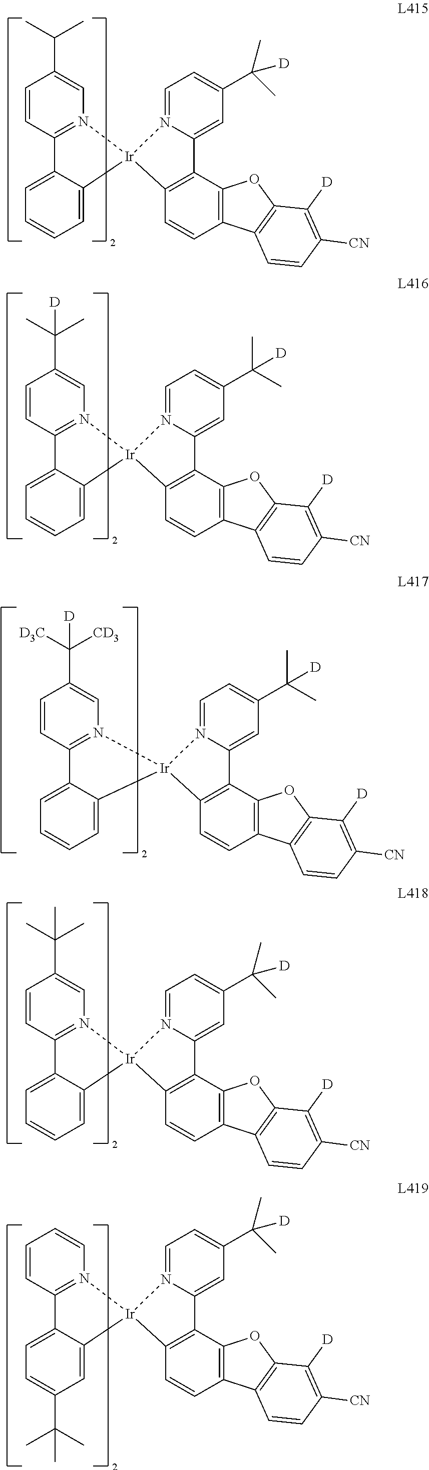

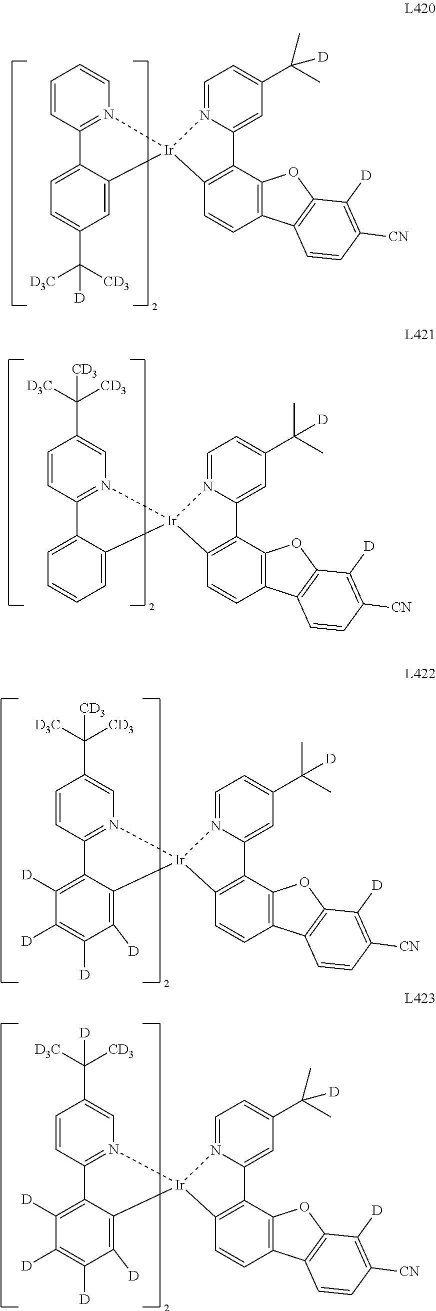

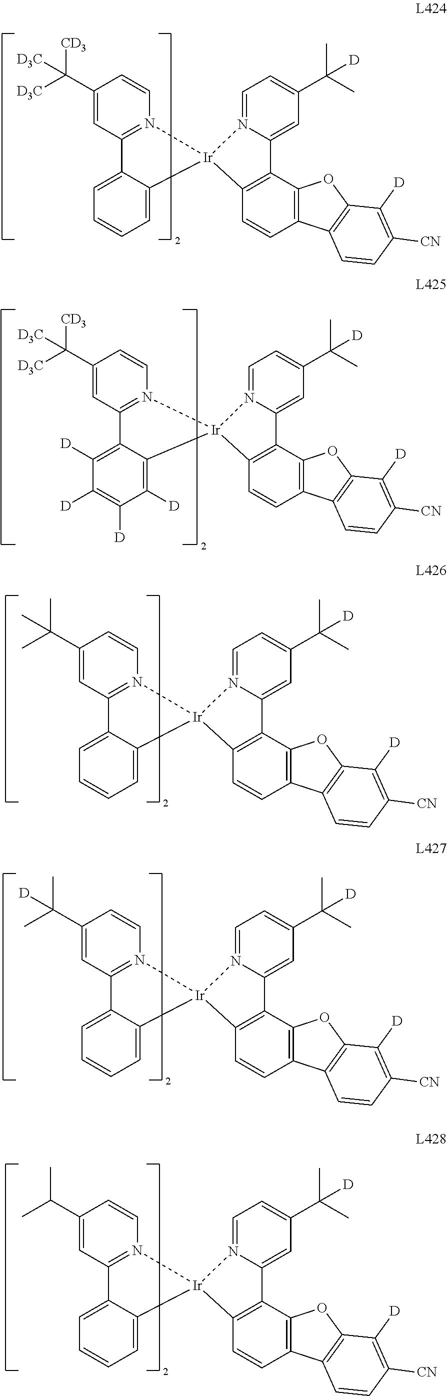

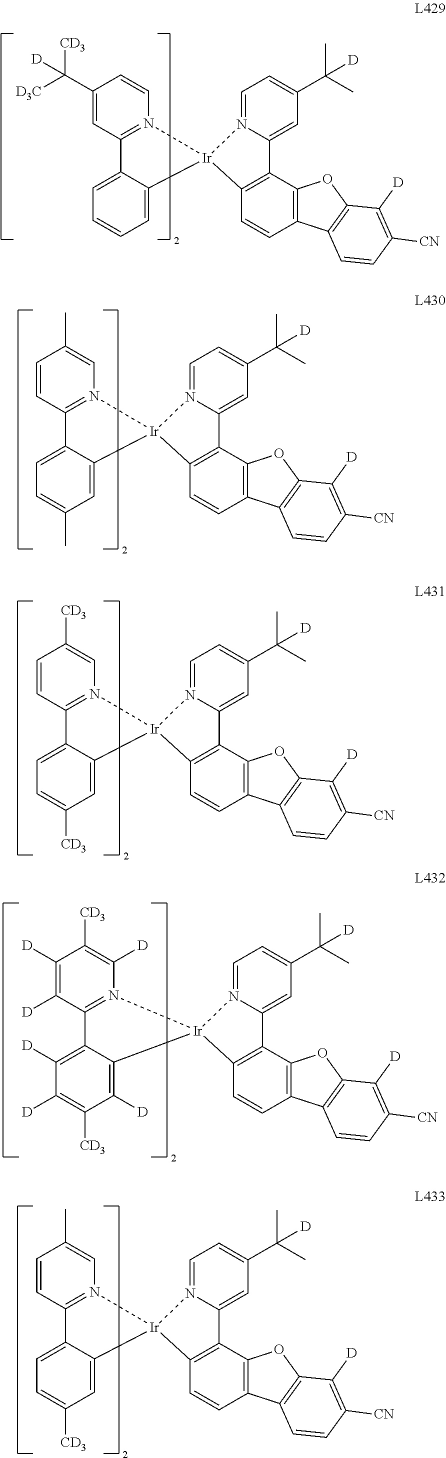

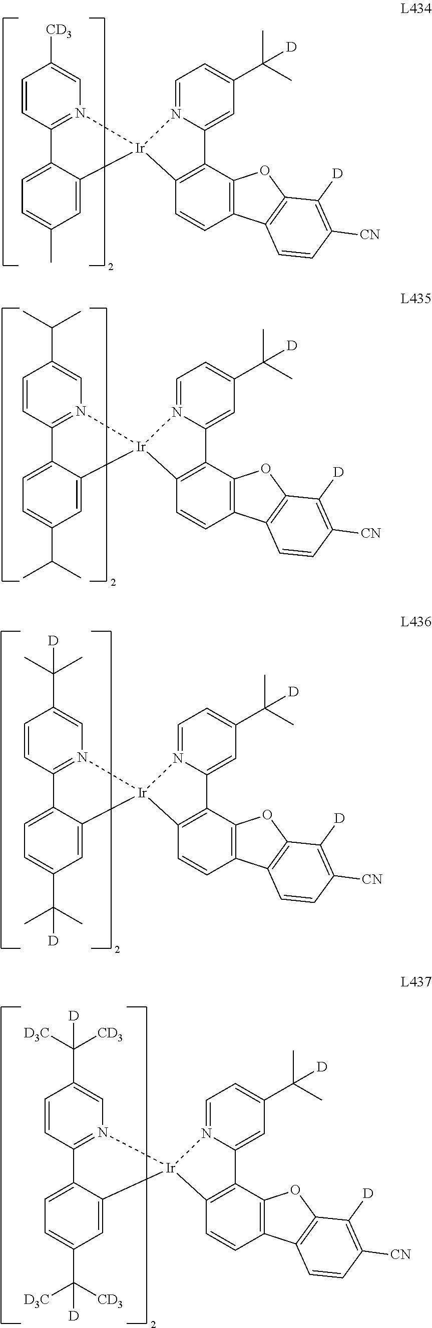

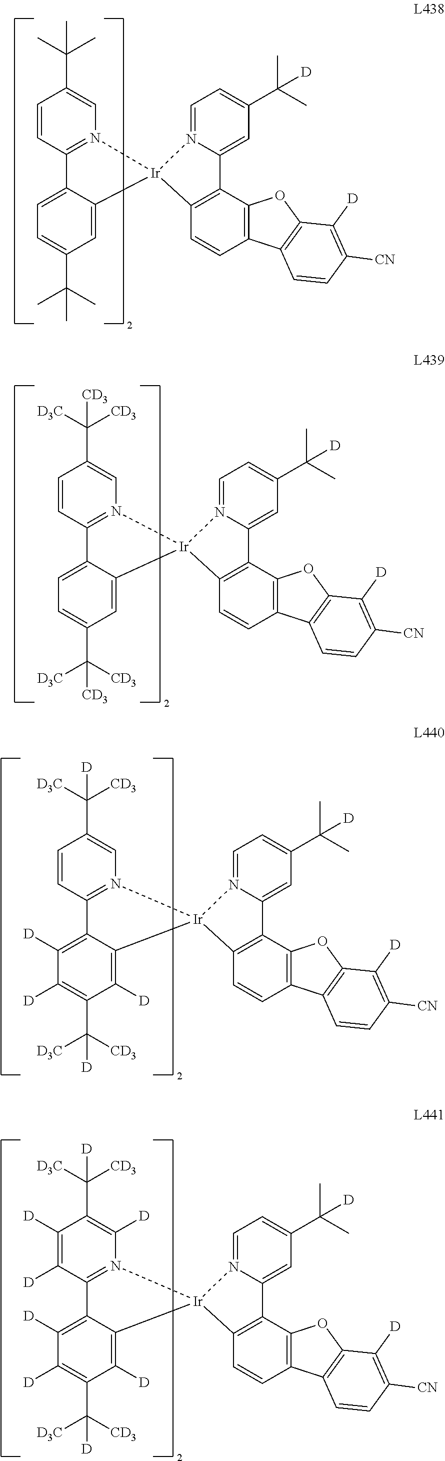

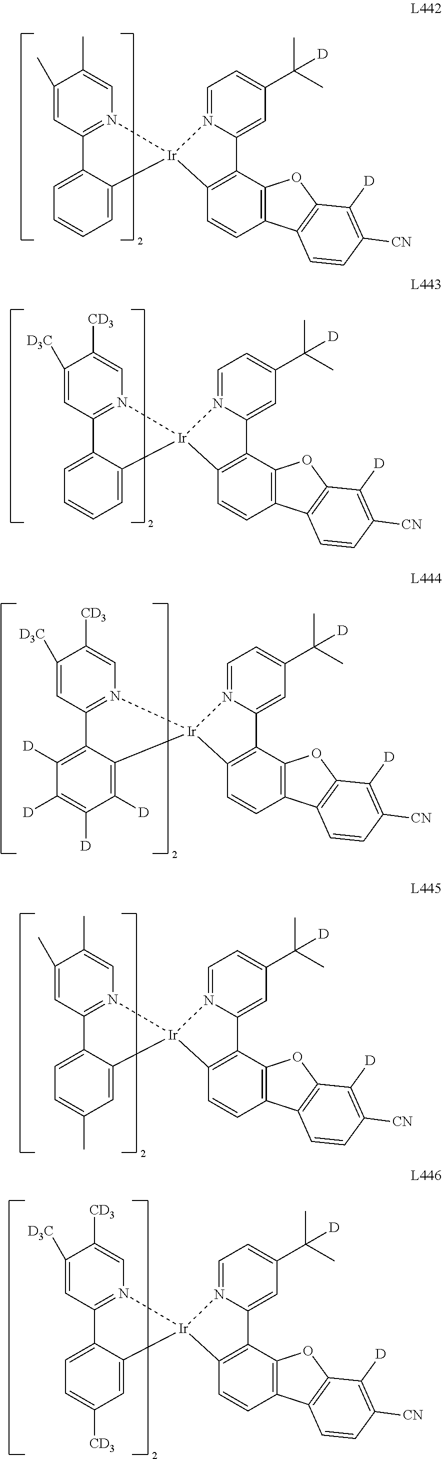

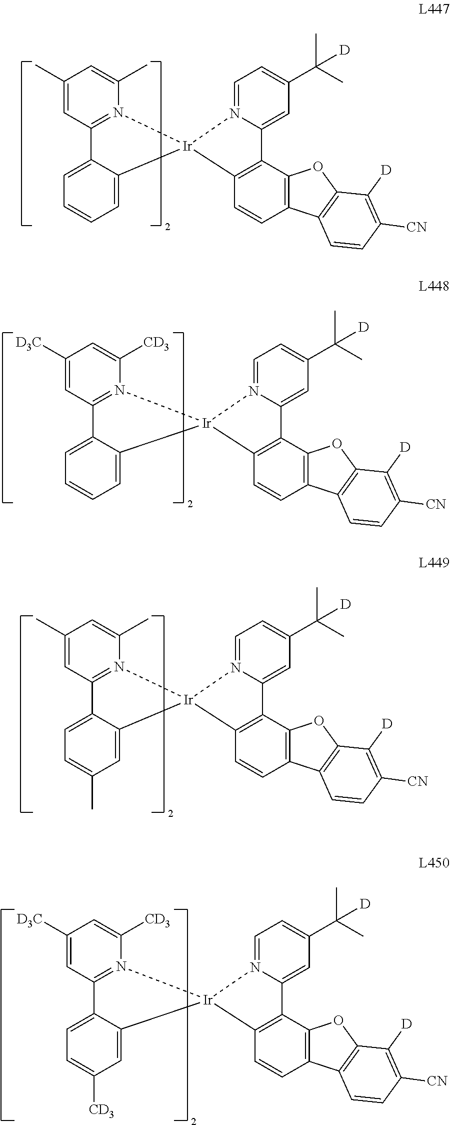

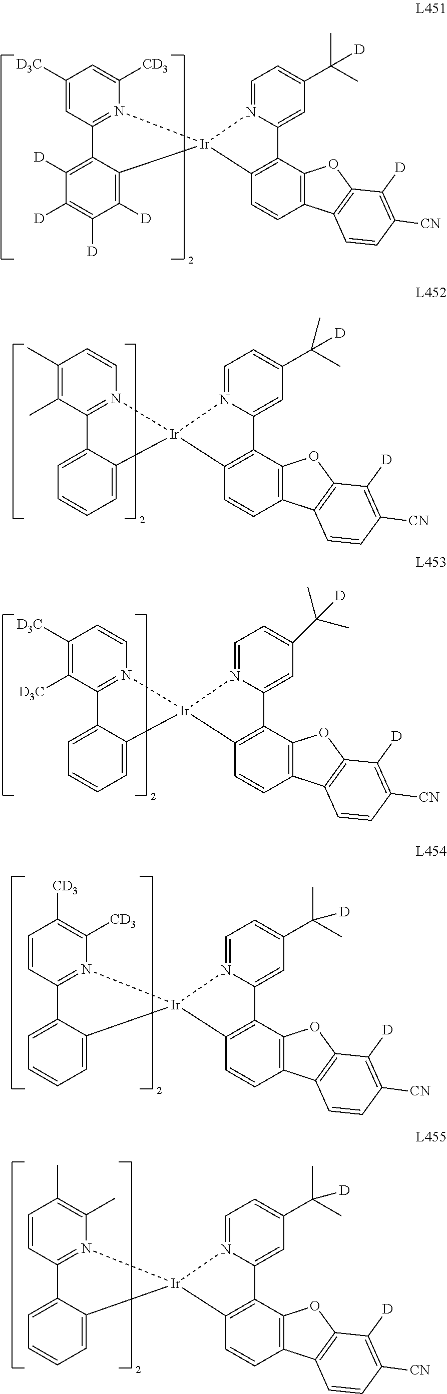

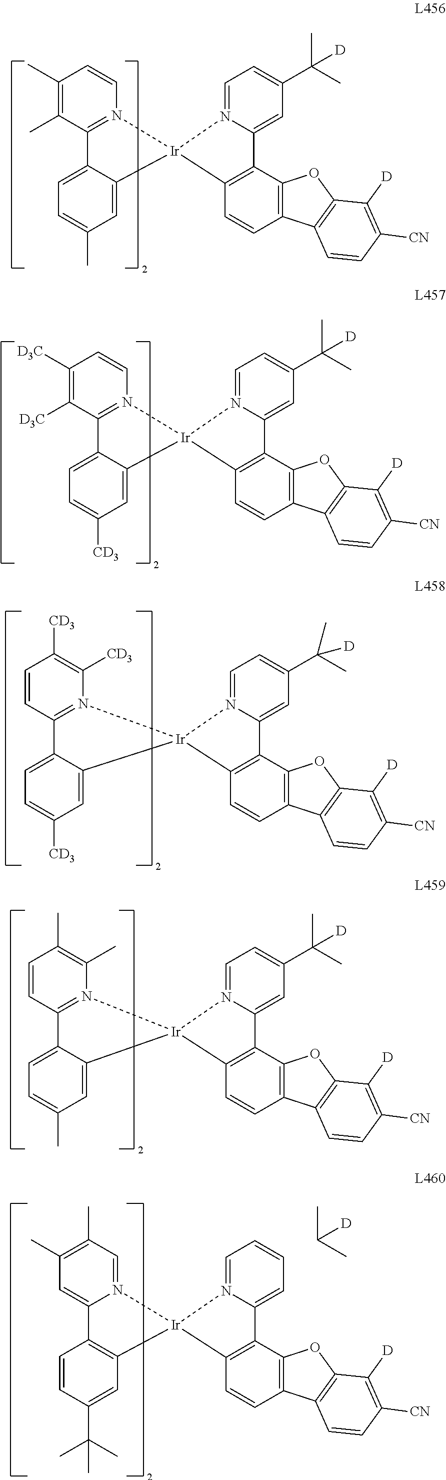

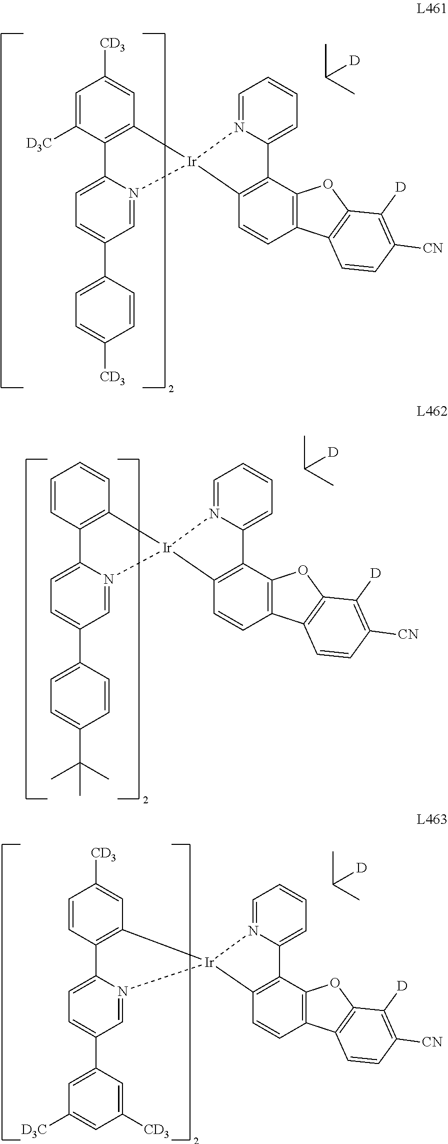

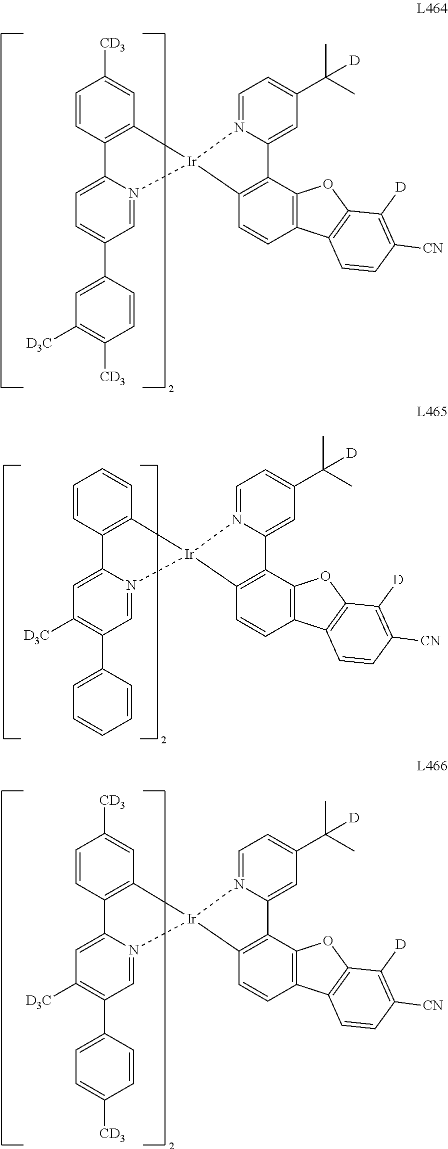

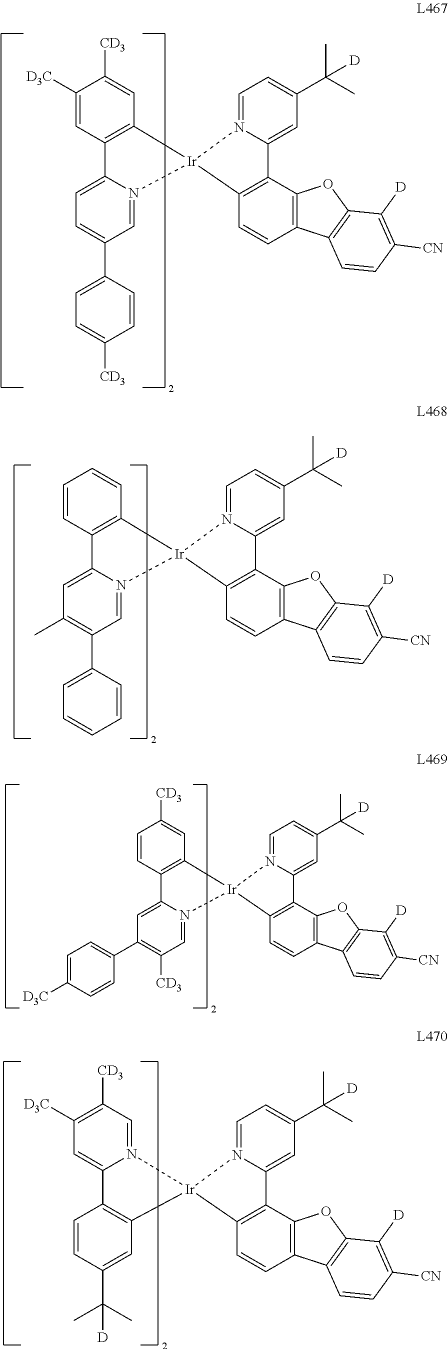

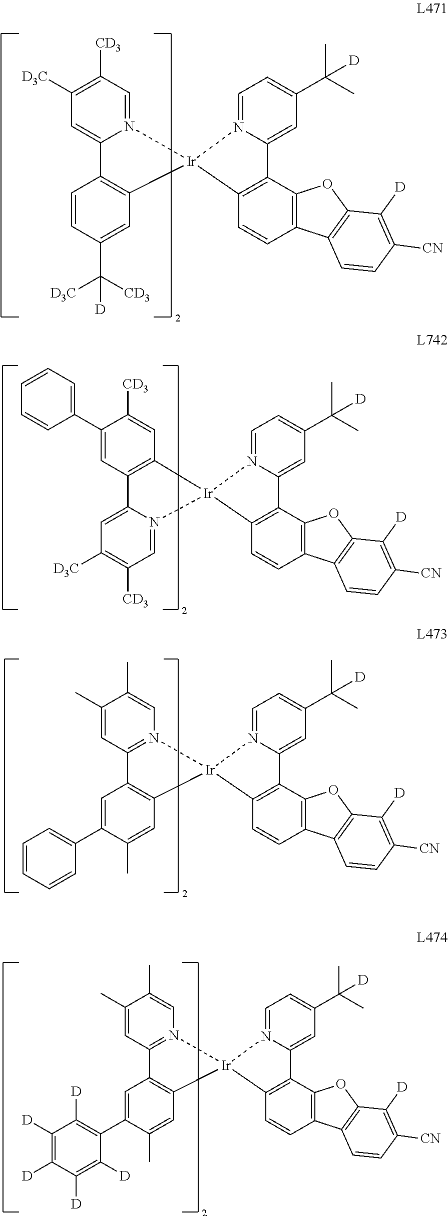

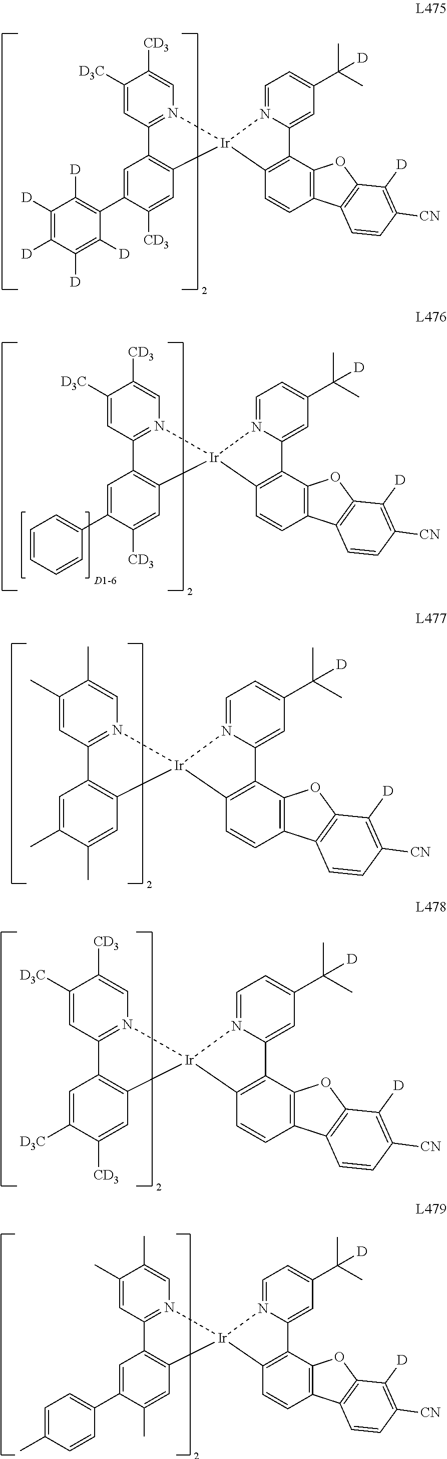

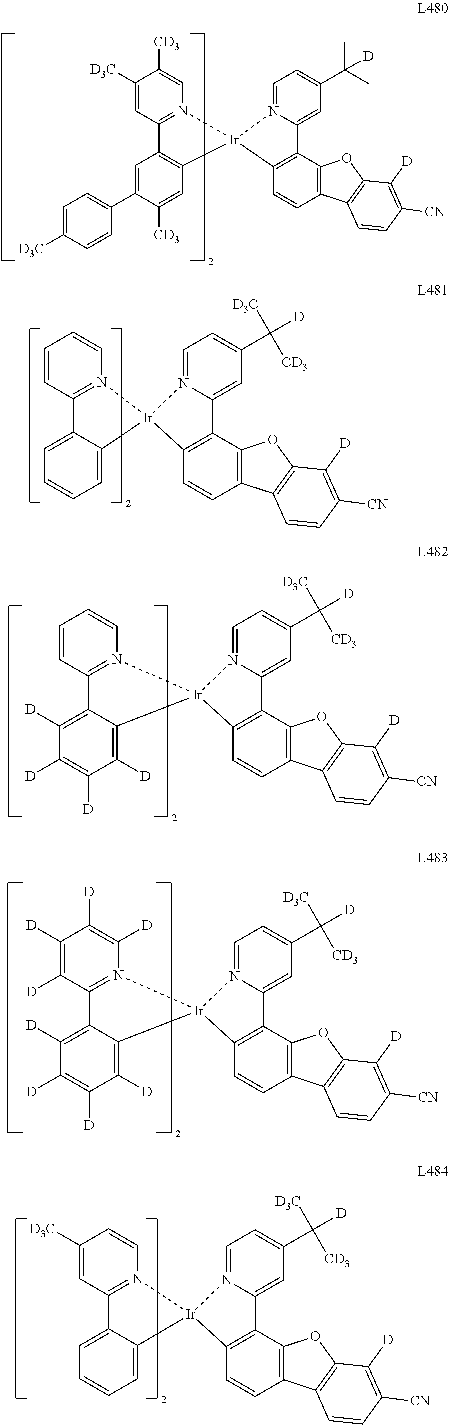

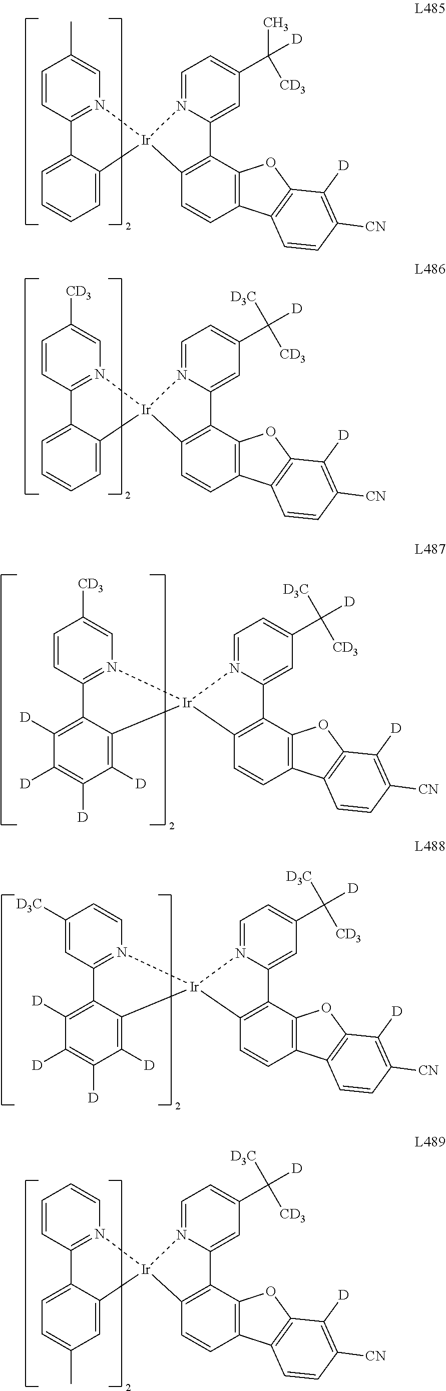

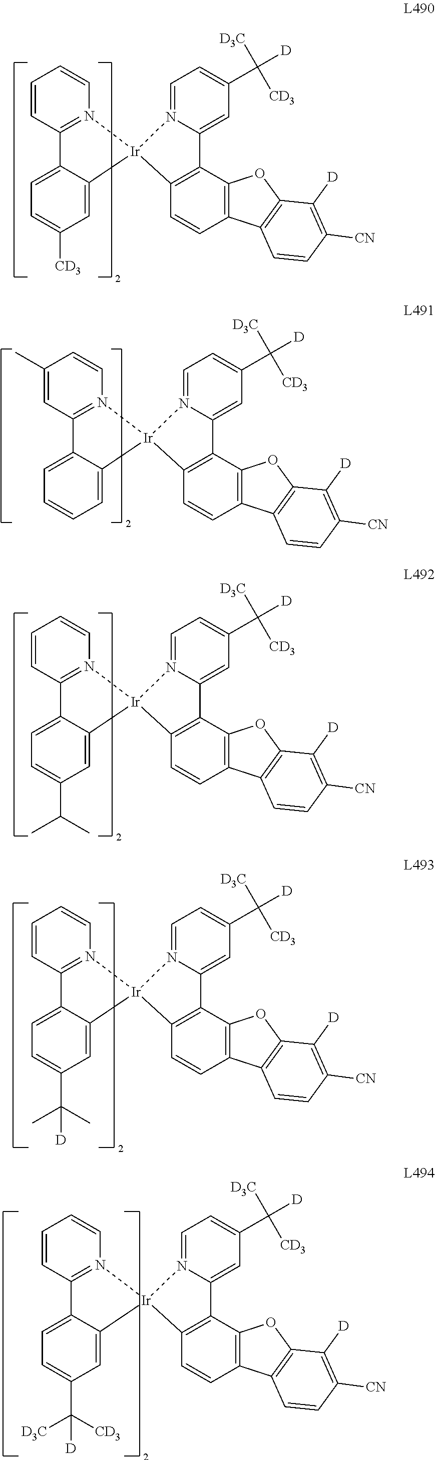

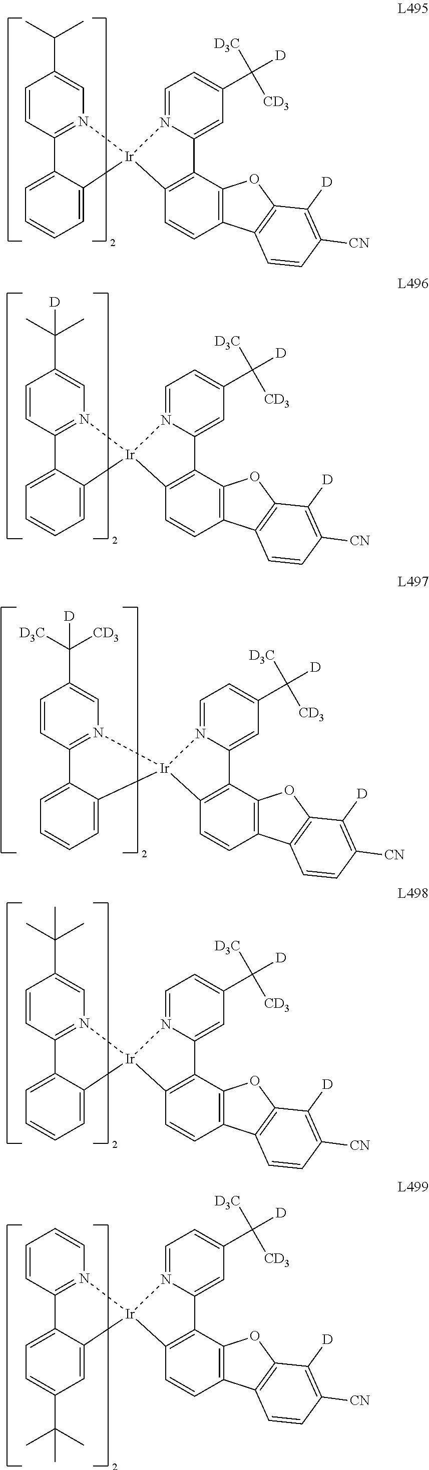

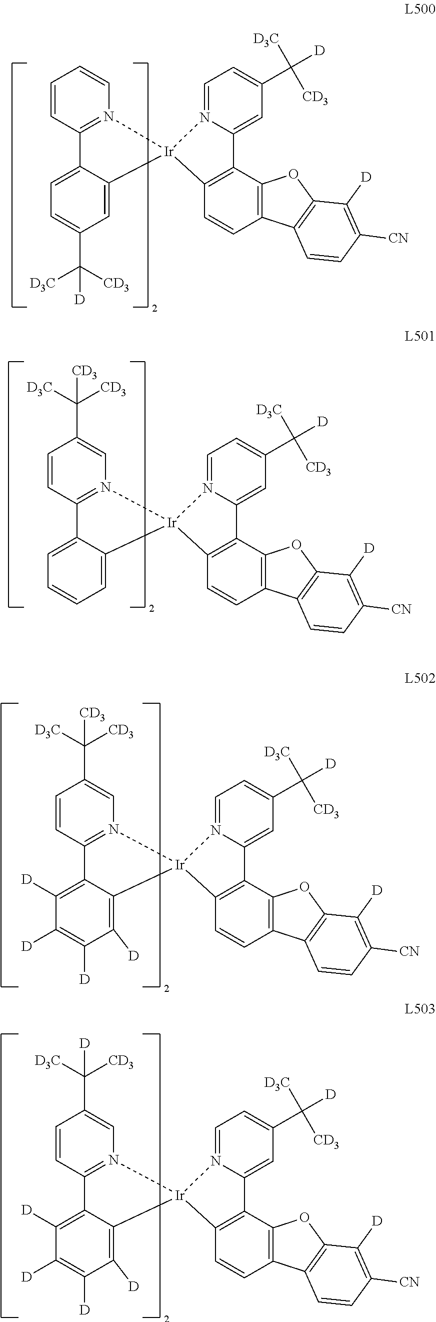

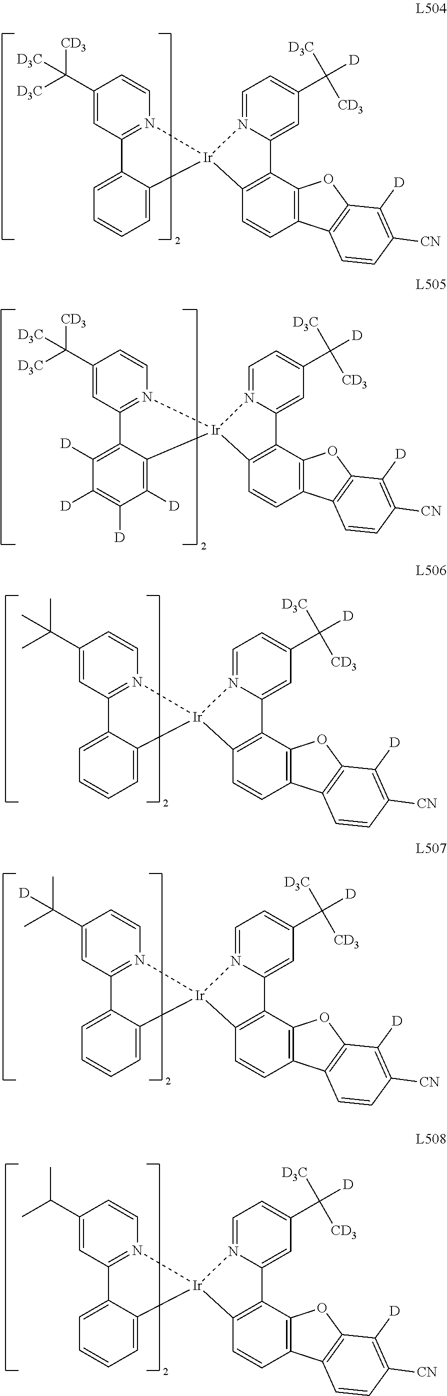

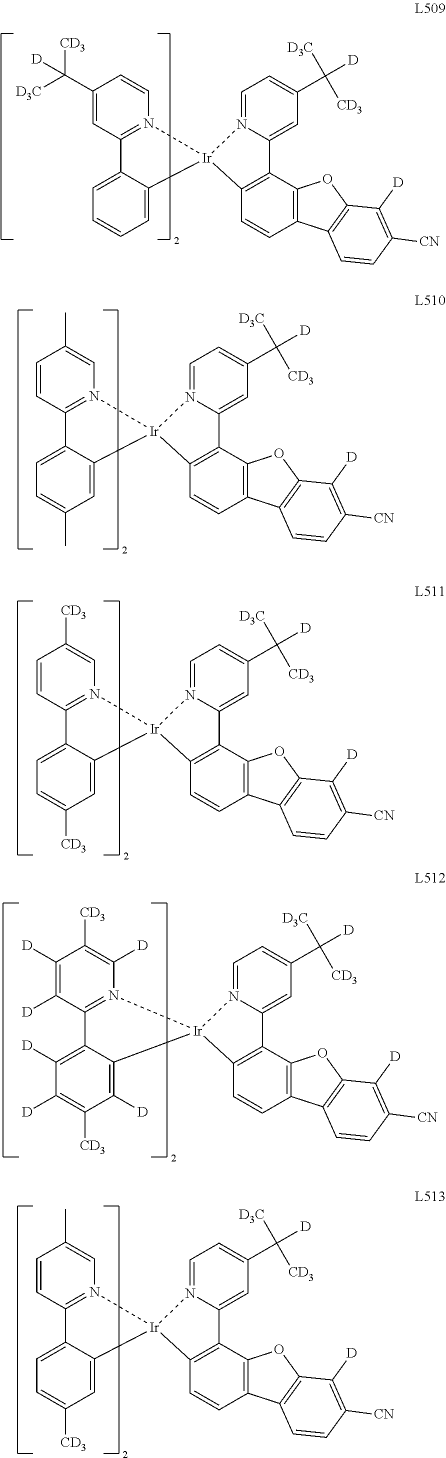

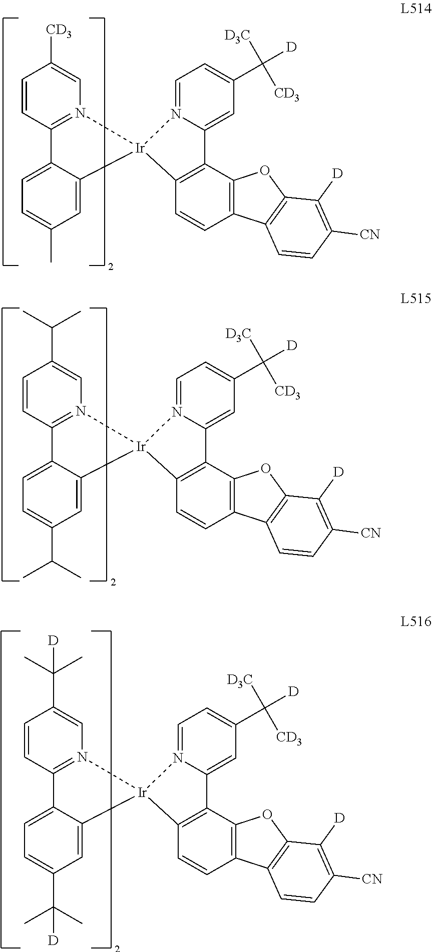

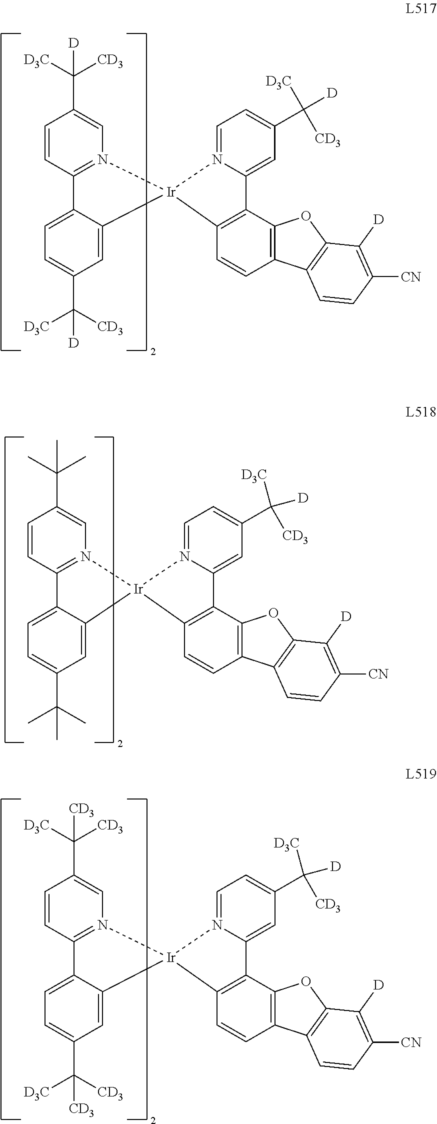

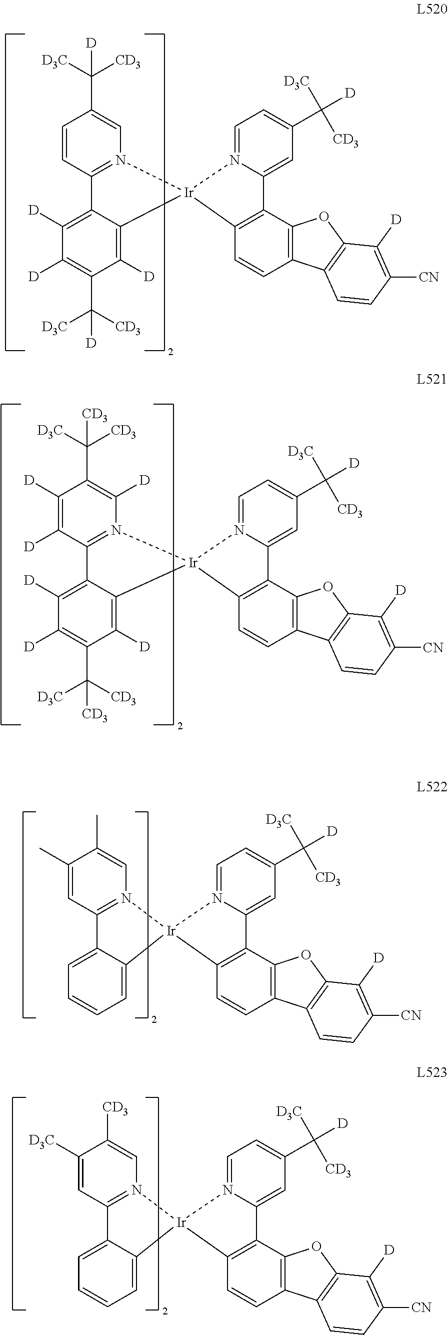

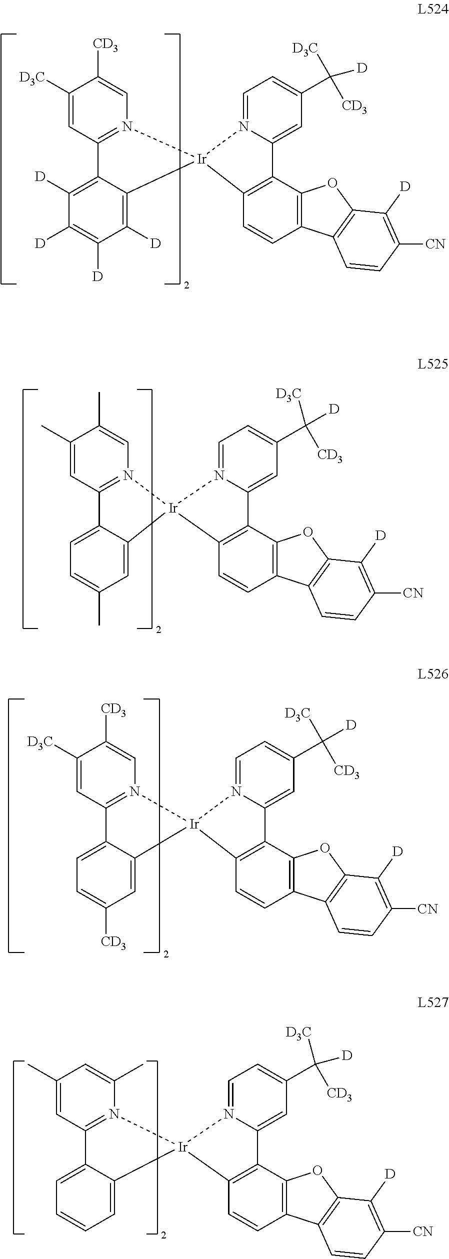

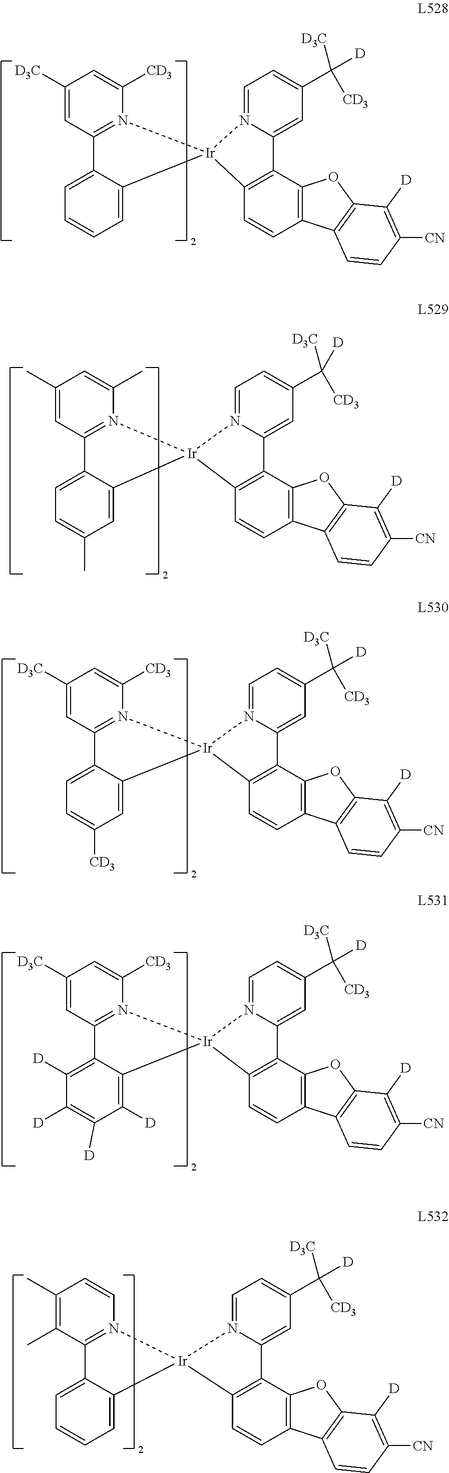

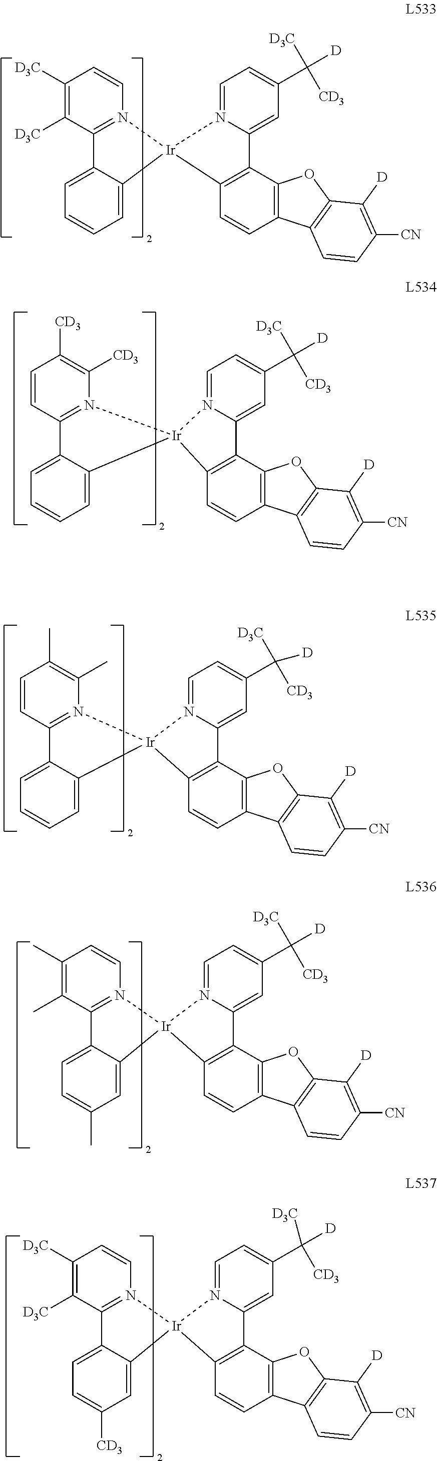

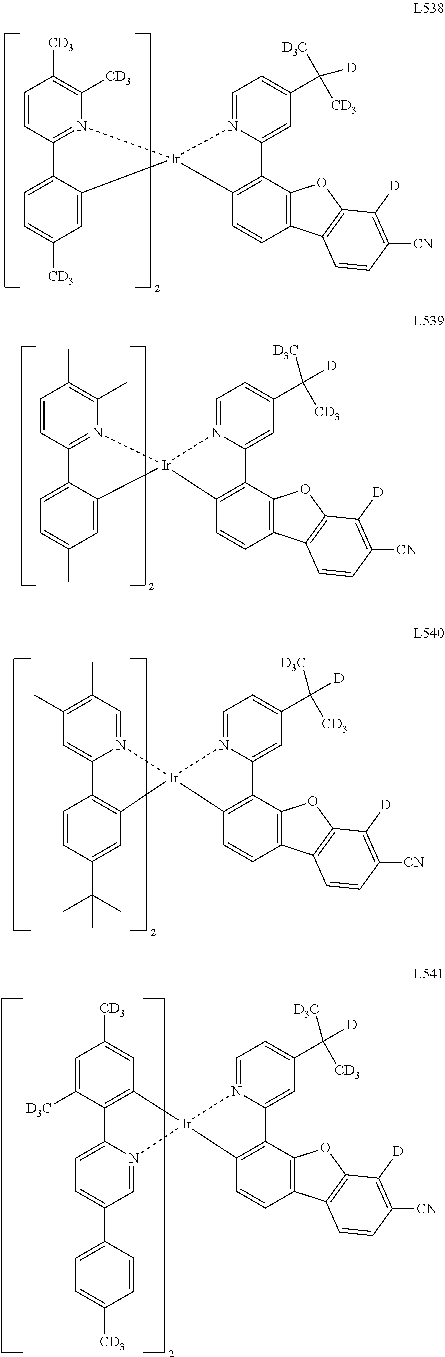

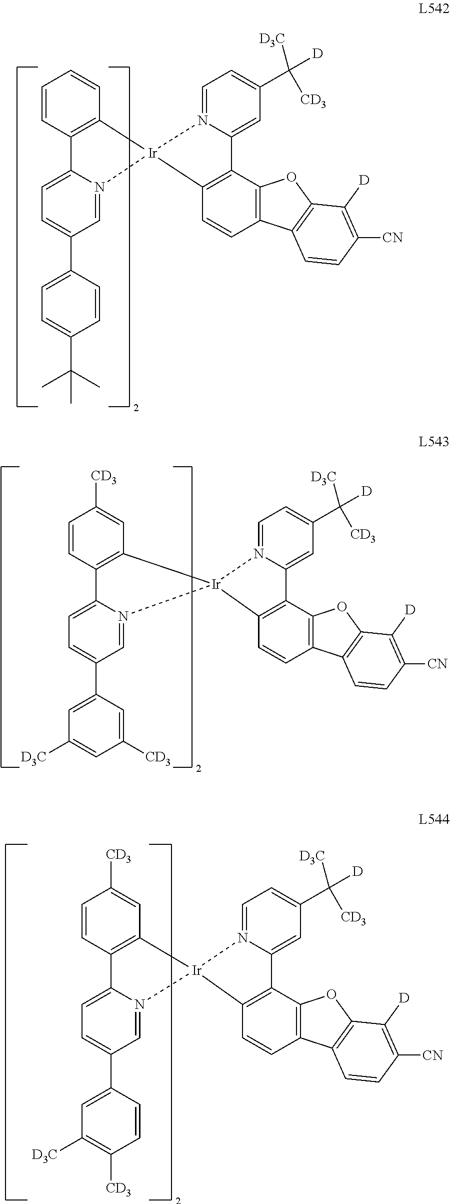

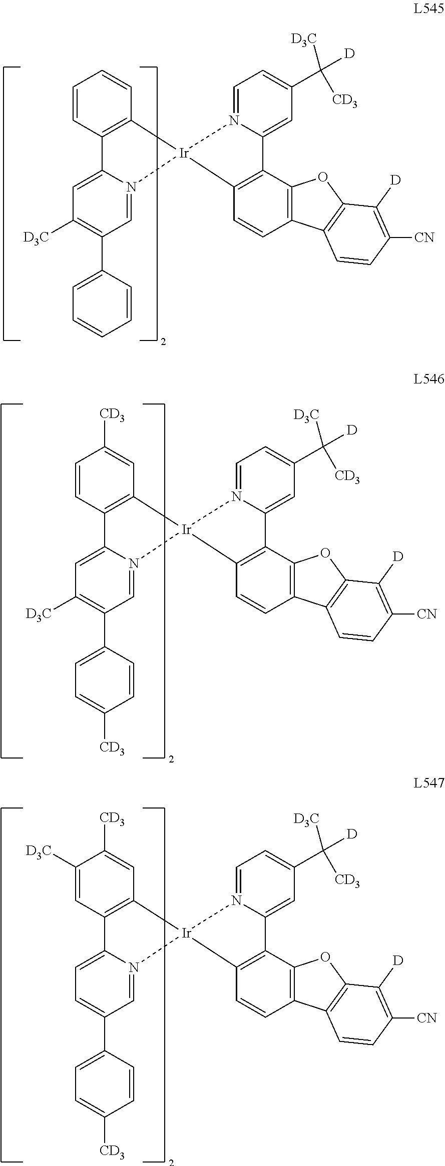

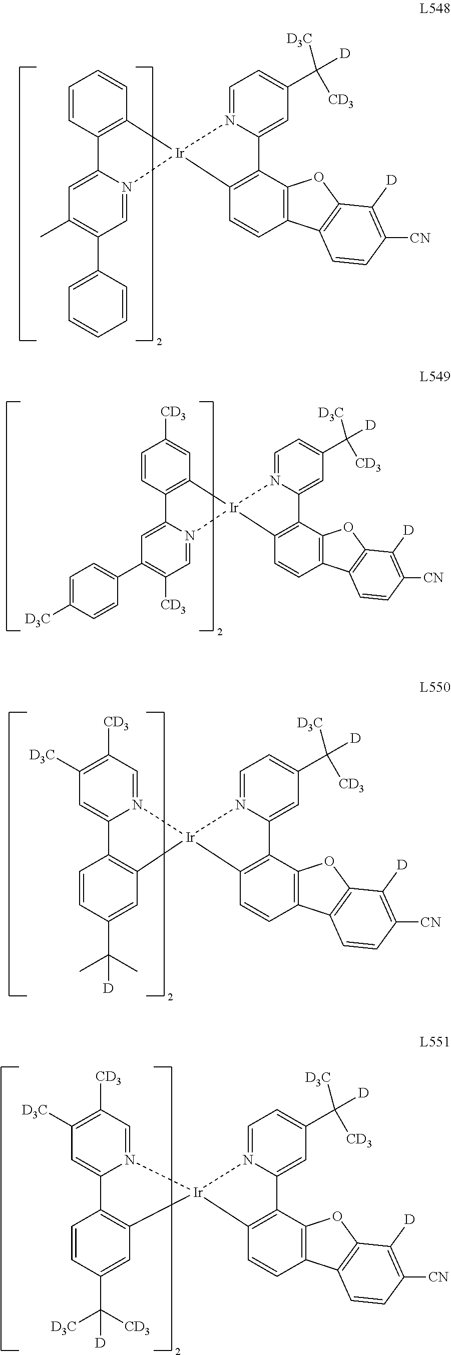

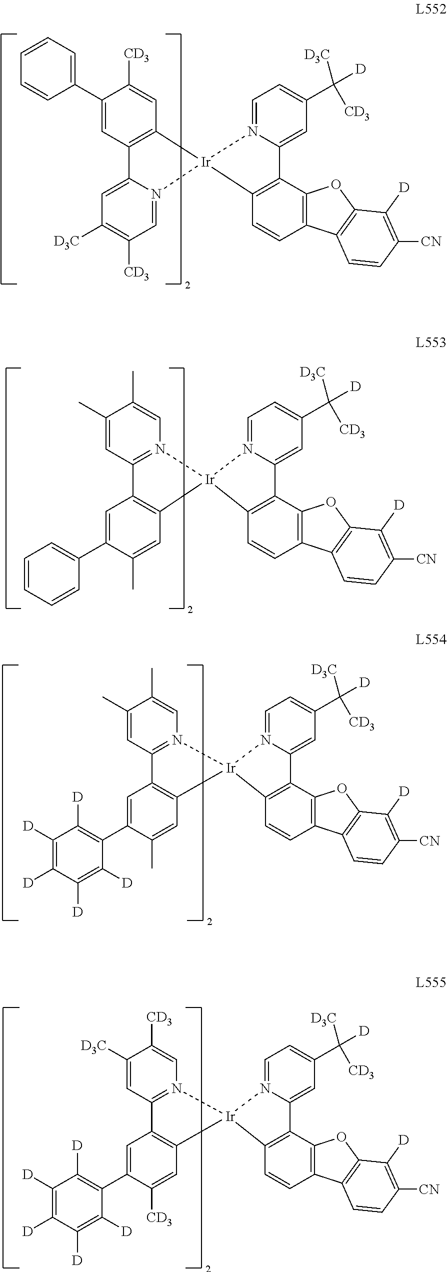

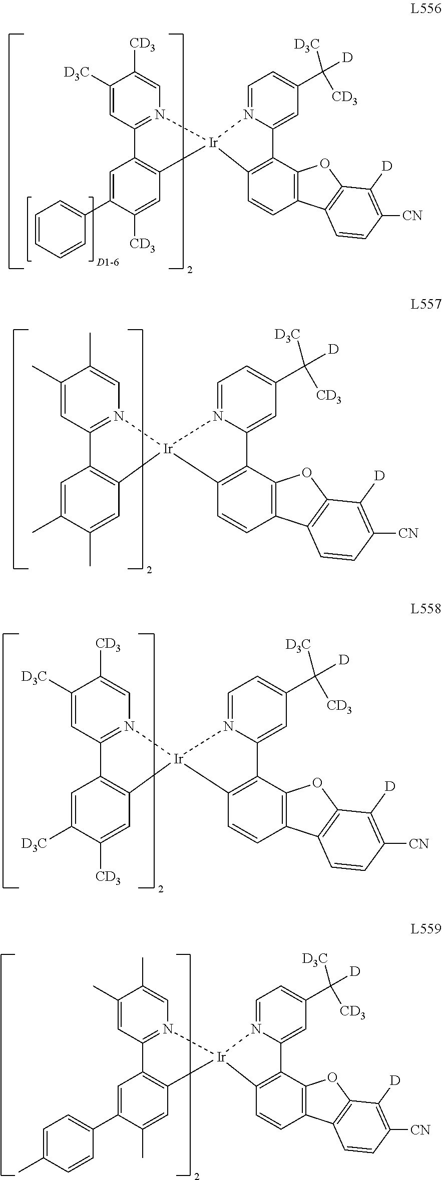

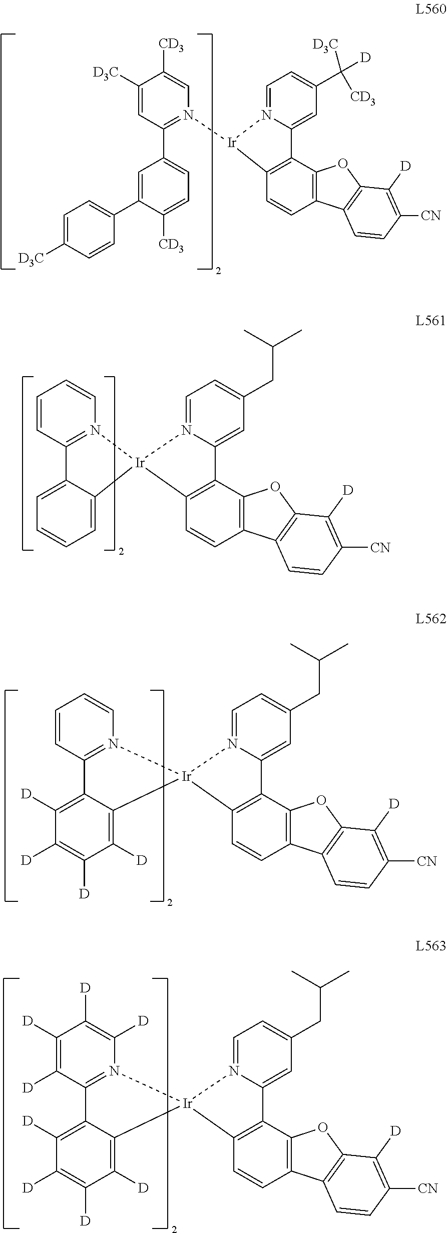

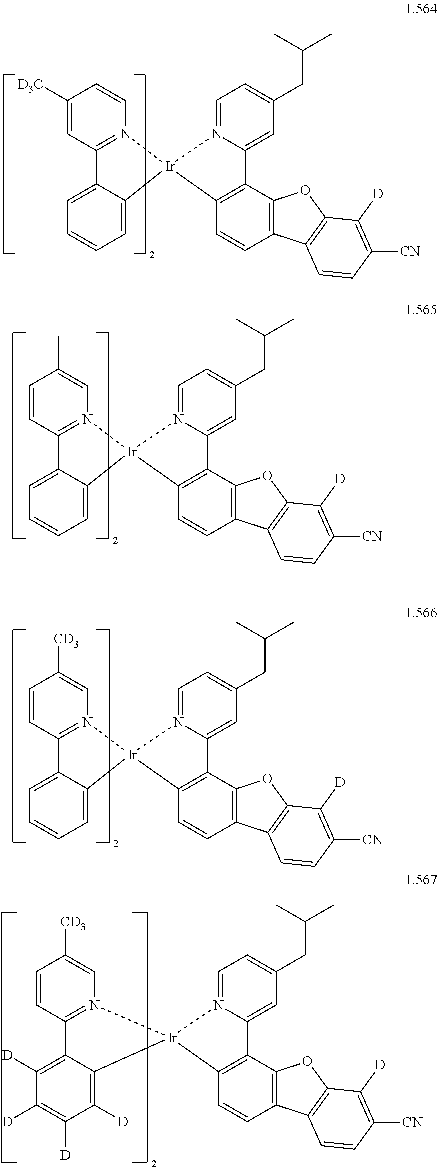

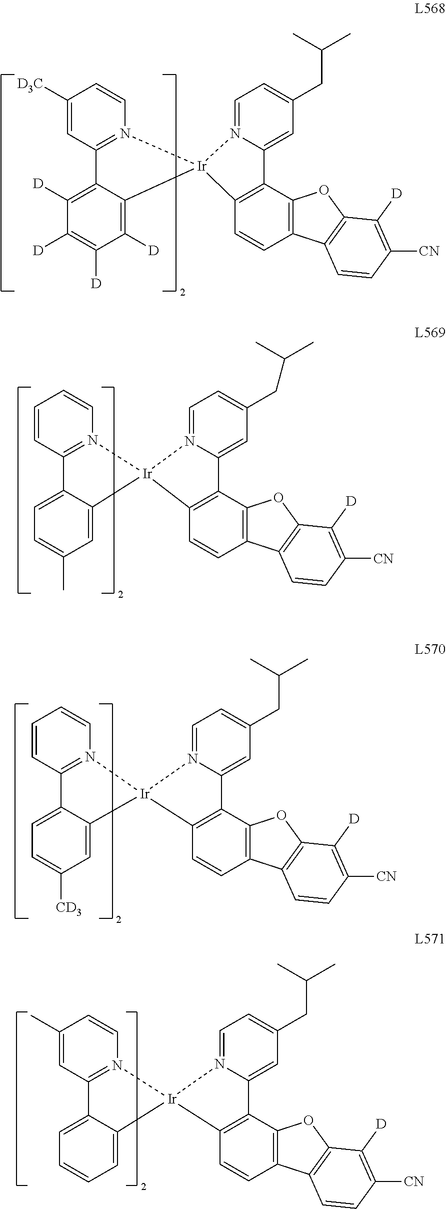

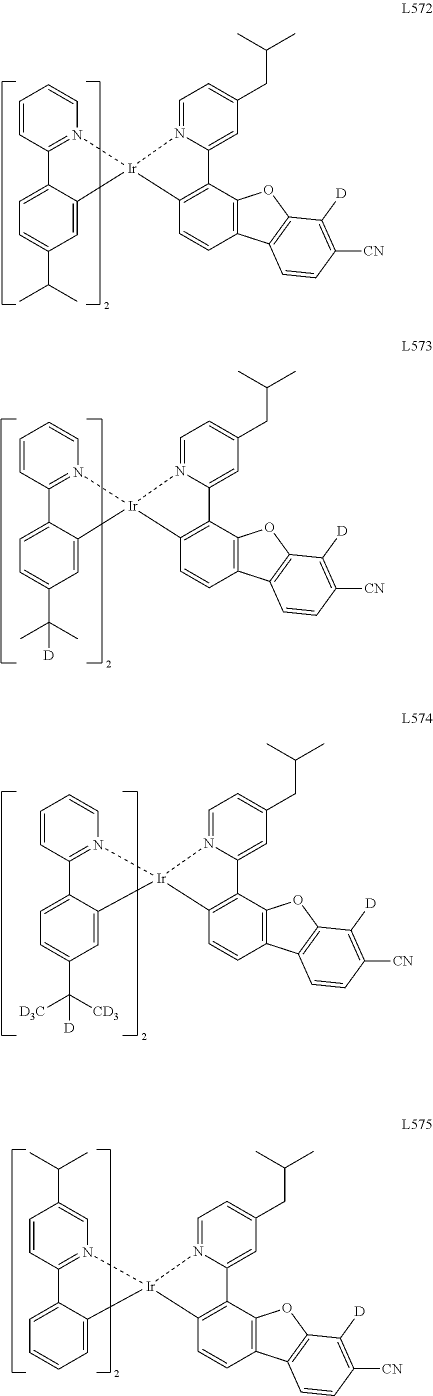

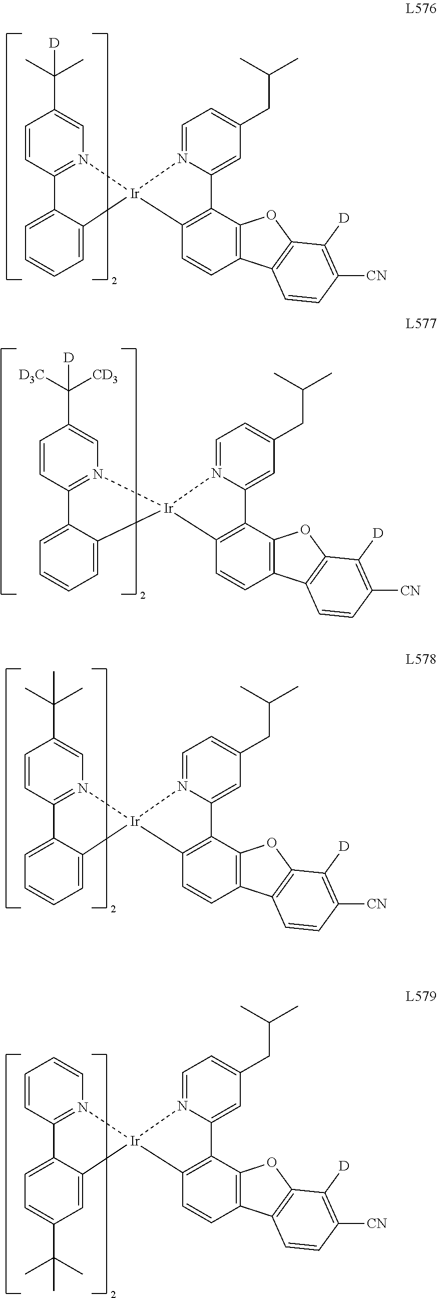

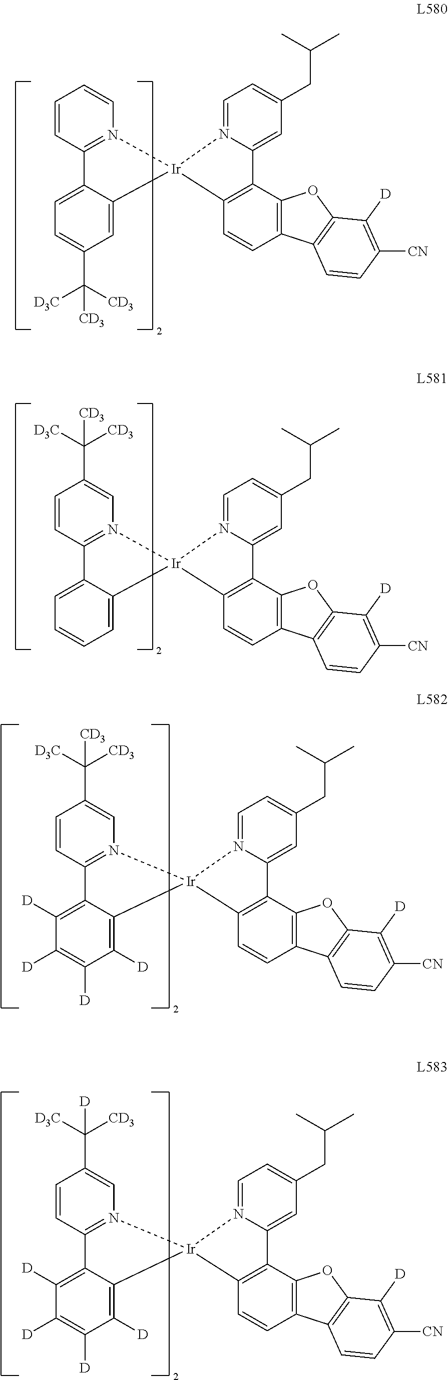

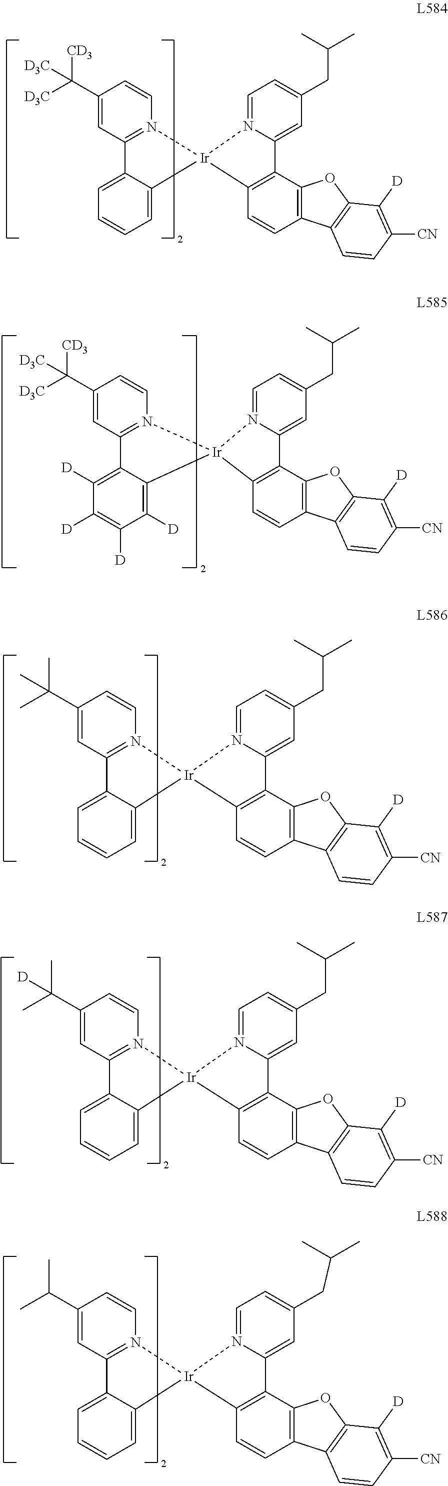

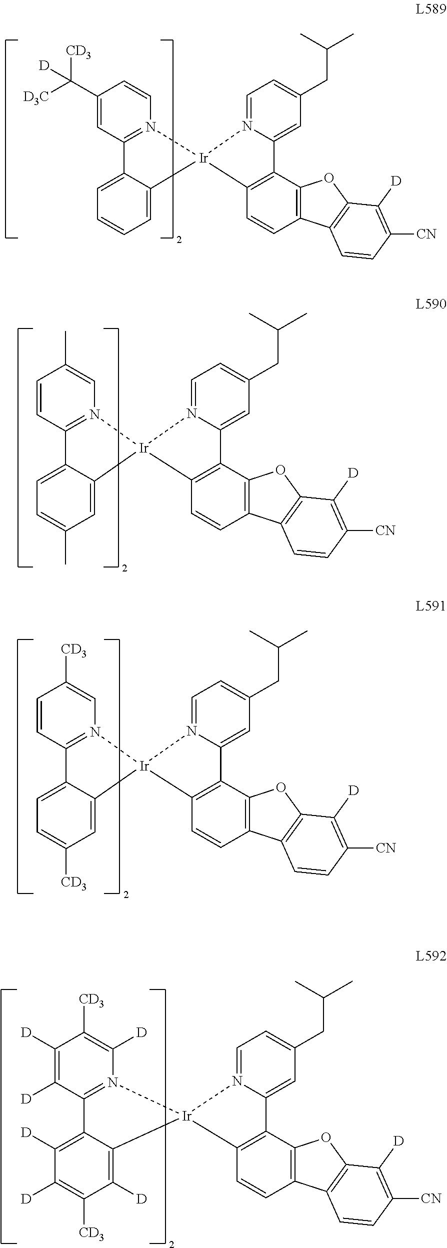

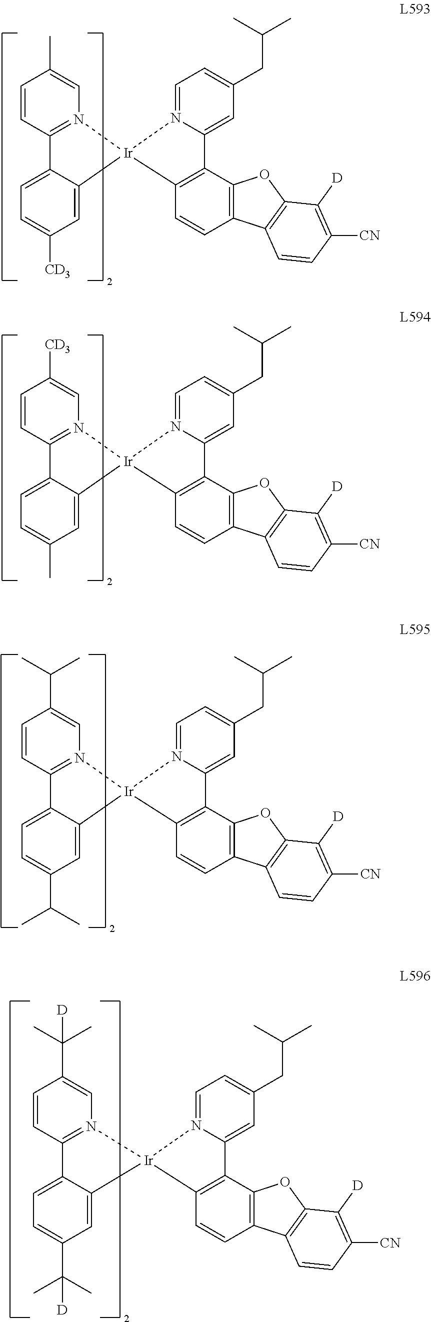

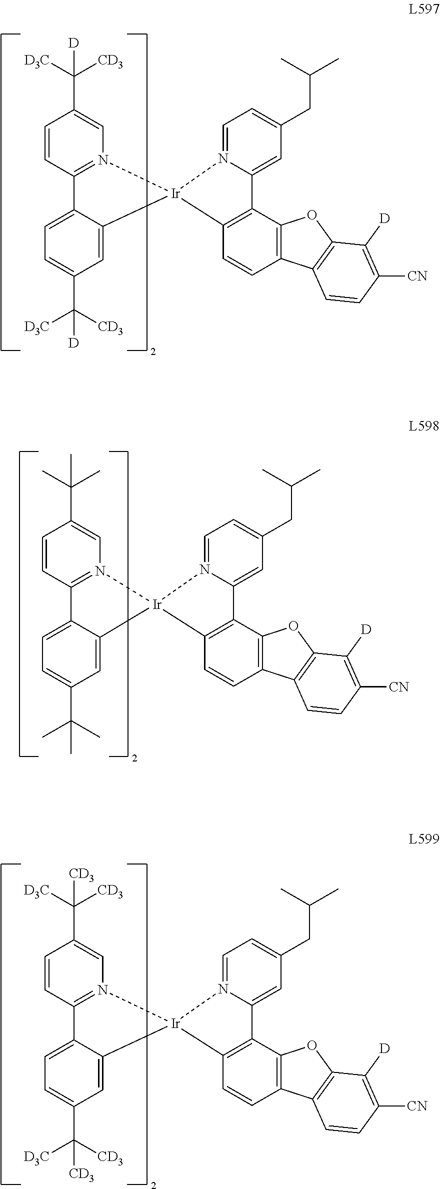

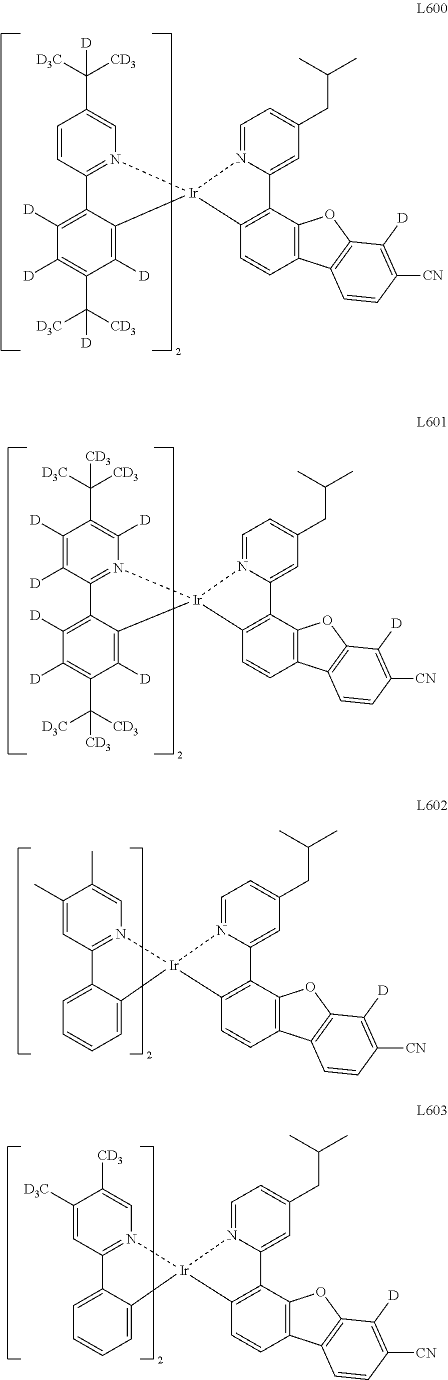

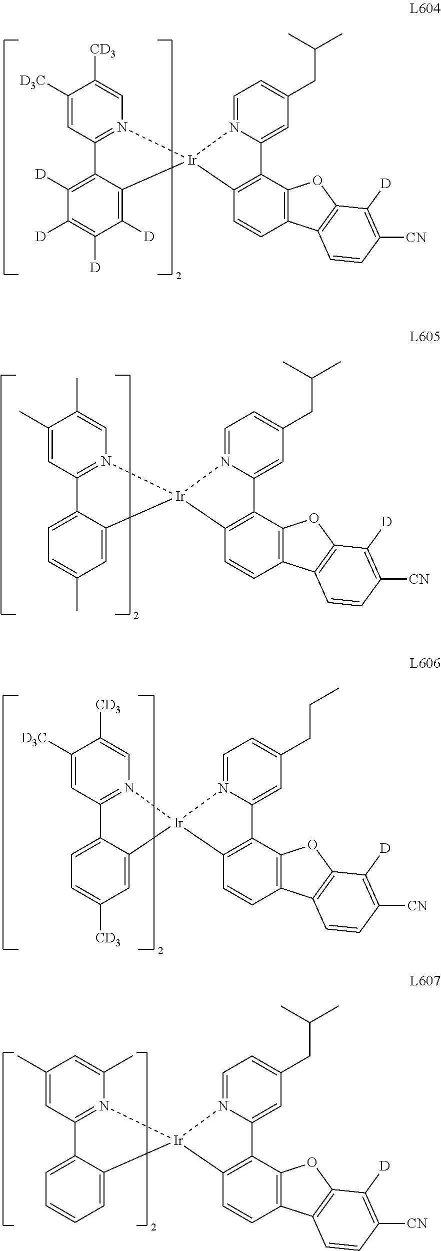

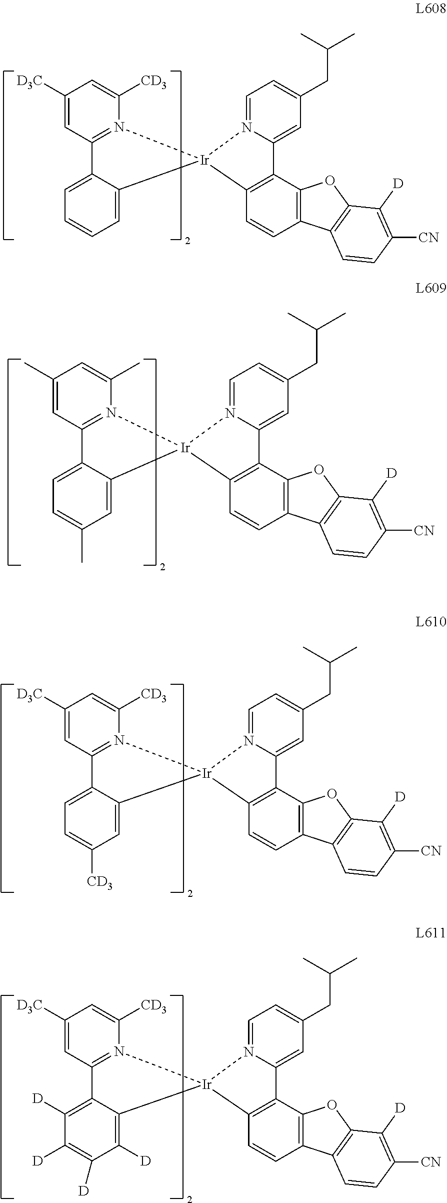

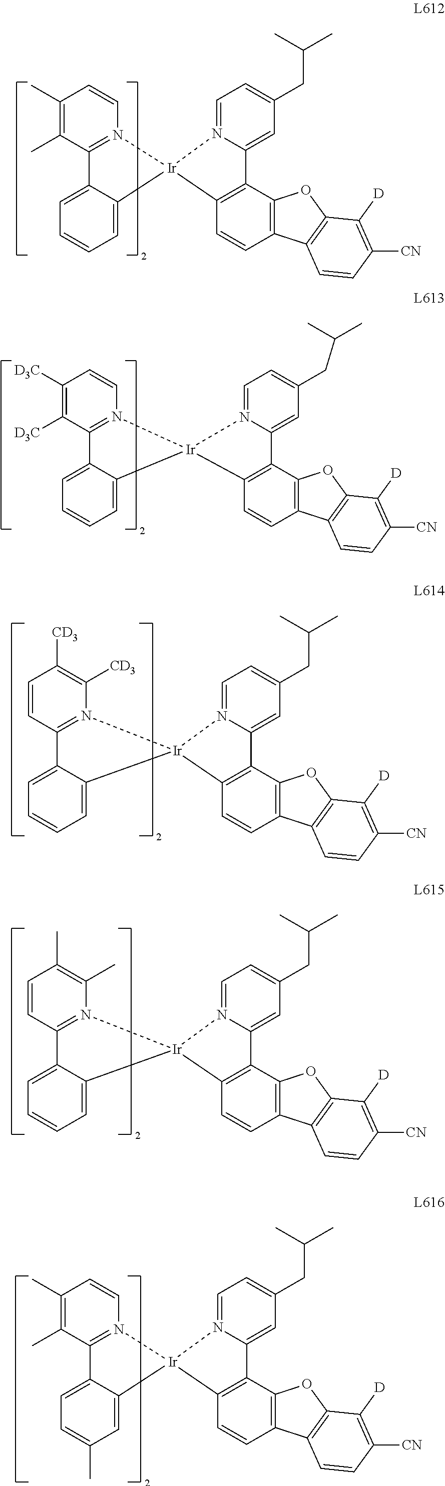

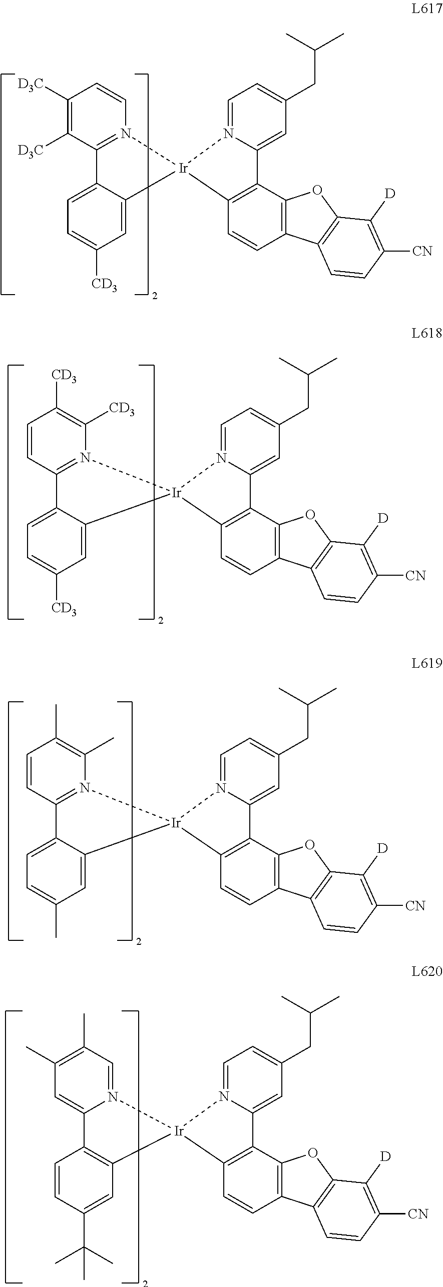

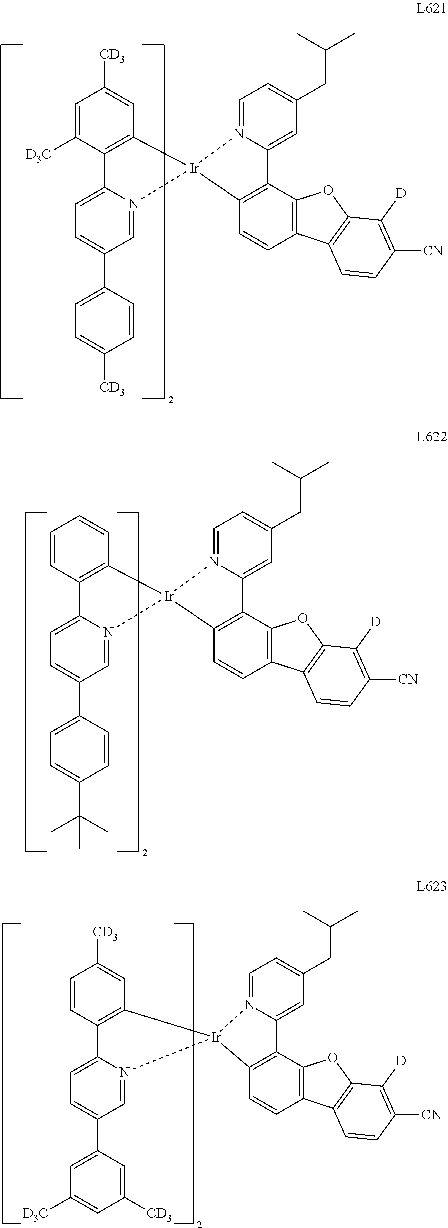

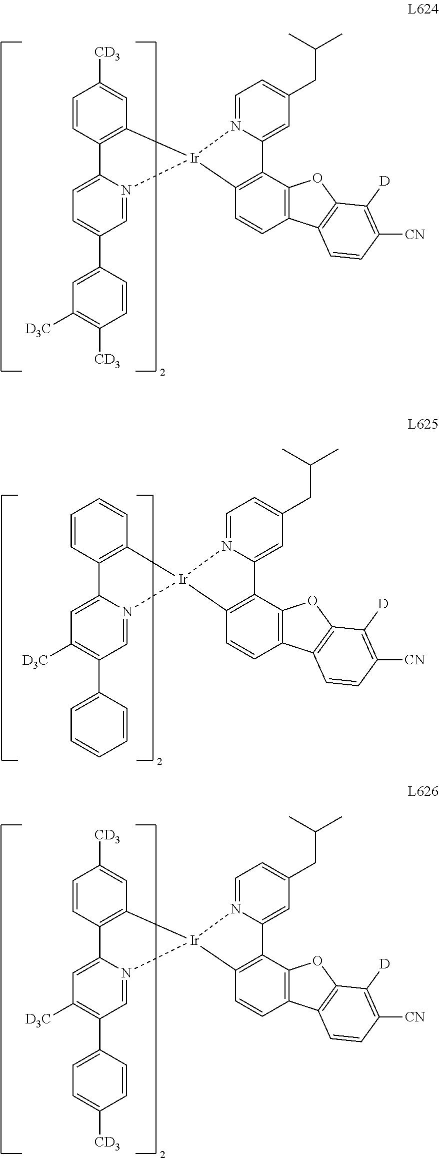

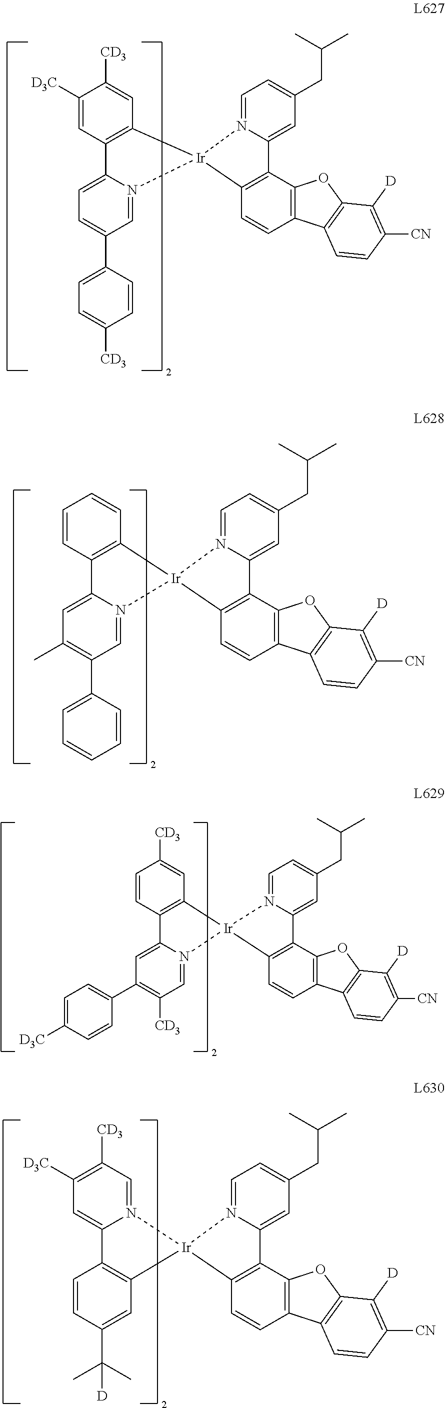

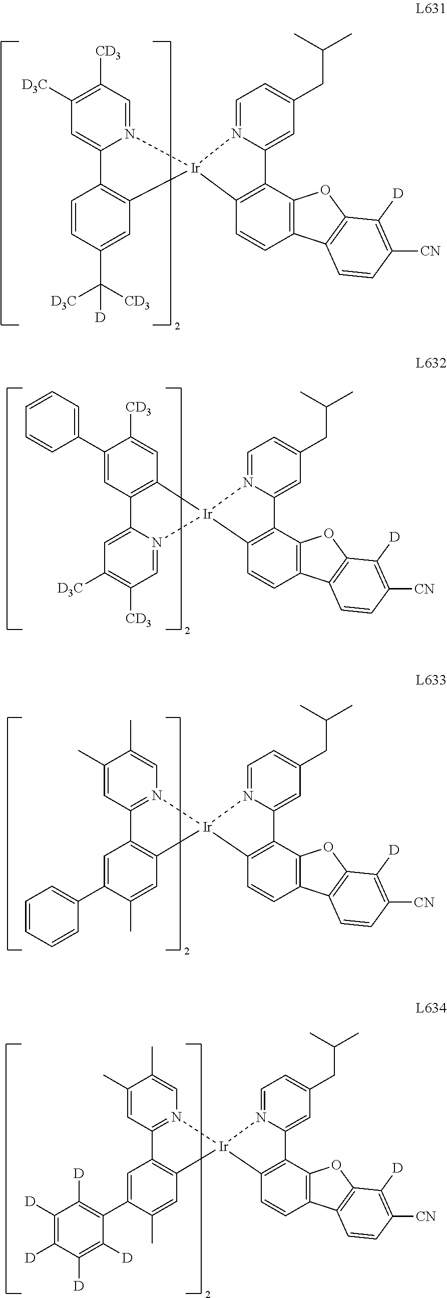

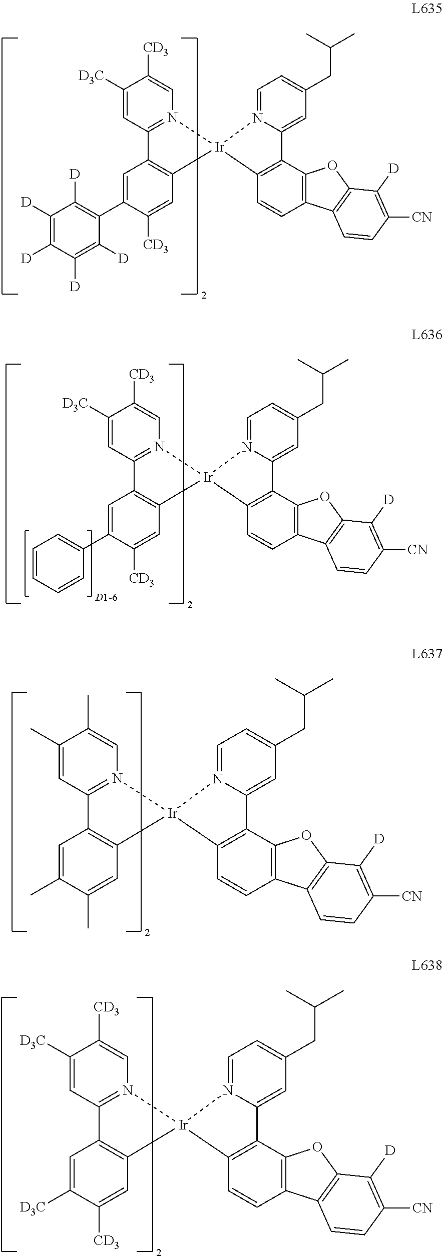

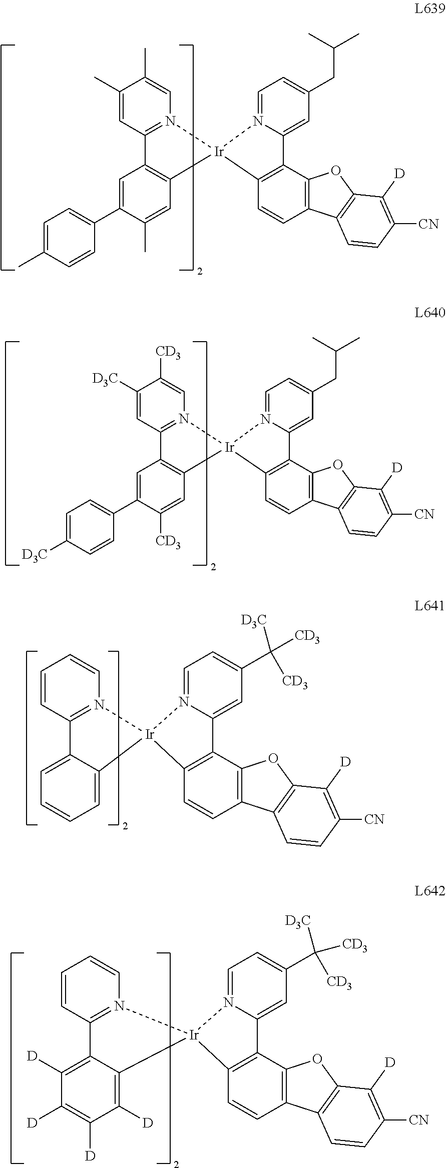

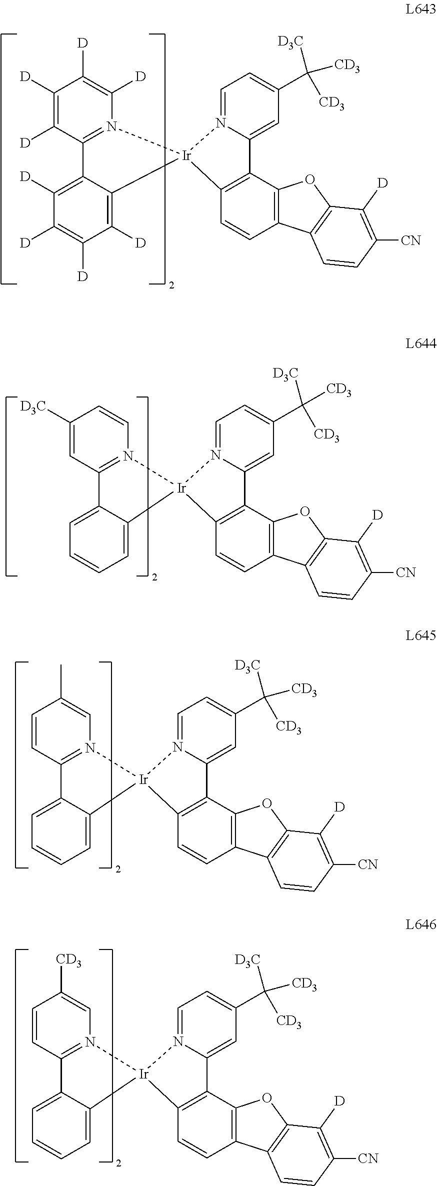

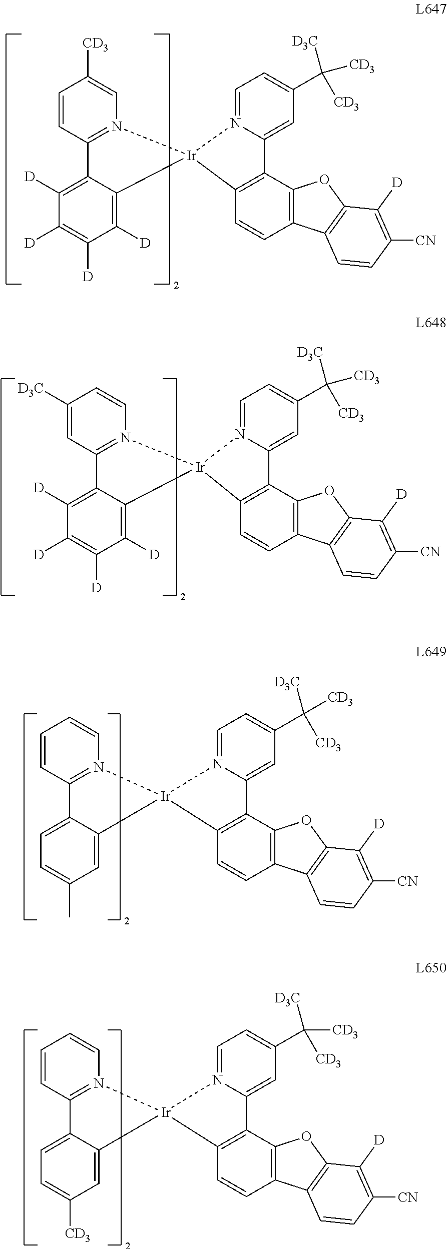

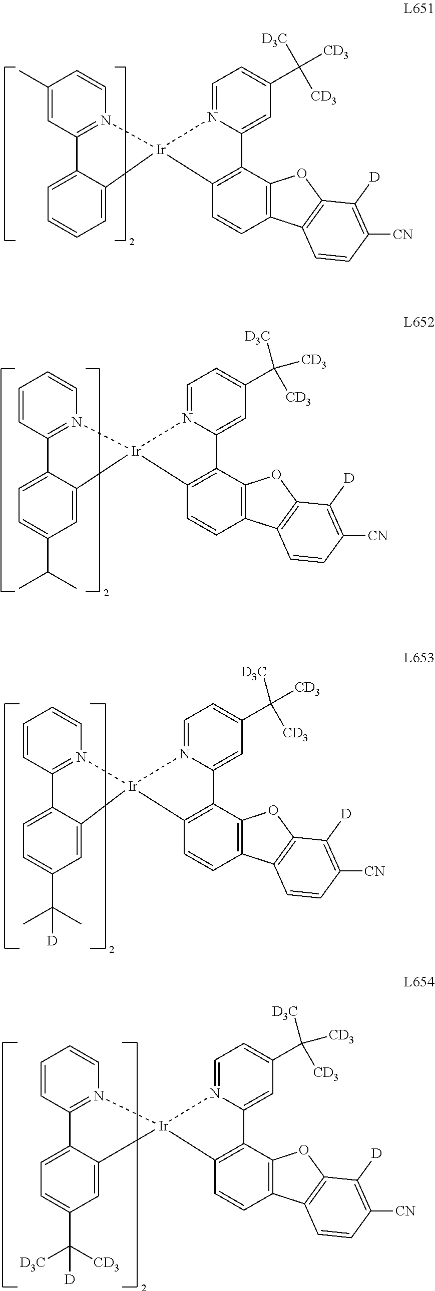

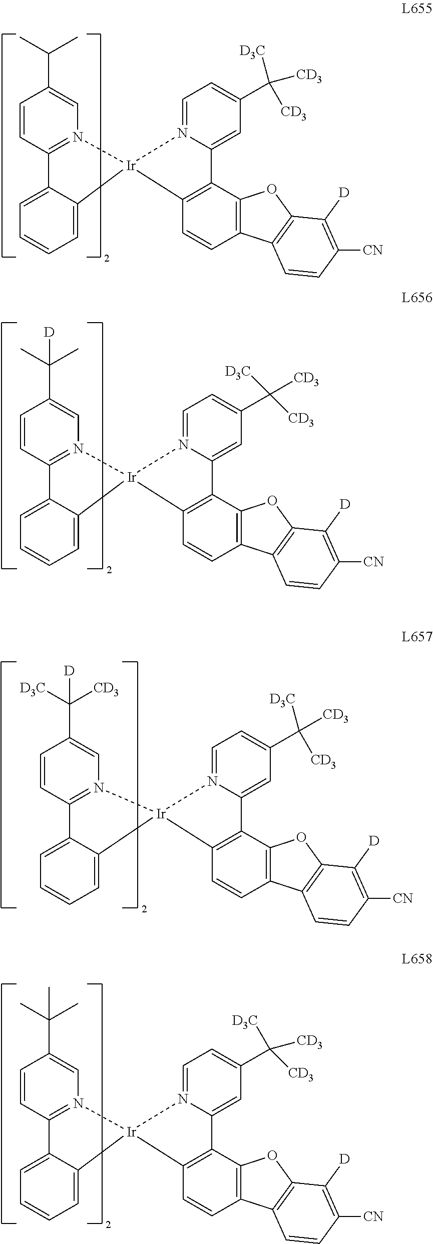

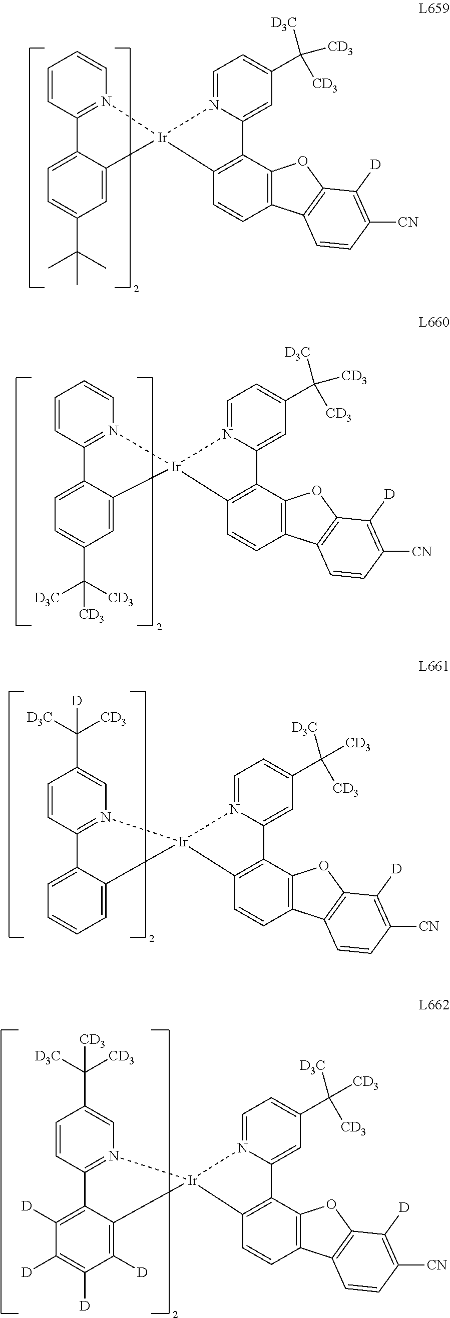

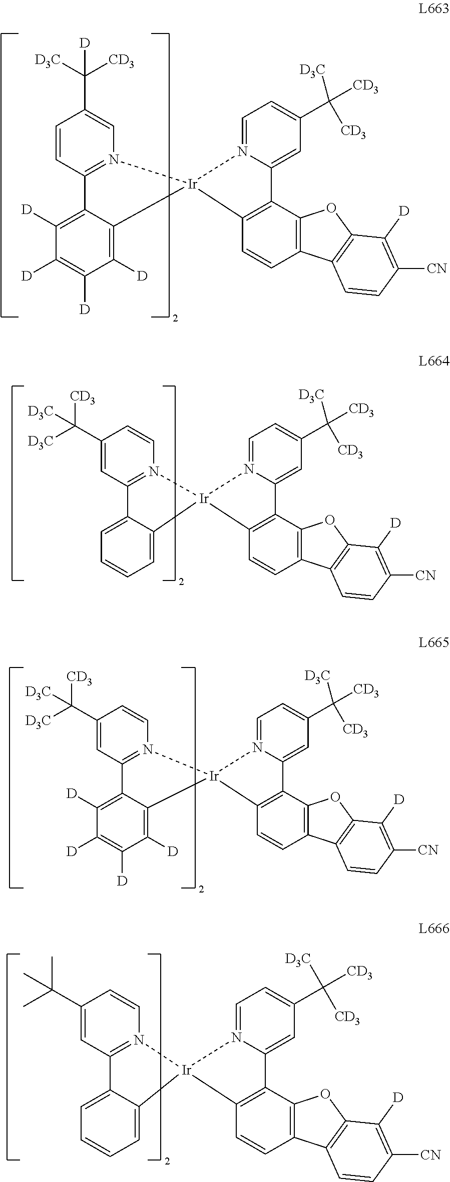

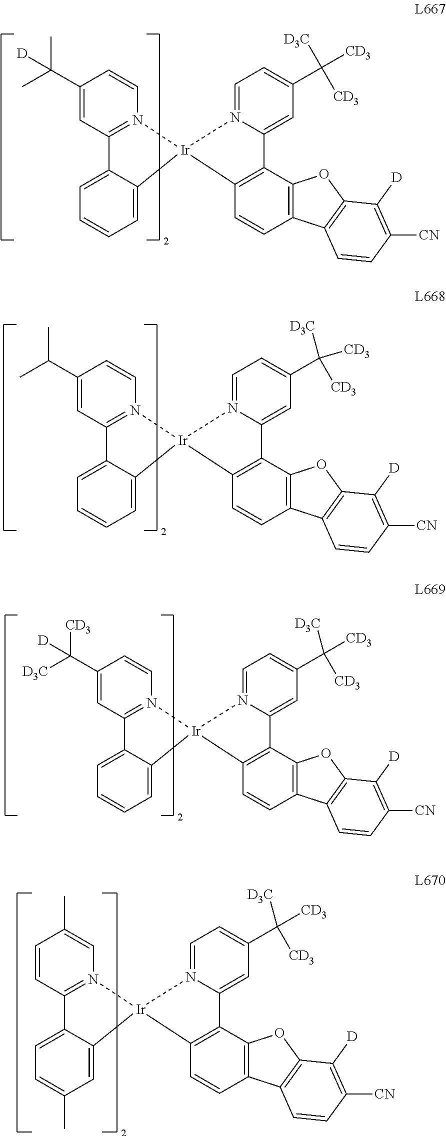

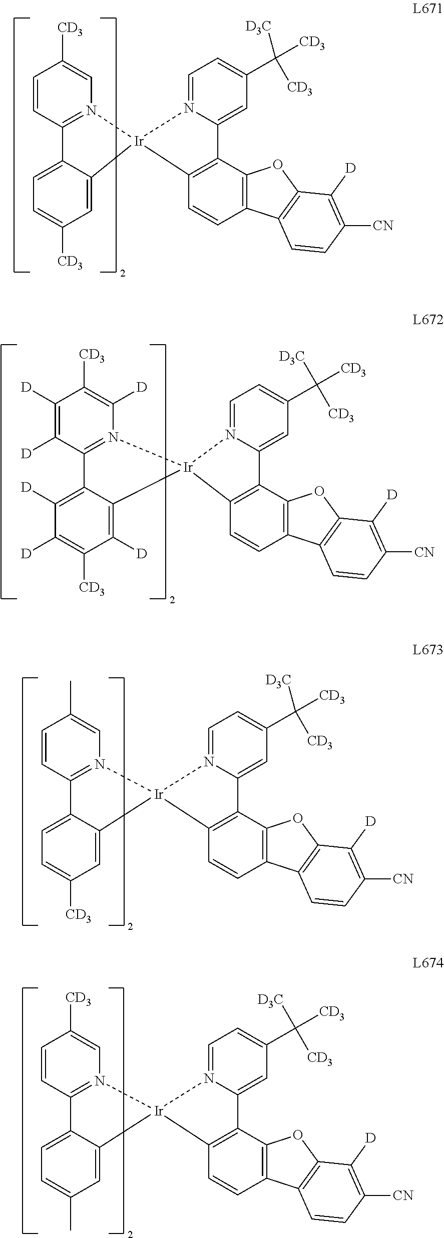

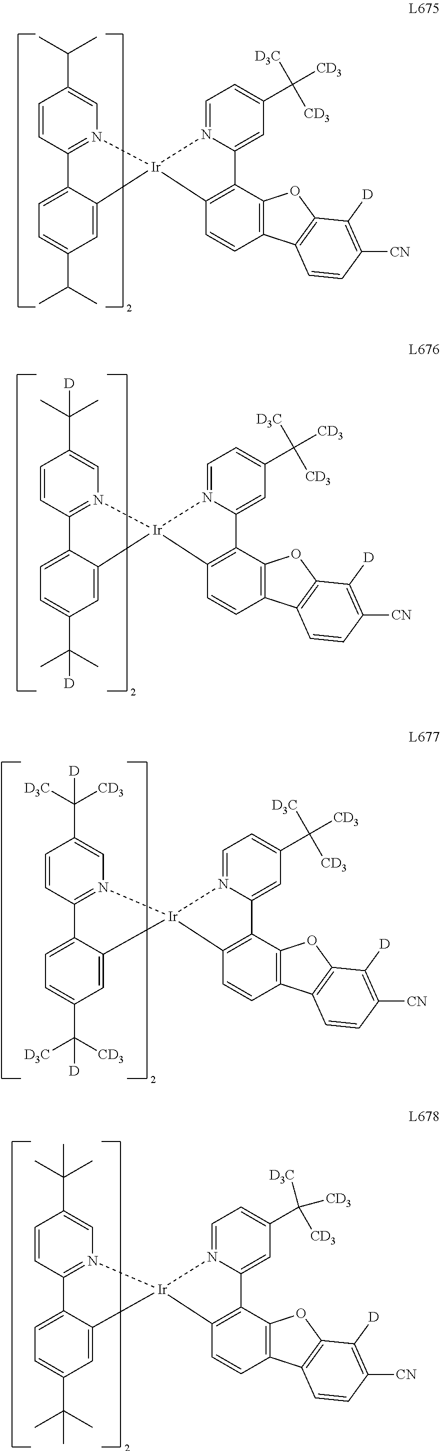

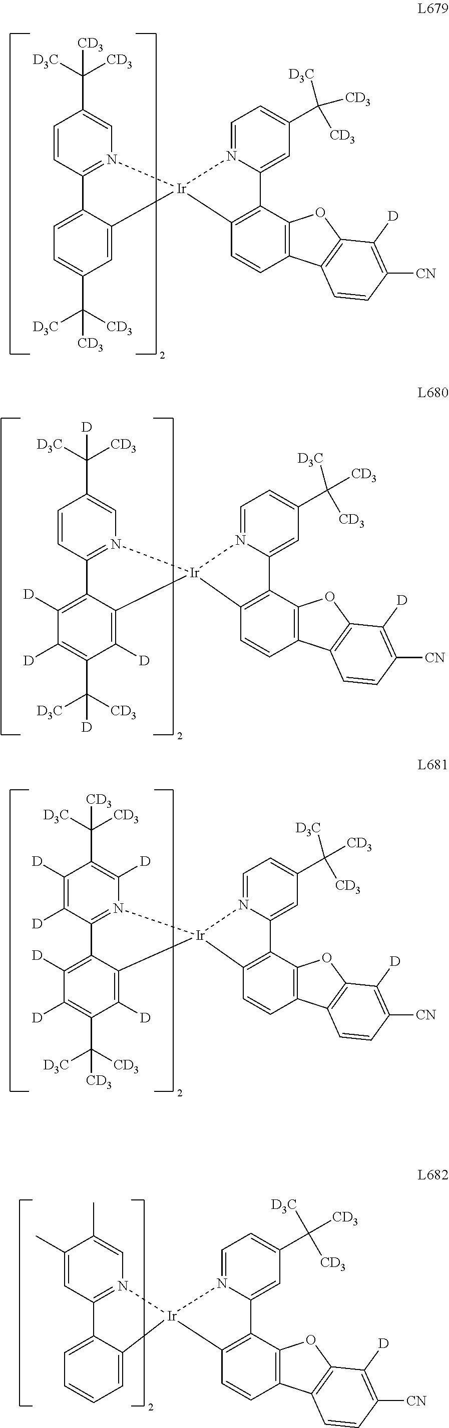

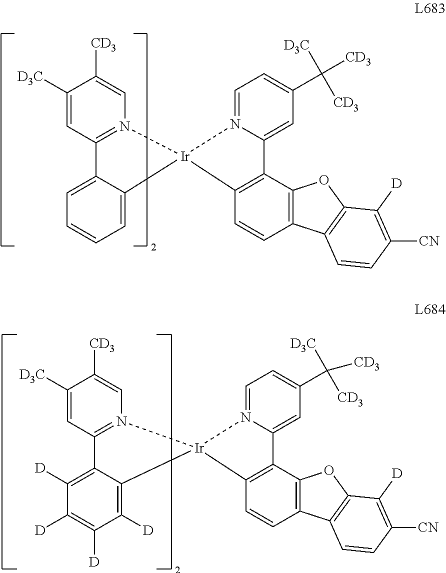

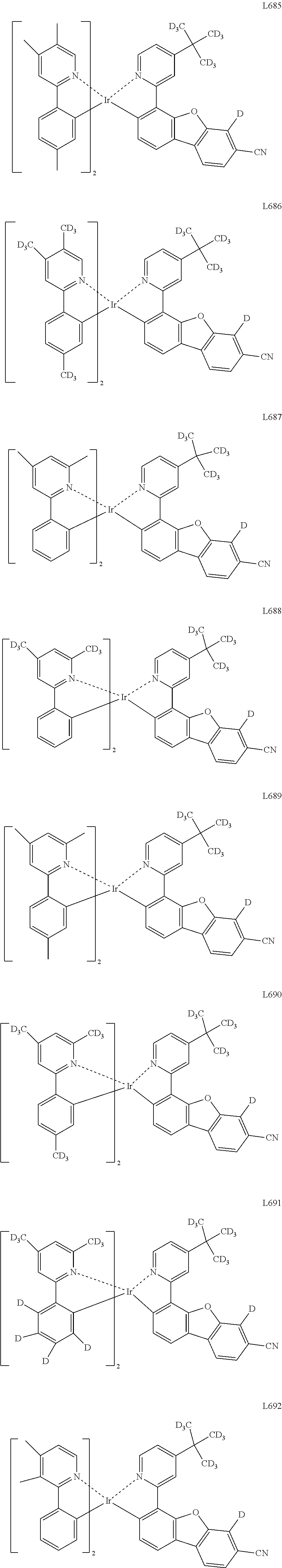

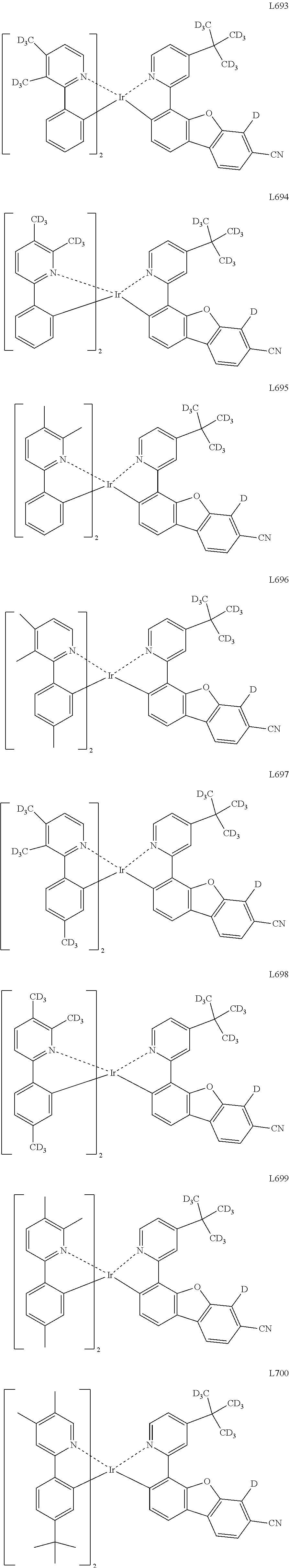

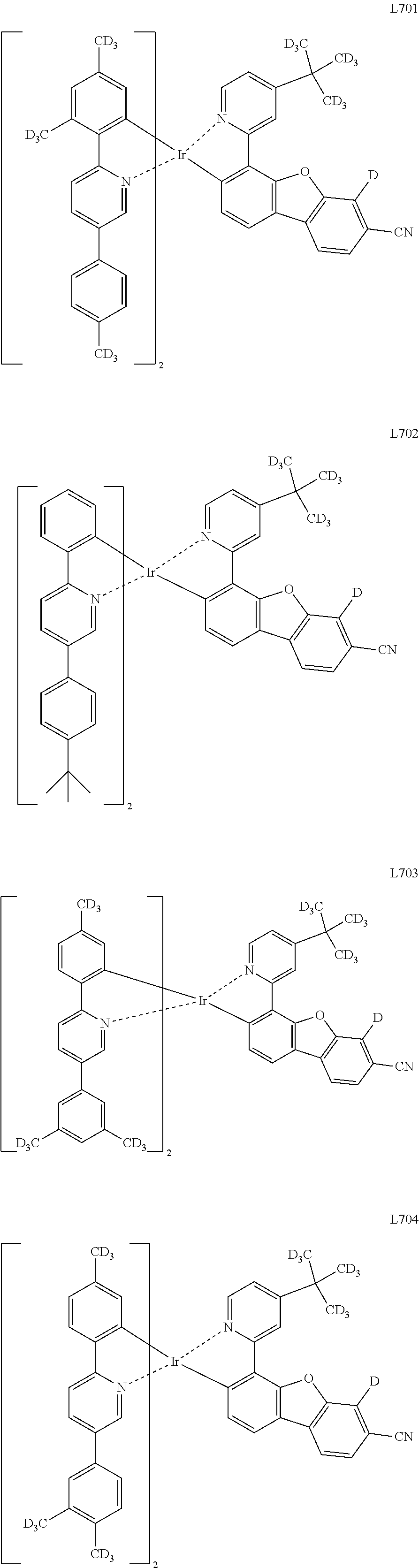

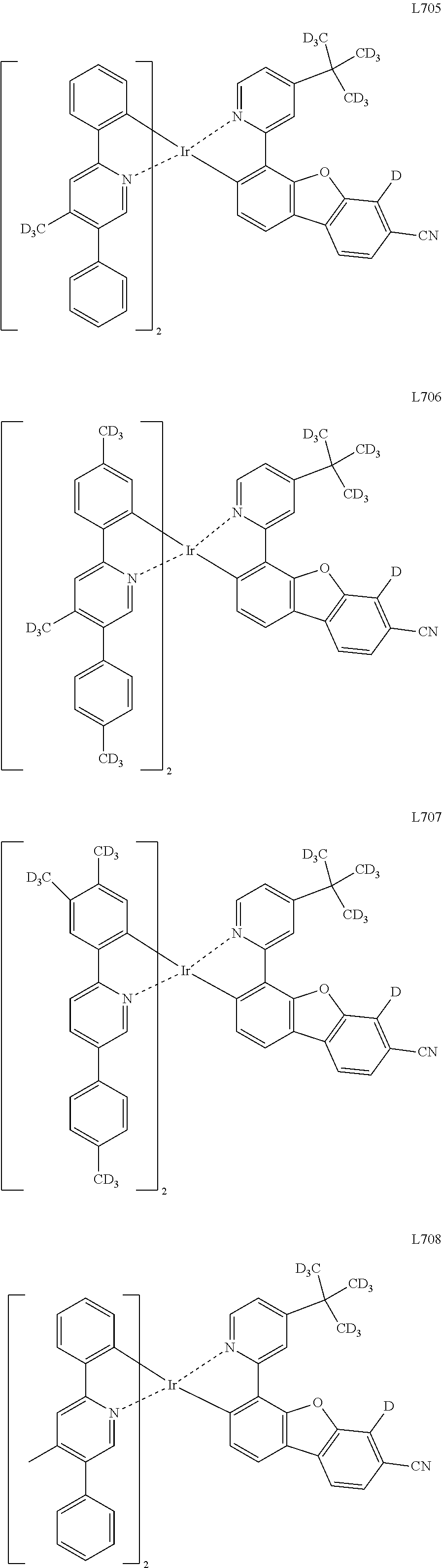

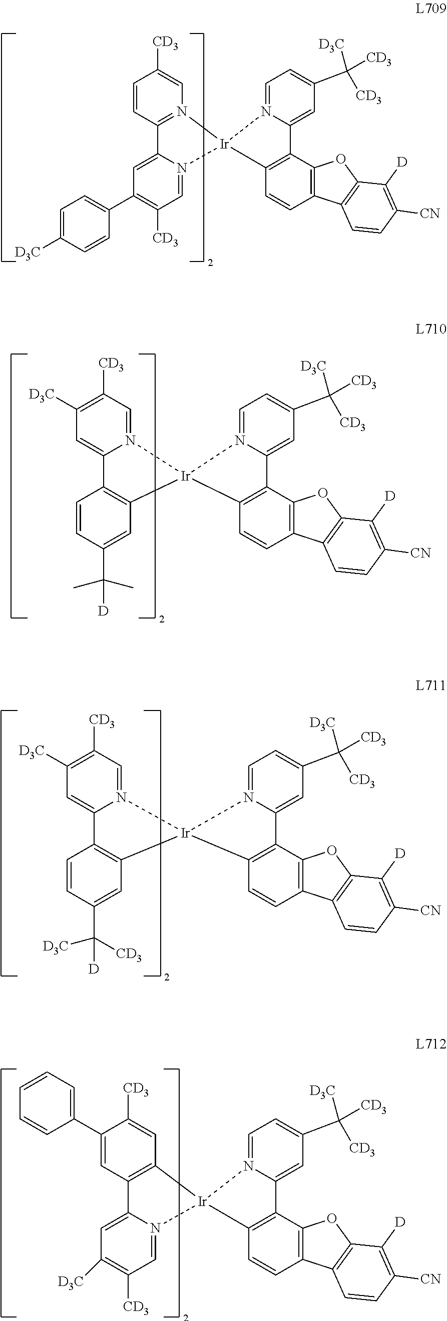

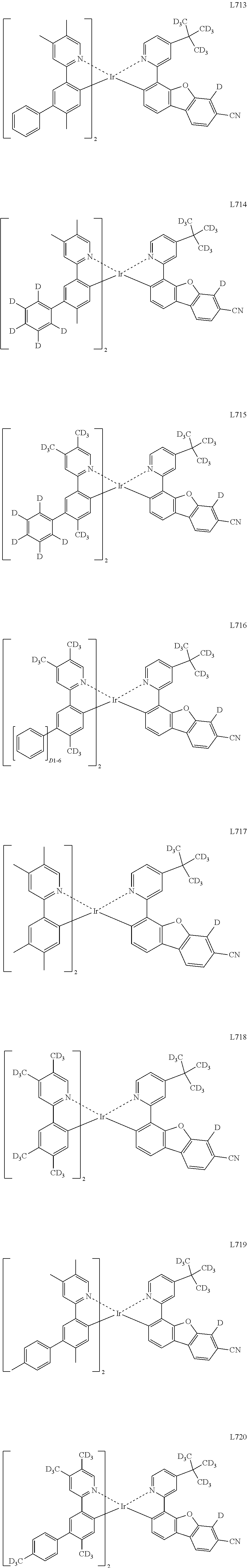

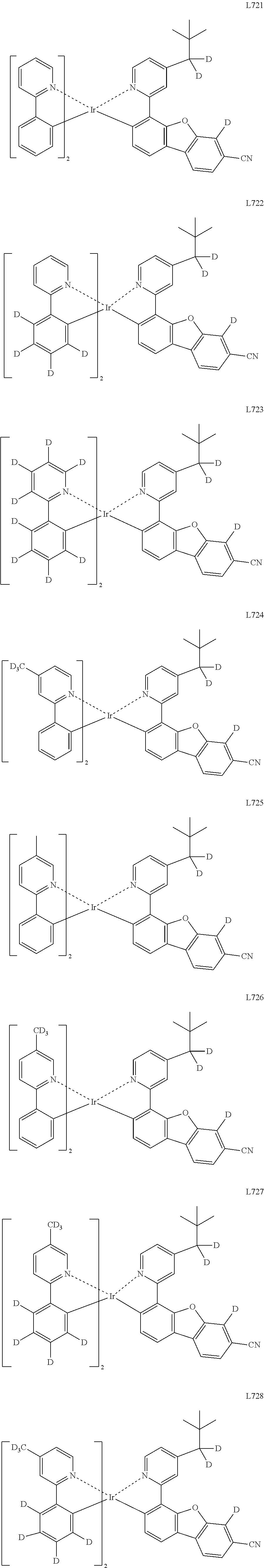

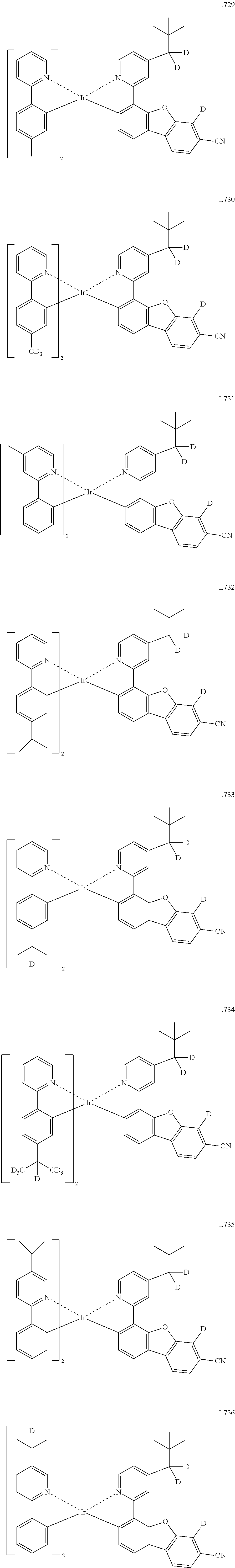

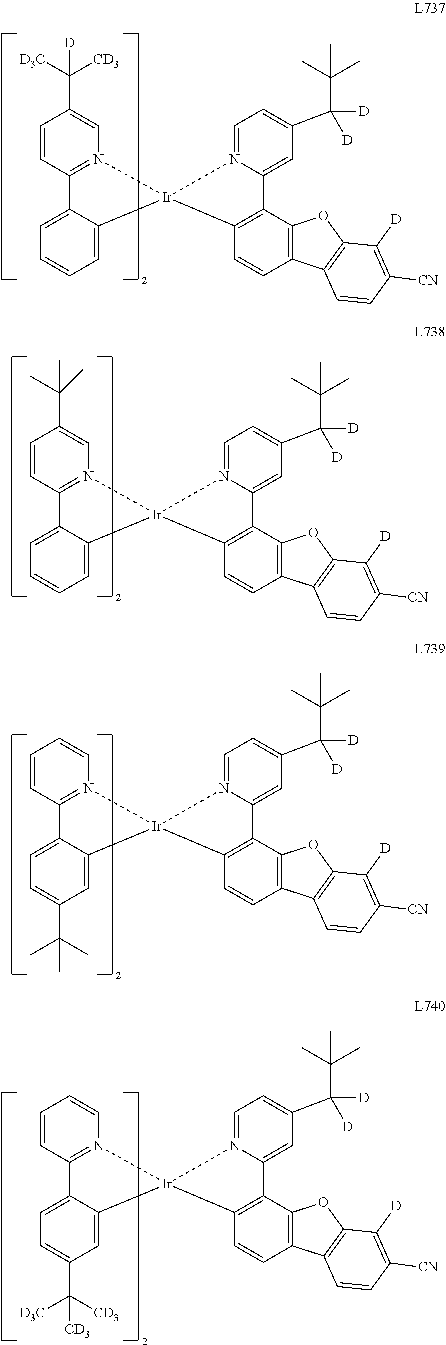

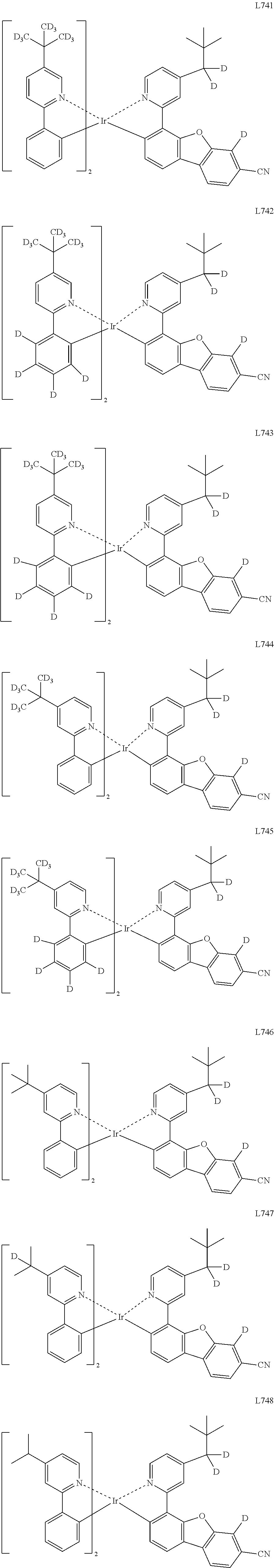

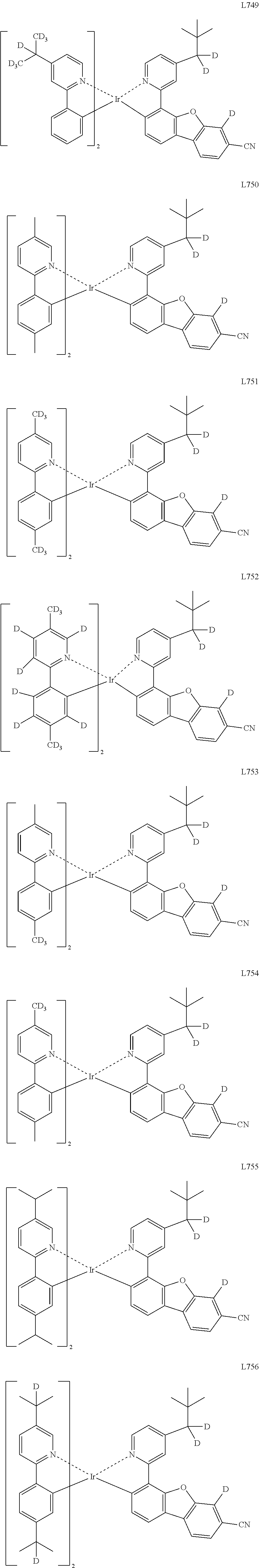

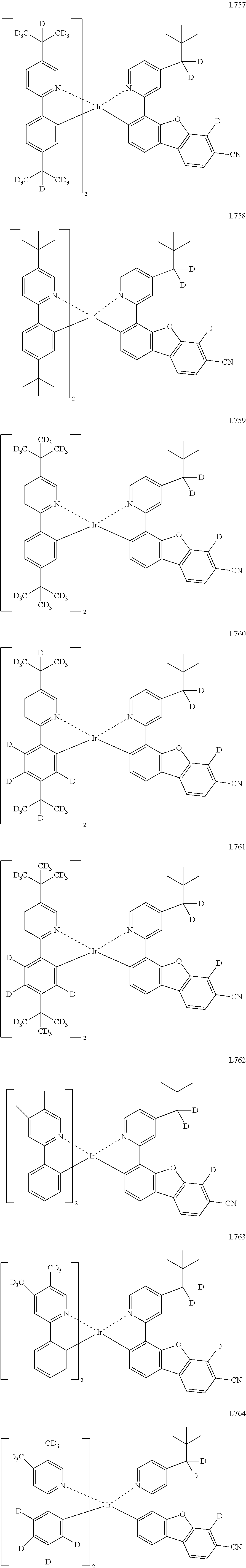

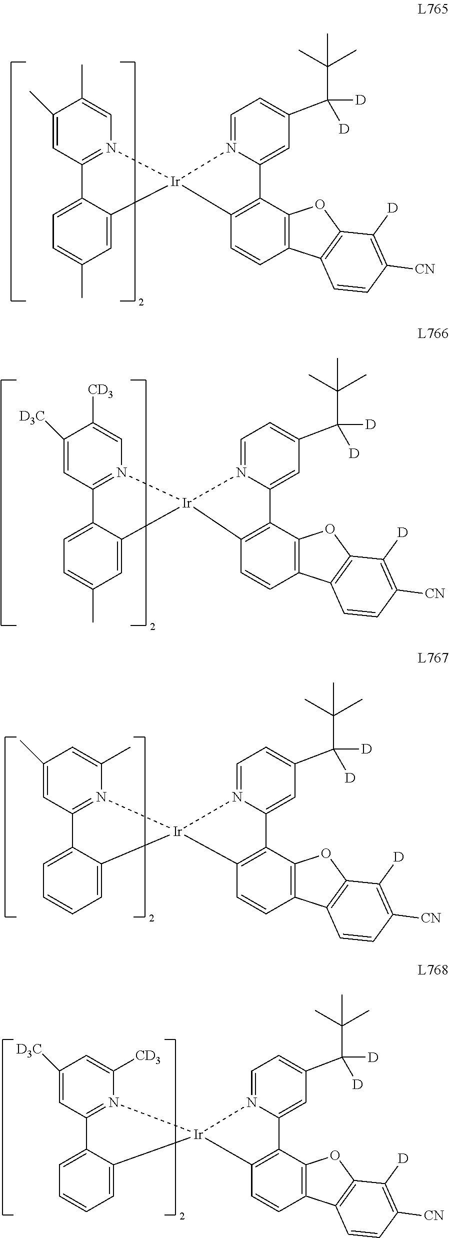

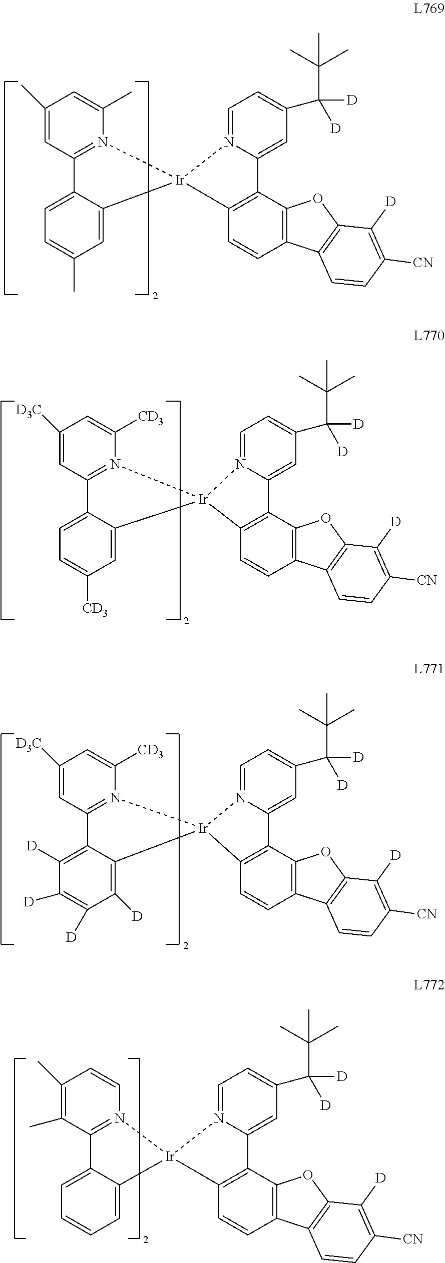

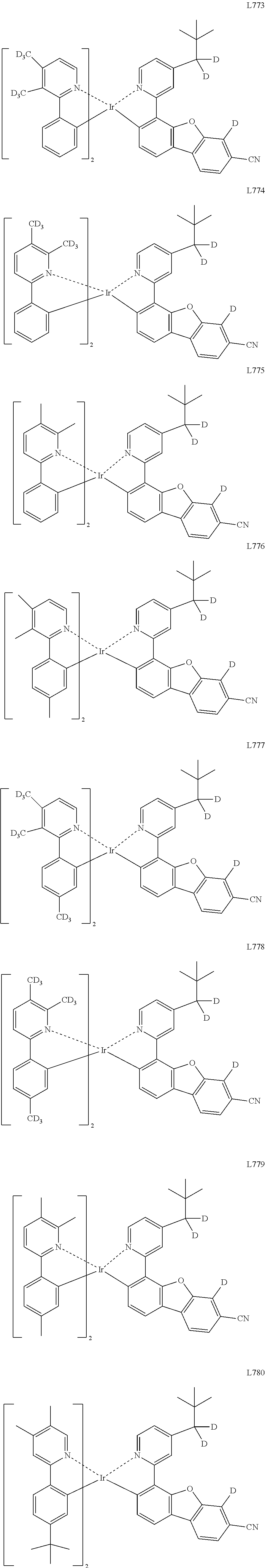

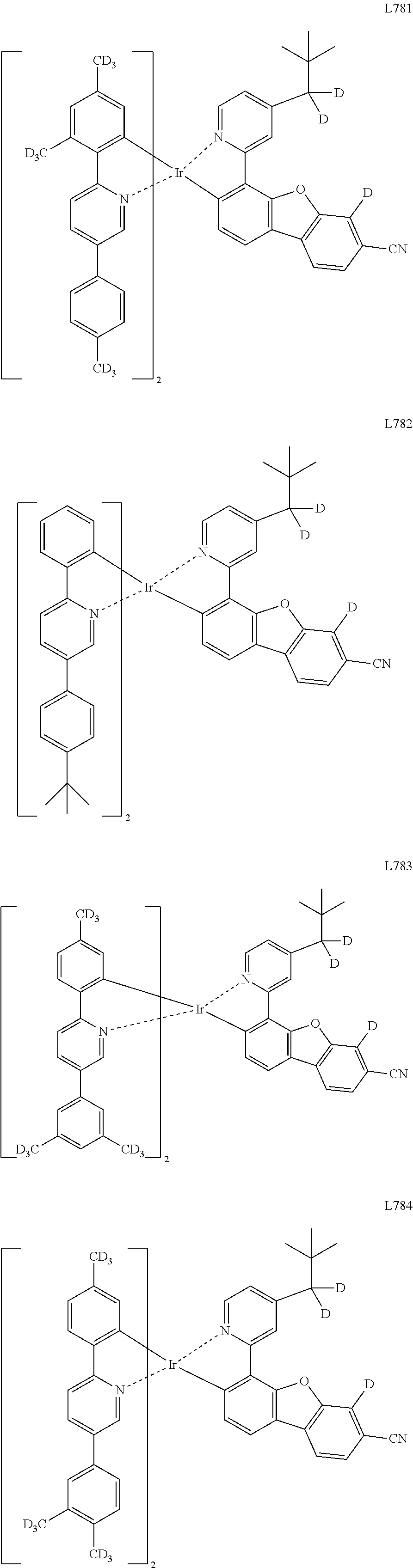

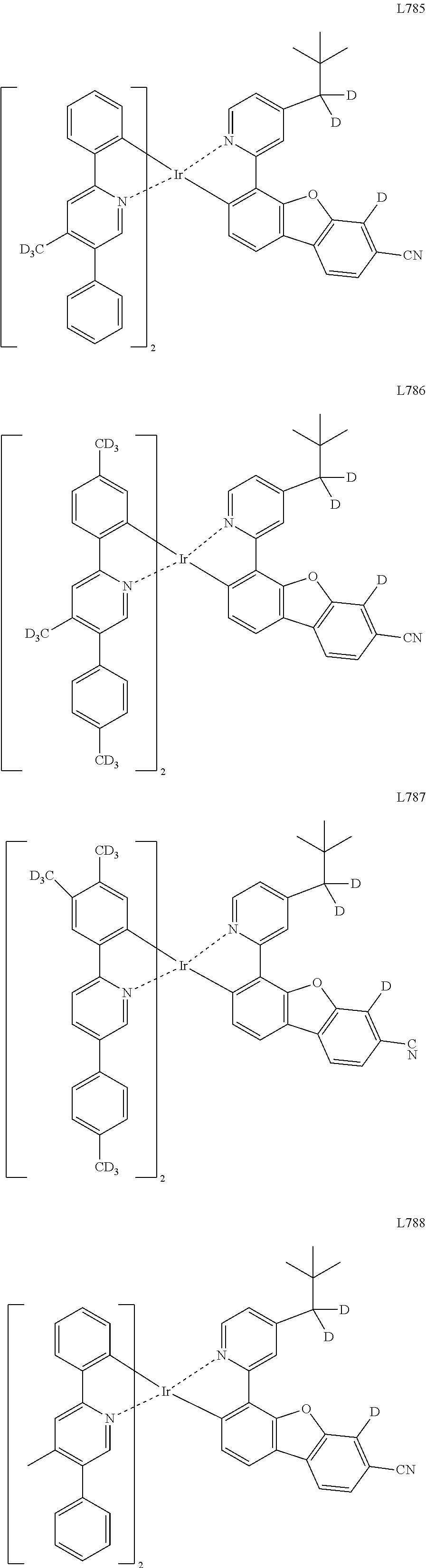

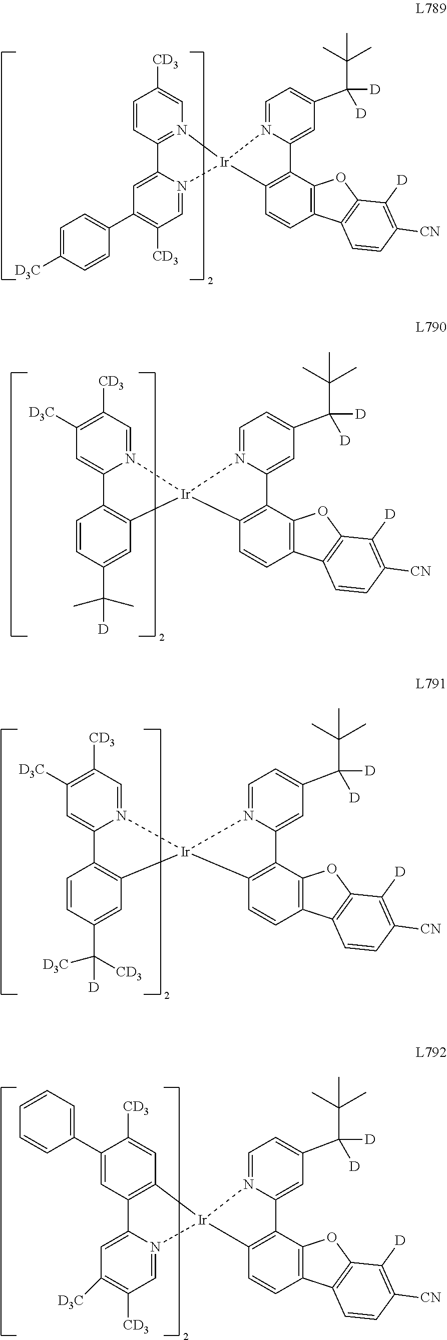

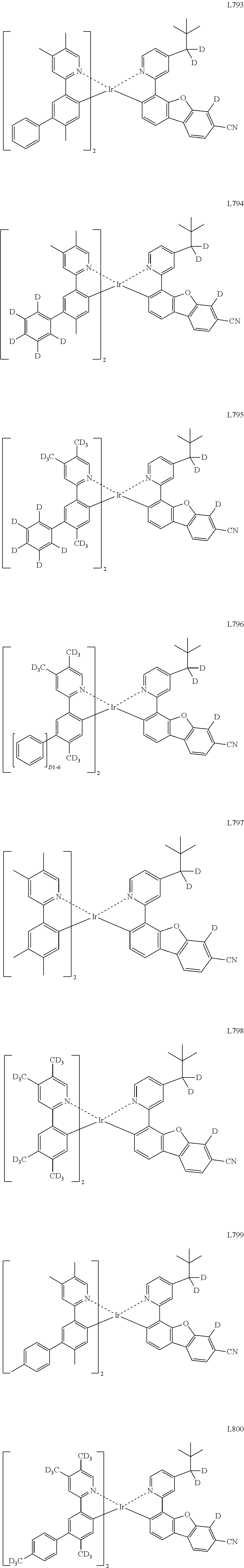

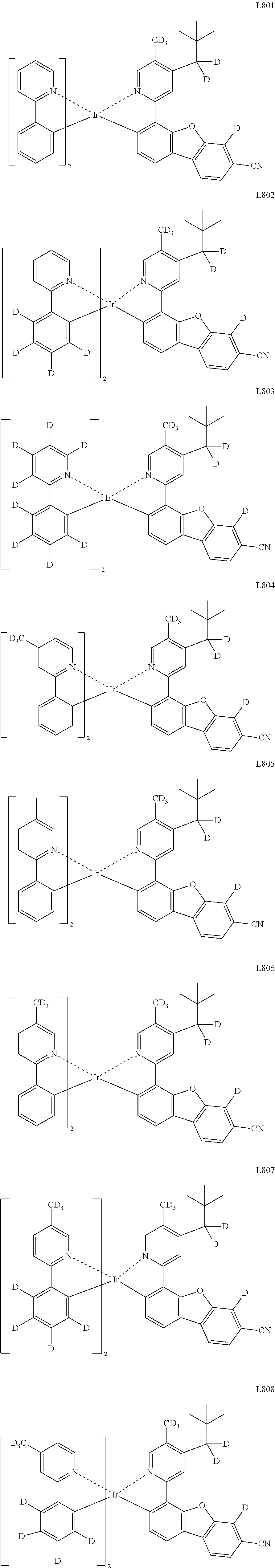

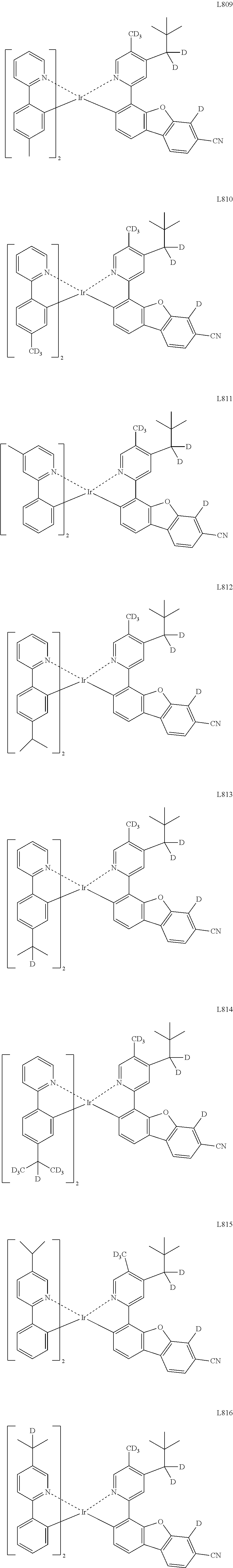

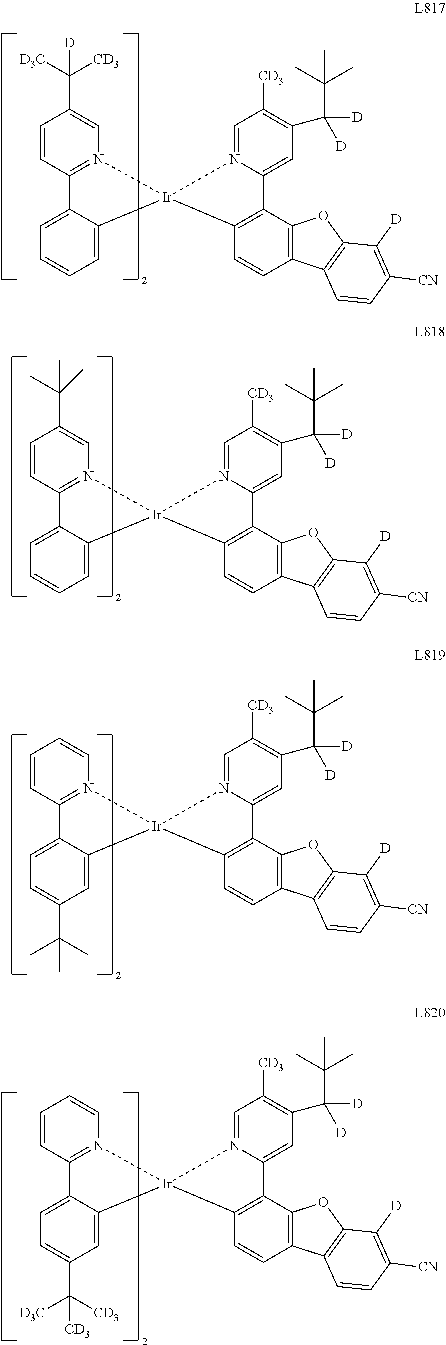

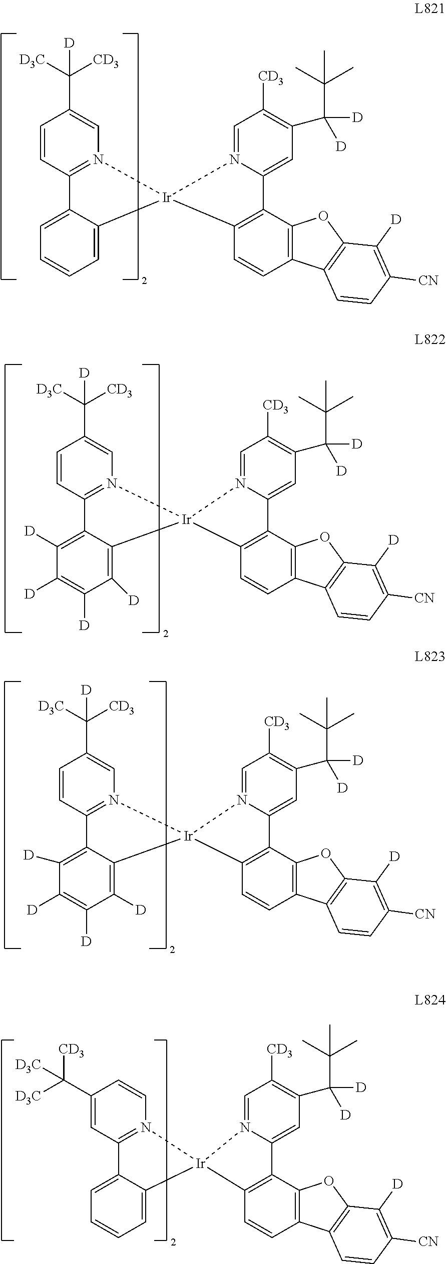

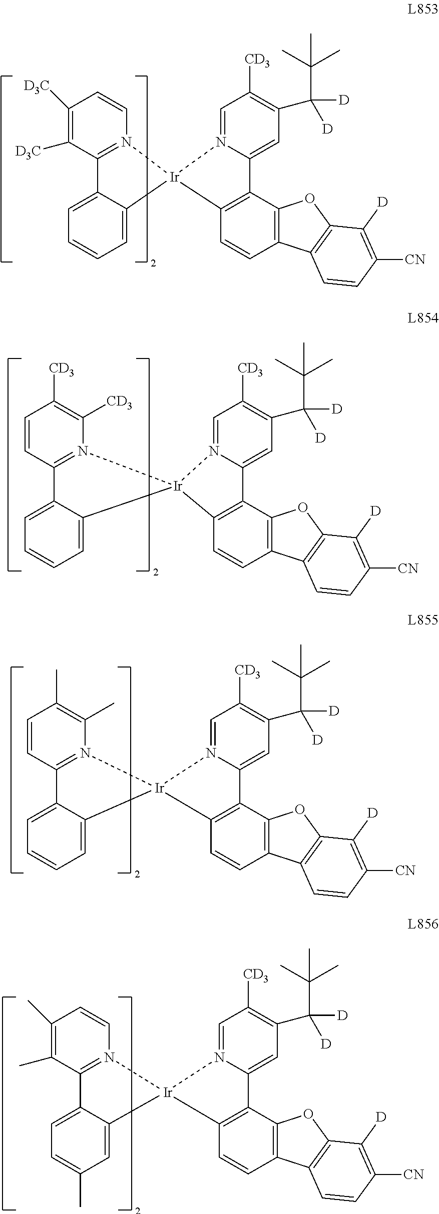

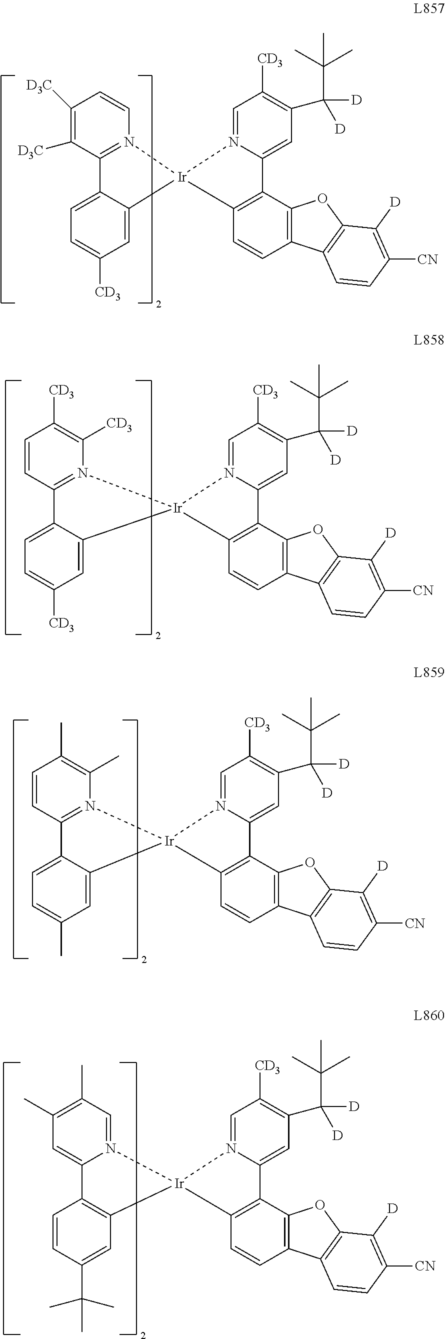

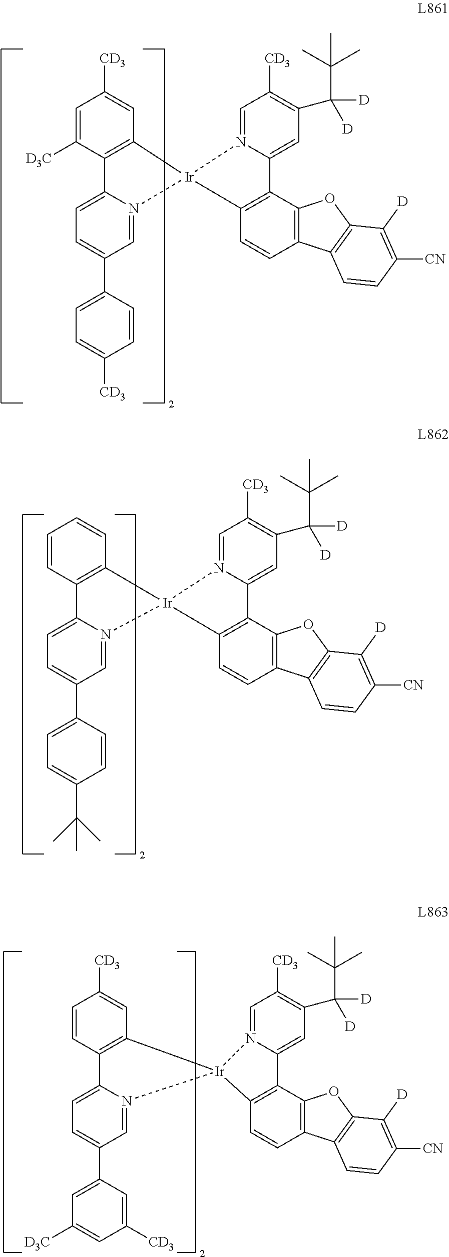

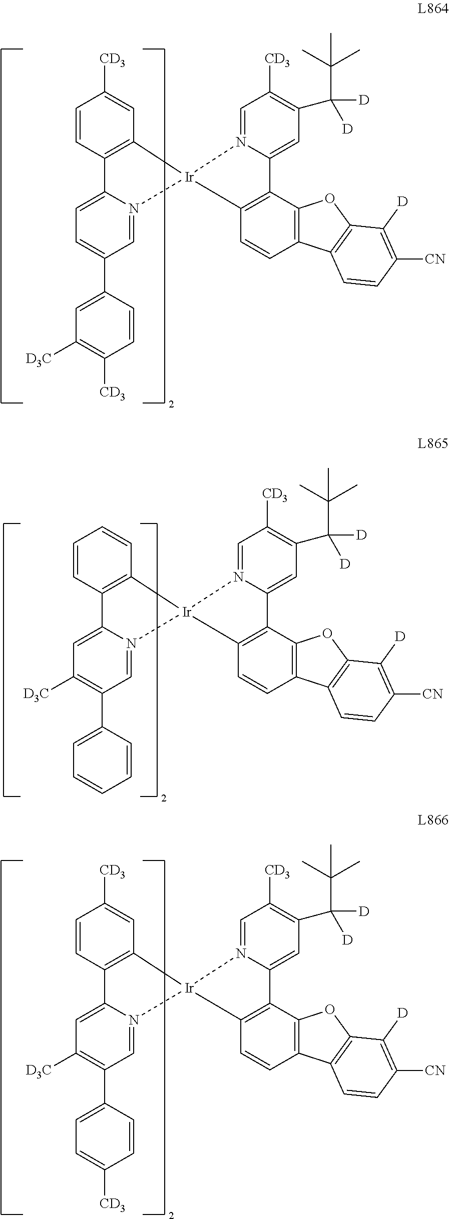

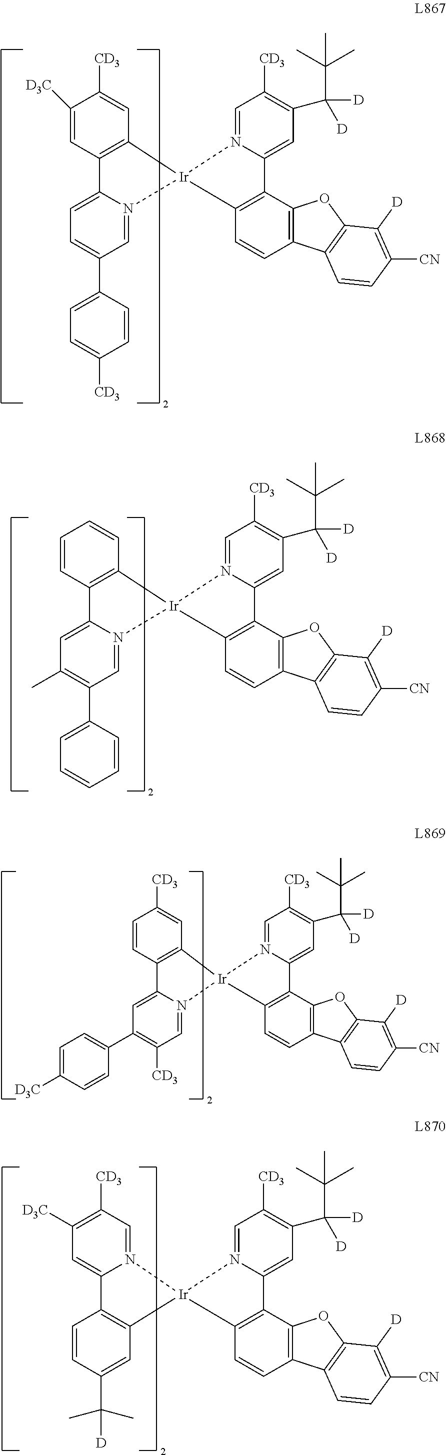

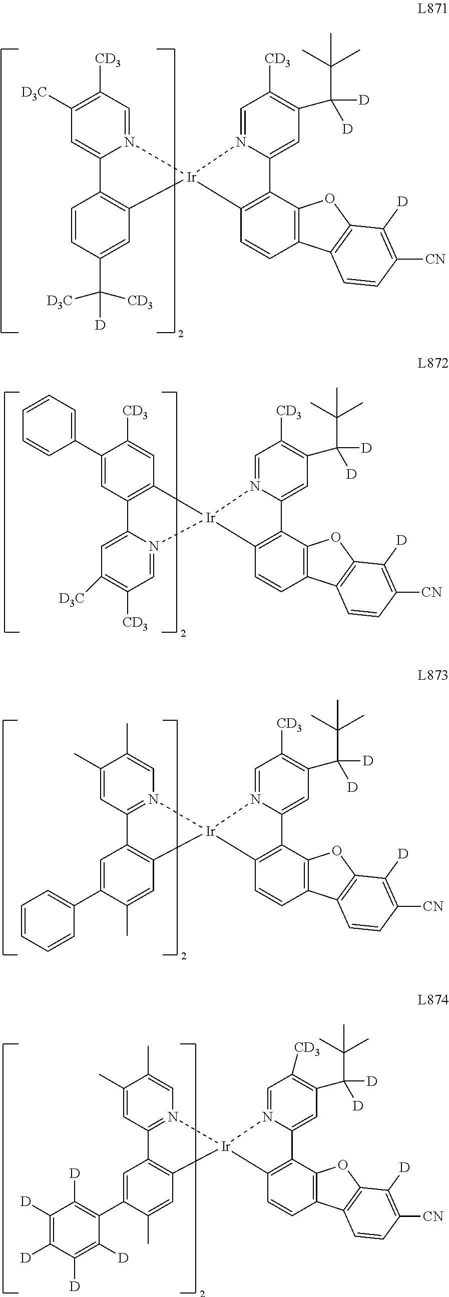

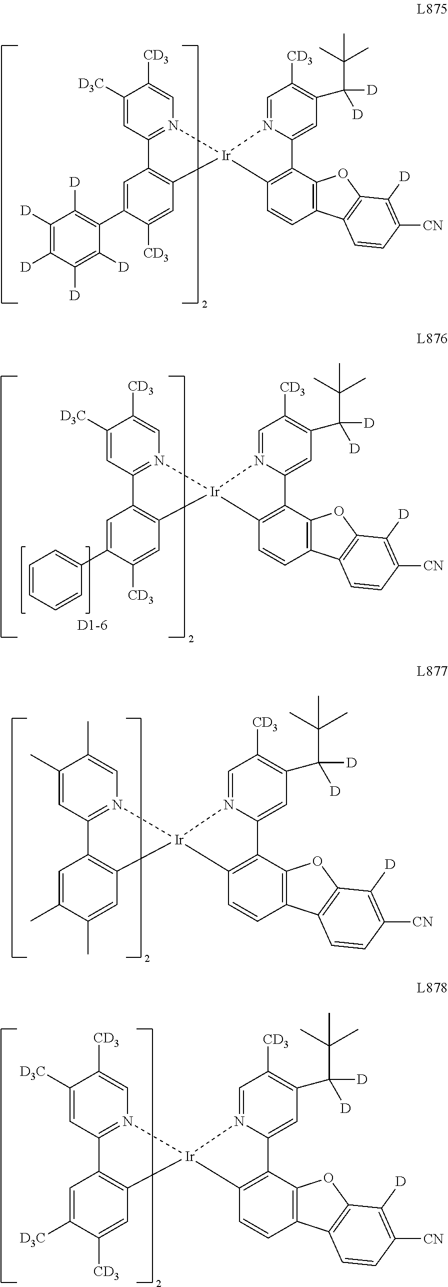

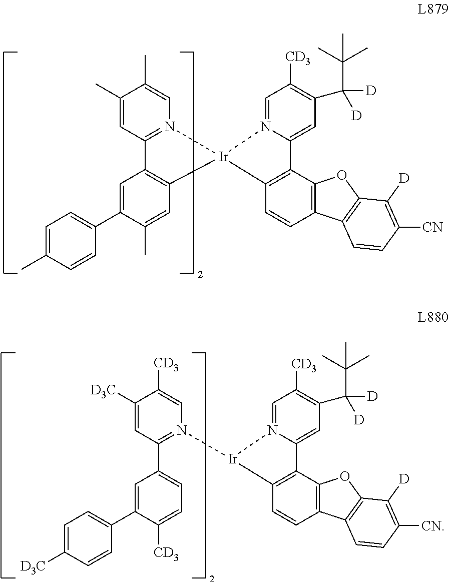

4. An organic electroluminescent device, wherein the organic electroluminescent device comprises an organic layer; the organic layer comprises an organometallic compound as claimed in claim 1.

5. The organic electroluminescent device according to claim 4, wherein the organic electroluminescent device further comprises a first electrode and a second electrode; the organics layer is disposed between the first electrode and the second electrode; and the organics layer comprises a light-emitting layer, the light-emitting layer comprising the organometallic compound.

6. The organic electroluminescent device according to claim 5, wherein the light-emitting layer comprises main material and dopant material; the dopant material comprises the organometallic compound; and the mass ratio of the main material to the dopant material is (10-99.5):0.5.

7. Application of an organic electroluminescent device of claim 4 in the preparation of an organic light-emitting device, an organic solar cell, an electronic paper, an organic photoreceptor or an organic thin-film transistor.
